(19) United States
(12) Patent Application Publication
(10) Pub. No.: US 2017/0179396 A1
(43) Pub. Date: Jun. 22, 2017

(54) ORGANIC LIGHT-EMITTING DEVICE

(71) Applicant: SAMSUNG DISPLAY CO., LTD., Yongin-si (KR)

(72) Inventors: Seulong Kim, Yongin-si (KR); Younsun Kim, Yongin-si (KR); Dongwoo Shin, Yongin-si (KR); Jungsub Lee, Yongin-si (KR); Naoyuki Ito, Yongin-si (KR); Jino Lim, Yongin-si (KR); Hyein Jeong, Yongin-si (KR)

(21) Appl. No.: 15/187,665

(22) Filed: Jun. 20, 2016

(30) Foreign Application Priority Data
Dec. 22, 2015 (KR) 10-2015-0184075

(51) Int. Cl. H01L 51/00; C09K 11/02; H01L 51/50

(52) U.S. Cl. CPC H01L 51/0058; H01L 51/5004; H01L 51/504; C09K 11/025; H01L 51/0054; H01L 51/0072; H01L 51/0067; H01L 51/0071; H01L 51/5012; H01L 51/506; H01L 51/5072; H01L 2251/552; H01L 2251/5384

(57) ABSTRACT

An organic light-emitting device including: a first electrode; a second electrode facing the first electrode; an emission layer between the first electrode and the second electrode; a hole transport region between the first electrode and the emission layer; and an electron transport region between the emission layer and the second electrode, wherein the emission layer includes a first compound represented by one of selected from Formulae 1A to 1E, and at least one selected from the hole transport region and the electron transport region includes a second compound represented by Formula 2A or 2B:

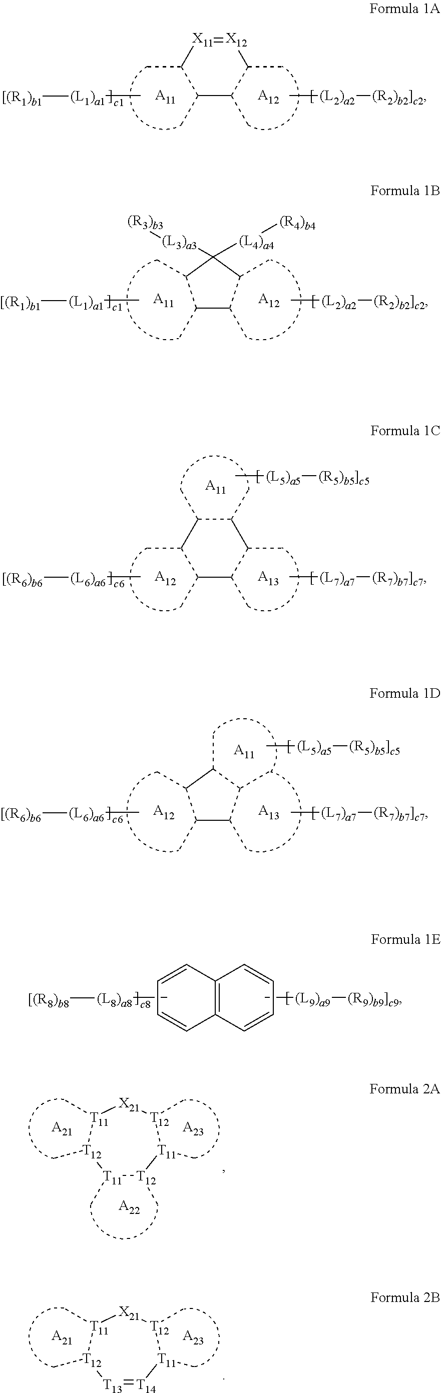

### CROSS-REFERENCE TO RELATED APPLICATION

This application claims priority to and the benefit of Korean Patent Application No. 10-2015-0184075, filed on Dec. 22, 2015 in the Korean Intellectual Property Office, the entire content of which is incorporated herein by reference.

### BACKGROUND

1. Field

One or more aspects of example embodiments of the present disclosure are related to an organic light-emitting device.

2. Description of the Related Art

Organic light emitting devices are self-emission devices that have wide viewing angles, high contrast ratios, short response times, and/or excellent brightness, driving voltage, and/or response speed characteristics compared to devices in the related art.

An example organic light-emitting device may include a first electrode on a substrate, and a hole transport region, an emission layer, an electron transport region, and a second electrode sequentially positioned on the first electrode. Holes provided from the first electrode may move toward the emission layer through the hole transport region, and electrons provided from the second electrode may move toward the emission layer through the electron transport region. Carriers (such as holes and electrons) may recombine in the emission layer to produce excitons. These excitons may transition (e.g., radiatively decay) from an excited state to a ground state to thereby generate light.

### SUMMARY

One or more aspects of example embodiments of the present disclosure are directed toward an organic light-emitting device having a low driving voltage and high efficiency.

Additional aspects will be set forth in part in the description which follows and, in part, will be apparent from the description, or may be learned by practice of the presented embodiments.

One or more example embodiments of the present disclosure provide an organic light-emitting device including:

a first electrode;

a second electrode facing the first electrode;

an emission layer between the first electrode and the second electrode;

a hole transport region between the first electrode and the emission layer; and

an electron transport region between the emission layer and the second electrode, wherein:

the emission layer includes a first compound,

at least one selected from the hole transport region and the electron transport region includes a second compound,

the first compound is represented by one selected from Formulae 1A to 1E, and

the second compound is represented by Formula 2A or 2B:

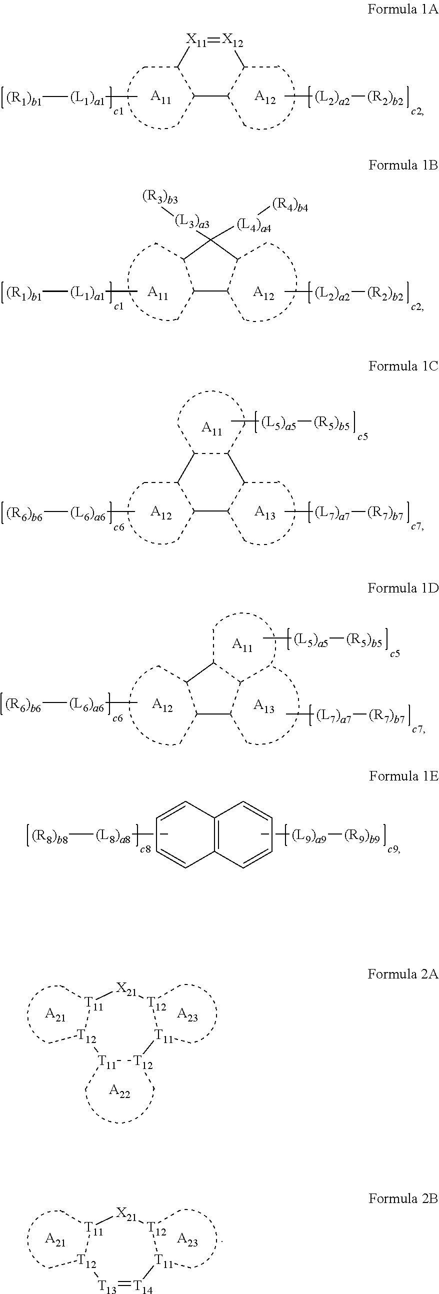

In Formulae 1A to 1E, 2A, and 2B,

rings A₁₁ to A₁₃ may each independently be selected from a C₆-C₆₀ aromatic group, a C₁-C₆₀ heteroaromatic group, and a C₆-C₆₀ non-aromatic condensed polycyclic group,

rings A₂₁, A₂₂, and A₂₃ may each independently be selected from a C₅-C₆₀ carbocyclic group and a C₁-C₆₀ heterocyclic group, each substituted with at least one *-[(L₂₂)ₐ₂₂-(R₂₂)_{b22}],

each T₁₁ and each T₁₂ may independently be selected from carbon (C) and nitrogen (N), two or more of the three T₁₁(s) in Formula 2A may be identical to or different from each other, T₁₃ may be N or C(R₂₇), T₁₄ may be N or C(R₂₈), two or more of the three T₁₂(s) in Formula 2A may be identical to or different from each other, the two T₁₁(s) in Formula 2B may be identical to or different from each other, the two T₁₂(s) in Formula 2B may be identical to or different from each other, and each bond between T₁₁ and T₁₂ may be a single bond or a double bond; wherein the three T₁₁(s) and the three T₁₂(s) in Formula 2A are not all nitrogen, and the two T₁₁(s), the two T₁₂(S), T₁₃, and T₁₄ in Formula 2B are not all nitrogen,

ring A₂₁, A₂₂, and A₂₃ may each be condensed (e.g., fused) with a central 7-membered ring in Formulae 2A and 2B, such that they each share a T₁₁ and a T₁₂ with the central 7-membered ring,

X₁₁ may be N or C[(L₃)ₐ₃-(R₃)_{b3}], and X₁₂ may be N or C[(L₄)ₐ₄-(R₄)_{b4}],

X₂₁ may be selected from oxygen (O), sulfur (S), selenium (Se), C(R₂₃)(R₂₄), Si(R₂₃)(R₂₄), and N[(L₂₁)ₐ₂₁-(R₂₁)_{b21}],

L₁ to L₉ may each independently be selected from a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, and a substituted or unsubstituted divalent non-aromatic condensed polycyclic group,

L₂₁ and L₂₂ may each independently be selected from a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed heteropolycyclic group,

a1 to a9, a21, and a22 may each independently be an integer selected from 0 to 5,

R₁ to R₉ may each independently be selected from hydrogen, deuterium, —F, —Cl, —Br, —I, a hydroxyl group, a cyano group, a nitro group, an amidino group, a hydrazino group, a hydrazono group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, —Si(Q₁)(Q₂)(Q₃), —N(Q₁)(Q₂), —B(Q₁)(Q₂), —C(═O)(Q₁), —S(═O)₂(Q₁), and —P(═O)(Q₁)(Q₂),

R₂₁ to R₂₄, R₂₇, and R₂₈ may each independently be selected from hydrogen, deuterium, —F, —Cl, —Br, —I, a hydroxyl group, a cyano group, a nitro group, an amidino group, a hydrazino group, a hydrazono group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₄)(Q₅)(Q₆), —N(Q₄)(Q₅), —B(Q₄)(Q₅), —C(═O)(Q₄), —S(═O)₂(Q₄), and —P(═O)(Q₄)(Q₅),

b1 to b9, b21, and b22 may each independently be an integer selected from 1 to 3,

c1, c2, and c5 to c7 may each independently be an integer selected from 0 to 10, provided that the sum of c5, c6, and c7 is 1 or more,

c8 and c9 may each independently be an integer selected from 0 to 4, provided that the sum of c8 and c9 is 1 or more,

at least one substituent of the substituted C₃-C₁₀ cycloalkylene group, substituted C₁-C₁₀ heterocycloalkylene group, substituted C₃-C₁₀ cycloalkenylene group, substituted C₁-C₁₀ heterocycloalkenylene group, substituted C₆-C₆₀ arylene group, substituted C₁-C₆₀ heteroarylene group, a substituted divalent non-aromatic condensed polycyclic group, a substituted divalent non-aromatic condensed heteropolycyclic group, substituted C₁-C₆₀ alkyl group, substituted C₂-C₆₀ alkenyl group, substituted C₂-C₆₀ alkynyl group, substituted C₁-C₆₀ alkoxy group, substituted C₃-C₁₀ cycloalkyl group, substituted C₁-C₁₀ heterocycloalkyl group, substituted C₃-C₁₀ cycloalkenyl group, substituted C₁-C₁₀ heterocycloalkenyl group, substituted C₆-C₆₀ aryl group, substituted C₆-C₆₀ aryloxy group, substituted C₆-C₆₀ arylthio group, substituted C₁-C₆₀ heteroaryl group, substituted monovalent non-aromatic condensed polycyclic group, and substituted monovalent non-aromatic condensed heteropolycyclic group may be selected from the group consisting of:

deuterium, —F, —Cl, —Br, —I, a hydroxyl group, a cyano group, a nitro group, an amidino group, a hydrazino group, a hydrazono group, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₂-C₆₀ alkenyl group, a C₂-C₆₀ alkynyl group, and a C₁-C₆₀ alkoxy group, each substituted with at least one selected from deuterium, —F, —Cl, —Br, —I, a hydroxyl group, a cyano group, a nitro group, an amidino group, a hydrazino group, a hydrazono group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), and —P(═O)(Q₁₁)(Q₁₂);

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, a biphenyl group, and a terphenyl group;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group, each substituted with at least one selected from deuterium, —F, —Cl, —Br, —I, a hydroxyl group, a cyano group, a nitro group, an amidino group, a hydrazino group, a hydrazono group, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), and —P(═O)(Q₂₁)(Q₂₂); and

—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), and —P(═O)(Q₃₁)(Q₃₂),

wherein Q₁ to Q₆, Q₁₁ to Q₁₃, Q₂₁ to Q₂₃, and Q₃₁ to Q₃₃ may each independently be selected from hydrogen, deuterium, —F, —Cl, —Br, —I, a hydroxyl group, a cyano group, a nitro group, an amidino group, a hydrazino group, a hydrazono group, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryl group substituted with a C₁-C₆₀ alkyl group, a C₆-C₆₀ aryl group substituted with a C₆-C₆₀ aryl group, a terphenyl group, a C₁-C₆₀ heteroaryl group, a C₁-C₆₀ heteroaryl group substituted with a C₁-C₆₀ alkyl group, a C₁-C₆₀ heteroaryl group substituted with a C₆-C₆₀ aryl group, a monovalent non-aromatic condensed polycyclic group, and a monovalent non-aromatic condensed heteropolycyclic group.

### BRIEF DESCRIPTION OF THE DRAWINGS

These and/or other aspects will become apparent and more readily appreciated from the following description of the example embodiments, taken in conjunction with the accompanying drawings, in which:

FIG. 1 is a schematic view of an organic light-emitting device according to an embodiment of the present disclosure;

FIG. 2 is a schematic view of an organic light-emitting device according to an embodiment of the present disclosure;

FIG. 3 is a schematic view of an organic light-emitting device according to an embodiment of the present disclosure;

FIG. 4 is a schematic view of an organic light-emitting device according to an embodiment of the present disclosure; and

FIG. 5 is a schematic view of an organic light-emitting device according to an embodiment of the present disclosure.

### DETAILED DESCRIPTION

Reference will now be made in more detail to example embodiments, examples of which are illustrated in the accompanying drawings, wherein like reference numerals refer to like elements throughout and duplicative descriptions thereof may not be provided. In this regard, the present embodiments may have different forms and should not be construed as being limited to the descriptions set forth herein. Accordingly, the embodiments are merely described below, by referring to the drawings, to explain aspects of the present description. As used herein, the term “and/or” includes any and all combinations of one or more of the associated listed items. Expressions such as “at least one of”, “one of”, and “selected from”, when preceding a list of elements, modify the entire list of elements and do not modify the individual elements of the list.

The thicknesses of layers, films, panels, regions, etc., may be exaggerated in the drawings for clarity. It will be understood that when an element such as a layer, film, region, or substrate is referred to as being “on” another element, it can be directly on the other element or intervening element(s) may also be present. In contrast, when an element is referred to as being “directly on” another element, no intervening elements are present.

An organic light-emitting device according to an embodiment of the present disclosure includes a first electrode; a second electrode facing the first electrode; an emission layer between the first electrode and the second electrode; a hole transport region between the first electrode and the emission layer; and an electron transport region between the emission layer and the second electrode, wherein the emission layer may include a first compound, and at least one selected from the hole transport region and the electron transport region may include a second compound.

The first compound may be represented by one selected from Formulae 1A to 1E, and the second compound may be represented by Formula 2A or 2B:

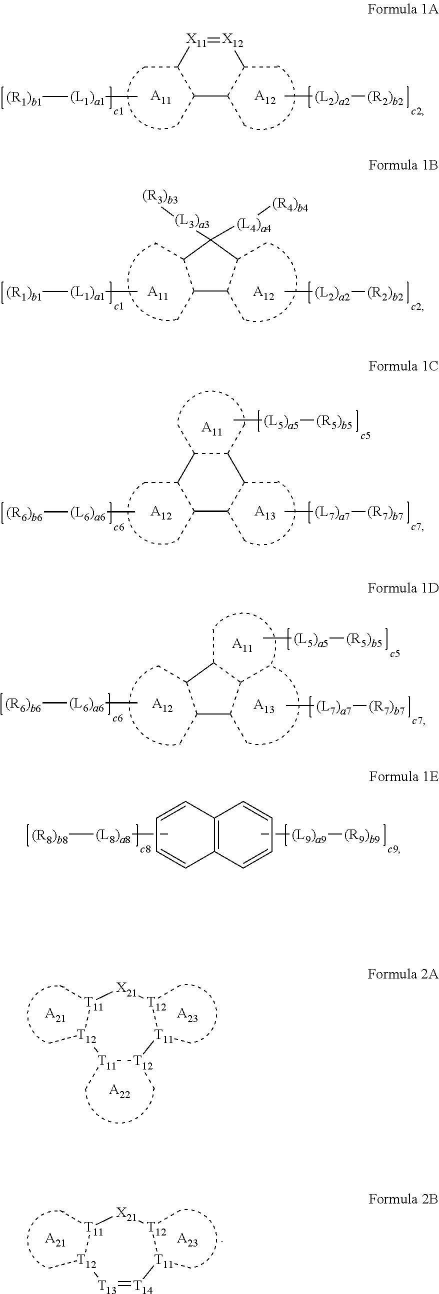

In Formulae 1A to 1D,

rings A₁₁ to A₁₃ may each independently be selected from a C₆-C₆₀ aromatic group, a C₁-C₆₀ heteroaromatic group, and a C₆-C₆₀ non-aromatic condensed polycyclic group.

Rings A₁₁ and A₁₂ in Formula 1A may each be fused with a central 6-membered ring that includes X₁₁ and X₁₂ as ring-forming atoms.

Rings A₁₁ and A₁₂ in Formula 1B may each be fused with a central 5-membered ring.

Rings A₁₁ to A₁₃ in Formula 1C may each be fused with a central 6-membered ring.

Rings A₁₁ to A₁₃ in Formula 1D may each be fused with a central 5-membered ring.

For example, rings A₁₁ to A₁₃ in Formula 1A to 1D may each independently be selected from a benzene group, a naphthalene group, an anthracene group, a phenanthrene group, a pyrene group, a triphenylene group, an indene group, a fluorene group, a benzofluorene group, a spiro-bifluorene group, a pyridine group, a pyrazine group, a pyrimidine group, a pyridazine group, a pyrrole group, an imidazole group, a quinoline group, an isoquinoline group, a quinoxaline group, a quinazoline group, a triazine group, an indenopyrazine group, an indenopyridine group, a phenanthroline group, and a phenanthridine group.

In one or more embodiments, rings A₁₁ to A₁₃ in Formulae 1A to 1D may each independently be selected from a benzene group, a naphthalene group, a phenanthrene group, a triphenylene group, a pyridine group, a pyridazine group, a pyrimidine group, a pyrazine group, an indenopyrazine group, an indenopyridine group, a fluorene group, and an indene group, but embodiments of the present disclosure are not limited thereto.

Rings A₂₁, A₂₂, and A₂₃ in Formulae 2A and 2B may each independently be selected from a C₅-C₆₀ carbocyclic group and a C₁-C₆₀ heterocyclic group, each substituted with at least one *-[(L₂₂)ₐ₂₂-(R₂₂)_{b22}]. L₂₂, a22, R₂₂, and b22 will be described in detail below.

Each T₁₁ and each T₁₂ in Formulae 2A and 2B may independently be selected from carbon (C) and nitrogen (N), two or more of the three T₁₁(s) in Formula 2A may be identical to or different from each other, T₁₃ may be N or C(R₂₇), T₁₄ may be N or C(R₂₈), two or more of the three T₁₂(s) in Formula 2A may be identical to or different from each other, the two T₁₁(s) in Formula 2B may be identical to or different from each other, the two T₁₂(s) in Formula 2B may be identical to or different from each other, and each bond between T₁₁ and T₁₂ may be a single bond or a double bond; wherein the three T₁₁(s) and the three T₁₂(s) in Formula 2A are not all nitrogen, and the two T₁₁(s), the two T₁₂(S), T₁₃, and T₁₄ in Formula 2B are not all nitrogen. Rings A₂₁, A₂₂, and A₂₃ may each be condensed (e.g., fused) with a central 7-membered ring in Formulae 2A and 2B, such that they each share a T₁₁ and a T₁₂ with the central 7-membered ring.

Each *-[(L₂₂)ₐ₂₂-(R₂₂)_{b22}] in ring A₂₁, *-[(L₂₂)ₐ₂₂-(R₂₂)_{b22}] in ring A₂₂, and *-[(L₂₂)ₐ₂₂-(R₂₂)_{b22}] in ring A₂₃ may be identical to or different from each other.

In one or more embodiments, when the number of *-[(L₂₂)ₐ₂₂-(R₂₂)_{b22}](s) in ring A₂₁ is two or more, the two or more *-[(L₂₂)ₐ₂₂-(R₂₂)_{b22}](s) may be identical to or different from each other; when the number of *-[(L₂₂)ₐ₂₂-(R₂₂)_{b22}](s) in ring A₂₂ is two or more, the two or more *-[(L₂₂)ₐ₂₂-(R₂₂)_{b22}](s) may be identical to or different from each other; and when the number of *-[(L₂₂)ₐ₂₂-(R₂₂)_{b22}](s) in ring A₂₃ is two or more, the two or more *-[(L₂₂)ₐ₂₂-(R₂₂)_{b22}](s) may be identical to or different from each other.

In one embodiment, rings A₂₁, A₂₂, and A₂₃ in Formulae 2A and 2B may each independently be selected from a benzene group, a naphthalene group, an anthracene group, an indene group, a fluorene group, a pyridine group, a pyrimidine group, a pyrazine group, a pyridazine group, a quinoline group, an isoquinoline group, a pyrrole group, a pyrazole group, an imidazole group, an oxazole group, a thiazole group, a cyclopentadiene group, a silole group, a selenophene group, a furan group, a thiophene group, an indole group, a benzimidazole group, a benzoxazole group, a benzothiazole group, an indene group, a benzosilole group, a benzoselenophene group, a benzofuran group, a benzothiophene group, a carbazole group, a fluorene group, a dibenzosilole group, a dibenzoselenophene group, a dibenzofuran group, a dibenzothiophene group, a pyrrolopyridine group, a cyclopentapyridine group, a silolopyridine group, a selenophenopyridine group, a furopyridine group, a thienopyridine group, a pyrrolopyrimidine group, a cyclopentapyrimidine group, a silolopyrimidine group, a selenophenopyrimidine group, a furopyrimidine group, a thienopyrimidine group, a pyrrolopyrazine group, a cyclopentapyrazine group, a silolopyrazine group, a selenophenopyrazine group, a furopyrazine group, a thienopyrazine group, a naphthopyrrole group, a cyclopentanaphthalene group, a naphthosilole group, a naphthoselenothiophene group, a naphthofuran group, a naphthothiophene group, a pyrroloquinoline group, a cyclopentaquinoline group, a siloloquinoline group, a selenophenoquinoline group, a furoquinoline group, a thienoquinoline group, a pyrroloisoquinoline group, a cyclopentaisoquinoline group, a siloloisoquinoline group, a selenophenoisoquinoline group, a furoisoquinoline group, a thienoisoquinoline group, an azacarbazole group, an azafluorene group, an azadibenzosilole group, an azadibenzoselenophene group, an azadibenzofuran group, an azadibenzothiophene group, an indenoquinoline group, an indenoisoquinoline group, an indenoquinoxaline group, a phenanthroline group, and an naphthoindole group, each substituted with at least one *-[(L₂₂)ₐ₂₂-(R₂₂)_{b22}].

In one or more embodiments, the case in which rings A₂₁, A₂₂, and A₂₃ in the second compound represented by Formula 2A or 2B are all (e.g., simultaneously) benzene groups, each substituted with at least one *-[(L₂₂)ₐ₂₂-(R₂₂)_{b22}], is excluded.

In one or more embodiments, rings A₂₁, A₂₂, and A₂₃ in Formulae 2A and 2B may each independently be selected from groups represented by Formulae 2-1 to 2-36, each substituted with at least one *-[(L₂₂)ₐ₂₂-(R₂₂)_{b22}]:

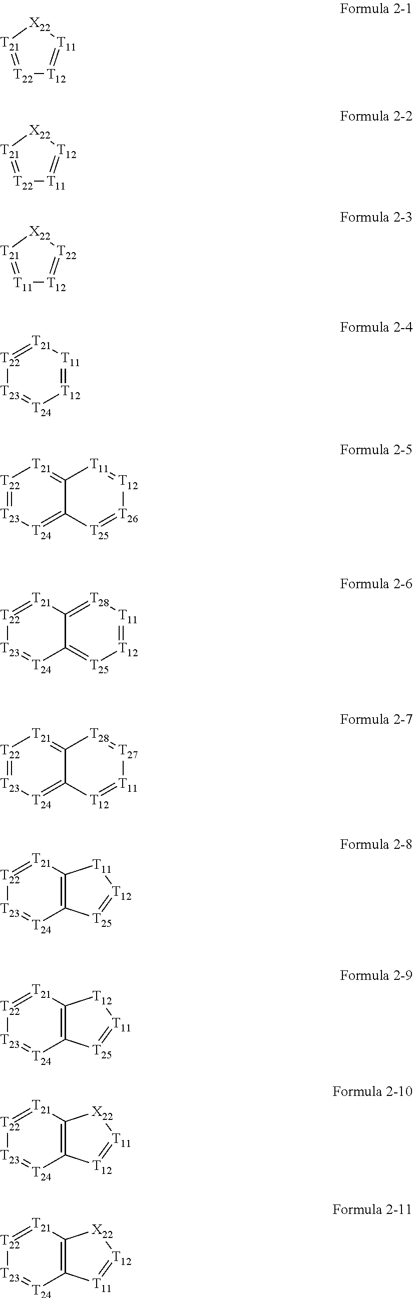

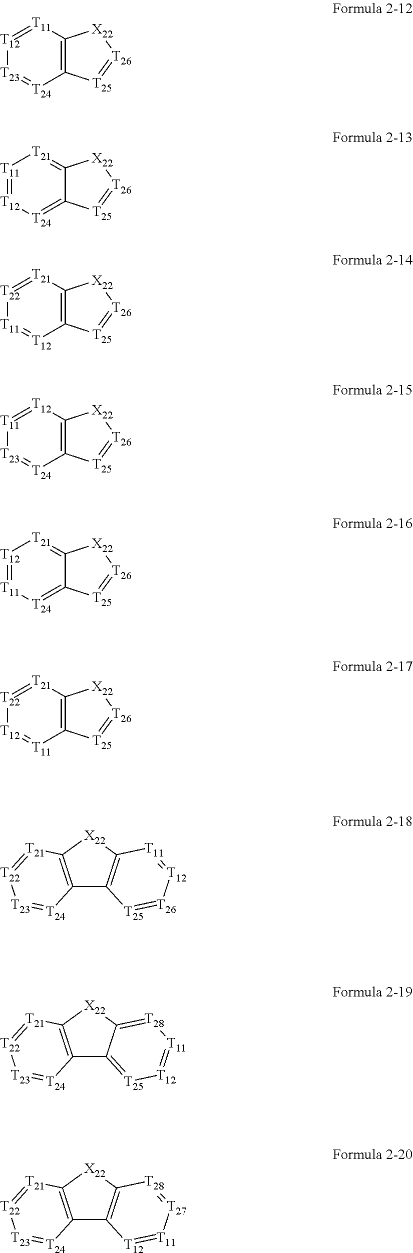

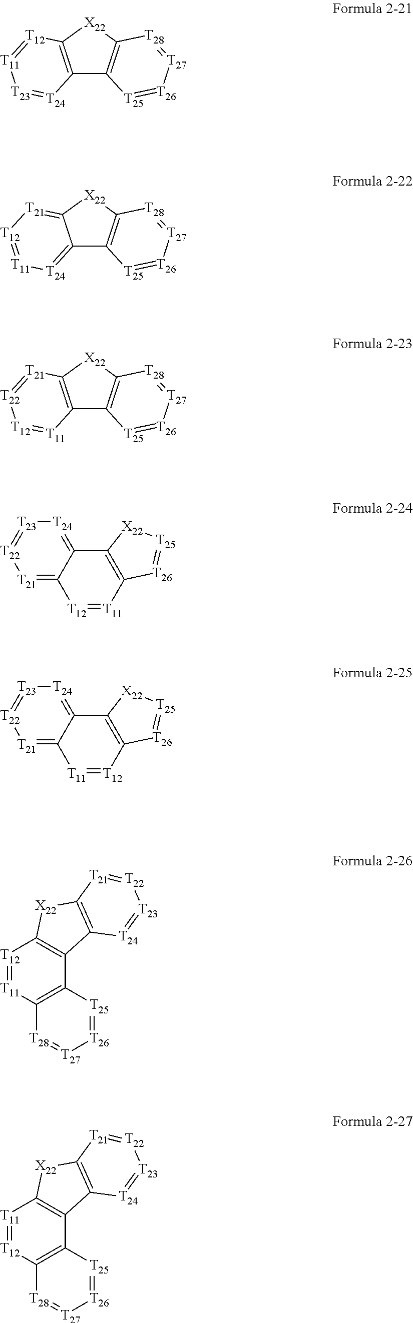

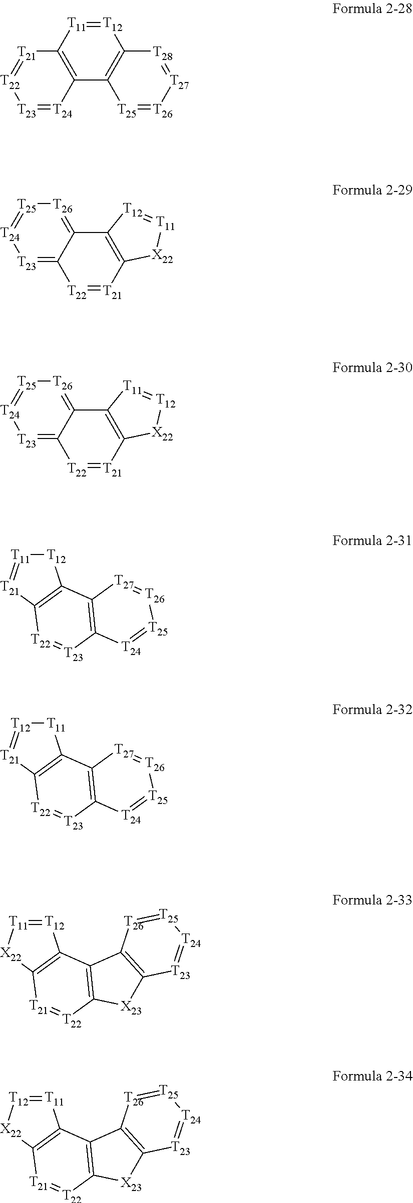

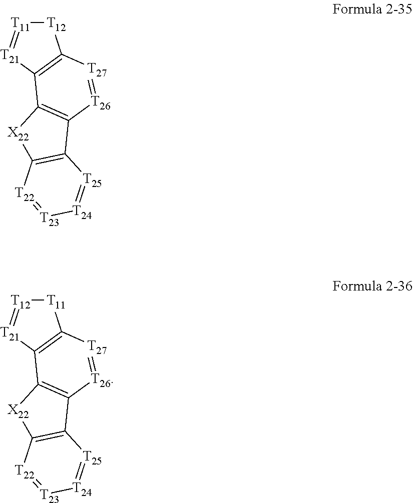

In Formulae 2-1 to 2-36,

T₁₁ and T₁₂ may each independently be the same as described herein in connection with Formulae 2A and 2B,

X₂₂ and X₂₃ may each independently be selected from oxygen (O), sulfur (S), selenium (Se), a moiety including C, a moiety including N, and a moiety including Si,

T₂₁ to T₂₈ may each independently be selected from N and a moiety including C.

When rings A₂₁ to A₂₃ include both X₂₂ and X₂₃, X₂₂ and X₂₃ may be identical to or different from each other.

For example, in Formulae 2-1 to 2-36, X₂₂ and X₂₃ may each independently be selected from O, S, Se, C(R₂₅)(R₂₆), N-[(L₂₂)ₐ₂₂-(R₂₂)_{b22}], and Si(R₂₅)(R₂₆), and T₂₁ to T₂₈ may each independently be selected from N and C-[(L₂₂)ₐ₂₂-(R₂₂)_{b22}]. R₂₅ and R₂₆ may each independently be selected from groups represented by *-[(L₂₂)ₐ₂₂-(R₂₂)_{b22})].

For example, X₂₂ and X₂₃ in Formulae 2-1 to 2-36 may each independently be selected from O, S, Se, C(R₂₅)(R₂₆), N-[(L₂₂)ₐ₂₂-(R₂₂)_{b22}], and Si(R₂₅)(R₂₆), and T₂₁ to T₂₈ may each independently be selected from N and C-[(L₂₂)ₐ₂₂-(R₂₂)_{b22}]. R₂₅ and R₂₆ may each independently be selected from groups represented by *-[(L₂₂)ₐ₂₂-(R₂₂)_{b22})].

In one or more embodiments, rings A₂₁, A₂₂, and A₂₃ in Formulae 2A and 2B may each independently be selected from groups represented by Formulae 2-101 to 2-229:

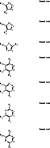

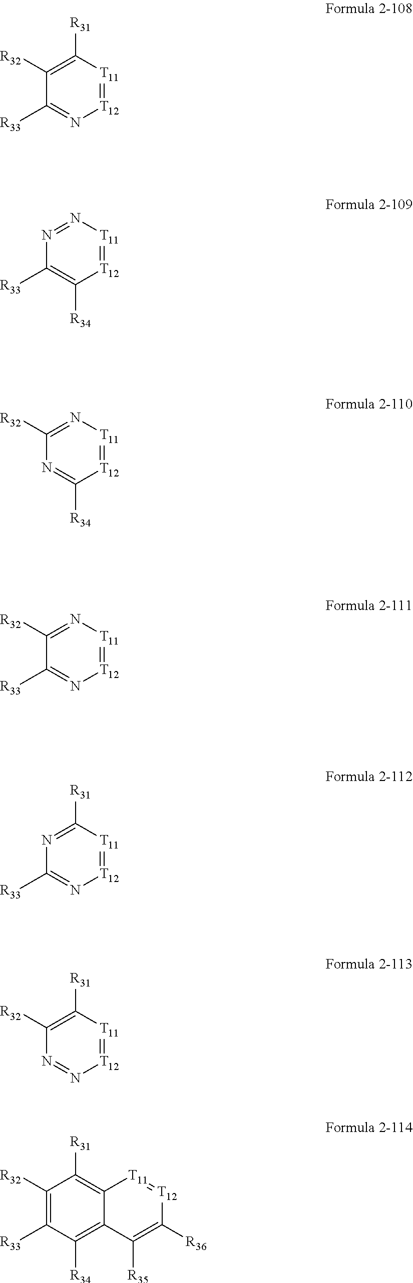

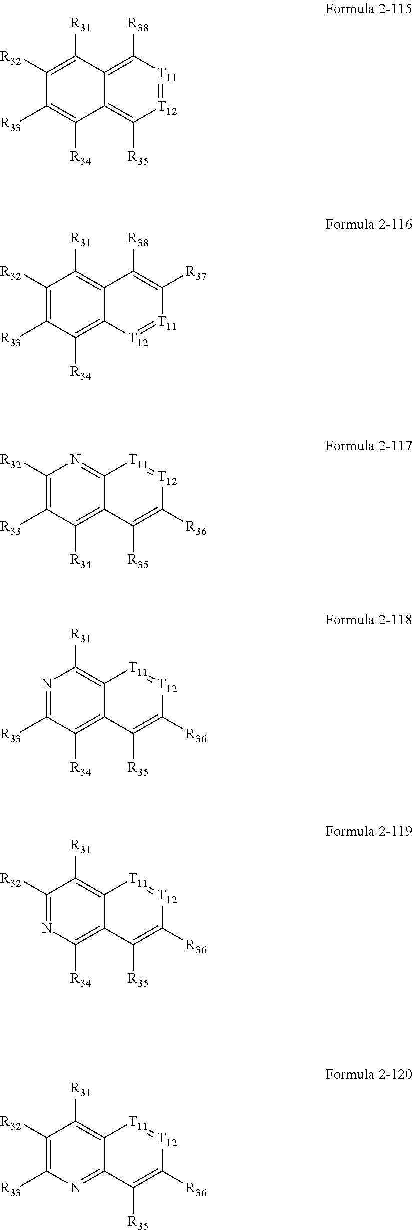

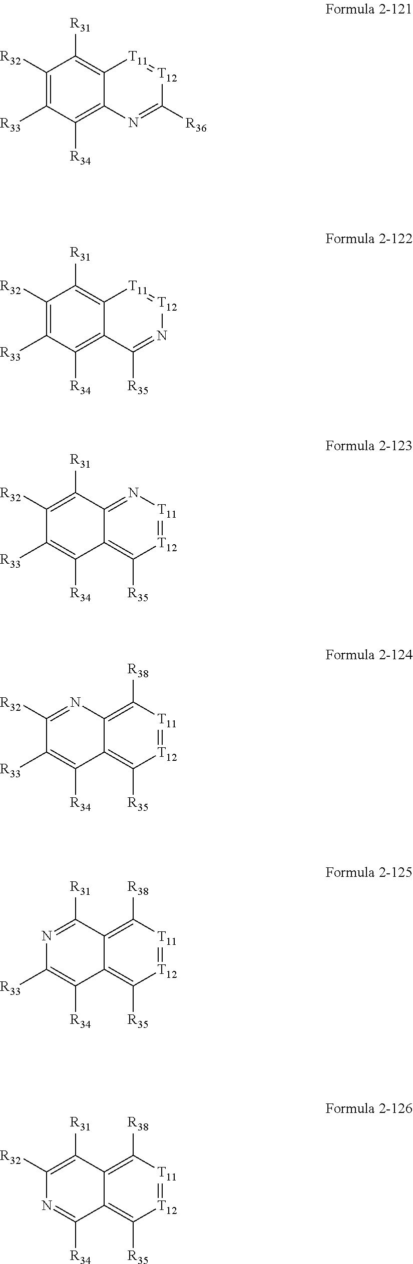

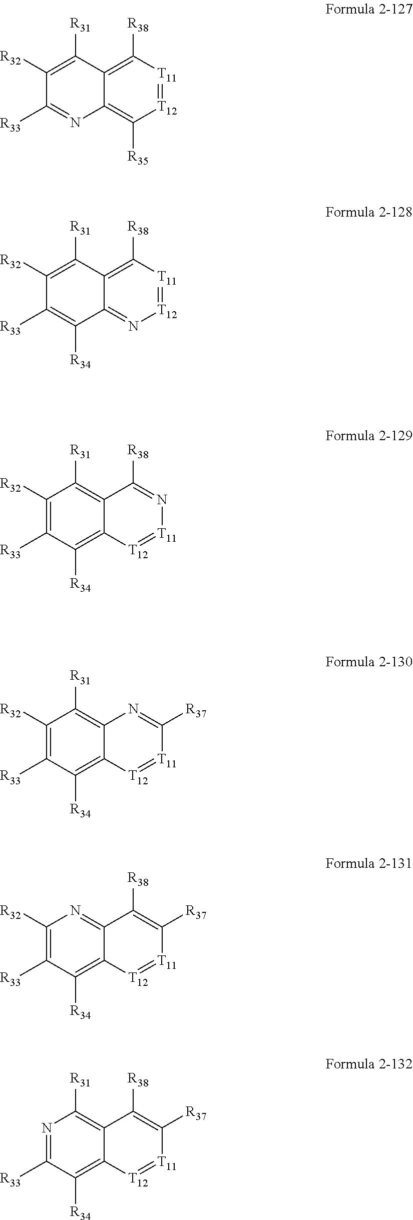

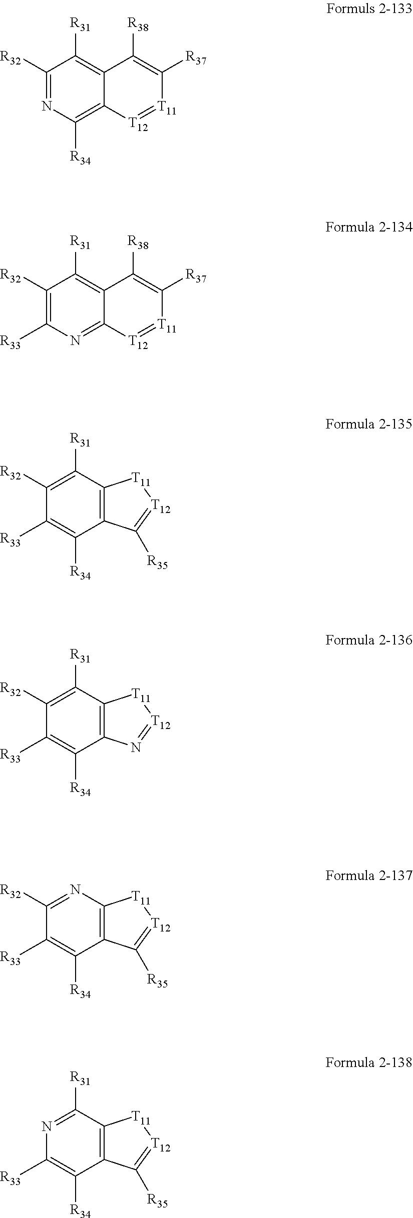

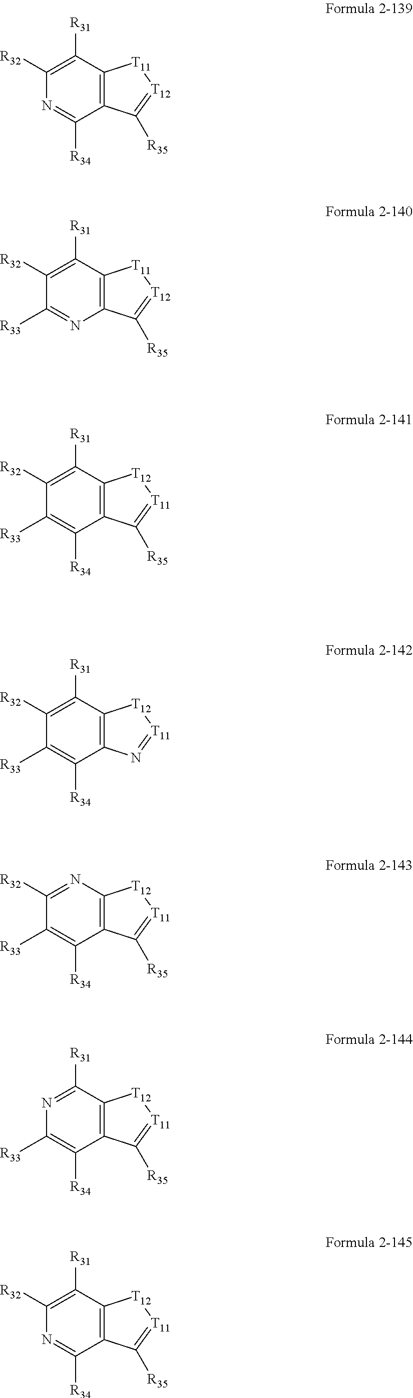

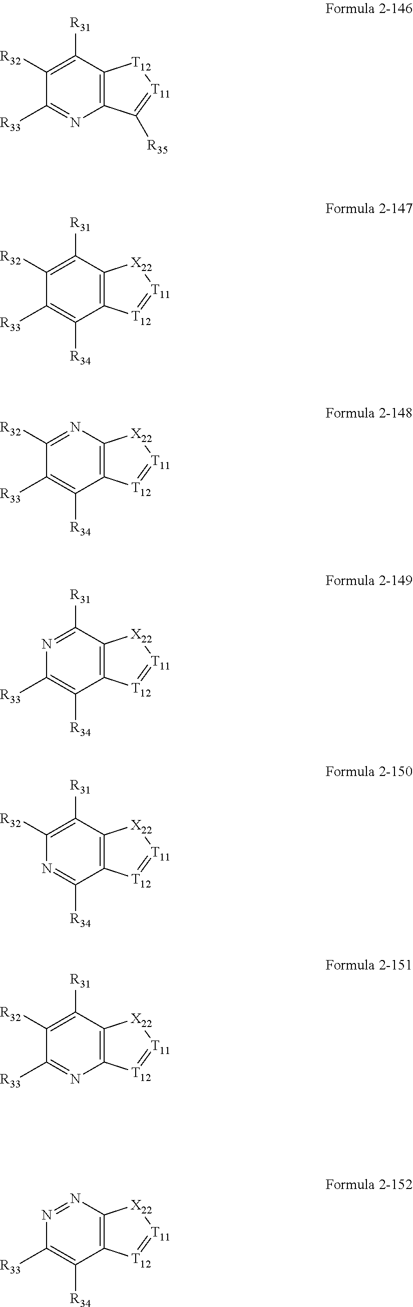

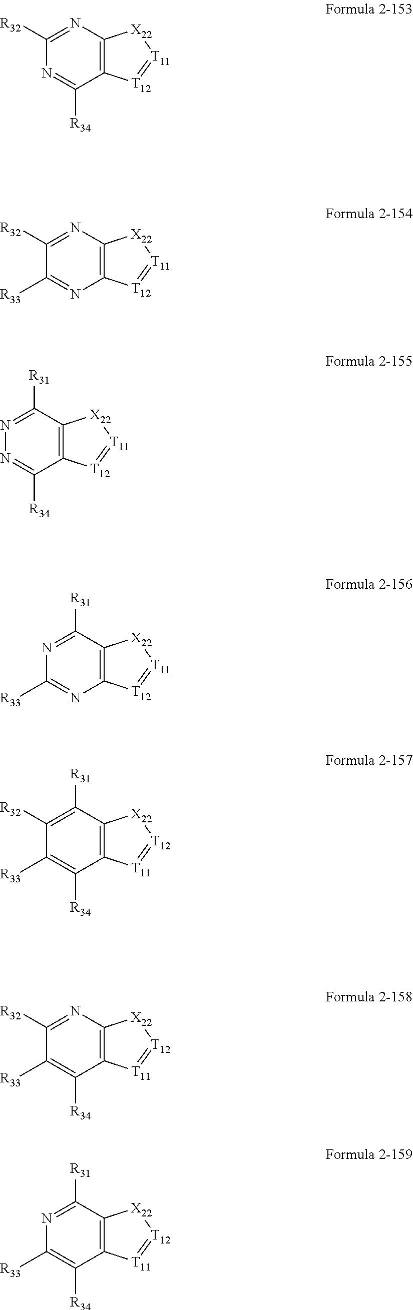

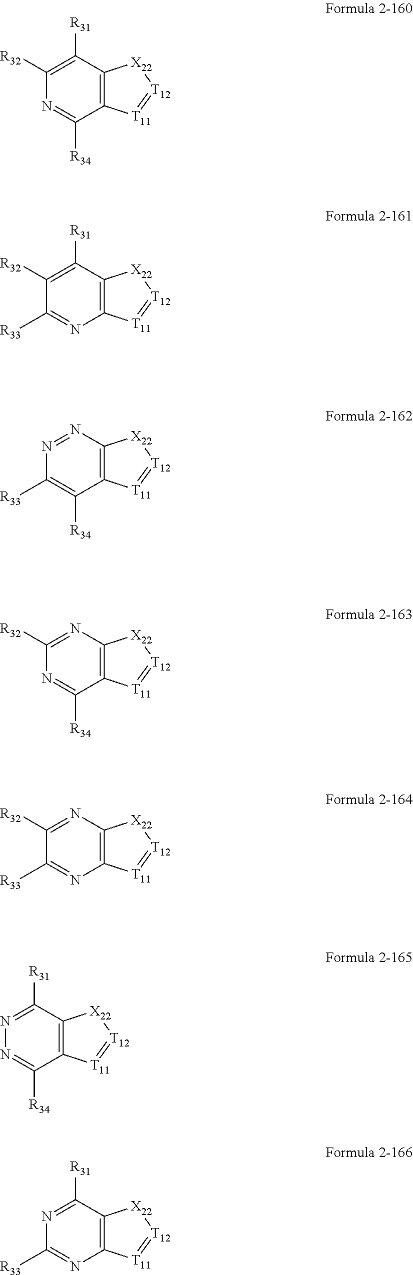

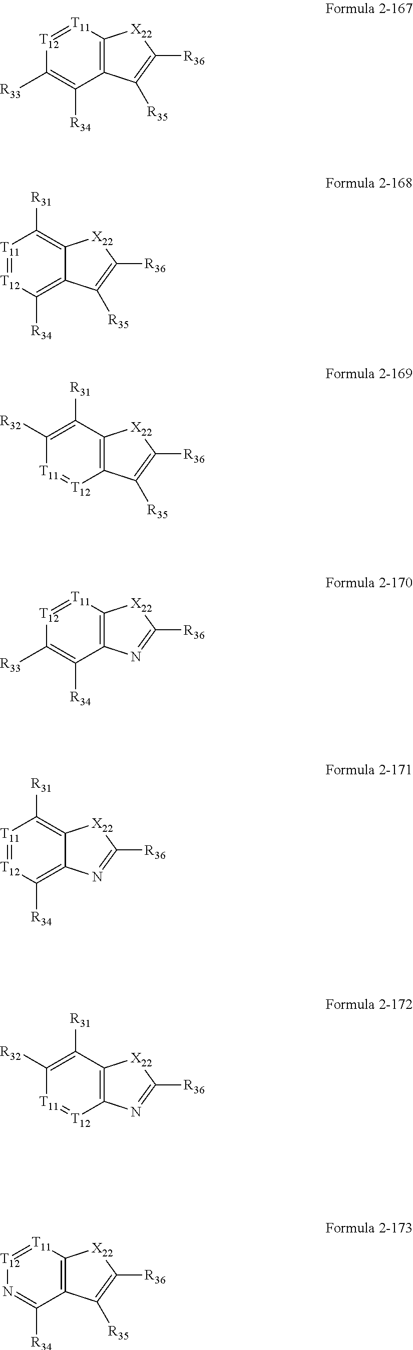

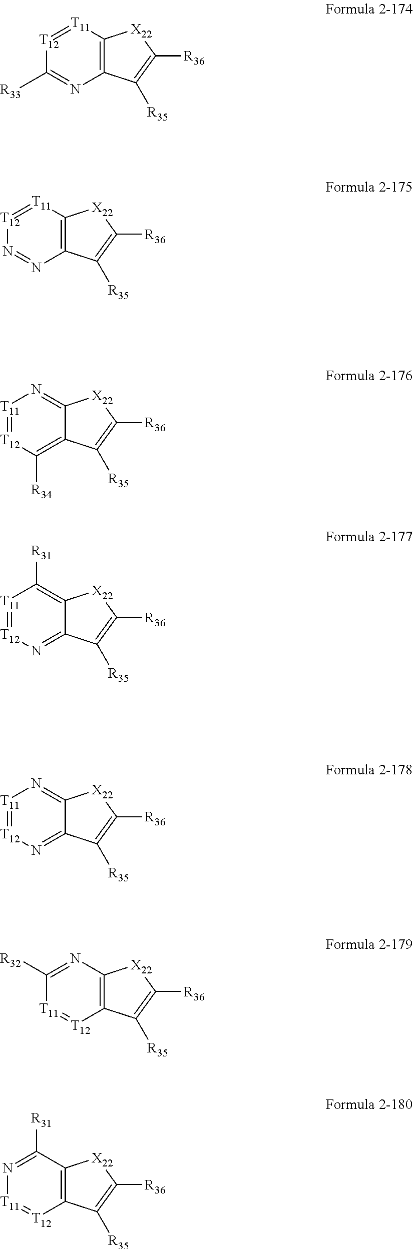

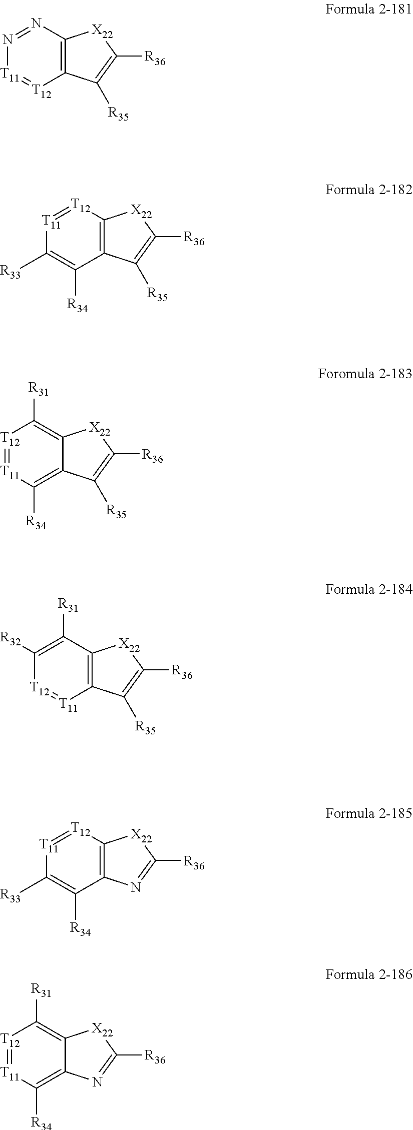

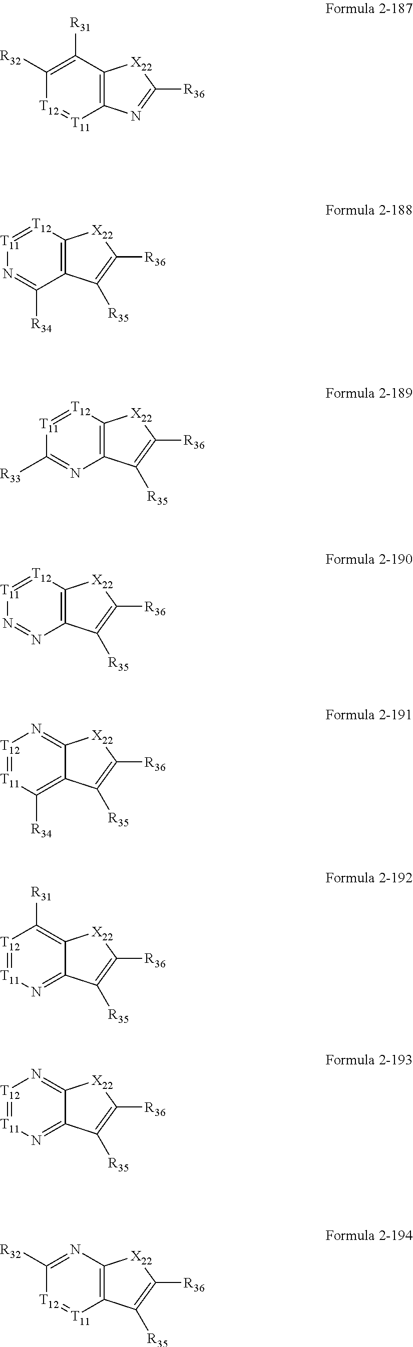

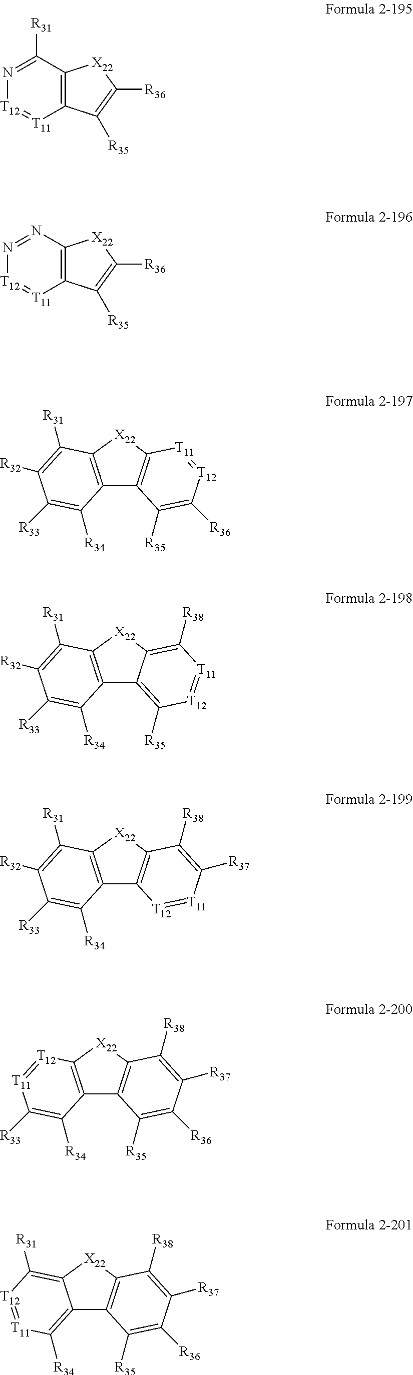

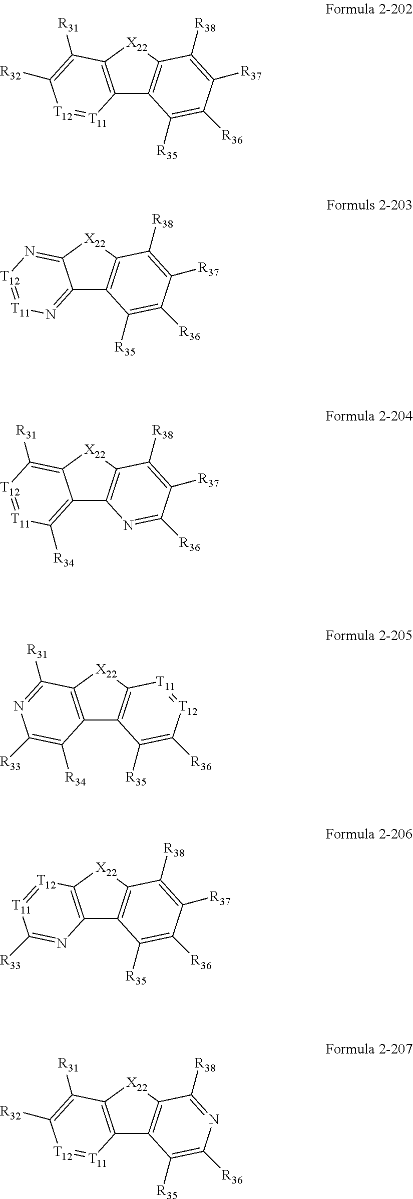

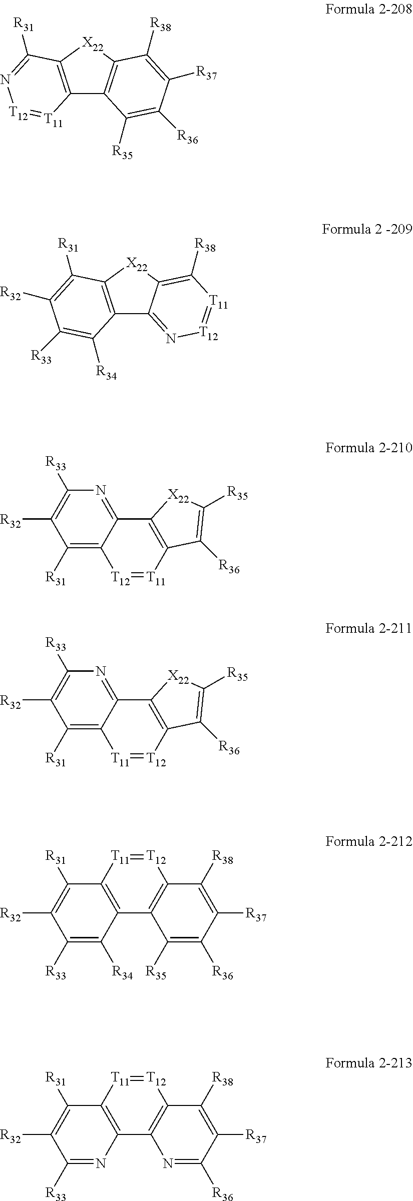

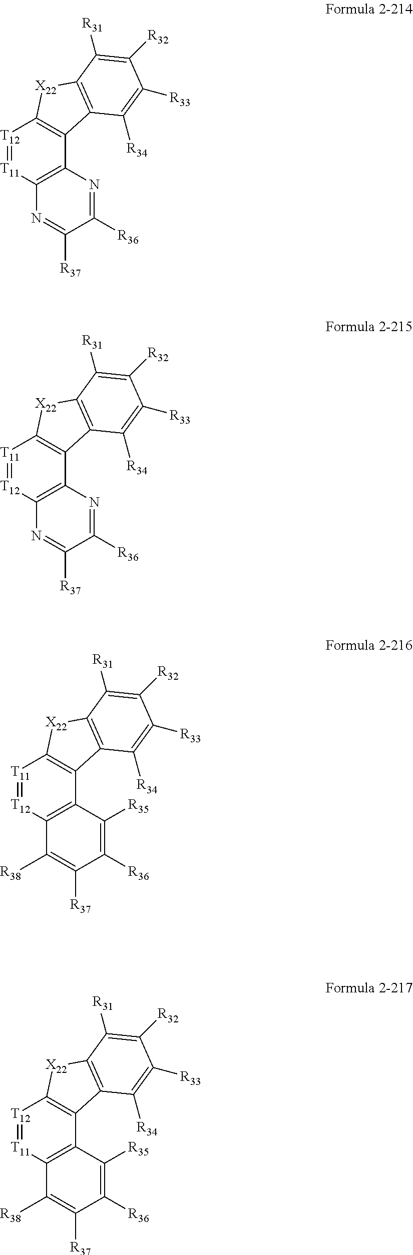

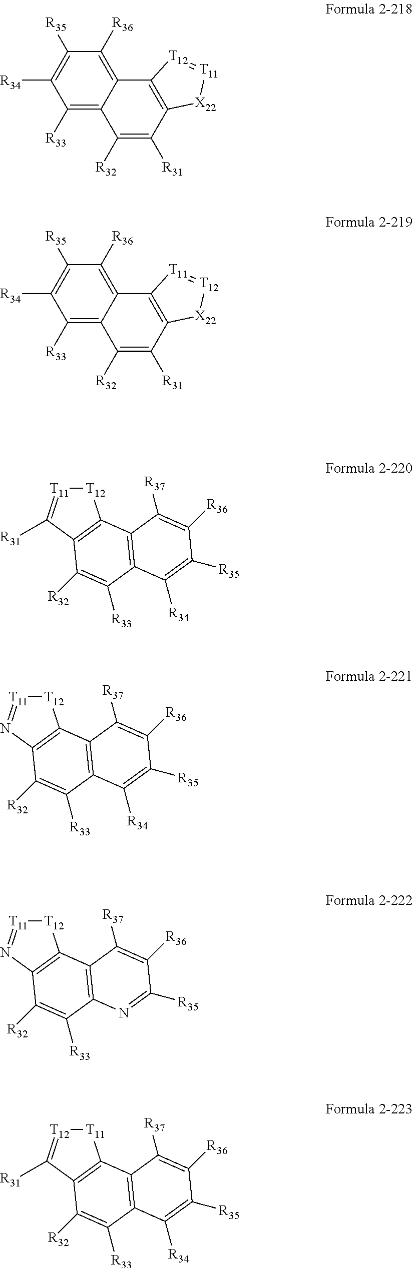

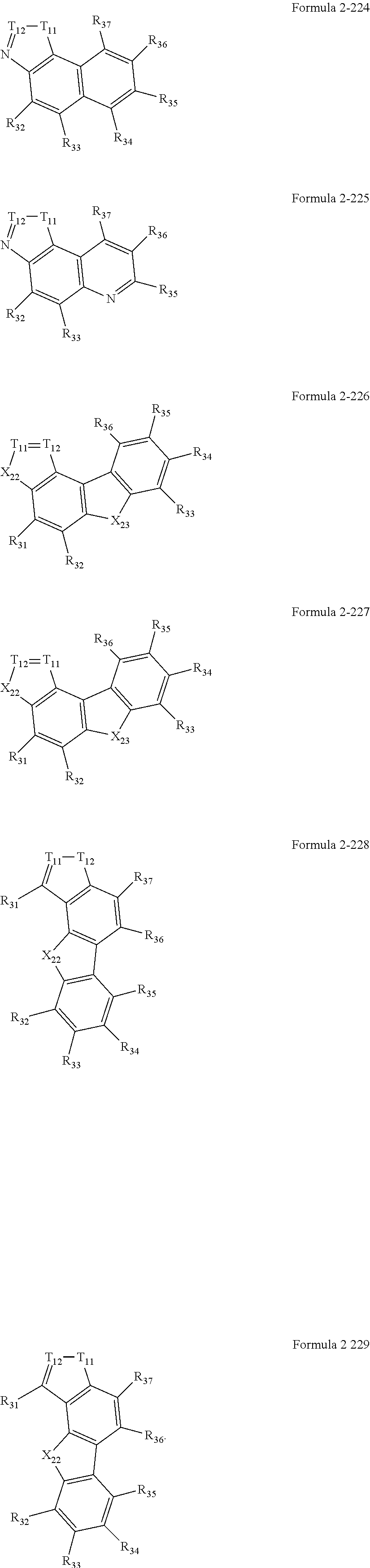

In Formulae 2-101 to 2-229,

T₁₁ and T₁₂ may each independently be the same as described above,

X₂₂ and X₂₃ may each independently be the same as described above, and

R₃₁ to R₃₈ may each independently be selected from substituents represented by *-[(L₂₂)ₐ₂₂-(R₂₂)_{b22}].

When the number of *-[(L₂₂)ₐ₂₂-(R₂₂)_{b22}](s) in R₃₁ to R₃₈ is 2 or more, the 2 or more *-[(L₂₂)ₐ₂₂-(R₂₂)_{b22}](s) may be identical to or different from each other.

In one or more embodiments, the case in which rings A₂₁, A₂₂, and A₂₃ in Formulae 2A and 2B are all (e.g., simultaneously) represented by Formula 2-104 is excluded.

In one or more embodiments, the second compound represented by Formula 2A or 2B may be represented by one selected from Formulae 2-201A to 2-269A (denoting a formula based on Formula 2A), and rings A₂₁, A₂₂, and A₂₃ in Formulae 2-201A to 2-269A may each be selected from the formulae shown in Table 1:

TABLE 1

| | Formula | | |
|---|---|---|---|
| | No. of ring | Formula No. of ring | Formula No. of ring |
| Formula No. | A₂₁ | A₂₂ | A₂₃ |
| 2-201A | 2-2 | 2-4 | 2-4 |
| 2-202A | 2-4 | 2-4 | 2-1 |
| 2-203A | 2-4 | 2-4 | 2-2 |
| 2-204A | 2-4 | 2-4 | 2-3 |
| 2-205A | 2-4 | 2-1 | 2-4 |
| 2-206A | 2-4 | 2-2 | 2-4 |
| 2-207A | 2-4 | 2-4 | 2-10 |
| 2-208A | 2-11 | 2-4 | 2-4 |
| 2-209A | 2-4 | 2-4 | 2-11 |
| 2-210A | 2-4 | 2-10 | 2-4 |
| 2-211A | 2-4 | 2-4 | 2-8 |
| 2-212A | 2-4 | 2-9 | 2-4 |
| 2-213A | 2-4 | 2-4 | 2-14 |
| 2-214A | 2-17 | 2-4 | 2-4 |
| 2-215A | 2-4 | 2-4 | 2-15 |
| 2-216A | 2-13 | 2-4 | 2-4 |
| 2-217A | 2-4 | 2-4 | 2-16 |
| 2-218A | 2-4 | 2-4 | 2-13 |
| 2-219A | 2-16 | 2-4 | 2-4 |
| 2-220A | 2-4 | 2-4 | 2-12 |
| 2-221A | 2-4 | 2-4 | 2-17 |
| 2-222A | 2-4 | 2-16 | 2-4 |
| 2-223A | 2-4 | 2-15 | 2-4 |
| 2-224A | 2-4 | 2-14 | 2-4 |
| 2-225A | 2-4 | 2-17 | 2-4 |
| 2-226A | 2-19 | 2-4 | 2-4 |
| 2-227A | 2-22 | 2-4 | 2-4 |
| 2-228A | 2-18 | 2-4 | 2-4 |
| 2-229A | 2-23 | 2-4 | 2-4 |
| 2-230A | 2-21 | 2-4 | 2-4 |
| 2-231A | 2-20 | 2-4 | 2-4 |
| 2-232A | 2-4 | 2-23 | 2-4 |
| 2-233A | 2-4 | 2-18 | 2-4 |
| 2-234A | 2-4 | 2-21 | 2-4 |
| 2-235A | 2-4 | 2-19 | 2-4 |
| 2-236A | 2-5 | 2-2 | 2-4 |
| 2-237A | 2-5 | 2-1 | 2-4 |
| 2-238A | 2-2 | 2-2 | 2-4 |
| 2-239A | 2-4 | 2-23 | 2-1 |
| 2-240A | 2-6 | 2-10 | 2-4 |
| 2-241A | 2-4 | 2-4 | 2-29 |
| 2-242A | 2-7 | 2-4 | 2-10 |
| 2-243A | 2-11 | 2-4 | 2-10 |
| 2-244A | 2-4 | 2-10 | 2-6 |
| 2-245A | 2-11 | 2-11 | 2-4 |
| 2-246A | 2-11 | 2-11 | 2-5 |
| 2-247A | 2-11 | 2-11 | 2-10 |
| 2-248A | 2-7 | 2-9 | 2-4 |
| 2-249A | 2-4 | 2-4 | 2-25 |
| 2-250A | 2-11 | 2-15 | 2-4 |
| 2-251A | 2-18 | 2-28 | 2-4 |
| 2-252A | 2-23 | 2-10 | 2-4 |
| 2-253A | 2-4 | 2-27 | 2-4 |
| 2-254A | 2-6 | 2-18 | 2-4 |
| 2-255A | 2-4 | 2-23 | 2-5 |
| 2-256A | 2-23 | 2-4 | 2-14 |
| 2-257A | 2-17 | 2-4 | 2-14 |
| 2-258A | 2-14 | 2-4 | 2-12 |
| 2-259A | 2-17 | 2-4 | 2-12 |
| 2-260A | 2-14 | 2-16 | 2-2 |
| 2-261A | 2-17 | 2-5 | 2-14 |
| 2-262A | 2-17 | 2-13 | 2-17 |
| 2-263A | 2-17 | 2-14 | 2-12 |
| 2-264A | 2-17 | 2-12 | 2-12 |
| 2-265A | 2-5 | 2-1 | 2-18 |
| 2-266A | 2-4 | 2-29 | 2-4 |
| 2-267A | 2-4 | 2-31 | 2-4 |
| 2-268A | 2-4 | 2-33 | 2-4 |
| 2-269A | 2-4 | 2-35 | 2-4 |

In one or more embodiments, the second compound represented by Formula 2A or 2B may be represented by one selected from Formulae 2-201B to 2-215B (denoting a formula based on Formula 2B), and rings A₂₁ and A₂₃ in Formulae 2-201B to 2-215B may each be selected from the formulae shown in Table 2:

TABLE 2

| | Formula | Formula No. of | Formula No. of ring |
|---|---|---|---|
| Formula No. | No. of ring A₂₁ | ring A₂₂ | A₂₃ |
| 2-201B | 2-4 | — | 2-19 |
| 2-202B | 2-4 | — | 2-22 |
| 2-203B | 2-4 | — | 2-18 |
| 2-204B | 2-4 | — | 2-23 |
| 2-205B | 2-4 | — | 2-21 |
| 2-206B | 2-4 | — | 2-20 |
| 2-207B | 2-5 | — | 2-23 |
| 2-208B | 2-7 | — | 2-23 |
| 2-209B | 2-4 | — | 2-26 |
| 2-210B | 2-7 | — | 2-22 |
| 2-211B | 2-13 | — | 2-16 |
| 2-212B | 2-5 | — | 2-19 |
| 2-213B | 2-7 | — | 2-20 |
| 2-214B | 2-19 | — | 2-18 |
| 2-215B | 2-18 | — | 2-18 |

In one or more embodiments, the second compound represented by Formula 2A or 2B may be represented by one selected from Formulae 2-301A to 2-421A (denoting a formula based on Formula 2A), and rings A₂₁, A₂₂, and A₂₃ in Formulae 2-301A to 2-419A and 2-421A to 2-431A may each be selected from the formulae shown in Table 3:

TABLE 3

| | Formula | | |
|---|---|---|---|
| | No. of ring | Formula No. of ring | Formula No. of ring |
| Formula No. | A₂₁ | A₂₂ | A₂₃ |
| 2-301A | 2-104 | 2-147 | 2-104 |
| 2-302A | 2-102 | 2-104 | 2-104 |
| 2-303A | 2-104 | 2-104 | 2-101 |
| 2-304A | 2-104 | 2-104 | 2-102 |
| 2-305A | 2-104 | 2-104 | 2-103 |
| 2-306A | 2-104 | 2-101 | 2-104 |
| 2-307A | 2-104 | 2-102 | 2-104 |
| 2-308A | 2-104 | 2-104 | 2-147 |
| 2-309A | 2-157 | 2-104 | 2-104 |
| 2-310A | 2-104 | 2-104 | 2-157 |
| 2-311A | 2-104 | 2-147 | 2-107 |
| 2-312A | 2-104 | 2-149 | 2-104 |
| 2-313A | 2-104 | 2-156 | 2-104 |
| 2-314A | 2-107 | 2-147 | 2-106 |
| 2-315A | 2-104 | 2-151 | 2-104 |
| 2-316A | 2-104 | 2-147 | 2-106 |
| 2-317A | 2-104 | 2-148 | 2-104 |
| 2-318A | 2-104 | 2-150 | 2-104 |
| 2-319A | 2-106 | 2-147 | 2-104 |
| 2-320A | 2-104 | 2-106 | 2-147 |
| 2-321A | 2-157 | 2-107 | 2-104 |
| 2-322A | 2-106 | 2-104 | 2-147 |
| 2-323A | 2-104 | 2-107 | 2-147 |
| 2-324A | 2-107 | 2-104 | 2-147 |
| 2-325A | 2-104 | 2-104 | 2-160 |
| 2-326A | 2-104 | 2-111 | 2-157 |
| 2-327A | 2-108 | 2-104 | 2-158 |
| 2-328A | 2-111 | 2-104 | 2-157 |
| 2-329A | 2-107 | 2-147 | 2-104 |
| 2-330A | 2-104 | 2-104 | 2-135 |
| 2-331A | 2-104 | 2-141 | 2-104 |
| 2-332A | 2-104 | 2-142 | 2-104 |
| 2-333A | 2-107 | 2-104 | 2-135 |
| 2-334A | 2-104 | 2-111 | 2-135 |
| 2-335A | 2-104 | 2-143 | 2-104 |
| 2-336A | 2-106 | 2-142 | 2-104 |
| 2-337A | 2-107 | 2-142 | 2-106 |
| 2-338A | 2-104 | 2-104 | 2-169 |
| 2-339A | 2-184 | 2-104 | 2-104 |
| 2-340A | 2-104 | 2-104 | 2-182 |
| 2-341A | 2-168 | 2-104 | 2-104 |
| 2-342A | 2-104 | 2-104 | 2-183 |
| 2-343A | 2-104 | 2-104 | 2-168 |
| 2-344A | 2-183 | 2-104 | 2-104 |
| 2-345A | 2-104 | 2-104 | 2-167 |
| 2-346A | 2-104 | 2-104 | 2-184 |
| 2-347A | 2-104 | 2-183 | 2-104 |
| 2-348A | 2-104 | 2-182 | 2-104 |
| 2-349A | 2-104 | 2-169 | 2-104 |
| 2-350A | 2-104 | 2-184 | 2-104 |
| 2-351A | 2-107 | 2-104 | 2-179 |
| 2-352A | 2-111 | 2-104 | 2-169 |
| 2-353A | 2-104 | 2-111 | 2-182 |
| 2-354A | 2-106 | 2-104 | 2-185 |
| 2-355A | 2-171 | 2-104 | 2-104 |
| 2-356A | 2-104 | 2-104 | 2-115 |
| 2-357A | 2-104 | 2-104 | 2-178 |
| 2-358A | 2-104 | 2-106 | 2-167 |
| 2-359A | 2-108 | 2-105 | 2-167 |
| 2-360A | 2-105 | 2-104 | 2-167 |
| 2-361A | 2-112 | 2-104 | 2-184 |
| 2-362A | 2-104 | 2-192 | 2-104 |
| 2-363A | 2-107 | 2-182 | 2-106 |
| 2-364A | 2-104 | 2-169 | 2-105 |
| 2-365A | 2-105 | 2-184 | 2-104 |
| 2-366A | 2-105 | 2-169 | 2-105 |
| 2-367A | 2-198 | 2-104 | 2-104 |
| 2-368A | 2-201 | 2-104 | 2-104 |
| 2-369A | 2-197 | 2-104 | 2-104 |
| 2-370A | 2-202 | 2-104 | 2-104 |
| 2-371A | 2-200 | 2-104 | 2-104 |
| 2-372A | 2-199 | 2-104 | 2-104 |
| 2-373A | 2-104 | 2-202 | 2-104 |
| 2-374A | 2-104 | 2-197 | 2-104 |
| 2-375A | 2-104 | 2-200 | 2-104 |
| 2-376A | 2-104 | 2-198 | 2-104 |
| 2-377A | 2-209 | 2-104 | 2-104 |
| 2-378A | 2-207 | 2-104 | 2-104 |
| 2-379A | 2-200 | 2-106 | 2-104 |
| 2-380A | 2-104 | 2-208 | 2-104 |
| 2-381A | 2-105 | 2-198 | 2-108 |
| 2-382A | 2-202 | 2-102 | 2-104 |
| 2-383A | 2-202 | 2-101 | 2-106 |
| 2-384A | 2-102 | 2-102 | 2-107 |
| 2-385A | 2-104 | 2-202 | 2-101 |
| 2-386A | 2-123 | 2-147 | 2-104 |
| 2-387A | 2-104 | 2-104 | 2-218 |
| 2-388A | 2-116 | 2-104 | 2-147 |
| 2-389A | 2-157 | 2-104 | 2-147 |
| 2-390A | 2-107 | 2-147 | 2-115 |
| 2-391A | 2-157 | 2-157 | 2-104 |
| 2-392A | 2-157 | 2-157 | 2-114 |
| 2-393A | 2-157 | 2-157 | 2-147 |
| 2-394A | 2-116 | 2-147 | 2-104 |
| 2-395A | 2-104 | 2-104 | 2-210 |
| 2-396A | 2-157 | 2-182 | 2-104 |
| 2-397A | 2-197 | 2-213 | 2-104 |
| 2-398A | 2-202 | 2-167 | 2-104 |
| 2-399A | 2-104 | 2-216 | 2-104 |
| 2-400A | 2-124 | 2-197 | 2-104 |
| 2-401A | 2-104 | 2-202 | 2-114 |
| 2-402A | 2-168 | 2-104 | 2-169 |
| 2-403A | 2-184 | 2-104 | 2-169 |
| 2-404A | 2-169 | 2-104 | 2-167 |
| 2-405A | 2-184 | 2-106 | 2-167 |
| 2-406A | 2-169 | 2-183 | 2-102 |
| 2-407A | 2-184 | 2-114 | 2-169 |
| 2-408A | 2-184 | 2-168 | 2-184 |
| 2-409A | 2-184 | 2-104 | 2-167 |
| 2-410A | 2-184 | 2-167 | 2-167 |
| 2-411A | 2-114 | 2-101 | 2-197 |
| 2-412A | 2-104 | 2-149 | 2-104 |
| 2-413A | 2-106 | 2-104 | 2-147 |
| 2-414A | 2-104 | 2-104 | 2-168 |
| 2-415A | 2-200 | 2-106 | 2-104 |
| 2-416A | 2-104 | 2-104 | 2-183 |
| 2-417A | 2-104 | 2-104 | 2-101 |
| 2-418A | 2-105 | 2-169 | 2-105 |
| 2-419A | 2-104 | 2-147 | 2-107 |
| 2-421A | 2-104 | 2-218 | 2-104 |
| 2-422A | 2-104 | 2-226 | 2-104 |
| 2-423A | 2-104 | 2-222 | 2-104 |
| 2-424A | 2-104 | 2-228 | 2-104 |
| 2-425A | 2-104 | 2-151 | 2-104 |
| 2-426A | 2-106 | 2-147 | 2-107 |
| 2-427A | 2-104 | 2-147 | 2-106 |
| 2-428A | 2-107 | 2-150 | 2-104 |
| 2-429A | 2-104 | 2-143 | 2-104 |
| 2-430A | 2-107 | 2-142 | 2-106 |
| 2-431A | 2-104 | 2-142 | 2-104 |

In one or more embodiments, the second compound represented by Formula 2A or 2B may be represented by one selected from Formulae 2-301B to 2-320B (denoting a formula based on Formula 2B), and rings A₂₁ and A₂₃ in Formulae 2-301B to 2-320B may each be selected from the formulae shown in Table 4:

TABLE 4

| | Formula | | |
|---|---|---|---|
| | No. of ring | Formula No. of ring | Formula No. of ring |
| Formula No. | A₂₁ | A₂₂ | A₂₃ |
| 2-301B | 2-104 | — | 2-198 |
| 2-302B | 2-104 | — | 2-201 |
| 2-303B | 2-104 | — | 2-197 |
| 2-304B | 2-104 | — | 2-202 |
| 2-305B | 2-104 | — | 2-200 |
| 2-306B | 2-104 | — | 2-199 |
| 2-307B | 2-104 | — | 2-203 |
| 2-308B | 2-104 | — | 2-204 |
| 2-309B | 2-106 | — | 2-205 |
| 2-310B | 2-104 | — | 2-206 |
| 2-311B | 2-112 | — | 2-199 |
| 2-312B | 2-114 | — | 2-202 |
| 2-313B | 2-116 | — | 2-202 |
| 2-314B | 2-104 | — | 2-214 |
| 2-315B | 2-130 | — | 2-201 |
| 2-316B | 2-168 | — | 2-183 |
| 2-317B | 2-114 | — | 2-198 |
| 2-318B | 2-116 | — | 2-199 |
| 2-319B | 2-198 | — | 2-197 |
| 2-320B | 2-197 | — | 2-197 |

In Formula 1A, X₁₁ may be N or C[(L₃)ₐ₃-(R₃)_{b3}], and X₁₂ may be N or C[(L₄)ₐ₄-(R₄)_{b4}].

For example, in Formula 1A,

X₁₁ may be N, and X₁₂ may be C[(L₄)ₐ₄-(R₄)_{b4}],

X₁₁ may be C[(L₃)ₐ₃-(R₃)_{b3}], and X₁₂ may be N, or

X₁₁ may be C[(L₃)ₐ₃-(R₃)_{b3}], and X₁₂ may be C[(L₄)ₐ₄-(R₄)_{b4}], but embodiments of X₁₁ are not limited thereto.

X₂₁ in Formulae 2A and 2B may be selected from O, S, Se, C(R₂₃)(R₂₄), Si(R₂₃)(R₂₄), and N-[(L₂₁)ₐ₂₁-(R₂₁)_{b21}].

In one embodiment, X₂₁ in Formulae 2A and 2B may be N[(L₂₁)ₐ₂₁-(R₂₁)_{b21}].

In one or more embodiments, X₂₁ in Formulae 2A and 2B may be O, S, Se, C(R₂₃)(R₂₄), or Si(R₂₃)(R₂₄),

at least one selected from rings A₂₁, A₂₂, and A₂₃ in Formula 2A and at least one selected from rings A₂₁ and A₂₃ in Formula 2B may each independently be selected from groups represented by Formulae 2-1 to 2-3, 2-10 to 2-27, and 2-33 to 2-36, and X₂₂ or X₂₃ in Formulae 2-1 to 2-3, 2-10 to 2-27, and 2-33 to 2-36 may be N-[(L₂₂)ₐ₂₂-(R₂₂)_{b22}].

In one or more embodiments, X₂₁ in Formulae 2A and 2B may be O, S, Se, C(R₂₃)(R₂₄), or Si(R₂₃)(R₂₄),

at least one selected from rings A₂₁, A₂₂, and A₂₃ in Formula 2A and at least one selected from rings A₂₁ and A₂₃ in Formula 2B may each independently be selected from groups represented by Formulae 2-101 to 2-103, 2-147 to 2-211, 2-214 to 2-219, and 2-226 to 2-229, and X₂₂ or X₂₃ in Formula 2-101 to 2-103, 2-147 to 2-211, 2-214 to 2-219, and 2-226 to 2-229 may be N-[(L₂₂)ₐ₂₂-(R₂₂)_{b22}], but embodiments of the present disclosure are not limited thereto.

In Formulae 2A and 2B, X₂₁ may be O, S, Se, C(R₂₃)(R₂₄), Si(R₂₃)(R₂₄), or N-[(L₂₁)ₐ₂₁-(R₂₁)_{b21}], and X₂₂ and X₂₃ may each independently be O, S, Se, C(R₂₅)(R₂₆), Si(R₂₅)(R₂₆), or N-[(L₂₂)ₐ₂₂-(R₂₂)_{b22}]. L₂₁, L₂₂, a21, a22, R₂₁ to R₂₆, b21, and b22 may each independently be the same as described below.

L₁ to L₉ in Formulae 1A to 1E, 2A, and 2B may each independently be selected from a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, and a substituted or unsubstituted divalent non-aromatic condensed polycyclic group,

L₂₁ and L₂₂ may each independently be selected from a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed heteropolycyclic group.

For example,

in Formulae 1A to 1E, 2A, and 2B,

L₁ to L₉, L₂₁, and L₂₂ may each independently be selected from the group consisting of:

a phenylene group, a pentalenylene group, an indenylene group, a naphthylene group, an azulenylene group, a heptalenylene group, an indacenylene group, an acenaphthylene group, a fluorenylene group, a spiro-bifluorenylene group, a spiro-benzofluorene-fluorenylene group, a benzofluorenylene group, a dibenzofluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, a pentacenylene group, a rubicenylene group, a coronenylene group, an ovalenylene group, a pyrrolylene group, a thiophenylene group, a furanylene group, a silolylene group, an imidazolylene group, a pyrazolylene group, a thiazolylene group, an isothiazolylene group, an oxazolylene group, an isoxazolylene group, a pyridinylene group, a pyrazinylene group, a pyrimidinylene group, a pyridazinylene group, an indolylene group, an isoindolylene group, an indazolylene group, a purinylene group, a quinolinylene group, an isoquinolinylene group, a benzoquinolinylene group, a phthalazinylene group, a naphthyridinylene group, a quinoxalinylene group, a quinazolinylene group, a cinnolinylene group, a phenanthridinylene group, an acridinylene group, a phenanthrolinylene group, a phenazinylene group, a benzimidazolylene group, a benzofuranylene group, a benzothiophenylene group, a benzosilolylene group, an isobenzothiazolylene group, a benzoxazolylene group, an isobenzoxazolylene group, a triazolylene group, a tetrazolylene group, an oxadiazolylene group, a triazinylene group, a dibenzofuranylene group, a dibenzothiophenylene group, a dibenzosilolylene group, a carbazolylene group, a benzocarbazolylene group, a dibenzocarbazolylene group, a thiadiazolylene group, an imidazopyridinylene group, an imidazopyrimidinylene group, an oxazolopyridinylene group, a thiazolopyridinylene group, a benzonaphthyridinylene group, an azafluorenylene group, an azaspiro-bifluorenylene group, an azacarbazolylene group, an azadibenzofuranylene group, an azadibenzothiophenylene group, and an azadibenzosilolylene group; and

a phenylene group, a pentalenylene group, an indenylene group, a naphthylene group, an azulenylene group, a heptalenylene group, an indacenylene group, an acenaphthylene group, a fluorenylene group, a spiro-bifluorenylene group, a spiro-benzofluorene-fluorenylene group, a benzofluorenylene group, a dibenzofluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, a pentacenylene group, a rubicenylene group, a coronenylene group, an ovalenylene group, a pyrrolylene group, a thiophenylene group, a furanylene group, a silolylene group, an imidazolylene group, a pyrazolylene group, a thiazolylene group, an isothiazolylene group, an oxazolylene group, an isoxazolylene group, a pyridinylene group, a pyrazinylene group, a pyrimidinylene group, a pyridazinylene group, an indolylene group, an isoindolylene group, an indazolylene group, a purinylene group, a quinolinylene group, an isoquinolinylene group, a benzoquinolinylene group, a phthalazinylene group, a naphthyridinylene group, a quinoxalinylene group, a quinazolinylene group, a cinnolinylene group, a phenanthridinylene group, an acridinylene group, a phenanthrolinylene group, a phenazinylene group, a benzimidazolylene group, a benzofuranylene group, a benzothiophenylene group, a benzosilolylene group, an isobenzothiazolylene group, a benzoxazolylene group, an isobenzoxazolylene group, a triazolylene group, a tetrazolylene group, an oxadiazolylene group, a triazinylene group, a dibenzofuranylene group, a dibenzothiophenylene group, a dibenzosilolylene group, a carbazolylene group, a benzocarbazolylene group, a dibenzocarbazolylene group, a thiadiazolylene group, an imidazopyridinylene group, an imidazopyrimidinylene group, an oxazolopyridinylene group, a thiazolopyridinylene group, a benzonaphthyridinylene group, an azafluorenylene group, an azaspiro-bifluorenylene group, an azacarbazolylene group, an azadibenzofuranylene group, an azadibenzothiophenylene group, and an azadibenzosilolylene group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, a monovalent non-aromatic condensed heteropolycyclic group, a biphenyl group, a terphenyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), and —P(═O)(Q₃₁)(Q₃₂), and

L₁ to L₉ may each not be a substituted or unsubstituted carbazolylene group, a substituted or unsubstituted dibenzofuranylene group, a substituted or unsubstituted dibenzothiophenylene group, a substituted or unsubstituted dibenzosilolylene group, or a substituted or unsubstituted dibenzocarbazolylene group,

wherein Q₃₁ to Q₃₃ may each independently be selected from the group consisting of:

a C₁-C₁₀ alkyl group, a C₁-C₁₀ alkoxy group, a phenyl group, a biphenyl group, a terphenyl group, a naphthyl group, a pyridinyl group, a pyrimidinyl group, a pyrazinyl group, a quinolinyl group, an isoquinolinyl group, a quinoxalinyl group, and a quinazolinyl group; and

a phenyl group, a biphenyl group, a terphenyl group, a naphthyl group, a pyridinyl group, a pyrimidinyl group, a pyrazinyl group, a quinolinyl group, an isoquinolinyl group, a quinoxalinyl group, and a quinazolinyl group, each substituted with at least one selected from a C₁-C₁₀ alkyl group, a C₁-C₁₀ alkoxy group, and a phenyl group.

In one or more embodiments,

L₁ to L₉, L₂₁, and L₂₂ in Formulae 1A to 1E, 2A, and 2B may each independently be selected from the group consisting of:

a phenylene group, a pentalenylene group, an indenylene group, a naphthylene group, an azulenylene group, a heptalenylene group, an indacenylene group, an acenaphthylene group, a fluorenylene group, a spiro-bifluorenylene group, a benzofluorenylene group, a dibenzofluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, a pentacenylene group, a rubicenylene group, a coronenylene group, an ovalenylene group, a pyrrolylene group, a thiophenylene group, a furanylene group, a silolylene group, an indolylene group, an isoindolylene group, a benzofuranylene group, a benzothiophenylene group, a benzosilolylene group, a dibenzofuranylene group, a dibenzothiophenylene group, a dibenzosilolylene group, a carbazolylene group, a benzocarbazolylene group, a dibenzocarbazolylene group, and a pyridinylene group; and

a phenylene group, a pentalenylene group, an indenylene group, a naphthylene group, an azulenylene group, a heptalenylene group, an indacenylene group, an acenaphthylene group, a fluorenylene group, a spiro-bifluorenylene group, a benzofluorenylene group, a dibenzofluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, a pentacenylene group, a rubicenylene group, a coronenylene group, an ovalenylene group, a pyrrolylene group, a thiophenylene group, a furanylene group, a silolylene group, an indolylene group, an isoindolylene group, a benzofuranylene group, a benzothiophenylene group, a benzosilolylene group, a dibenzofuranylene group, a dibenzothiophenylene group, a dibenzosilolylene group, a carbazolylene group, a benzocarbazolylene group, a dibenzocarbazolylene group, and a pyridinylene group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenylene group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, a silolyl group, an indolyl group, an isoindolyl group, a benzofuranyl group, a benzothiophenyl group, a benzosilolyl group, a dibenzofuranyl group, a dibenzothiophenyl group, a dibenzosilolyl group, a carbazolyl group, a benzocarbazolyl group, a dibenzocarbazolyl group, a pyridinyl group, —Si(Q₃₁)(Q₃₂)(Q₃₃) —N(Q₃₁)(Q₃₂), —B(Q₃₁)(Q₃₂), —C(═O)(Q₃₁), —S(═O)₂(Q₃₁), and —P(═O)(Q₃₁)(Q₃₂), and

L₁ to L₉ may each not be a substituted or unsubstituted carbazolylene group, a substituted or unsubstituted dibenzofuranylene group, a substituted or unsubstituted dibenzothiophenylene group, a substituted or unsubstituted dibenzosilolylene group, or a substituted or unsubstituted dibenzocarbazolylene group,

wherein Q₃₁ to Q₃₃ may each independently be selected from the group consisting of:

a C₁-C₁₀ alkyl group, a C₁-C₁₀ alkoxy group, a phenyl group, a biphenyl group, a terphenyl group, a naphthyl group, a pyridinyl group, a pyrimidinyl group, a pyrazinyl group, a quinolinyl group, an isoquinolinyl group, a quinoxalinyl group, and a quinazolinyl group; and

a phenyl group, a biphenyl group, a terphenyl group, a naphthyl group, a pyridinyl group, a pyrimidinyl group, a pyrazinyl group, a quinolinyl group, an isoquinolinyl group, a quinoxalinyl group, and a quinazolinyl group, each substituted with at least one selected from a C₁-C₁₀ alkyl group, a C₁-C₁₀ alkoxy group, and a phenyl group.

In one or more embodiments, in Formulae 1A to 1E, 2A, and 2B, L₁ to L₉ may each independently be selected from groups represented by Formulae 3-1 to 3-22 and 3-25 to 3-100,

L₂₁ and L₂₂ may each independently be selected from groups Formulae 3-1 to 3-100, and

when L₁ to L₉ are each independently selected from groups represented by Formulae 3-17 to 3-20, Y₁ in Formulae 3-17 to 3-20 may be C(Z₃)(Z₄):

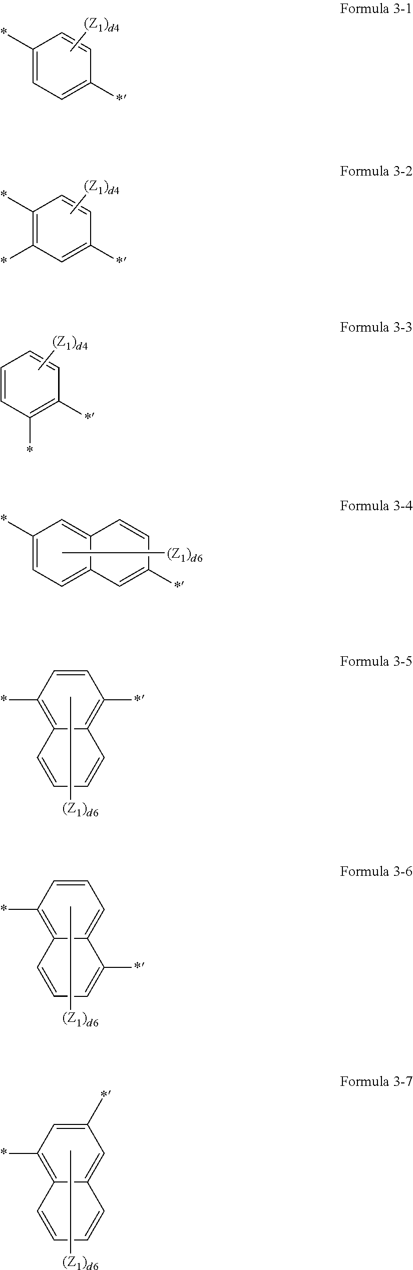

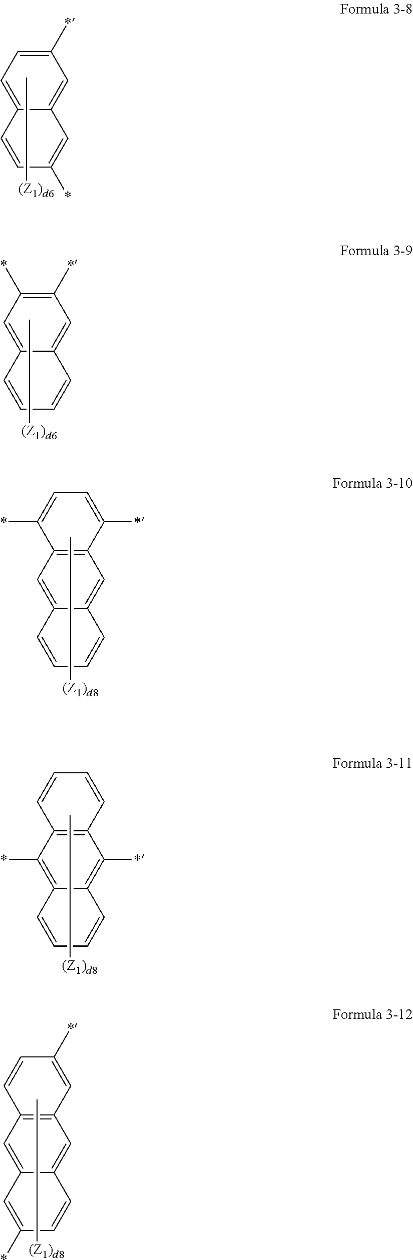

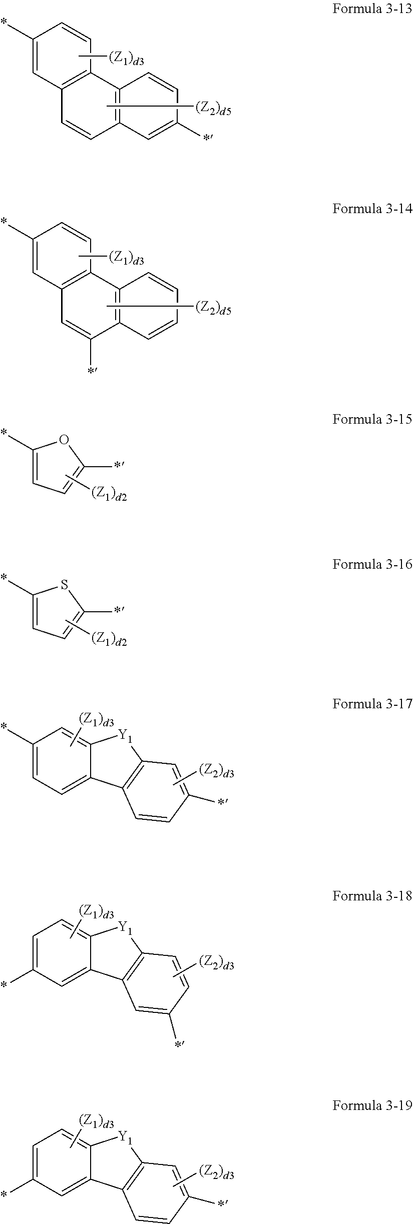

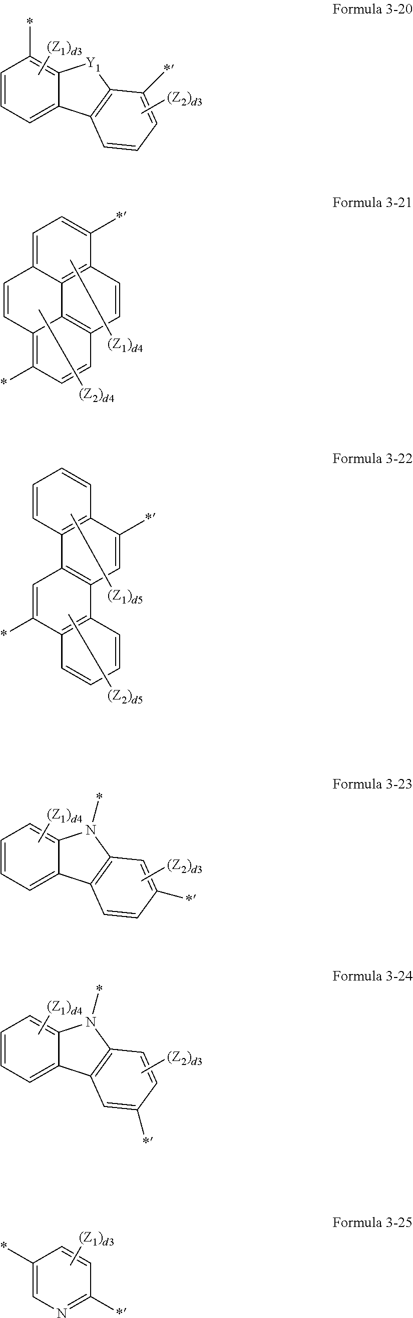

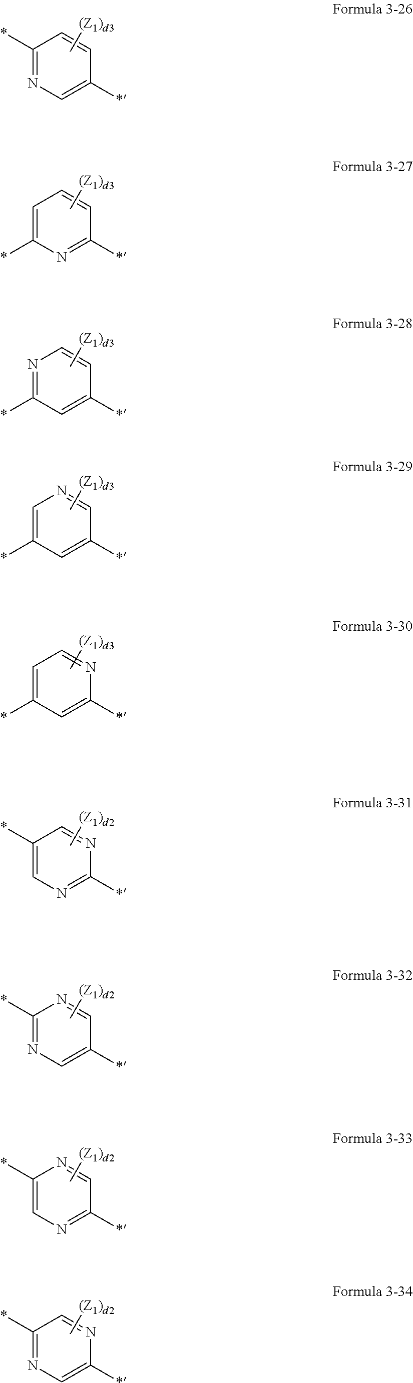

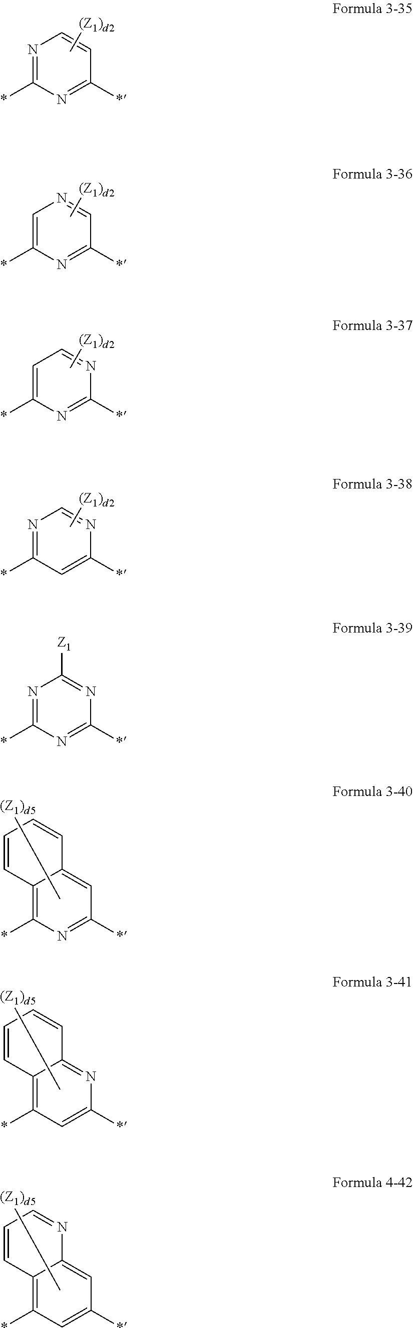

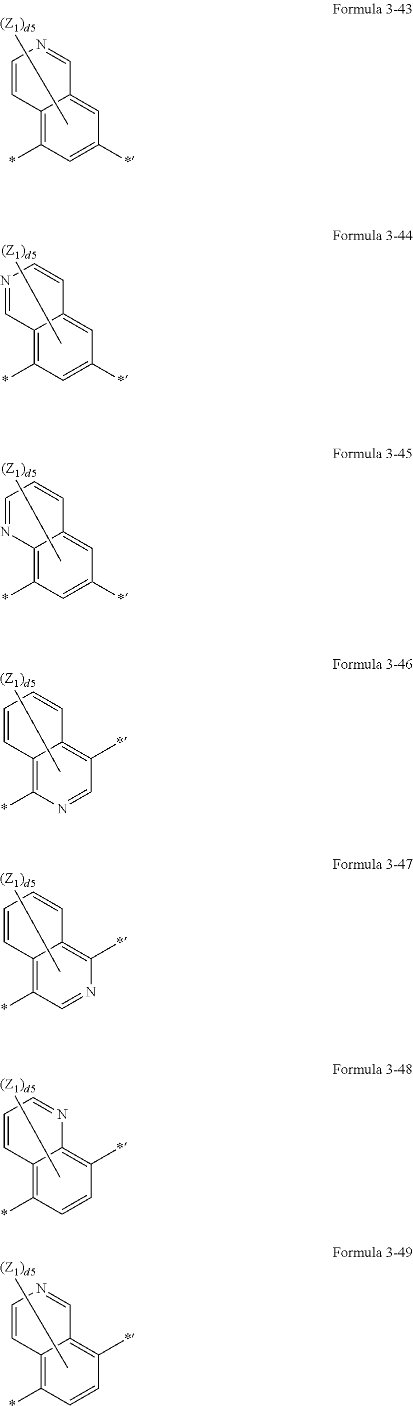

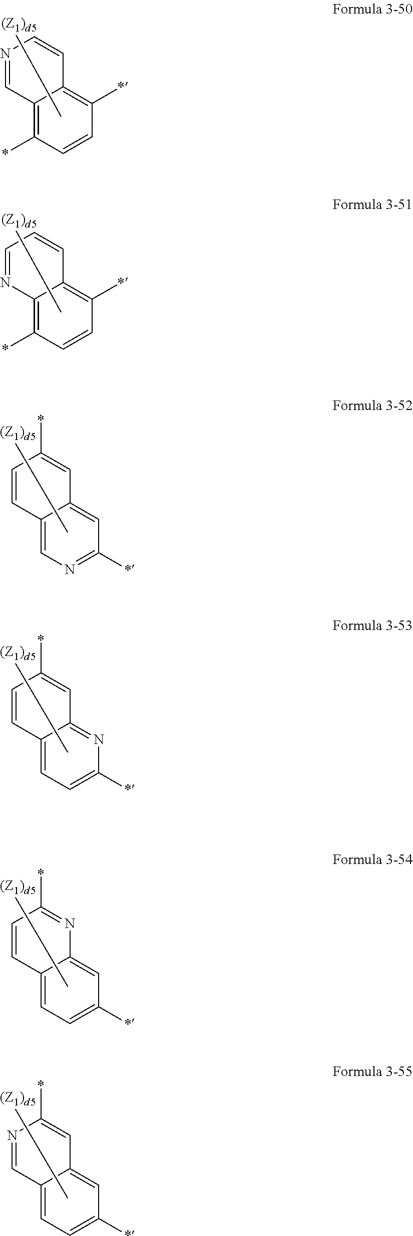

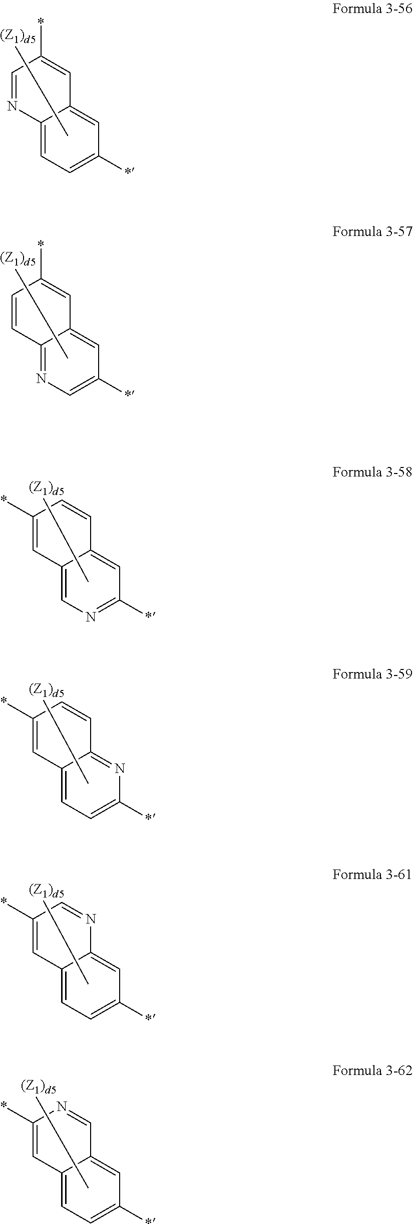

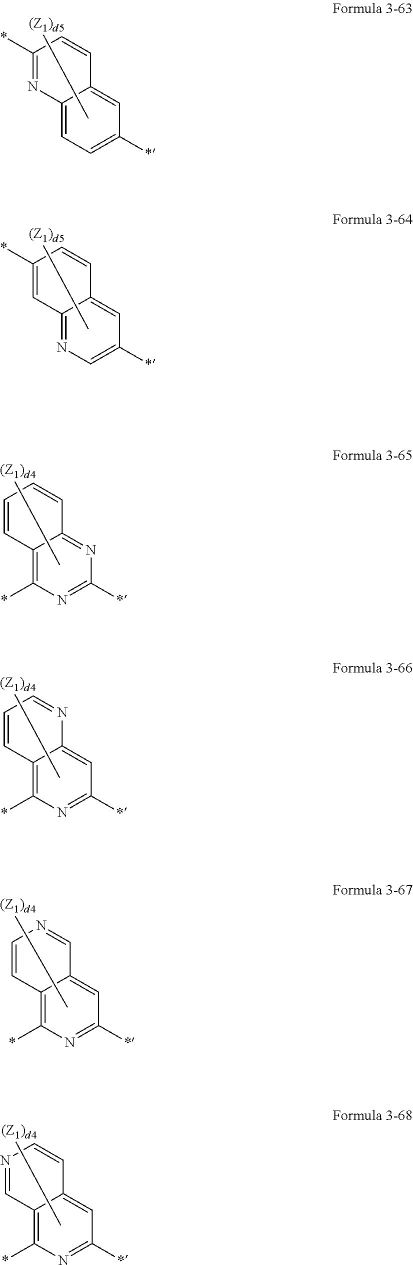

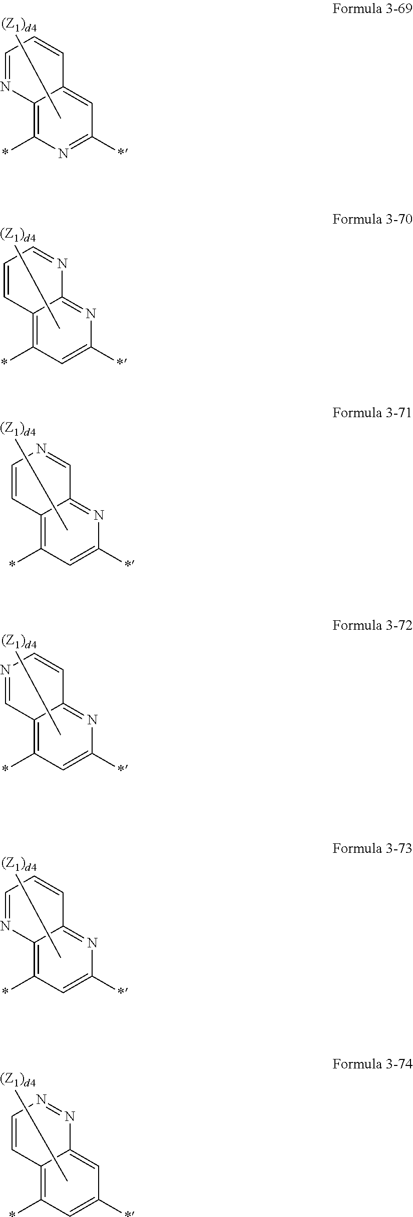

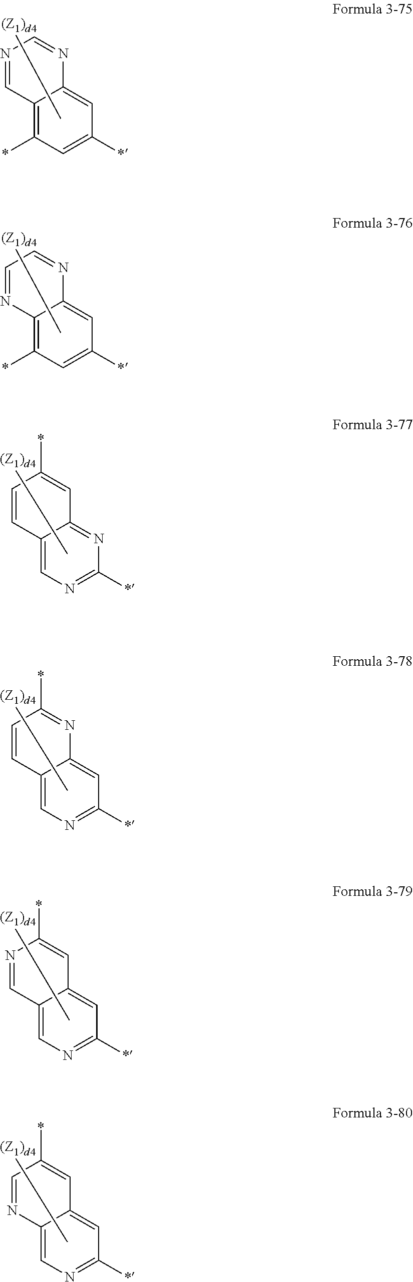

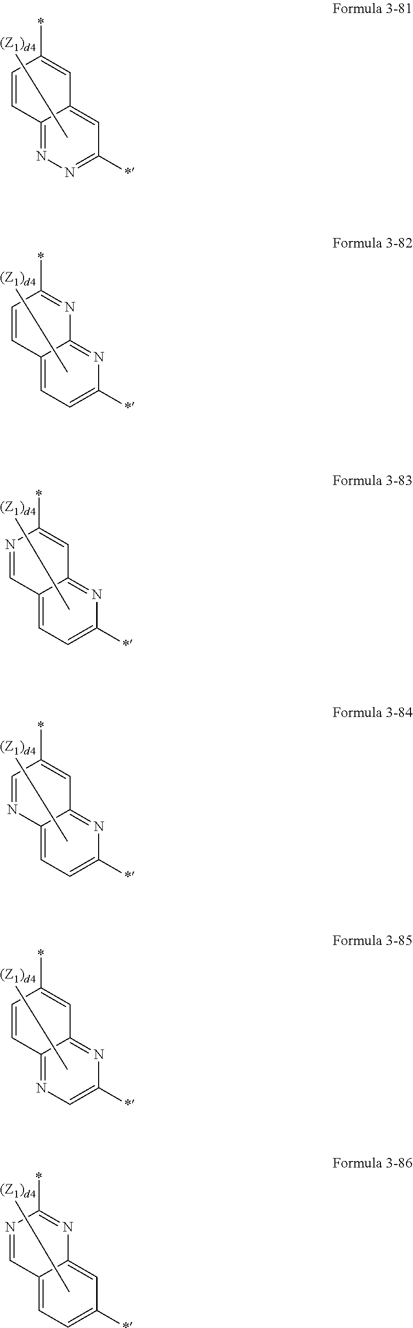

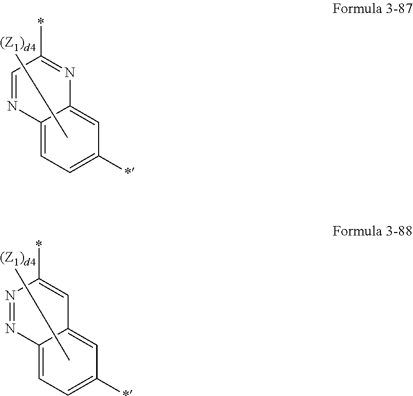

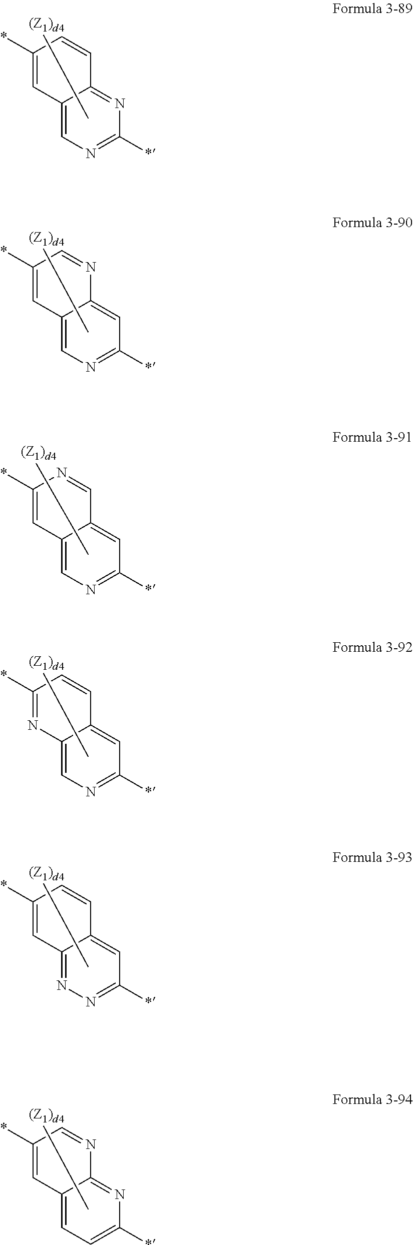

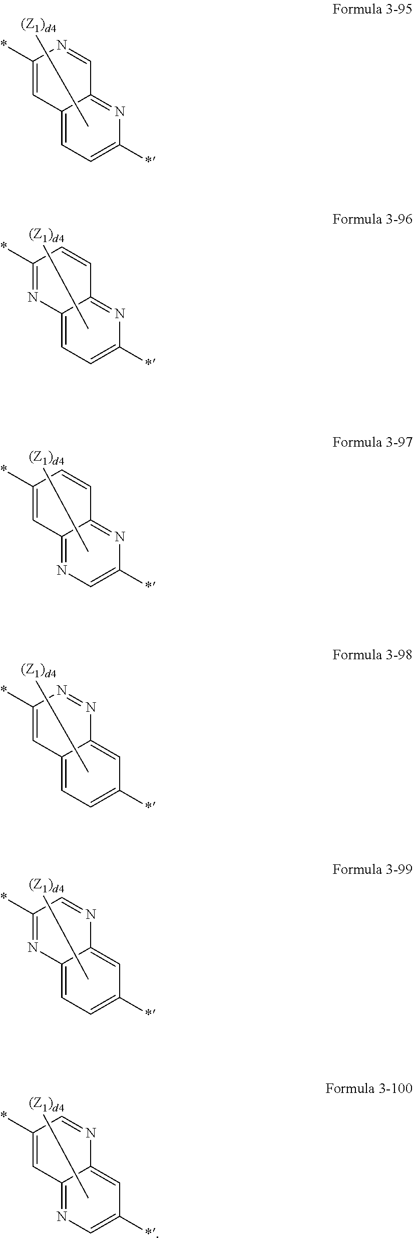

In Formulae 3-1 to 3-100,

Y₁ may be O, S, C(Z₃)(Z₄), N(Z₅), or Si(Z₆)(Z₇),

Z₁ to Z₇ may each independently be selected from hydrogen, deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, a silolyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an indolyl group, an isoindolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzimidazolyl group, a benzofuranyl group, a benzothiophenyl group, a benzosilolyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a dibenzosilolyl group, a carbazolyl group, a benzocarbazolyl group, a dibenzocarbazolyl group, a thiadiazolyl group, an imidazopyridinyl group, an imidazopyrimidinyl group, a benzonaphthyridinyl group, an azafluorenyl group, an azaspiro-bifluorenyl group, an azacarbazolyl group, an azadibenzofuranyl group, an azadibenzothiophenyl group, an azadibenzosilolyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), and —P(═O)(Q₃₁)(Q₃₂),

Q₃₁ to Q₃₃ may each independently be selected from the group consisting of: a C₁-C₁₀ alkyl group, a C₁-C₁₀ alkoxy group, a phenyl group, a biphenyl group, a terphenyl group, a naphthyl group, a pyridinyl group, a pyrimidinyl group, a pyrazinyl group, a quinolinyl group, an isoquinolinyl group, a quinoxalinyl group, and a quinazolinyl group; and

a phenyl group, a biphenyl group, a terphenyl group, a naphthyl group, a pyridinyl group, a pyrimidinyl group, a pyrazinyl group, a quinolinyl group, an isoquinolinyl group, a quinoxalinyl group, and a quinazolinyl group, each substituted with at least one selected from a C₁-C₁₀ alkyl group, a C₁-C₁₀ alkoxy group, and a phenyl group,

d2 may be an integer selected from 0 to 2,

d3 may be an integer selected from 0 to 3,

d4 may be an integer selected from 0 to 4,

d5 may be an integer selected from 0 to 5,

d6 may be an integer selected from 0 to 6,

d8 may be an integer selected from 0 to 8, and

* and *′ may each independently indicate a binding site to a neighboring atom.

a1 to a9, a21, and a22 in Formulae 1A to 1E and 2A to 2B indicate the numbers of L₁ to L₉, L₂₁, and L₂₂ groups, respectively. a1 to a7, a21, and a22 in Formulae 1A to 1E and 2A to 2B may each independently be an integer selected from 0 to 5. When a1 is two or more, two or more L₁(s) may be identical to or different from each other; when a2 is two or more, two or more L₂(s) may be identical to or different from each other; when a3 is two or more, two or more L₃(s) may be identical to or different from each other; when a4 is two or more, two or more L₄(s) may be identical to or different from each other; when a5 is two or more, two or more L₅(s) may be identical to or different from each other; when a6 is two or more, two or more L₆(s) may be identical to or different from each other; when a7 is two or more, two or more L₇(s) may be identical to or different from each other; when a8 is two or more, two or more L₈(s) may be identical to or different from each other; when a9 is two or more, two or more L₉(s) may be identical to or different from each other; when a21 is two or more, two or more L₂₁(s) may be identical to or different from each other; and when a22 is two or more, two or more L₂₂(s) may be identical to or different from each other. When a1 is 0, *-(L₁)ₐ₁-*′ indicates a single bond; when a2 is 0, *-(L₂)ₐ₂-*′ indicates a single bond; when a3 is 0, *-(L₅)ₐ₅-*′ indicates a single bond; when a4 is 0, *-(L₄)ₐ₄-*′ indicates a single bond; when a5 is 0, *-(L₅)ₐ₅-*′ indicates a single bond; when a6 is 0, *-(L₆)ₐ₆-*′ indicates a single bond; when a7 is 0, *-(L₇)ₐ₇-*′ indicates a single bond; when a8 is 0, *-(L₈)ₐ₈-*′ indicates a single bond; when a9 is 0, *-(L₉)ₐ₉-*′ indicates a single bond; when a21 is 0, *-(L₂₁)ₐ₂₁-*′ indicates a single bond; and when a22 is 0, *-(L₂₂)ₐ₂₂-*′ indicates a single bond.

In one embodiment, a1 to a9, a21, and a22 in Formulae 1A to 1E and 2A to 2B may each independently be an integer selected from 0 to 3, but embodiments of the present disclosure are not limited thereto.

In Formulae 1A to 1E, 2A, and 2B,

R₁ to R₉ may each independently be selected from hydrogen, deuterium (-D), —F, —Cl, —Br, —I, a hydroxyl group, a cyano group, a nitro group, an amidino group, a hydrazino group, a hydrazono group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, —Si(Q₁)(Q₂)(Q₃), —N(Q₁)(Q₂), —B(Q₁)(Q₂), —C(═O)(Q₁), —S(═O)₂(Q₁), and —P(═O)(Q₁)(Q₂),

R₂₁ to R₂₄ may each independently be selected from hydrogen, deuterium (-D), —F, —Cl, —Br, —I, a hydroxyl group, a cyano group, a nitro group, an amidino group, a hydrazino group, a hydrazono group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₄)(Q₅)(Q₆), —N(Q₄)(Q₅), —B(Q₄)(Q₅), —C(═O)(Q₄), —S(═O)₂(Q₄), and —P(═O)(Q₄)(Q₅). Q₁ to Q₆ may each independently be the same as described above.

For example, in Formulae 1A to 1E, 2A, and 2B,

R₁ to R₉ may each independently be selected from the group consisting of:

hydrogen, deuterium, —F, —Cl, —Br, —I, a hydroxyl group, a cyano group, a nitro group, an amidino group, a hydrazino group, a hydrazono group, a C₁-C₂₀ alkyl group, and a C₁-C₂₀ alkoxy group;

a cyclopentyl group, a cyclohexyl group, a cycloheptyl group, a cyclopentenyl group, a cyclohexenyl group, a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a spiro-benzofluorene-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, a silolyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an indolyl group, an isoindolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzimidazolyl group, a benzofuranyl group, a benzothiophenyl group, a benzosilolyl group, an isobenzothiazolyl group, a benzoxazolyl group, an isobenzoxazolyl group, a triazolyl group, a tetrazolyl group, an oxadiazolyl group, a triazinyl group, a benzocarbazolyl group, a dibenzocarbazolyl group, a thiadiazolyl group, an imidazopyridinyl group, an imidazopyrimidinyl group, an oxazolopyridinyl group, a thiazolopyridinyl group, a benzonaphthyridinyl group, an azafluorenyl group, an azaspiro-bifluorenyl group, an azacarbazolyl group, an azadibenzofuranyl group, an azadibenzothiophenyl group, an azadibenzosilolyl group, —Si(Q₁)(Q₂)(Q₃), —N(Q₁)(Q₂), —B(Q₁)(Q₂), —C(═O)(Q₁), —S(═O)₂(Q₁), and —P(═O)(Q₁)(Q₂), and

a cyclopentyl group, a cyclohexyl group, a cycloheptyl group, a cyclopentenyl group, a cyclohexenyl group, a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a spiro-benzofluorene-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, a silolyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an indolyl group, an isoindolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzimidazolyl group, a benzofuranyl group, a benzothiophenyl group, a benzosilolyl group, an isobenzothiazolyl group, a benzoxazolyl group, an isobenzoxazolyl group, a triazolyl group, a tetrazolyl group, an oxadiazolyl group, a triazinyl group, a benzocarbazolyl group, a dibenzocarbazolyl group, a thiadiazolyl group, an imidazopyridinyl group, an imidazopyrimidinyl group, an oxazolopyridinyl group, a thiazolopyridinyl group, a benzonaphthyridinyl group, an azafluorenyl group, an azaspiro-bifluorenyl group, an azacarbazolyl group, an azadibenzofuranyl group, an azadibenzothiophenyl group, and an azadibenzosilolyl group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, a monovalent non-aromatic condensed heteropolycyclic group, a biphenyl group, a terphenyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), and —P(═O)(Q₃₁)(Q₃₂),

R₂₁ to R₂₄, R₂₇, and R₂₈ may each independently be selected from the group consisting of:

hydrogen, deuterium, —F, —Cl, —Br, —I, a hydroxyl group, a cyano group, a nitro group, an amidino group, a hydrazino group, a hydrazono group, a C₁-C₂₀ alkyl group, and a C₁-C₂₀ alkoxy group;

a cyclopentyl group, a cyclohexyl group, a cycloheptyl group, a cyclopentenyl group, a cyclohexenyl group, a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a spiro-benzofluorene-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, a silolyl group, an imidazolyl group, a pyrazolyl group, a thiazolyl group, an isothiazolyl group, and oxazolyl group, an isoxazolyl group, a pyridinyl group, a pyrazinyl group, a pyrimidinyl group, a pyridazinyl group, an indolyl group, an isoindolyl group, an indazolyl group, a purinyl group, a quinolinyl group, an isoquinolinyl group, a benzoquinolinyl group, a phthalazinyl group, a napthyridinyl group, a quinoxalinyl group, a quinazolinyl group, a cinnolinyl group, a phenanthridinyl group, an acridinyl group, a phenanthrolinyl group, a phenazinyl group, a benzimidazolyl group, a benzofuranyl group, a benzothiophenyl group, a benzosilolyl group, an isobenzothiazolyl group, a benzoxazoyl group, an isobenzoxazolyl group, a triazolyl group, a tetrazolyl group, an oxadiazolyl group, a trianzinyl group, a dibenzofuranyl group, a dibenzothiophenyl group, a dibenzosilolyl group, a carbazolyl group, a benzocarbazolyl group, a dibenzocarbazolyl group, a thiadiazolyl group, an imidazopyridinyl group, an imidazopyrimidinyl group, and oxazolopyridinyl group, a thiazolopyridinyl group, a benzonaphthyridinyl group, an azafluorenyl group, an azaspiro-bifluorenyl group, an azacarbazolyl group, an azadibenzofuranyl group, an azadibenzothiophenyl group, an azadibenzosilolyl group, —Si(Q₄)(Q₅)(Q₆), —N(Q₄)(Q₅), —B(Q₄)(Q₅), —C(═O)(Q₄), —S(═O)₂(Q₄), and —P(═O)(Q₄)(Q₅); and

a cyclopentyl group, a cyclohexyl group, a cycloheptyl group, a cyclopentenyl group, a cyclohexenyl group, a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a spiro-benzofluorene-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacentyl group, a rubicenyl group, a coronenyl group, an ovalenyl group, a pyrrolyl group, a thiophenyl group, a furanyl group, a silolyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an indolyl group, an isoindolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzimidazolyl group, a benzofuranyl group, a benzothiophenyl group, a benzosilolyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a dibenzosilolyl group, a carbazolyl group, a benzocarbazolyl group, a dibenzocarbazolyl group, a thiadiazolyl group, an imidazopyridinyl group, an imidazopyrimidinyl group, an oxazolopyridinyl group, a thiazolopyridinyl group, a benzonaphthyridinyl group, an azafluorenyl group, an azaspiro-bifluorenyl group, an azacarbazolyl group, an azadibenzofuranyl group, an azadibenzothiophenyl group, and an azadibenzosilolyl group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, a monovalent non-aromatic condensed heteropolycyclic group, a biphenyl group, a terphenyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), and —P(═O)(Q₃₁)(Q₃₂),

wherein Q₁ to Q₆ and Q₃₁ to Q₃₃ may each independently be selected from the group consisting of:

a C₁-C₁₀ alkyl group, a C₁-C₁₀ alkoxy group, a phenyl group, a biphenyl group, a terphenyl group, a naphthyl group, a pyridinyl group, a pyrimidinyl group, a pyrazinyl group, a quinolinyl group, an isoquinolinyl group, a quinoxalinyl group, and a quinazolinyl group; and

a phenyl group, a biphenyl group, a terphenyl group, a naphthyl group, a pyridinyl group, a pyrimidinyl group, a pyrazinyl group, a quinolinyl group, an isoquinolinyl group, a quinoxalinyl group, and a quinazolinyl group, each substituted with at least one selected from a C₁-C₁₀ alkyl group, a C₁-C₁₀ alkoxy group, and a phenyl group.

For example, in Formulae 1A to 1E, 2A, and 2B,

R₁ to R₉ may each independently be selected from the group consisting of:

hydrogen, deuterium, —F, —Cl, —Br, —I, a hydroxyl group, a cyano group, a nitro group, an amidino group, a hydrazino group, a hydrazono group, a C₁-C₂₀ alkyl group, and a C₁-C₂₀ alkoxy group;

a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a spiro-benzofluorene-fluorenyl group, an indenofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzimidazolyl group, an isobenzothiazolyl group, a benzoxazolyl group, an isobenzoxazolyl group, a triazolyl group, a tetrazolyl group, an oxadiazolyl group, a triazinyl group, a thiadiazolyl group, an imidazopyridinyl group, an imidazopyrimidinyl group, —Si(Q₁)(Q₂)(Q₃), —N(Q₁)(Q₂), —B(Q₁)(Q₂), —C(═O)(Q₁), —S(═O)₂(Q₁), and —P(═O)(Q₁)(Q₂), and

a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a spiro-benzofluorene-fluorenyl group, an indenofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzimidazolyl group, an isobenzothiazolyl group, a benzoxazolyl group, an isobenzoxazolyl group, a triazolyl group, a tetrazolyl group, an oxadiazolyl group, a triazinyl group, a thiadiazolyl group, an imidazopyridinyl group, and an imidazopyrimidinyl group, each substituted with at least one selected from deuterium, —F, —Cl, —Br, —I, a hydroxyl group, a cyano group, a nitro group, an amidino group, a hydrazino group, a hydrazono group, a C₁-C₁₀ alkyl group, a C₁-C₁₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, a monovalent non-aromatic condensed heteropolycyclic group, a biphenyl group, a terphenyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), and —P(═O)(Q₃₁)(Q₃₂),

R₂₁ to R₂₄, R₂₇, and R₂₈ may each independently be selected from the group consisting of:

a phenyl group, a biphenyl group, a terphenyl group, a pentalenyl group, an indenyl group, a naphthyl group, an azulenyl group, an indacenyl group, an acenaphthyl group, a fluorenyl group, a spiro-bifluorenyl group, a benzofluorenyl group, a dibenzofluorenyl group, a spiro-benzofluorene-fluorenyl group, an indenofluorenyl group, a phenalenyl group, a phenanthrenyl group, an anthracenyl group, a fluoranthenyl group, a triphenylenyl group, a pyrenyl group, a chrysenyl group, a picenyl group, a perylenyl group, a pentaphenyl group, a hexacenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a dibenzosilolyl group, a thiadiazolyl group, an imidazopyridinyl group, an imidazopyrimidinyl group, —Si(Q₄)(Q₅)(Q₆), —N(Q₄)(Q₅), —B(Q₄)(Q₆), —C(═O)(Q₄), —S(═O)₂(Q₄), and —P(═O)(Q₄)(Q₅); and

a phenyl group, a biphenyl group, a terphenyl group, a pentalenyl group, an indenyl group, a naphthyl group, an azulenyl group, an indacenyl group, an acenaphthyl group, a fluorenyl group, a spiro-bifluorenyl group, a benzofluorenyl group, a dibenzofluorenyl group, a spiro-benzofluorene-fluorenyl group, an indenofluorenyl group, a phenalenyl group, a phenanthrenyl group, an anthracenyl group, a fluoranthenyl group, a triphenylenyl group, a pyrenyl group, a chrysenyl group, a picenyl group, a perylenyl group, a pentaphenyl group, a pentacenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a dibenzosilolyl group, a thiadiazolyl group, an imidazopyridinyl group, and an imidazopyrimidinyl group, each substituted with at least one selected from deuterium, —F, —Cl, —Br, —I, a hydroxyl group, a cyano group, a nitro group, an amidino group, a hydrazino group, a hydrazono group, a C₁-C₁₀ alkyl group, a C₁-C₁₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, a monovalent non-aromatic condensed heteropolycyclic group, a biphenyl group, a terphenyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), and —P(═O)(Q₃₁)(Q₃₂),

R₂₂ to R₂₄, R₂₇, and R₂₈ may each independently be selected from hydrogen, deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, —Si(Q₄)(Q₅)(Q₆), —S(═O)₂(Q₄), and —P(═O)(Q₄)(Q₅), and

Q₁ to Q₆ and Q₃₁ to Q₃₃ may each independently be selected from the group consisting of:

a C₁-C₁₀ alkyl group, a C₁-C₁₀ alkoxy group, a phenyl group, a biphenyl group, a terphenyl group, a naphthyl group, a pyridinyl group, a pyrimidinyl group, a pyrazinyl group, a quinolinyl group, an isoquinolinyl group, a quinoxalinyl group, and a quinazolinyl group; and

a phenyl group, a biphenyl group, a terphenyl group, a naphthyl group, a pyridinyl group, a pyrimidinyl group, a pyrazinyl group, a quinolinyl group, an isoquinolinyl group, a quinoxalinyl group, and a quinazolinyl group, each substituted with at least one selected from a C₁-C₁₀ alkyl group, a C₁-C₁₀ alkoxy group, and a phenyl group.

In one or more embodiments, in Formulae 1A to 1E, 2A, and 2B,

R₁ to R₉ may each independently be selected from the group consisting of:

hydrogen, deuterium, —F, —Cl, —Br, —I, a hydroxyl group, a cyano group, a nitro group, an amidino group, a hydrazino group, a hydrazono group, a C₁-C₂₀ alkyl group, and a C₁-C₂₀ alkoxy group;

a group represented by any of Formulae 5-1 to 5-44, 6-1 to 6-121, 6-123, and 6-124; and

—Si(Q₁)(Q₂)(Q₃), —N(Q₁)(Q₂), —B(Q₁)(Q₂), —C(═O)(Q₁), —S(═O)₂(Q₁), and —P(═O)(Q₁)(Q₂),

when R₁ to R₉ are selected from groups represented by Formulae 5-13 to 5-36 and 5-43, Y₃₁ and Y₃₂ in Formulae 5-13 to 5-36 and 5-43 may each independently be C(Z₃₃)(Z₃₄),

R₂₁ may be selected from groups represented by Formulae 5-1 to 5-45 and 6-1 to 6-124,

R₂₂ to R₂₄, R₂₇, and R₂₈ may each independently be selected from the group consisting of:

hydrogen, deuterium, —F, —Cl, —Br, —I, a hydroxyl group, a cyano group, a nitro group, an amidino group, a hydrazino group, a hydrazono group, a C₁-C₂₀ alkyl group, and a C₁-C₂₀ alkoxy group;

a group represented by any of Formulae 5-1 to 5-45 and Formulae 6-1 to 6-124; and

—Si(Q₄)(Q₅)(Q₆), —N(Q₄)(Q₅), —B(Q₄)(Q₅), —C(═O)(Q₄), —S(═O)₂(Q₄), and —P(═O)(Q₄)(Q₅), but embodiments of the present disclosure are not limited thereto:

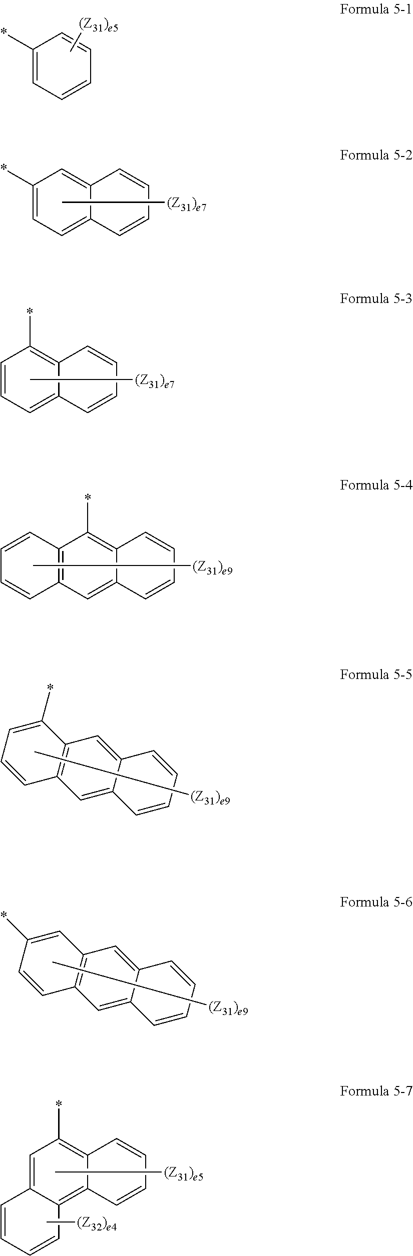

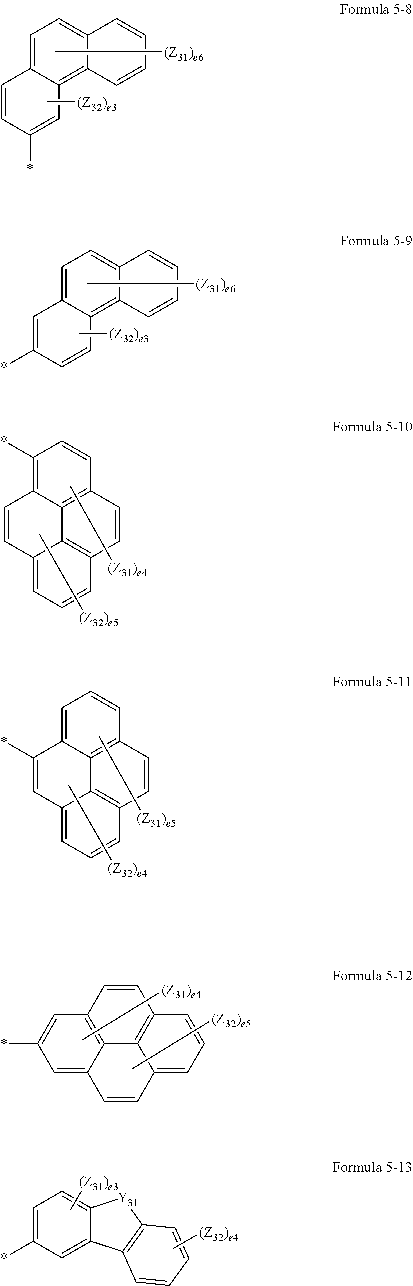

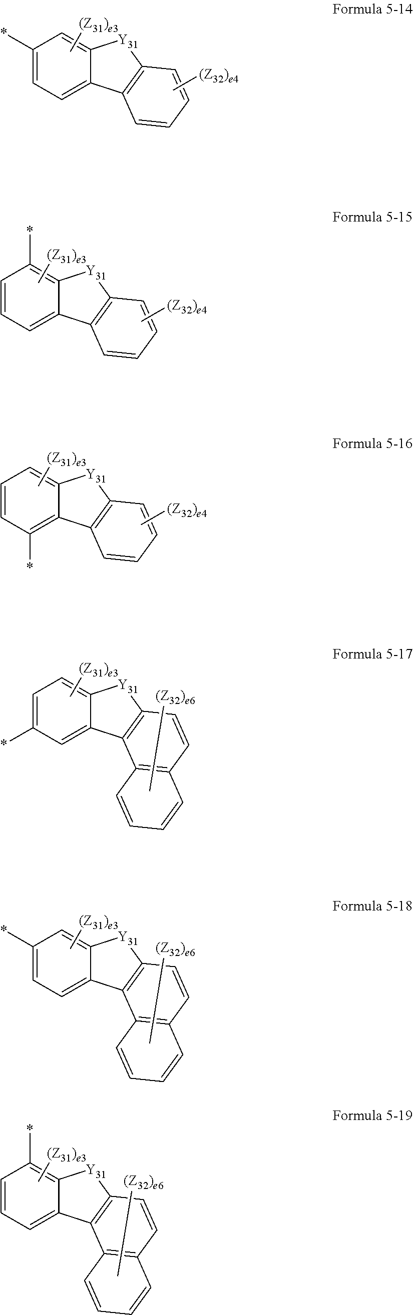

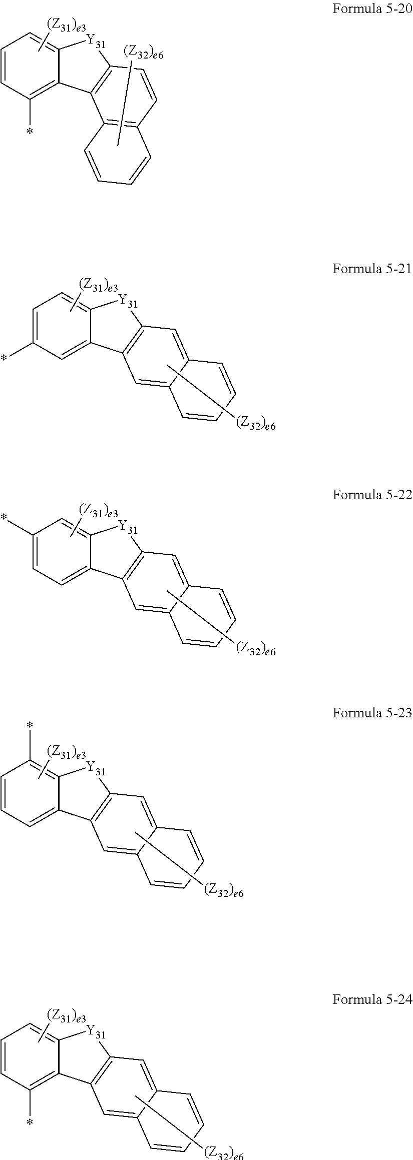

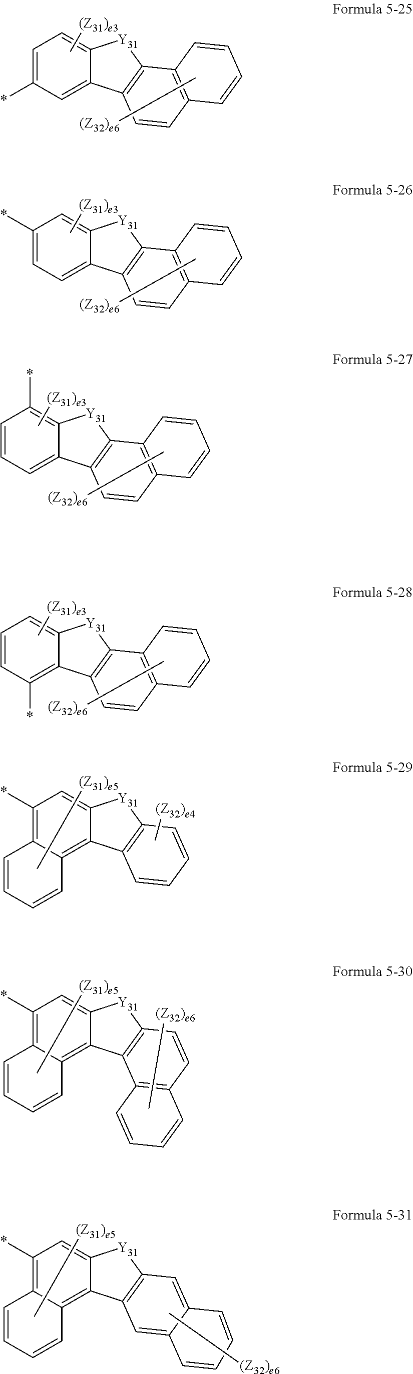

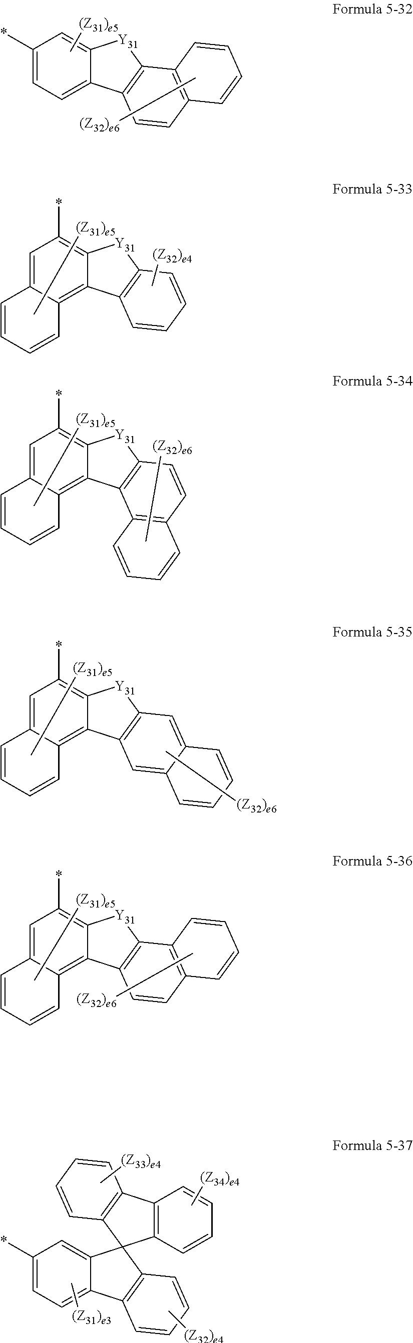

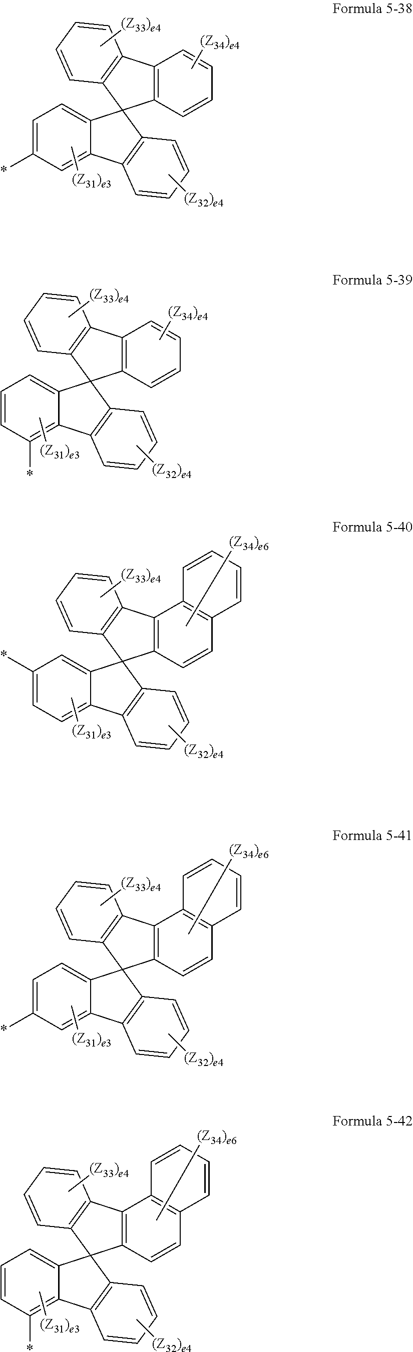

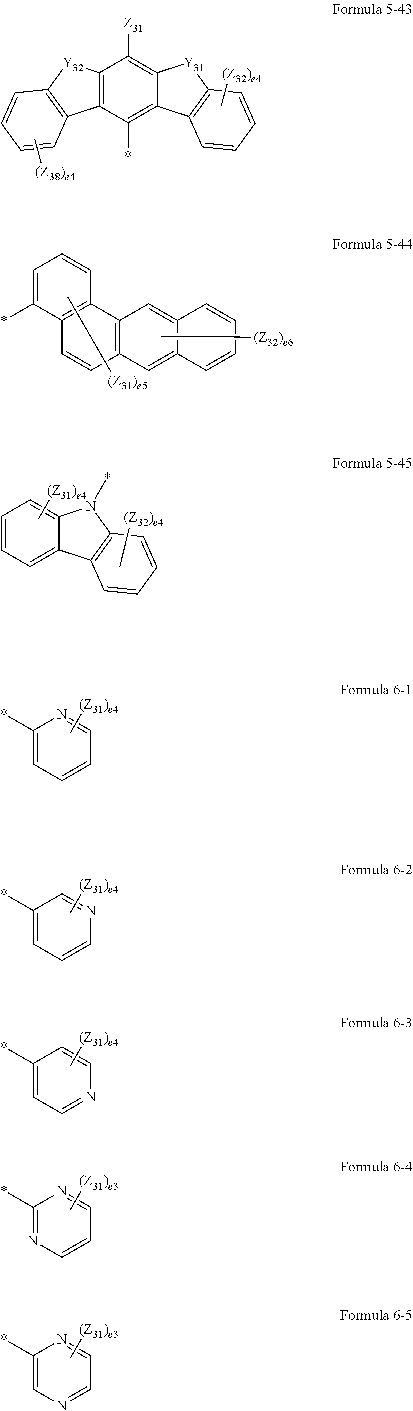

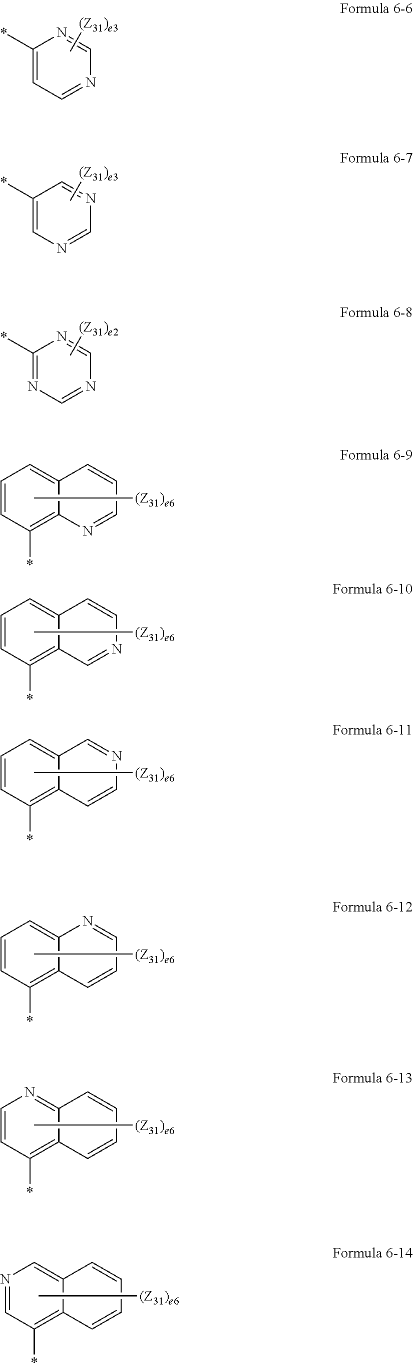

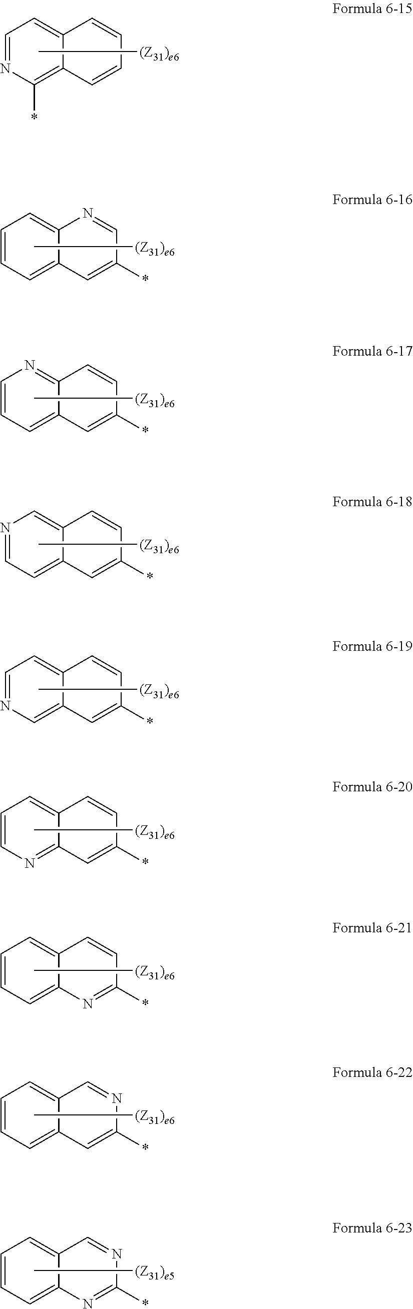

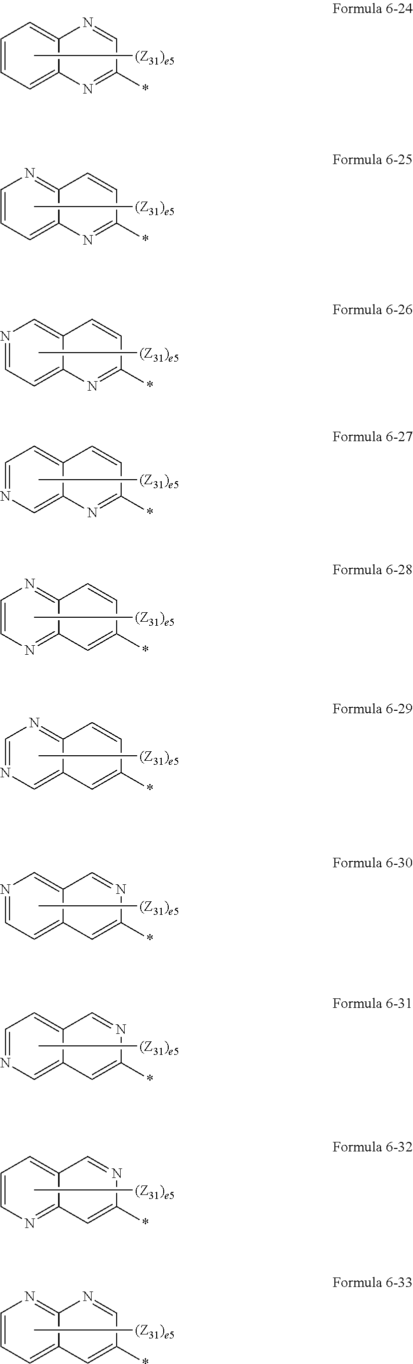

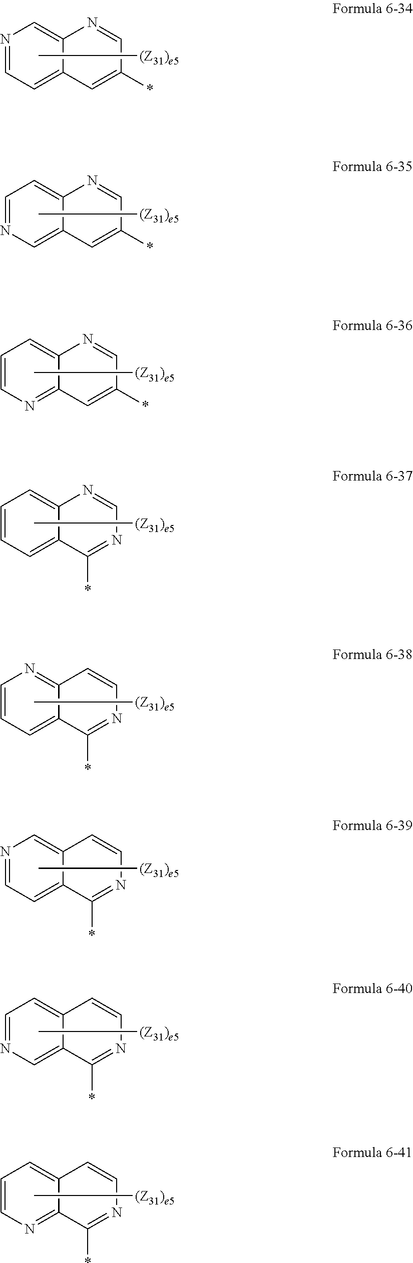

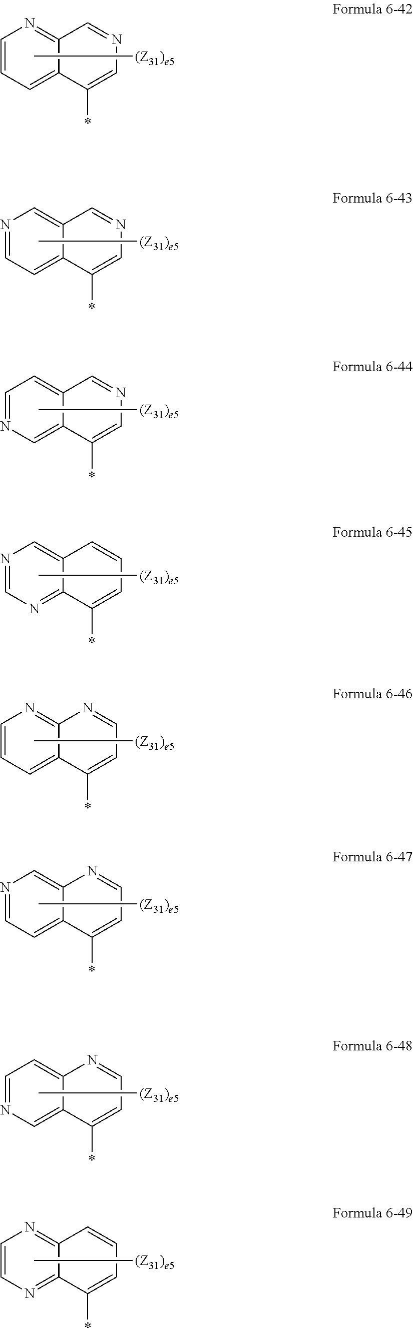

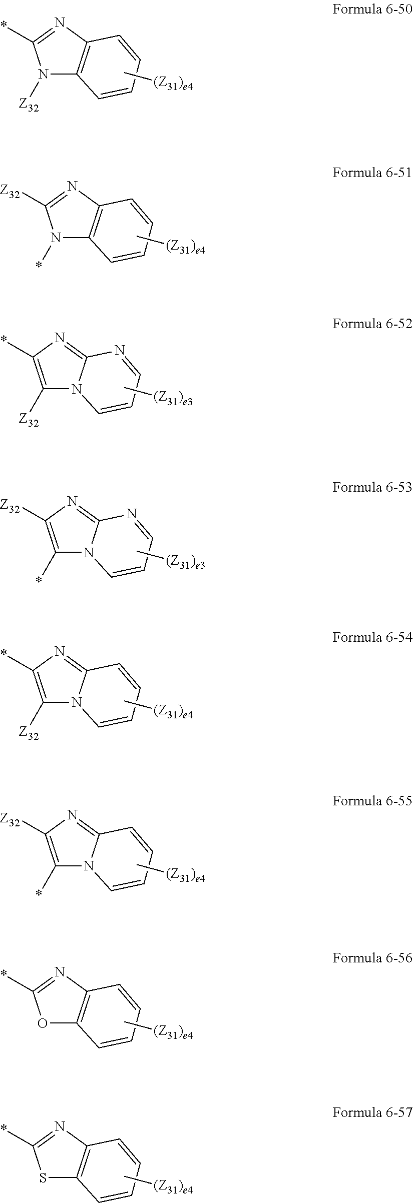

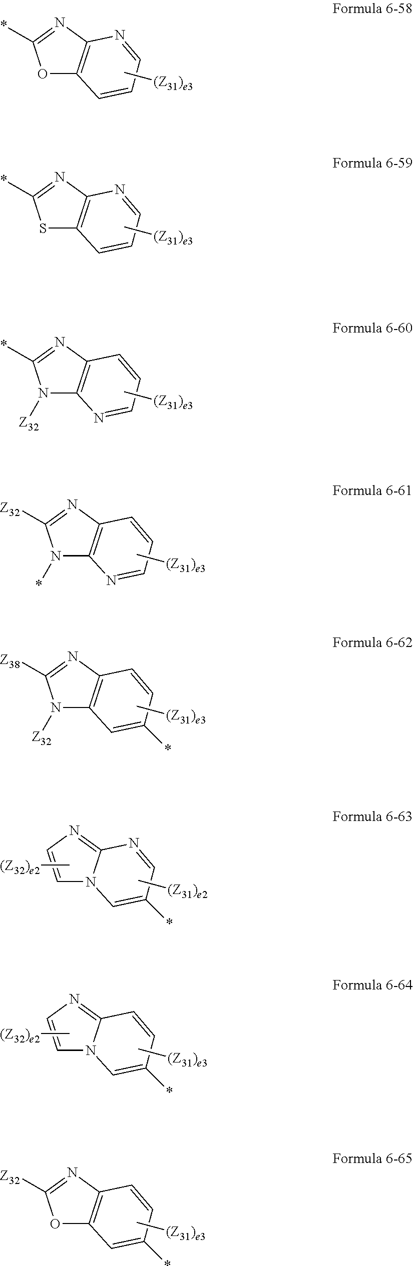

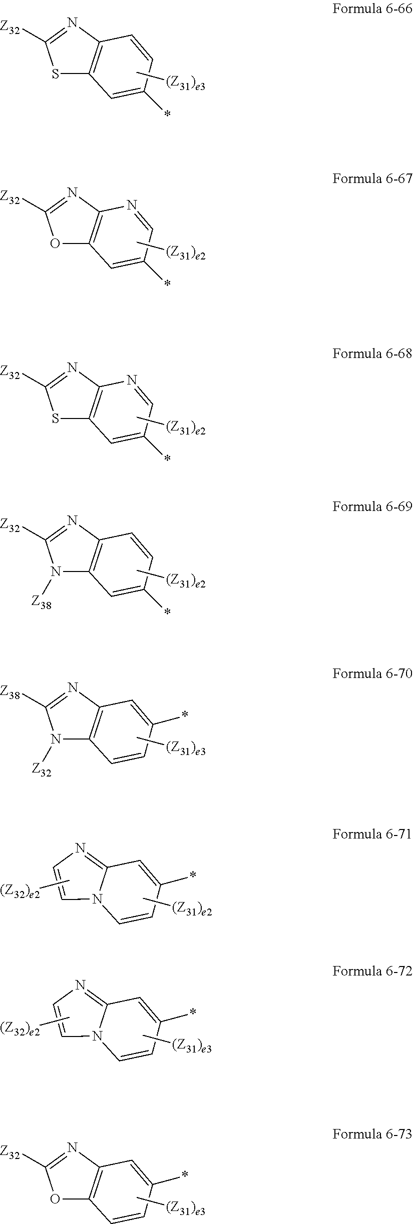

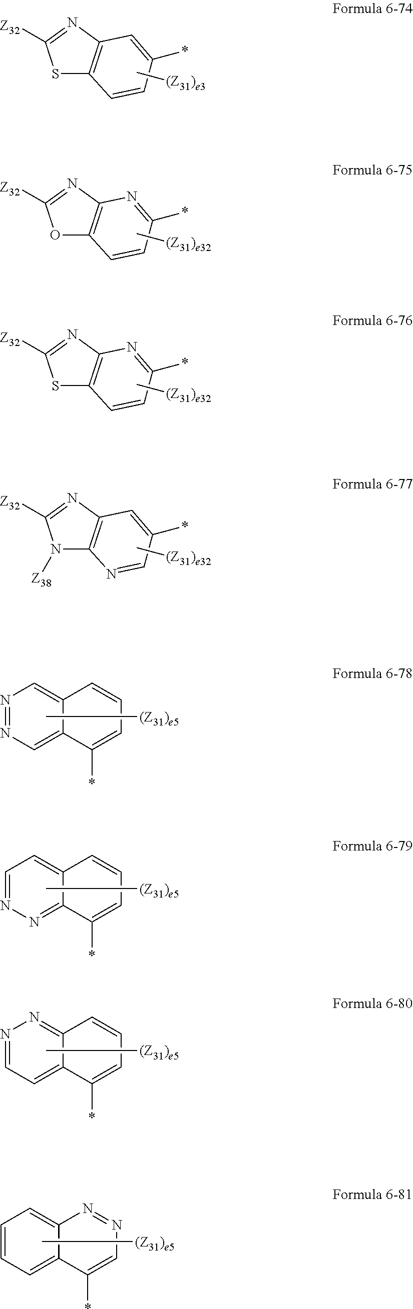

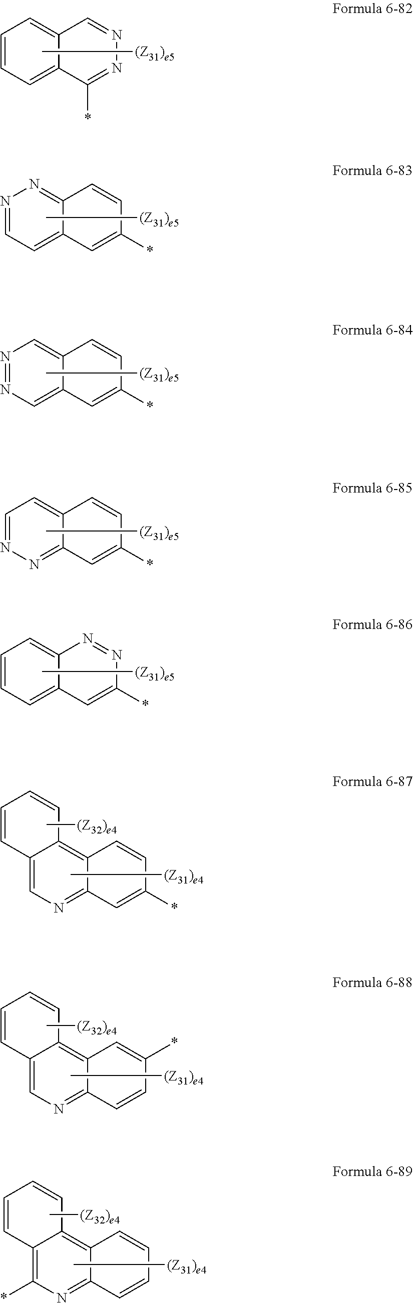

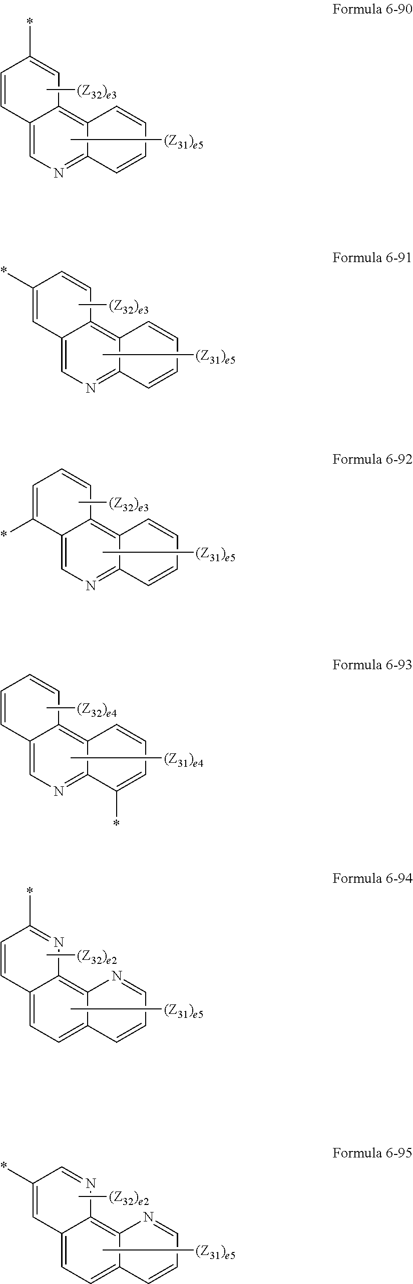

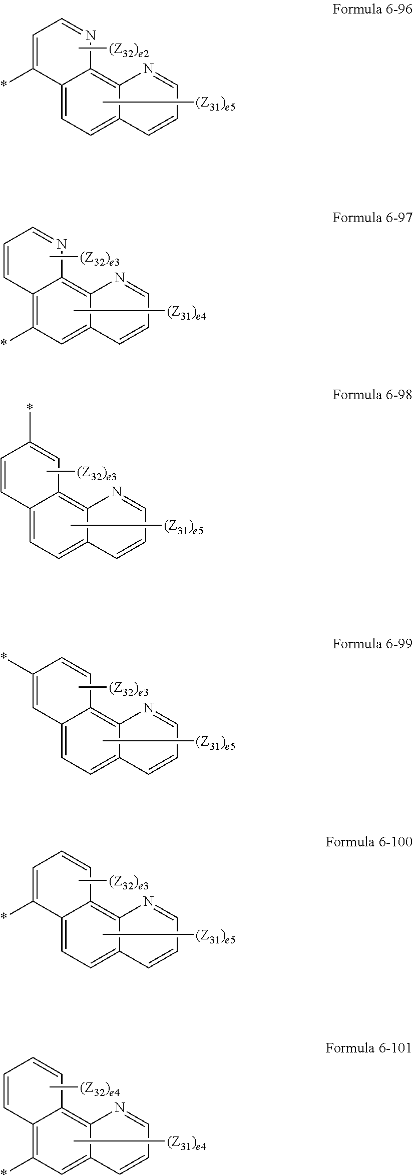

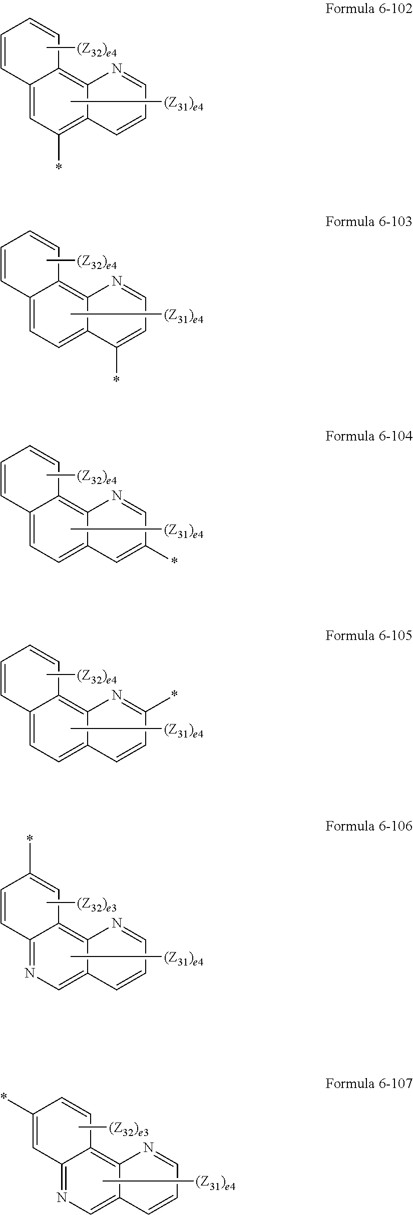

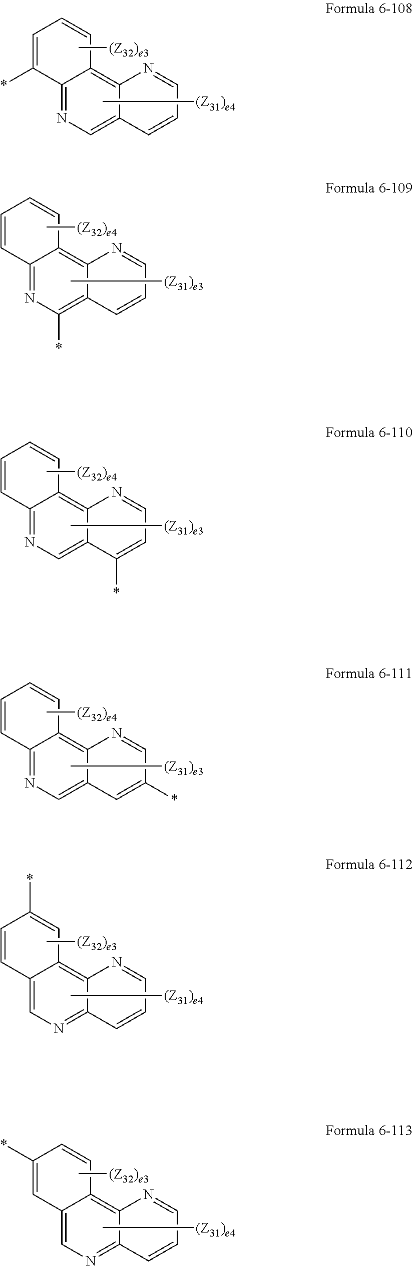

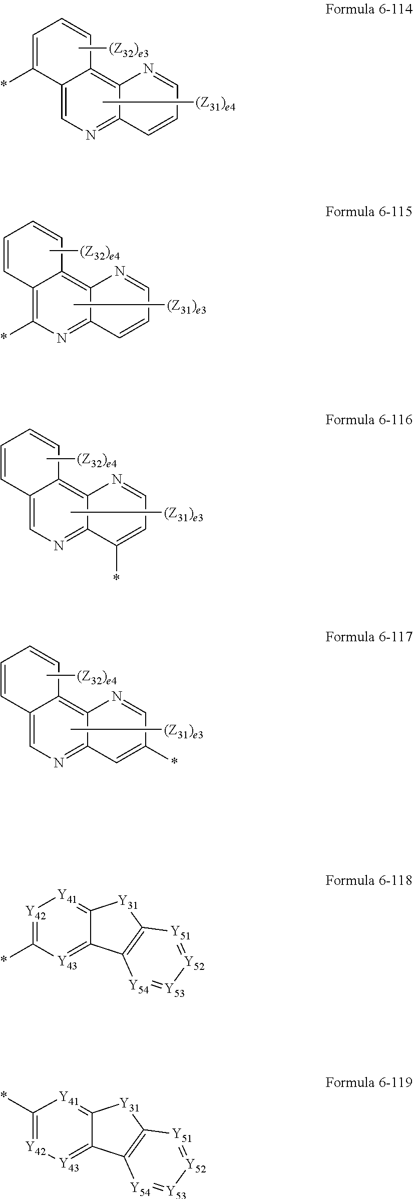

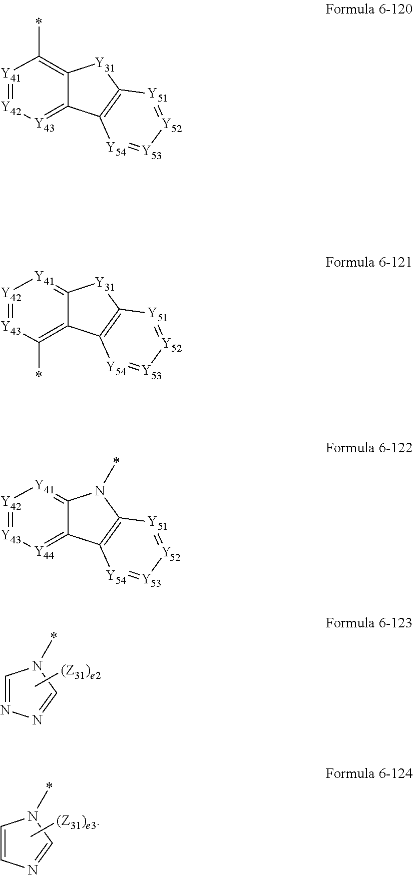

In Formulae 5-1 to 5-45 and 6-1 to 6-124,

Y₃₁ and Y₃₂ may each independently be O, S, C(Z₃₃)(Z₃₄), N(Z₃₅), or Si(Z₃₆)(Z₃₇),

Y₄₁ may be N or C(Z₄₁), Y₄₂ may be N or C(Z₄₂), Y₄₃ may be N or C(Z₄₃), Y₄₄ may be N or C(Z₄₄), Y₅₁ may be N or C(Z₅₁), Y₅₂ may be N or C(Z₅₂), Y₅₃ may be N or C(Z₅₃), Y₅₄ may be N or C(Z₅₄), at least one selected from Y₄₁ to Y₄₃ and Y₅₁ to Y₅₄ in Formulae 5-118 to 5-121 may be N, and at least one selected from Y₄₁ to Y₄₄ and Y₅₁ to Y₅₄ in Formula 5-122 may be N,

Z₃₁ to Z₃₇, Z₄₁ to Z₄₄, and Z₅₁ to Z₅₄ may each independently be selected from hydrogen, deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group a pentacenyl group, a rubicenyl group, a coronenyl group, an ovalenyl group, a pyrrolyl group, a thiophenyl group, a furanyl group, a silolyl group, and imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an indolyl group, an isoindolyl group, an indazolyl group, a purinyl group, a quinolinyl group, an isoquinolinyl group, a benzoquinolinyl group, a phthalazinyl group, a naphthyridinyl group, a quinozalinyl group, a quinazolinyl group, a cinnolinyl group, a phenanthridinyl group, an acridinyl group, a phenanthrolinyl group, a phenazinyl group, a benzimidazolyl group, a benzofuranyl group, a benzothiophenyl group, a benzosilolyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a dibenzosilolyl group, a carbazolyl group, a benzocarbazolyl group, a dibenzocarbazolyl group, a thiadiazolyl group, an imidazopyridinyl group, an imidazopyrimidinyl group, a benzoaphthyridinyl group, an azafluorenyl group, an azaspiro-bifluorenyl group, an azacarbazolyl group, an azadibenzofuranyl group, an azadibenzothiophenyl group, an azadibenzosilolyl group, and —Si(Q₃₁)(Q₃₂)(Q₃₃),

Q₁ to Q₃ and Q₃₁ to Q₃₃ may each independently be selected from the group consisting of:

a C₁-C₁₀ alkyl group, a C₁-C₁₀ alkoxy group, a phenyl group, a biphenyl group, a terphenyl group, a naphthyl group, a pyridinyl group, a pyrimidinyl group, a pyrazinyl group, a quinolinyl group, an isoquinolinyl group, a quinoxalinyl group, and a quinazolunyl group; and

a phenyl group, a biphenyl group, a terphenyl group, a paphthyl group, a pyridinyl group, a pyrimidinyl group, a pyrazinyl group, a quinolinyl group, an isoquinolinyl group, a quinoxalinyl group, and a quinazolinyl group, each substituted with at least one selected from a C₁-C₁₀ alkyl group, a C₁-C₁₀ alkoxy group, and a phenyl group,

e3 may be an integer selected from 0 to 3,

e2 may be an integer selected from 0 to 2,

e4 may be an integer selected from 0 to 4,

e5 may be an integer selected from 0 to 5,

e6 may be an integer selected from 0 to 6,

e7 may be an integer selected from 0 to 7,

e9 may be an integer selected from 0 to 9, and

* may indicate a binding site to a neighboring atom.

In one or more embodiments,

in Formulae 1A to 1E, 2A, and 2B,

R₁ to R₉ may each independently be selected from the group consisting of:

hydrogen, deuterium, —F, —Cl, —Br, —I, a hydroxyl group, a cyano group, a nitro group, an amidino group, a hydrazino group, a hydrazono group, a C₁-C₂₀ alkyl group, and a C₁-C₂₀ alkoxy group;

a group represented by any of Formulae 9-1 to 9-28, 9-53 to 9-88, and 10-1 to 10-121; and

—Si(Q₁)(Q₂)(Q₃), —N(Q₁)(Q₂), —B(Q₁)(Q₂), —C(═O)(Q₁), —S(═O)₂(Q₁), and —P(═O)(Q₁)(Q₂),

R₂₁ may be selected from groups represented by Formulae 9-1 to 9-100 and 10-1 to 10-121,

R₂₂ to R₂₄ may each independently be selected from the group consisting of:

hydrogen, deuterium, —F, —Cl, —Br, —I, a hydroxyl group, a cyano group, a nitro group, an amidino group, a hydrazino group, a hydrazono group, a C₁-C₂₀ alkyl group, and a C₁-C₂₀ alkoxy group;

a group represented by any of Formulae 9-1 to 9-100 and 10-1 to 10-121; and

—Si(Q₄)(Q₅)(Q₆), —N(Q₄)(Q₅), —B(Q₄)(Q₅), —C(═O)(Q₄), —S(═O)₂(Q₄), and —P(═O)(Q₄)(Q₅), but embodiments of the present disclosure are not limited thereto:

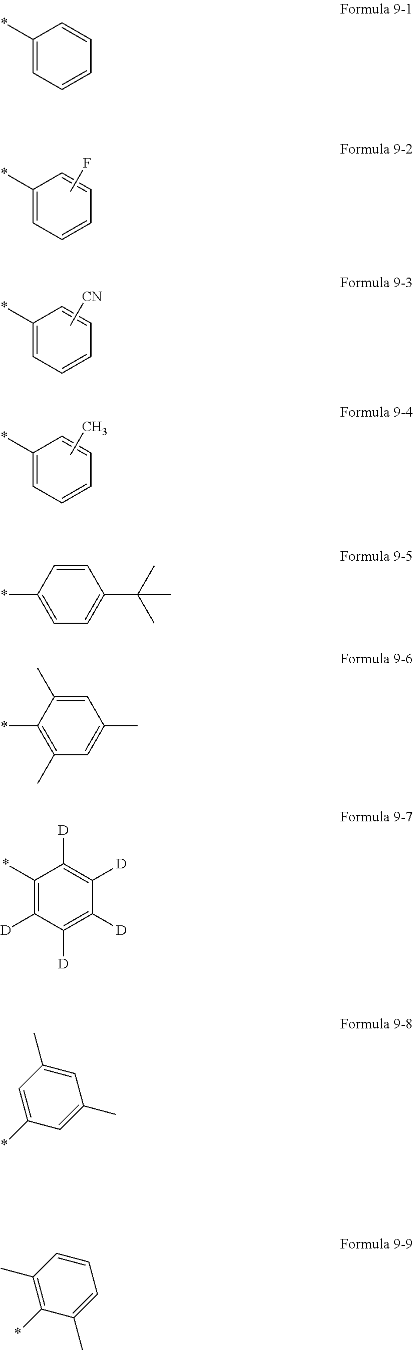

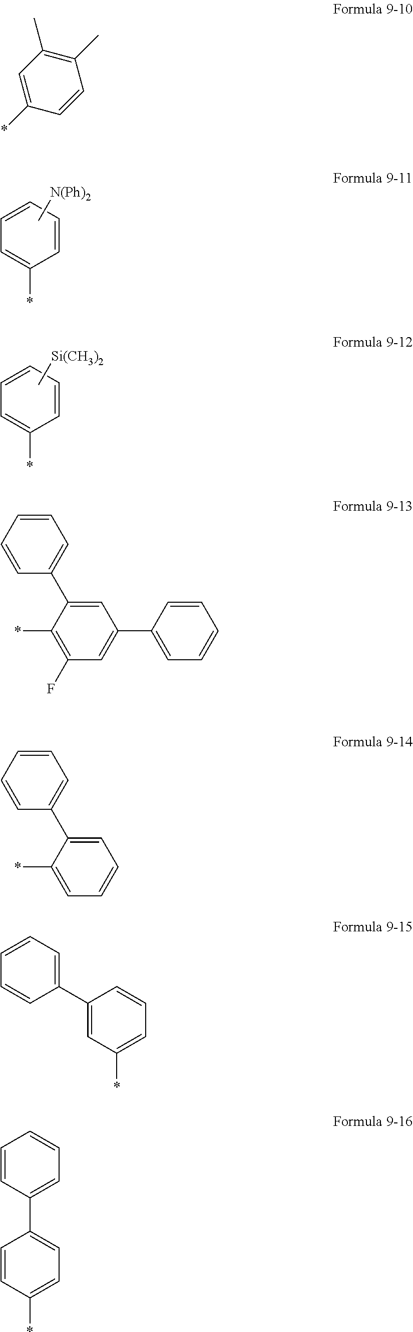

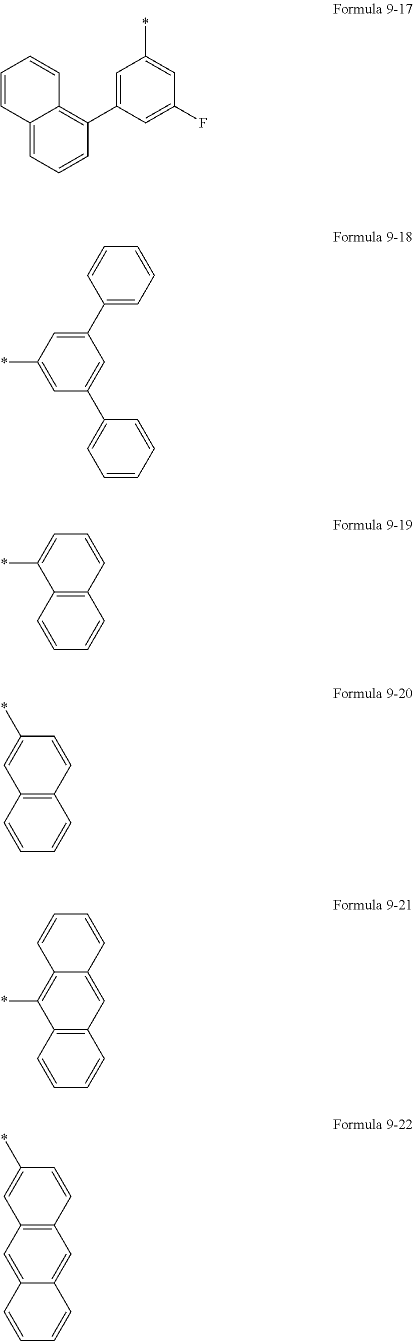 [SMILES: *c1cc(F)cc(-c2cccc3ccccc23)c1 ; *c1cc(-c2ccccc2)cc(-c2ccccc2)c1 ; *c1cccc2ccccc12 ; *c1ccc2ccccc2c1 ; *c1c2ccccc2cc2ccccc12 ; *c1ccc2cc3ccccc3cc2c1]

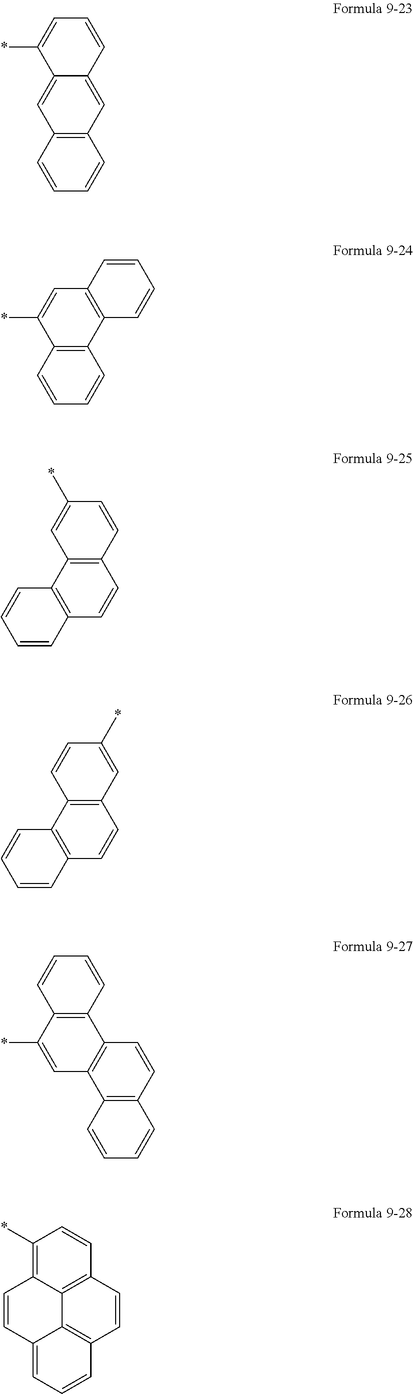 [SMILES: *c1cccc2cc3ccccc3cc12 ; *c1cc2ccccc2c2ccccc12 ; *c1ccc2ccc3ccccc3c2c1 ; *c1ccc2c(ccc3ccccc32)c1 ; *c1cc2c3ccccc3ccc2c2ccccc12 ; *c1ccc2ccc3cccc4ccc1c2c34]

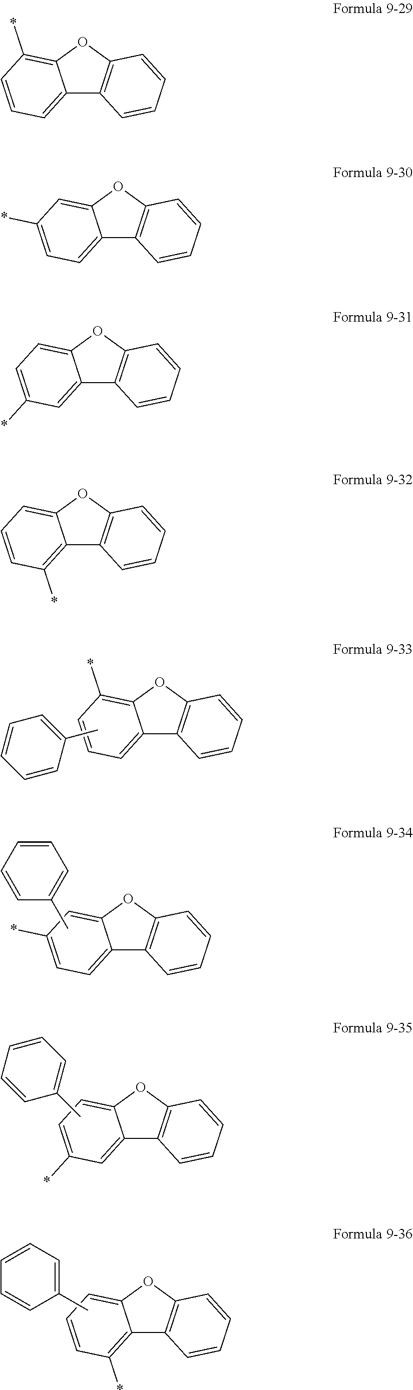

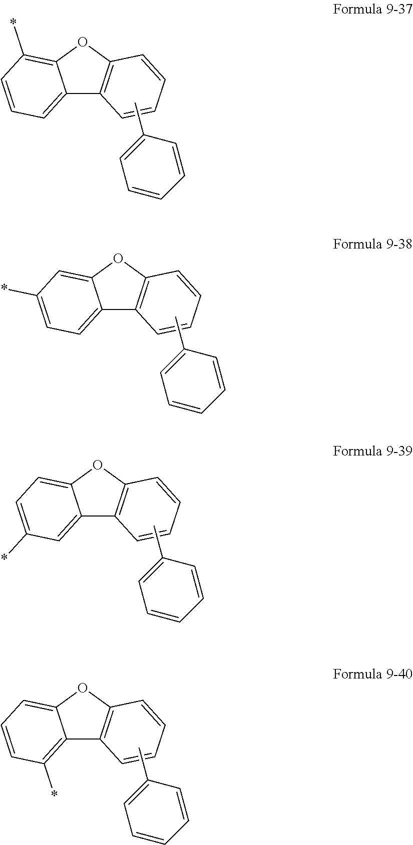

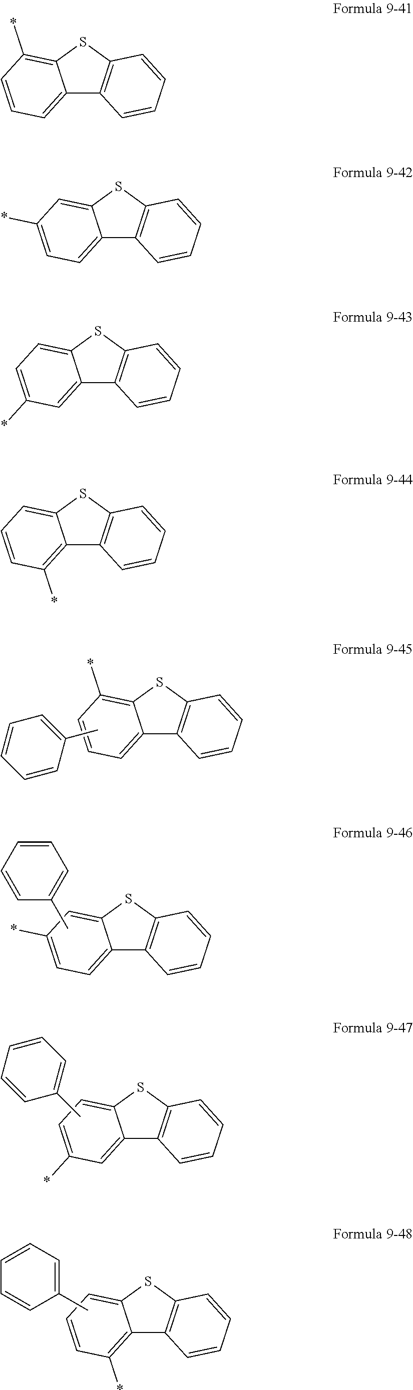

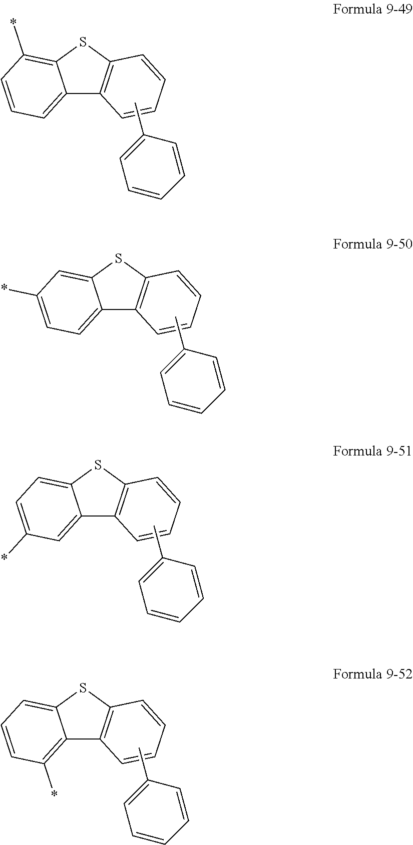

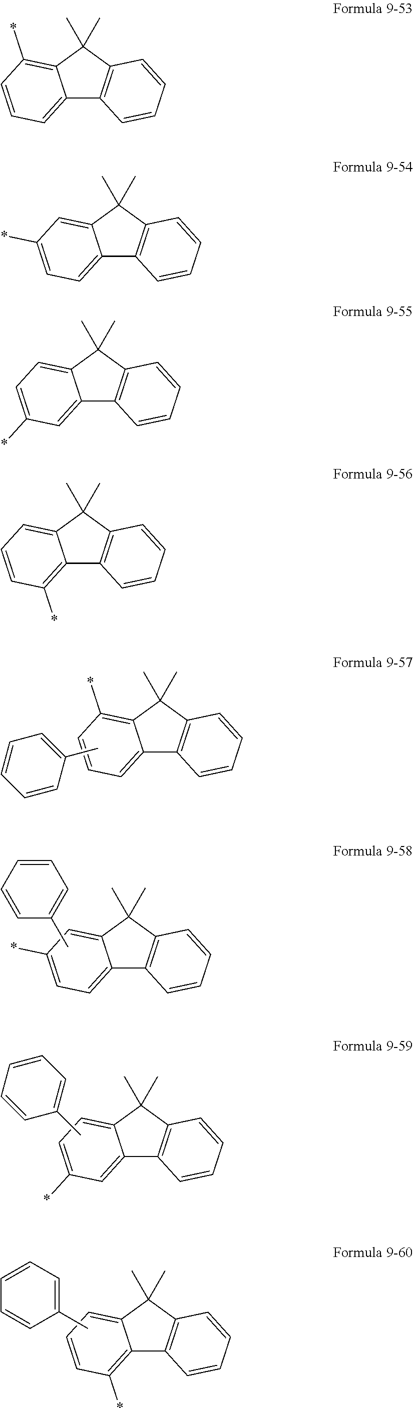

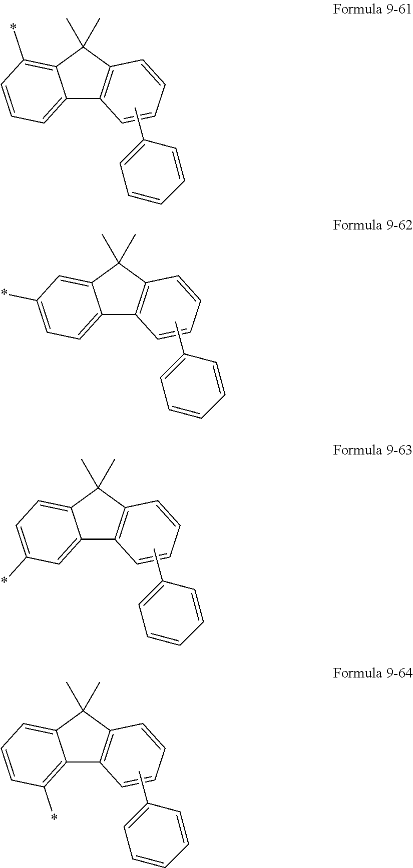

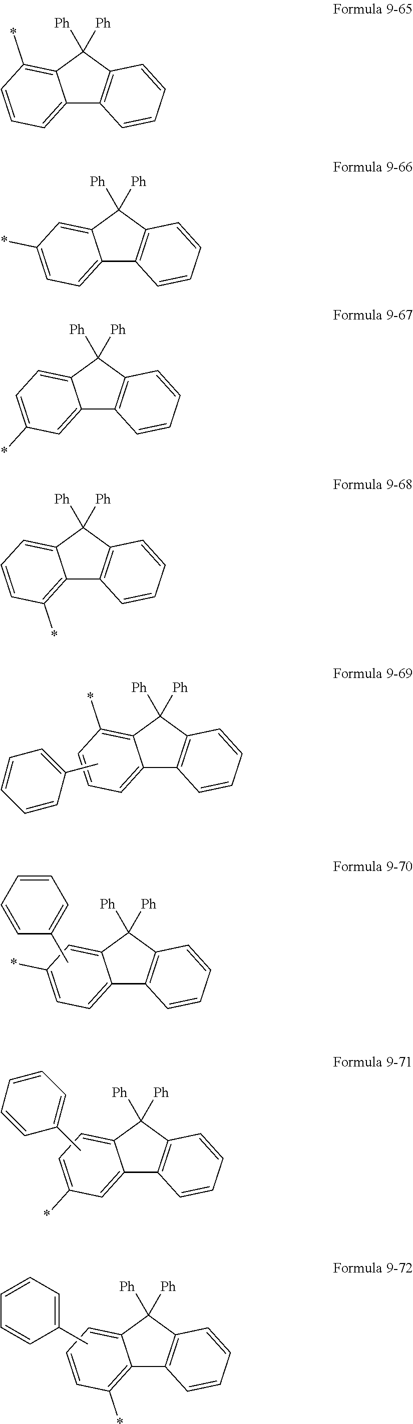

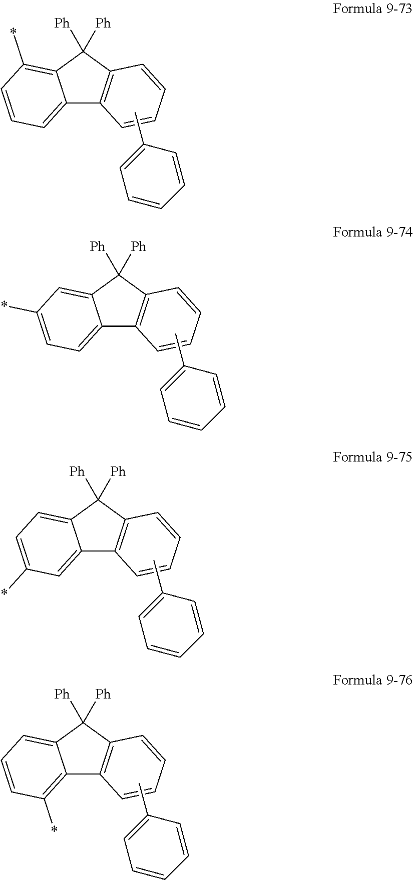

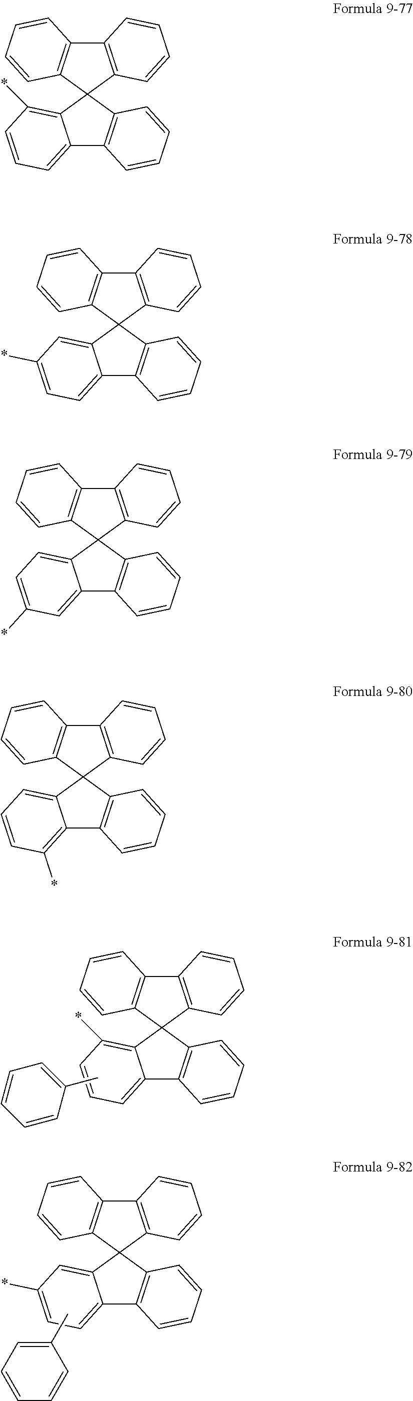

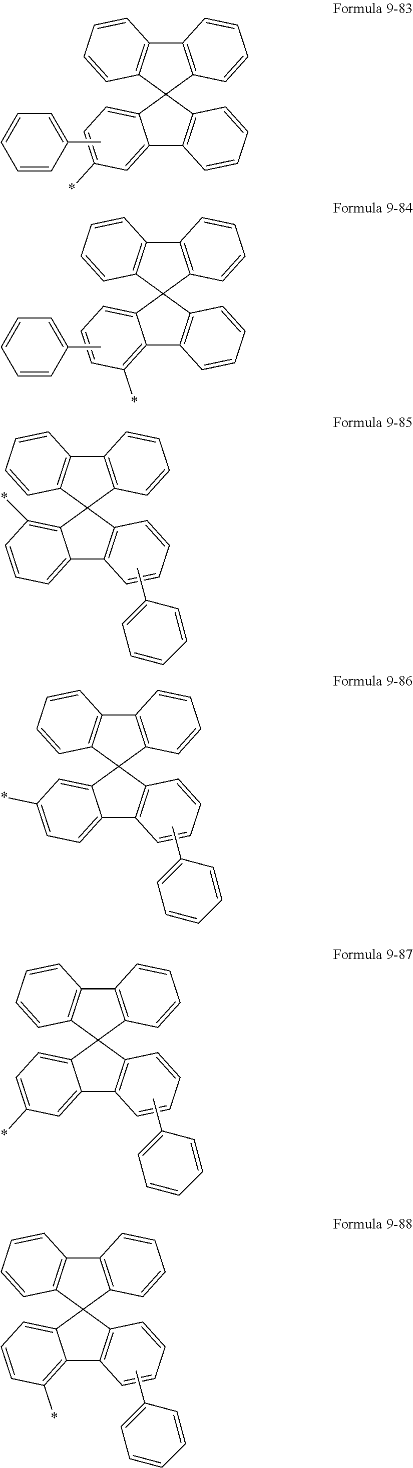

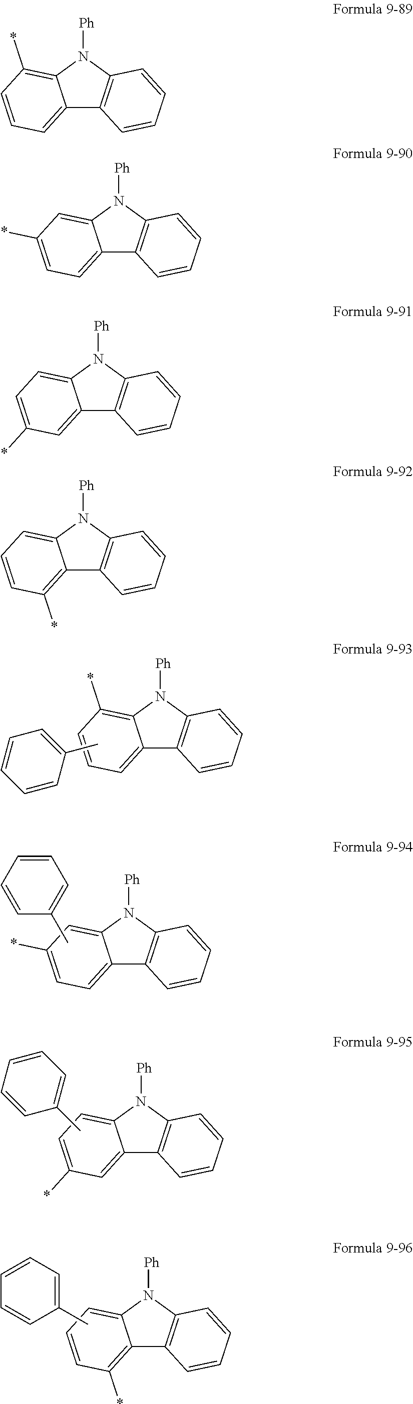

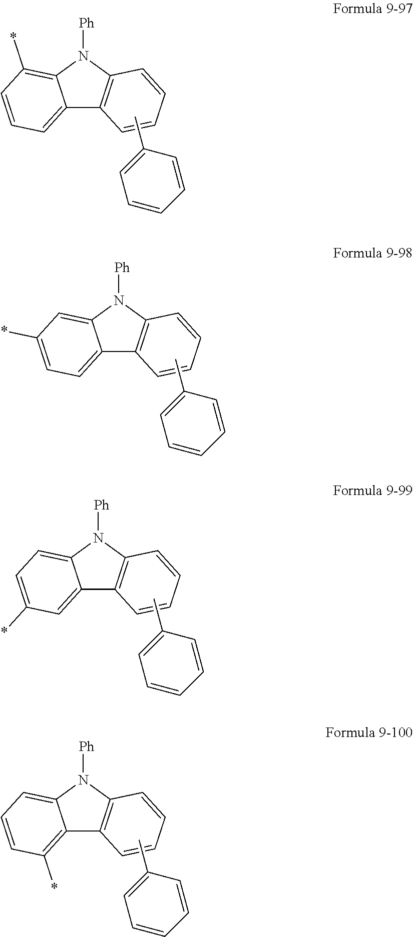

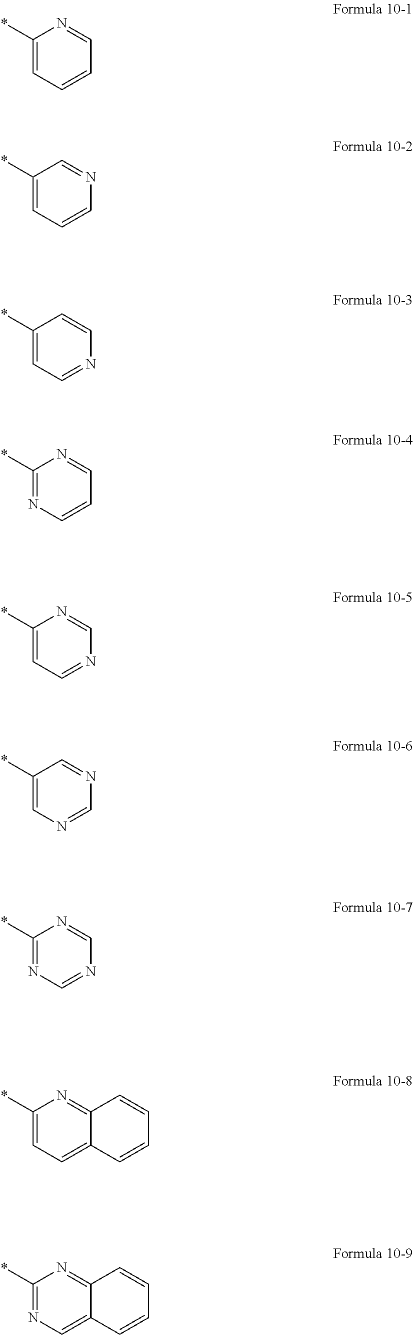

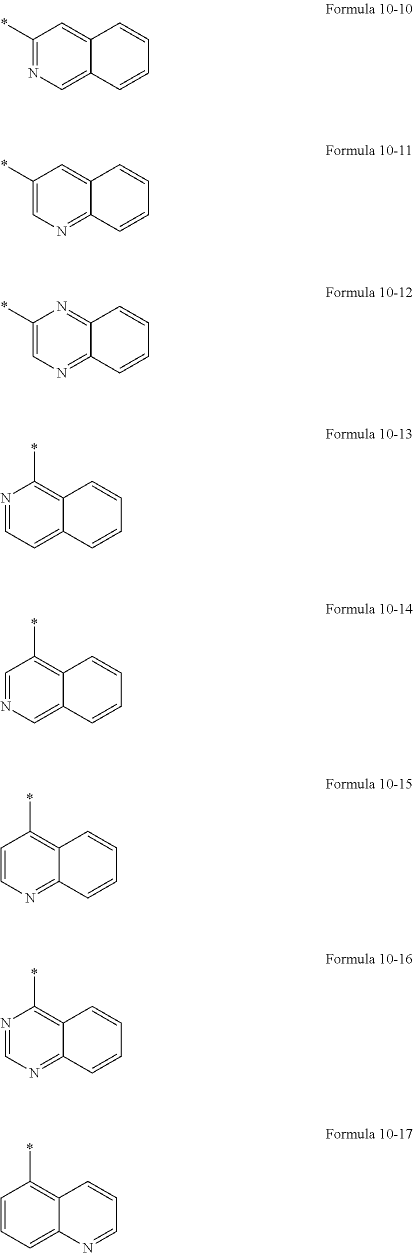

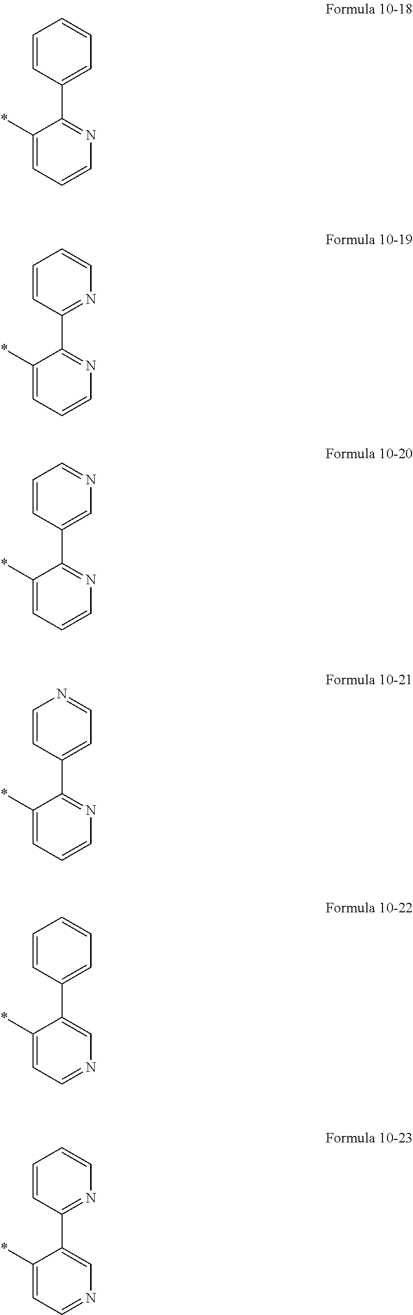 [SMILES: *c1cccnc1-c1ccccc1 ; *c1cccnc1-c1ccccn1 ; *c1cccnc1-c1cccnc1 ; *c1cccnc1-c1ccncc1 ; *c1ccncc1-c1ccccc1 ; *c1ccncc1-c1ccccn1]

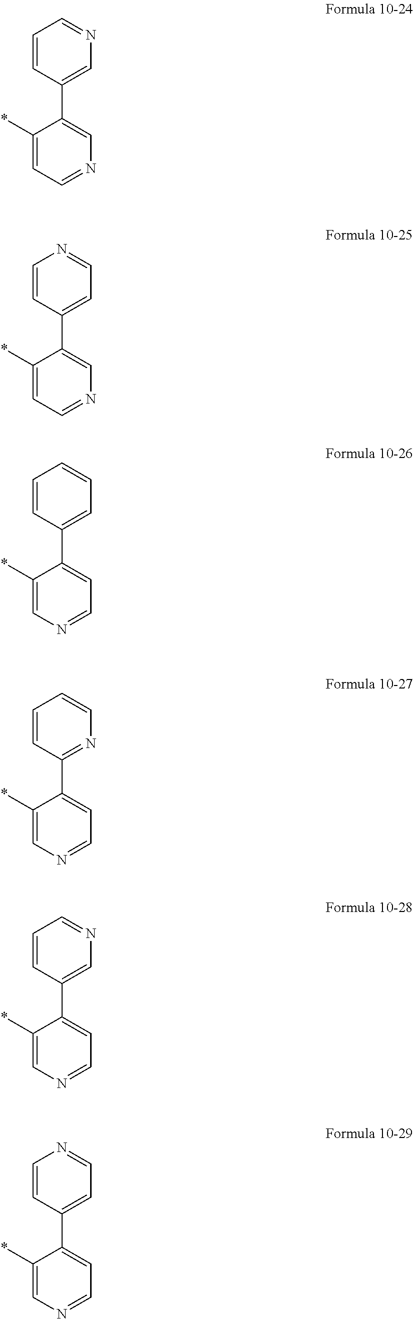 [SMILES: *c1ccncc1-c1cccnc1 ; *c1ccncc1-c1ccncc1 ; *c1cnccc1-c1ccccc1 ; *c1cnccc1-c1ccccn1 ; *c1cnccc1-c1cccnc1 ; *c1cnccc1-c1ccncc1]

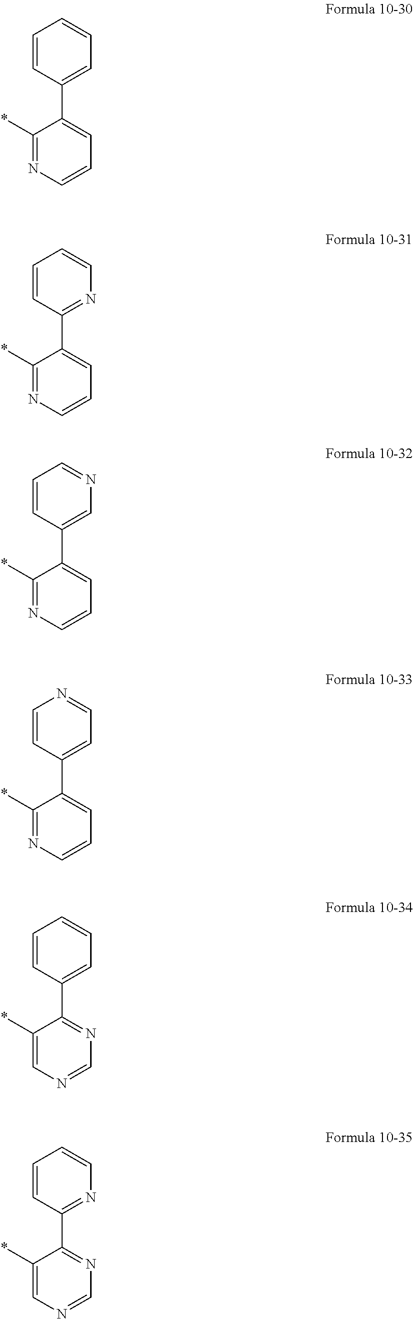 [SMILES: *c1ncccc1-c1ccccc1 ; *c1ncccc1-c1ccccn1 ; *c1ncccc1-c1cccnc1 ; *c1ncccc1-c1ccncc1 ; *c1cncnc1-c1ccccc1 ; *c1cncnc1-c1ccccn1]

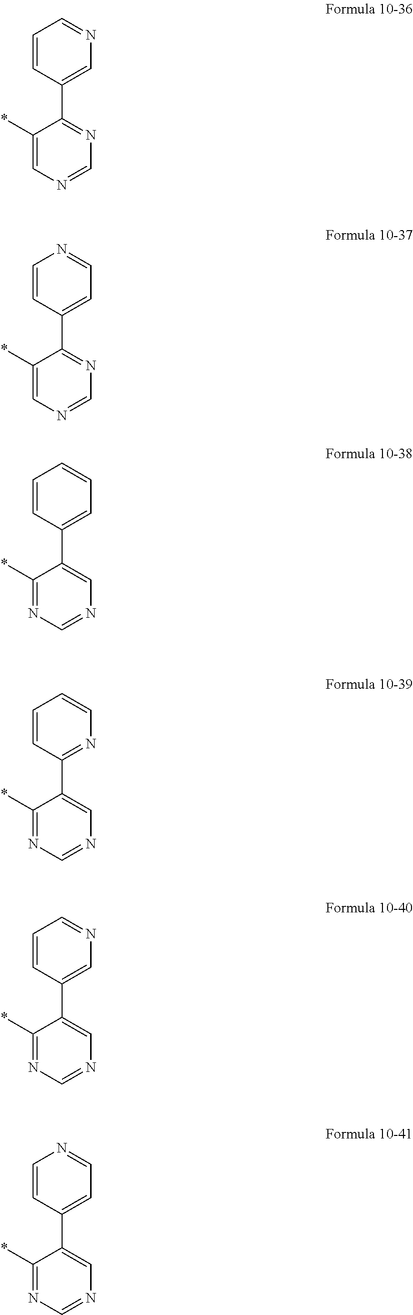 [SMILES: *c1cncnc1-c1cccnc1 ; *c1cncnc1-c1ccncc1 ; *c1ncncc1-c1ccccc1 ; *c1ncncc1-c1ccccn1 ; *c1ncncc1-c1cccnc1 ; *c1ncncc1-c1ccncc1]

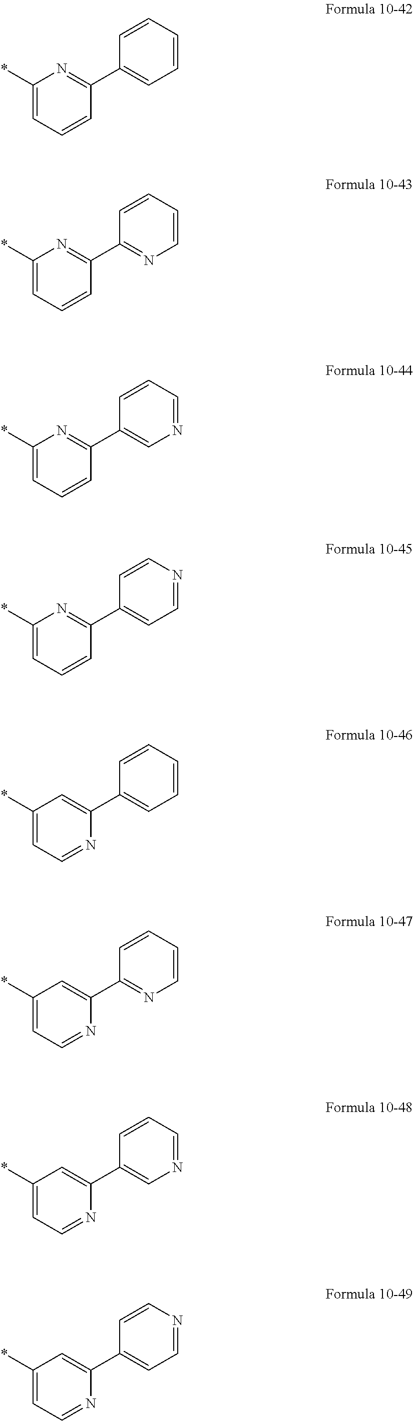

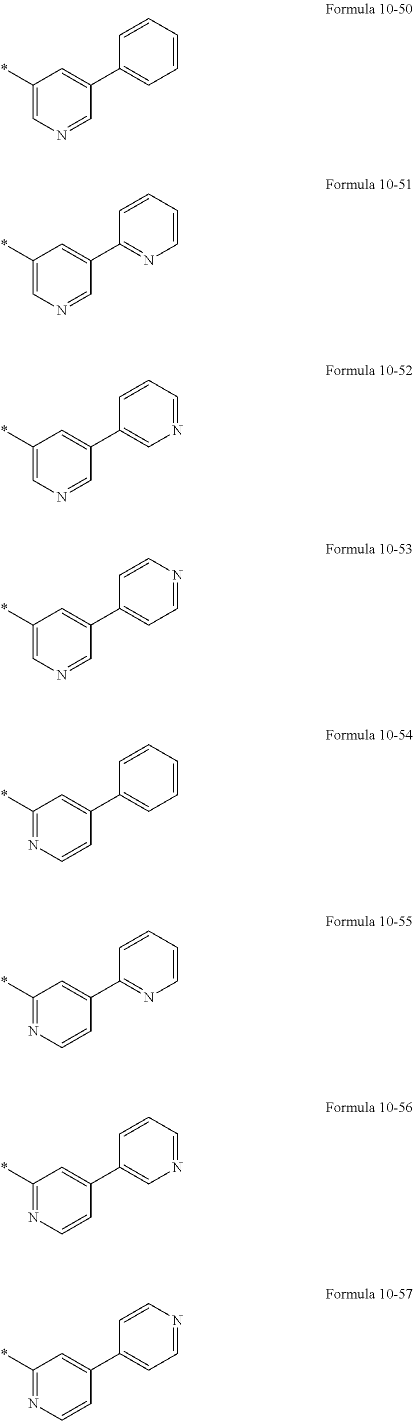

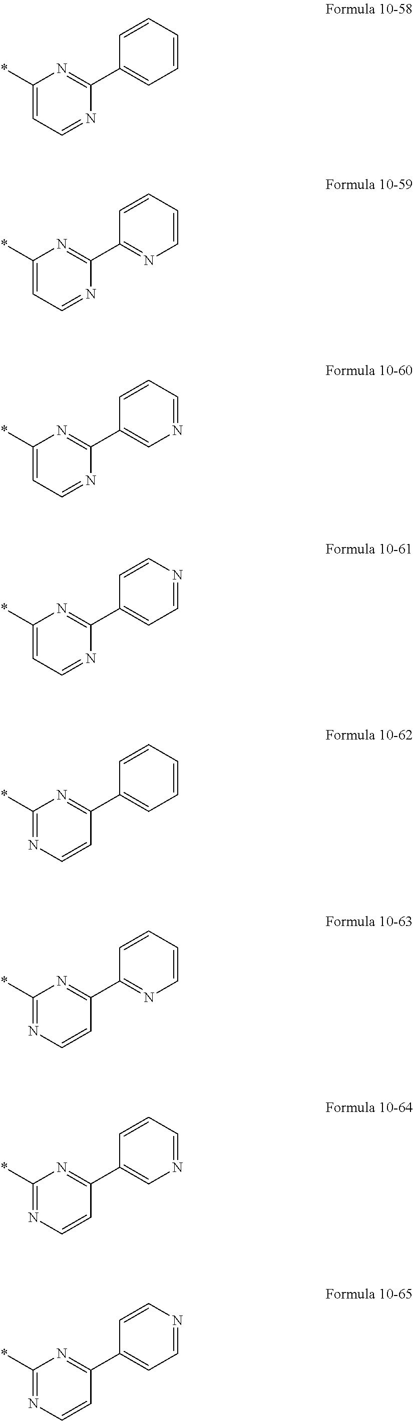

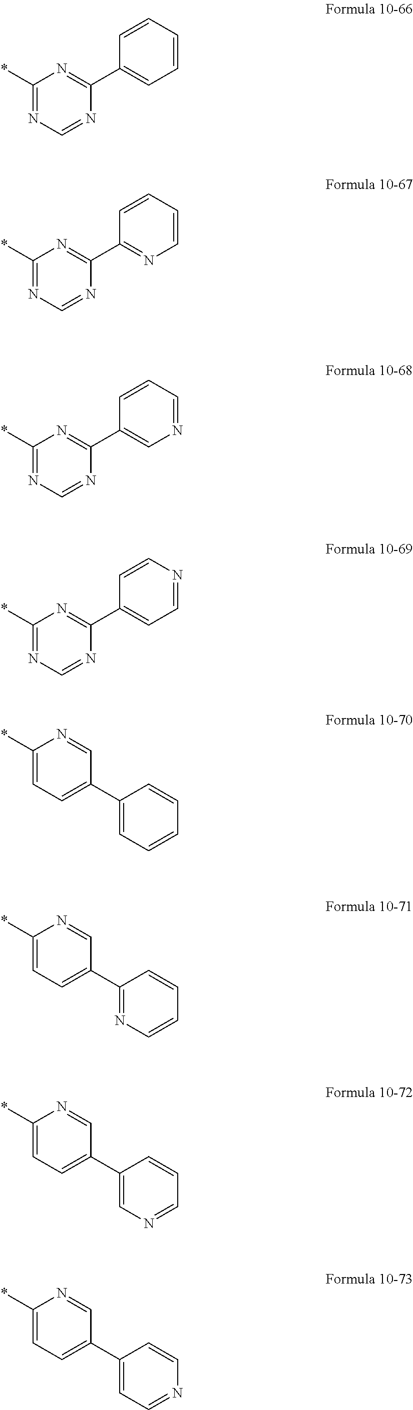

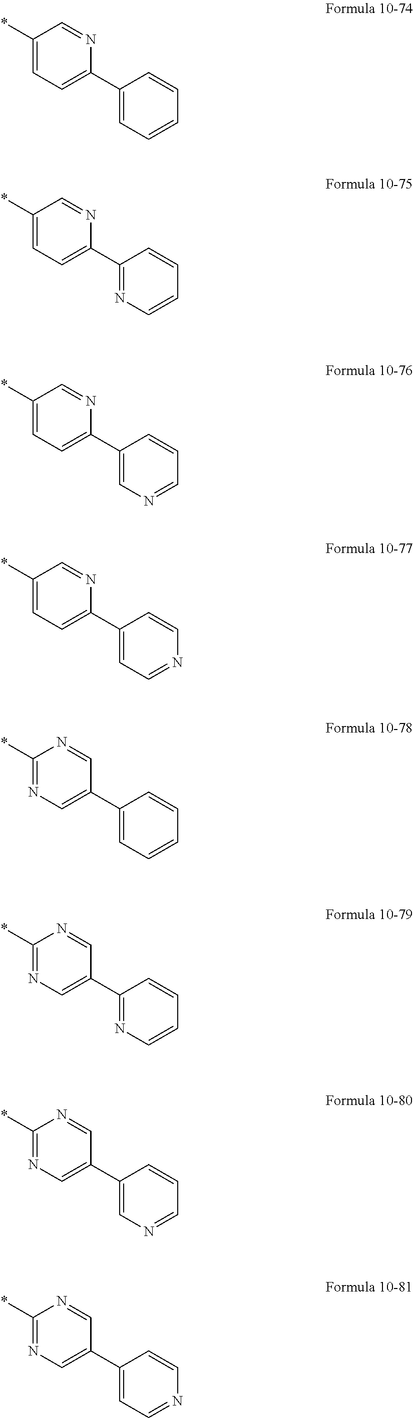

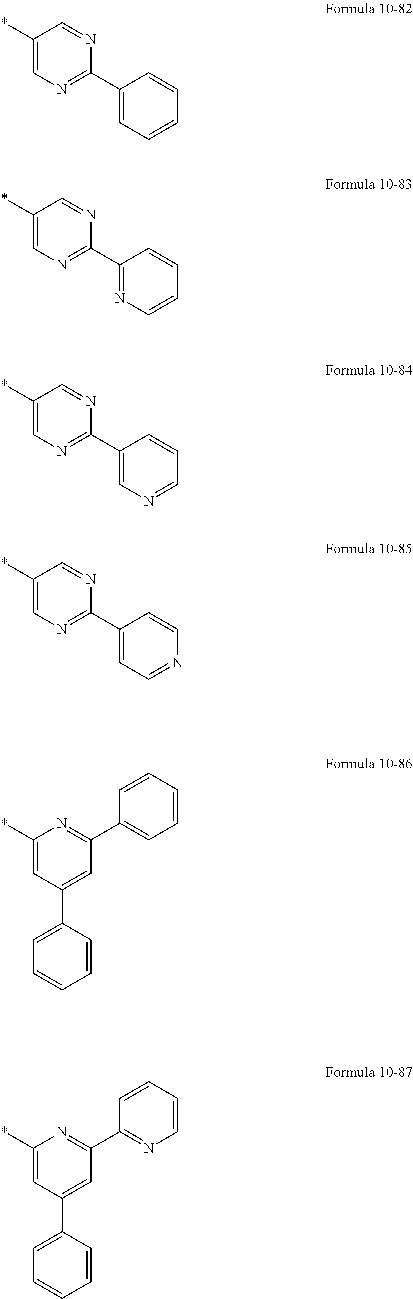 [SMILES: *c1cnc(-c2ccccc2)nc1 ; *c1cnc(-c2ccccn2)nc1 ; *c1cnc(-c2cccnc2)nc1 ; *c1cnc(-c2ccncc2)nc1 ; *c1cc(-c2ccccc2)cc(-c2ccccc2)n1 ; *c1cc(-c2ccccc2)cc(-c2ccccn2)n1]

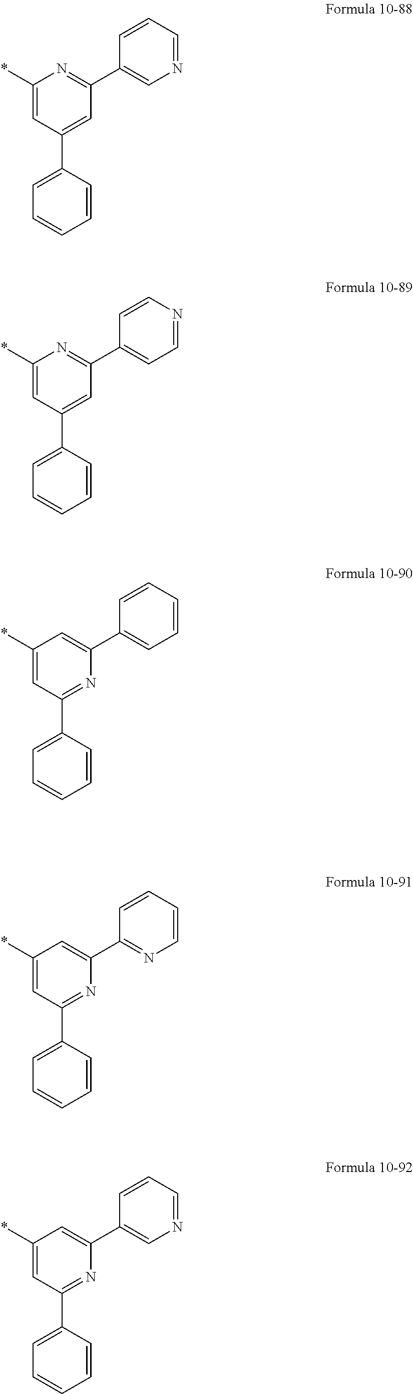 [SMILES: *c1cc(-c2ccccc2)cc(-c2cccnc2)n1 ; *c1cc(-c2ccccc2)cc(-c2ccncc2)n1 ; *c1cc(-c2ccccc2)nc(-c2ccccc2)c1 ; *c1cc(-c2ccccc2)nc(-c2ccccn2)c1 ; *c1cc(-c2ccccc2)nc(-c2cccnc2)c1]

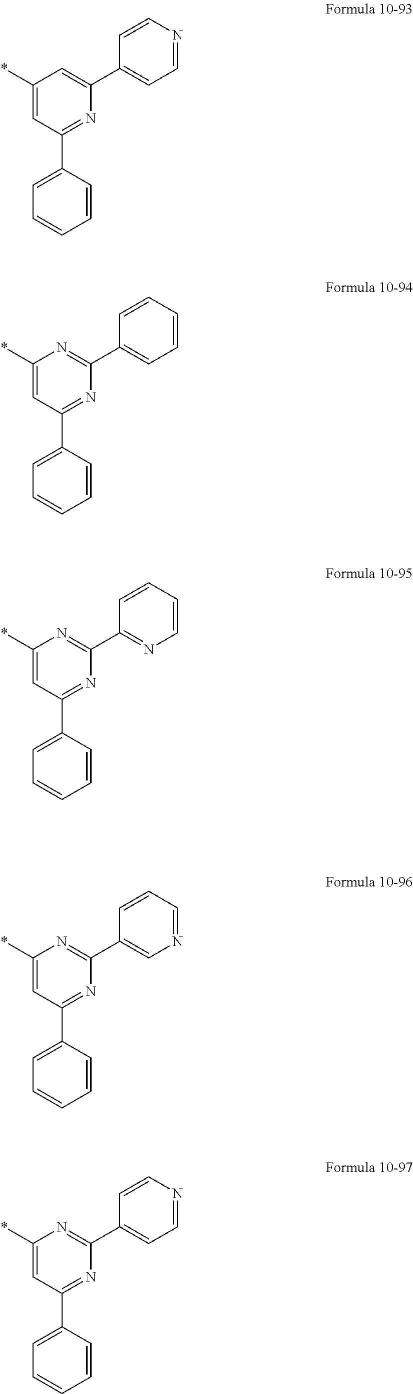 [SMILES: *c1cc(-c2ccccc2)nc(-c2ccncc2)c1 ; *c1cc(-c2ccccc2)nc(-c2ccccc2)n1 ; *c1cc(-c2ccccc2)nc(-c2ccccn2)n1 ; *c1cc(-c2ccccc2)nc(-c2cccnc2)n1 ; *c1cc(-c2ccccc2)nc(-c2ccncc2)n1]

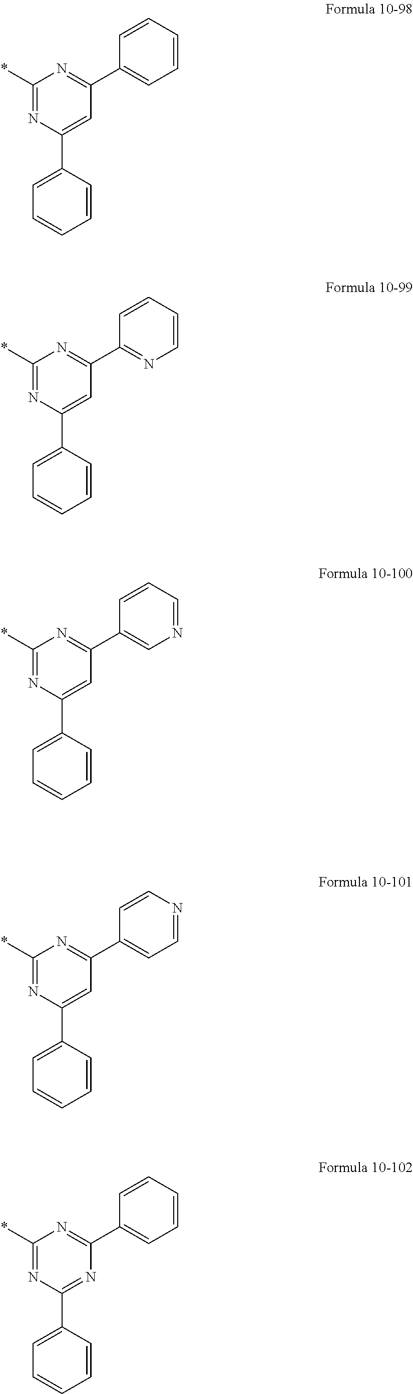 [SMILES: *c1nc(-c2ccccc2)cc(-c2ccccc2)n1 ; *c1nc(-c2ccccc2)cc(-c2ccccn2)n1 ; *c1nc(-c2ccccc2)cc(-c2cccnc2)n1 ; *c1nc(-c2ccccc2)cc(-c2ccncc2)n1 ; *c1nc(-c2ccccc2)nc(-c2ccccc2)n1]

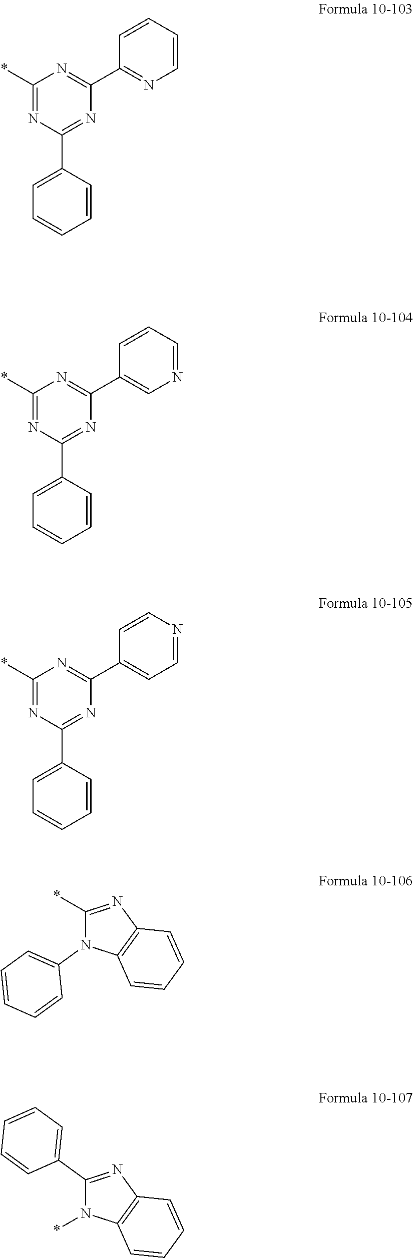 [SMILES: *c1nc(-c2ccccc2)nc(-c2ccccn2)n1 ; *c1nc(-c2ccccc2)nc(-c2cccnc2)n1 ; *c1nc(-c2ccccc2)nc(-c2ccncc2)n1 ; *c1nc2ccccc2n1-c1ccccc1 ; *n1c(-c2ccccc2)nc2ccccc21]

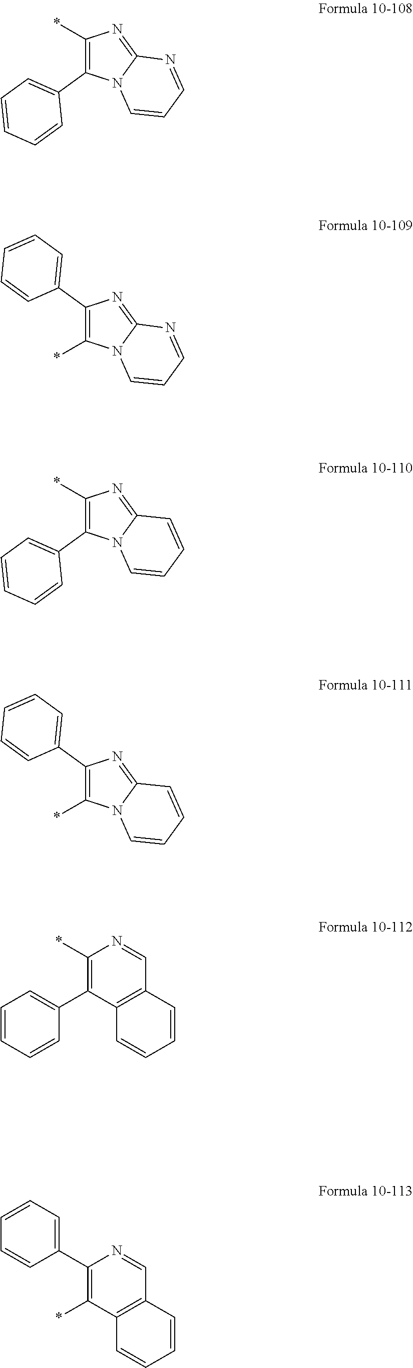 [SMILES: *c1nc2ncccn2c1-c1ccccc1 ; *c1c(-c2ccccc2)nc2ncccn12 ; *c1nc2ccccn2c1-c1ccccc1 ; *c1c(-c2ccccc2)nc2ccccn12 ; *c1ncc2ccccc2c1-c1ccccc1 ; *c1c(-c2ccccc2)ncc2ccccc12]

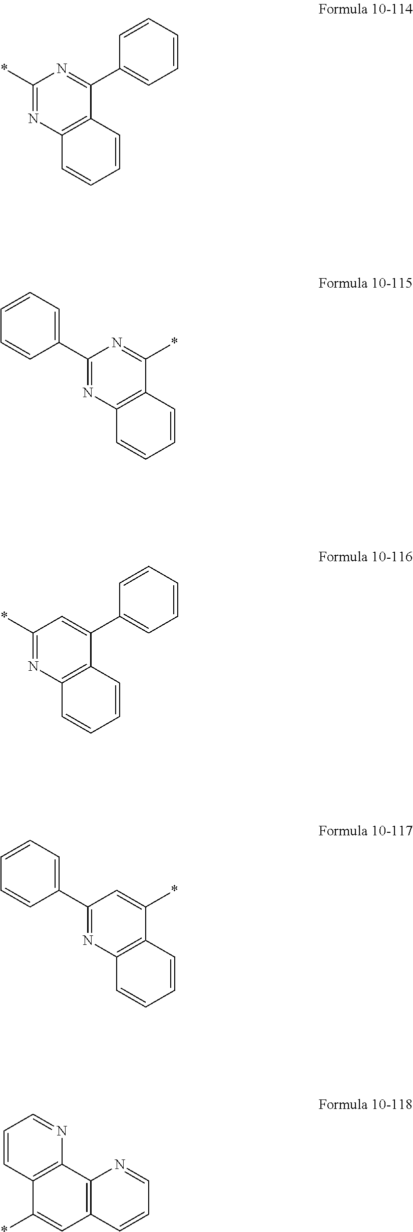 [SMILES: *c1nc(-c2ccccc2)c2ccccc2n1 ; *c1nc(-c2ccccc2)nc2ccccc12 ; *c1cc(-c2ccccc2)c2ccccc2n1 ; *c1cc(-c2ccccc2)nc2ccccc12 ; *c1cc2cccnc2c2ncccc12]

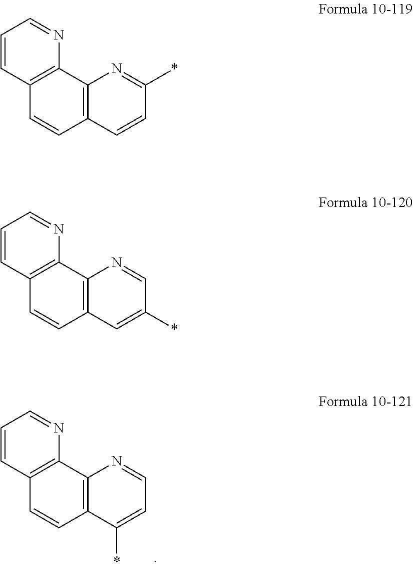 [SMILES: *c1ccc2ccc3cccnc3c2n1 ; *c1cnc2c(ccc3cccnc32)c1 ; *c1ccnc2c1ccc1cccnc12]

In Formulae 9-1 to 9-100 and 10-1 to 10-121, Ph indicates a phenyl group, and * indicates a binding site to a neighboring atom.

b1 to b7, b21, and b22 in Formulae 1A to 1E, 2A, and 2B indicate the numbers of R₁ to R₉, R₂₁, and R₂₂ groups, respectively. b1 to b7, b21, and b22 may each independently be an integer selected from 1 to 3. When b1 is two or more, two or more R₁(s) may be identical to or different from each other; when b2 is two or more, two or more R₂(s) may be identical to or different from each other; when b3 is two or more, two or more R₃(s) may be identical to or different from each other; when b4 is two or more, two or more R₄(s) may be identical to or different from each other; when b5 is two or more, two or more R₅(s) may be identical to or different from each other; when b6 is two or more, two or more R₆(s) may be identical to or different from each other; when b7 is two or more, two or more R₇(s) may be identical to or different from each other; when b8 is two or more, two or more R₅(s) may be identical to or different from each other; when b9 is two or more, two or more R₉(s) may be identical to or different from each other; when b21 is two or more, two or more R₂₁(s) may be identical to or different from each other; and when b22 is two or more, two or more R₂₂(s) may be identical to or different from each other.

In one embodiment, b1 to b9, b21, and b22 in Formulae 1A to 1E, 2A, and 2B may each independently be 1 or 2, but embodiments of the present disclosure are not limited thereto.

c1, c2, and c5 to c9 in Formulae 1A to 1E indicate the number of *-[(L₁)ₐ₁-(R₁)_{b1}], *-[(L₂)ₐ₂-(R₂)_{b2}], *-[(L₅)ₐ₅-(R₅)_{b5}], *-[(L₆)ₐ₆-(R₆)_{bd}], *-[(L₇)ₐ₇-(R₇)_{b7}], *-[(L₈)ₐ₈-(R₈)_{b8}], and *-[(L₉)ₐ₉-(R₉)_{b9}] groups, respectively. c1, c2, and c5 to c7 in Formulae 1A to 1E may each independently be an integer selected from 0 to 10, provided that the sum of c5, c6, and c7 is 1 or more, and c8 and c9 may each independently be an integer selected from 0 to 4, provided that the sum of c8 and c9 is 1 or more.

In Formulae 1A to 1E, when c1 is two or more, two or more *-[(L₁)ₐ₁-(R₁)_{b1}](s) may be identical to or different from each other; when c2 is two or more, two or more *-[(L₂)ₐ₂-(R₂)_{b2}](s) may be identical to or different from each other; when c5 is two or more, two or more *-[(L₅)ₐ₅-(R₅)_{b5}](s) may be identical to or different from each other; when c6 is two or more, two or more *-[(L₆)ₐ₆-(R₆)_{b6}](s) may be identical to or different from each other; when c7 is two or more, two or more *-[(L₇)ₐ₇-(R₇)_{b7}](s) may be identical to or different from each other; when c8 is two or more, two or more *-[(L₈)ₐ₈-(R₈)_{b8}](s) may be identical to or different from each other; and when c9 is two or more, two or more *-[(L₉)ₐ₉-(R₉)_{b9}](s) may be identical to or different from each other.

In one embodiment, c1, c2, and c5 to c7 in Formulae 1A to 1E may each independently be an integer selected from 0 to 8, provided that the sum of c5, c6, and c7 is 1 or more.

In one embodiment, the first compound represented by one selected from Formulae 1A to 1E may be represented by one selected from Formula 1E and Formulae 1-1 to 1-6:

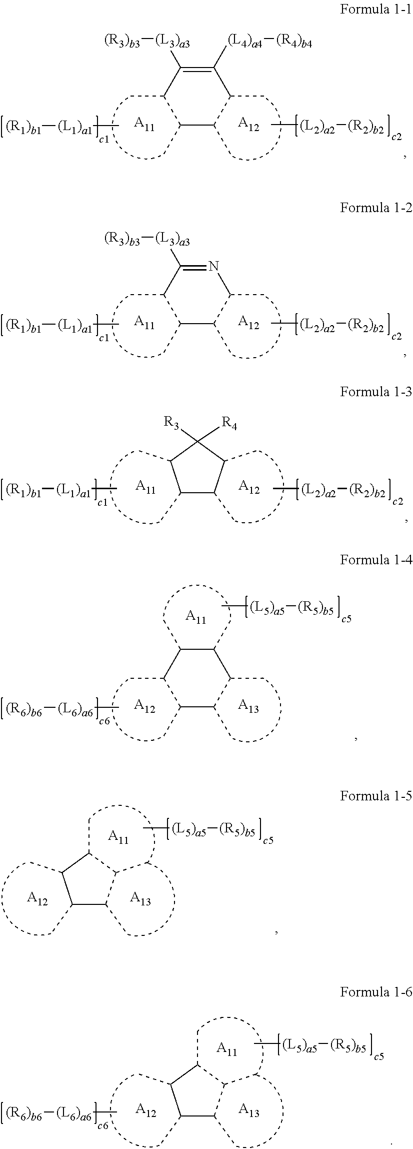

Formula 1E may be the same as described above,

in Formulae 1-1 to 1-6, rings A₁₁ to A₁₃, L₁ to L₆, a1 to a6, R₁ to R₆, and b1 to b6 may each independently be the same as described herein in connection with Formulae 1A to 1D,

c1, c2, and c6 may each independently be an integer selected from 0 to 10, and

c5 may be an integer selected from 1 to 10.

In one or more embodiments, the first compound represented by one selected from Formulae 1A to 1E may be represented by one selected from Formulae 1(1) to 1(11), but embodiments of the present disclosure are not limited thereto:

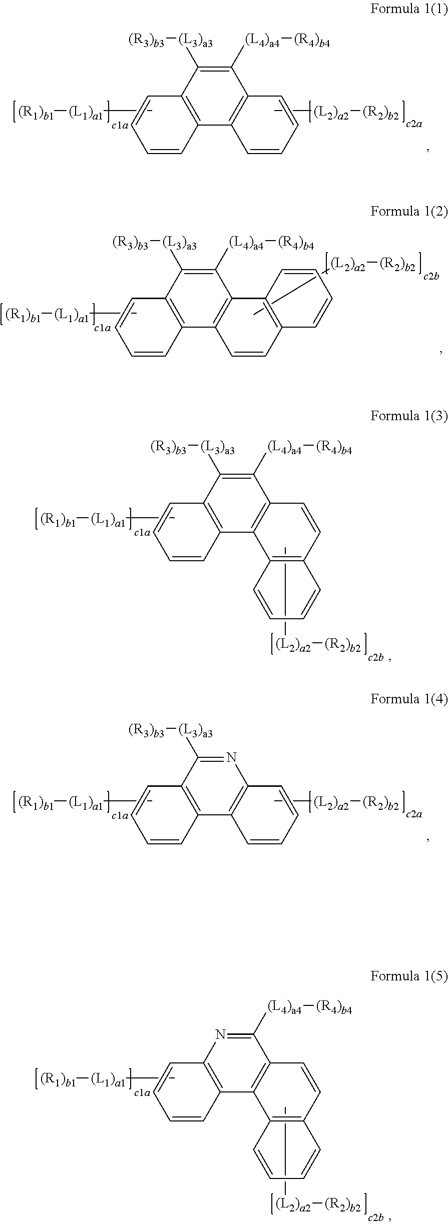

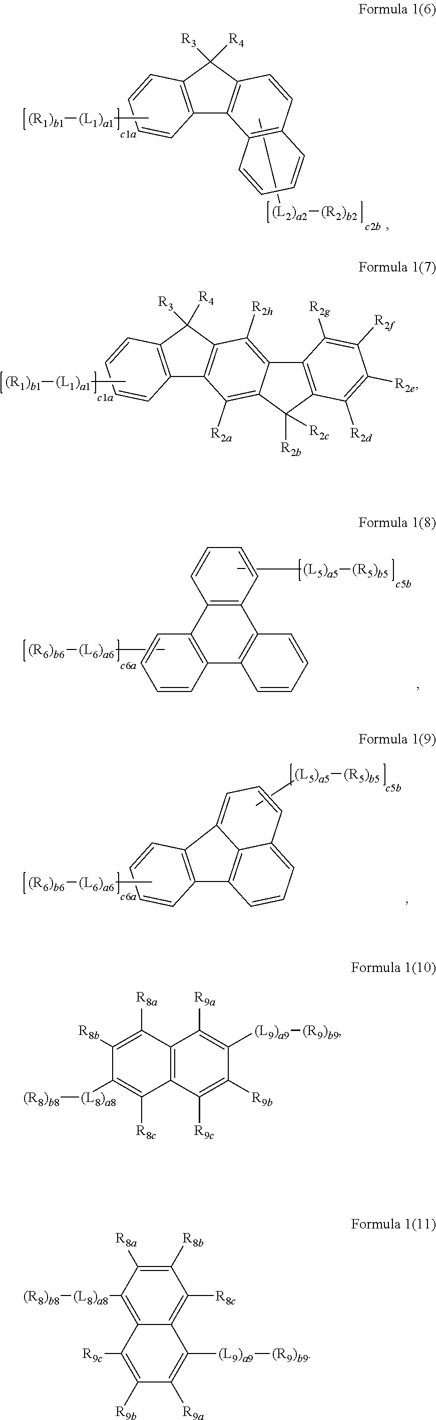

In Formulae 1(1) to 1(11),

L₁ to L₉, a1 to a9, R₁ to R₉, and b1 to b9 may each independently be the same as described above,

R₂ₐ to R₂ₕ may each independently be the same as described herein in connection with R₂,

R₈ₐ to R_{8c} may each be the same as described in connection with R₈,

R₉ₐ to R_{9c} may each be the same as described in connection with R₉,

c1a may be an integer selected from 0 to 4,

c2a may be an integer selected from 0 to 4,

c2b may be an integer selected from 0 to 6,

c5a may be an integer selected from 0 to 4,

c5b may be an integer selected from 0 to 3,

c6a may be an integer selected from 0 to 4, and

the sum of c5a and c6a or the sum of c5b and c6a may be 1 or more.

In one embodiment, the first compound represented by one selected from Formulae 1A to 1E may be selected from Compounds 1-1 to 1-93:

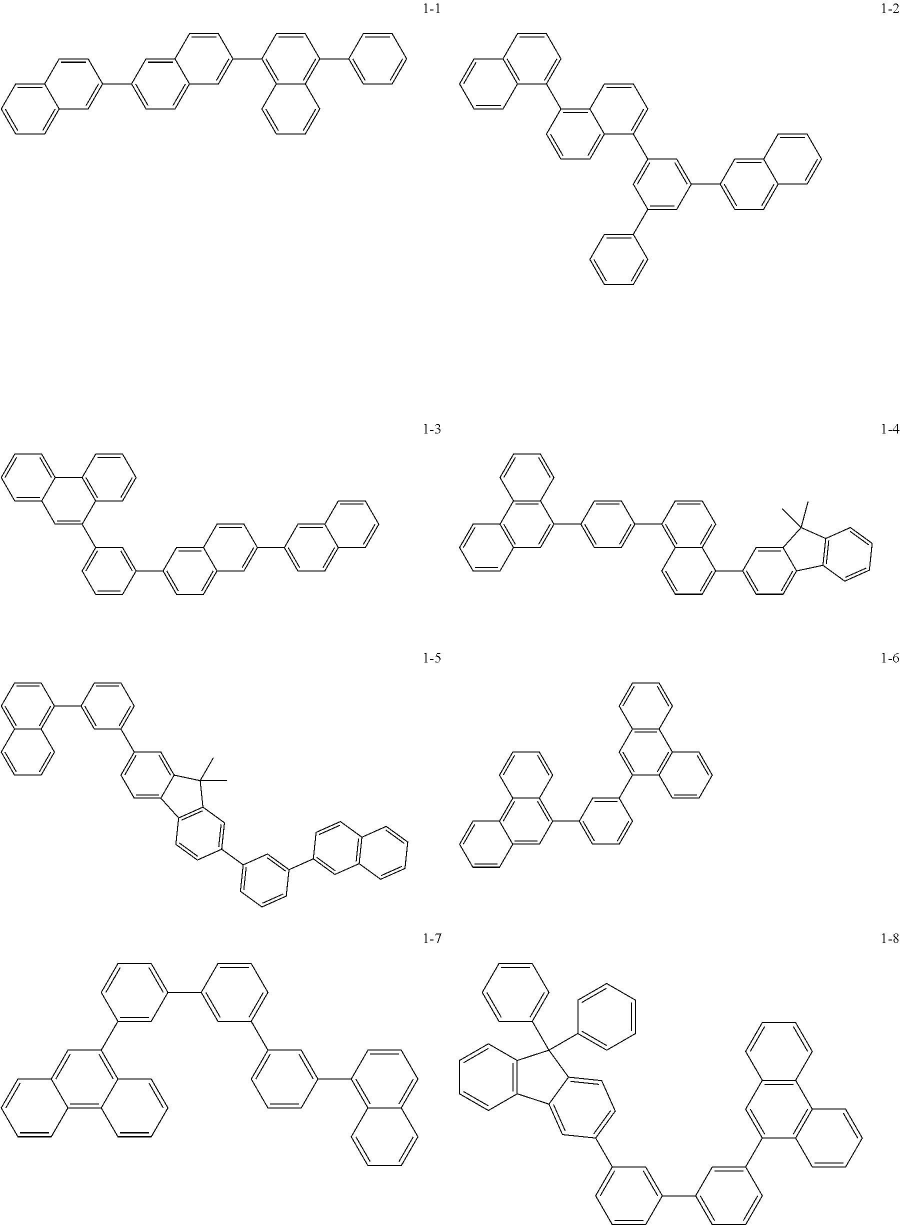

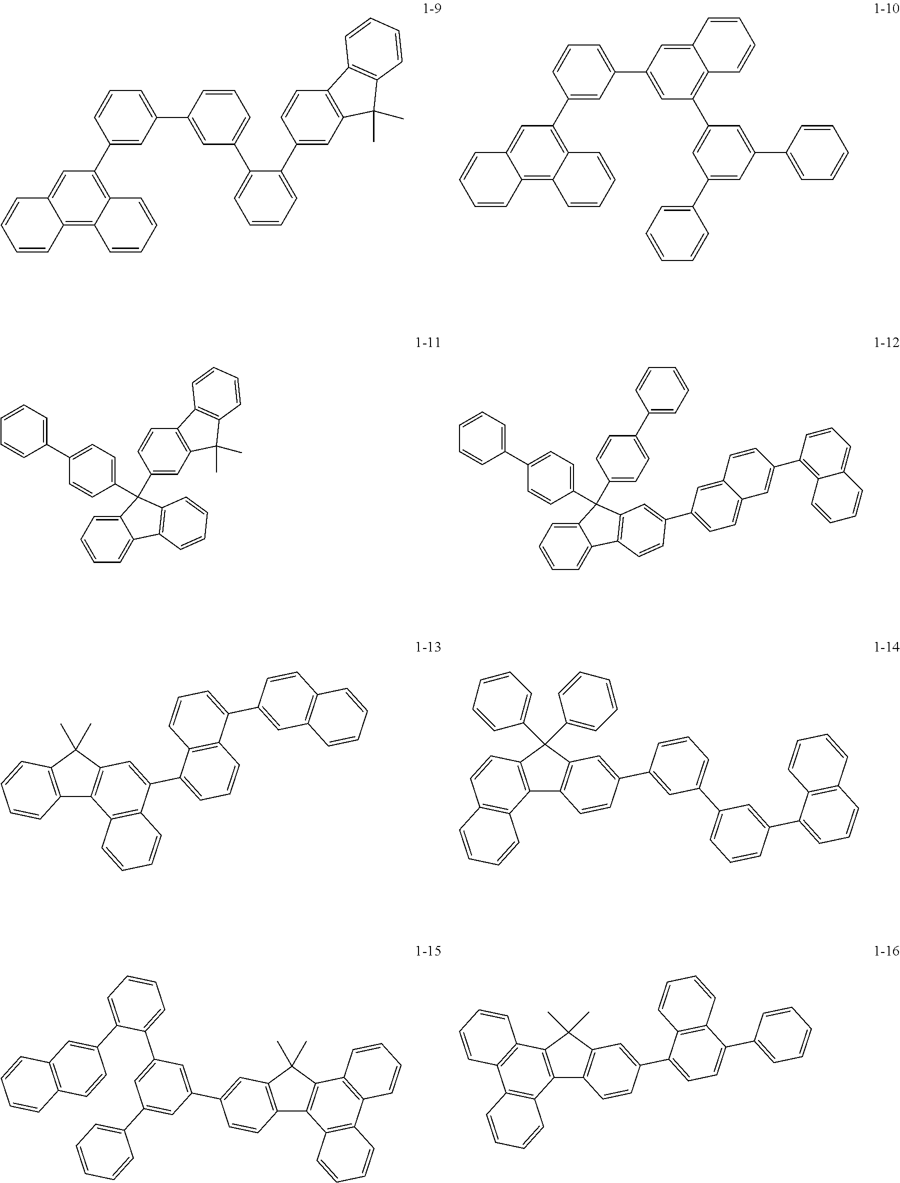

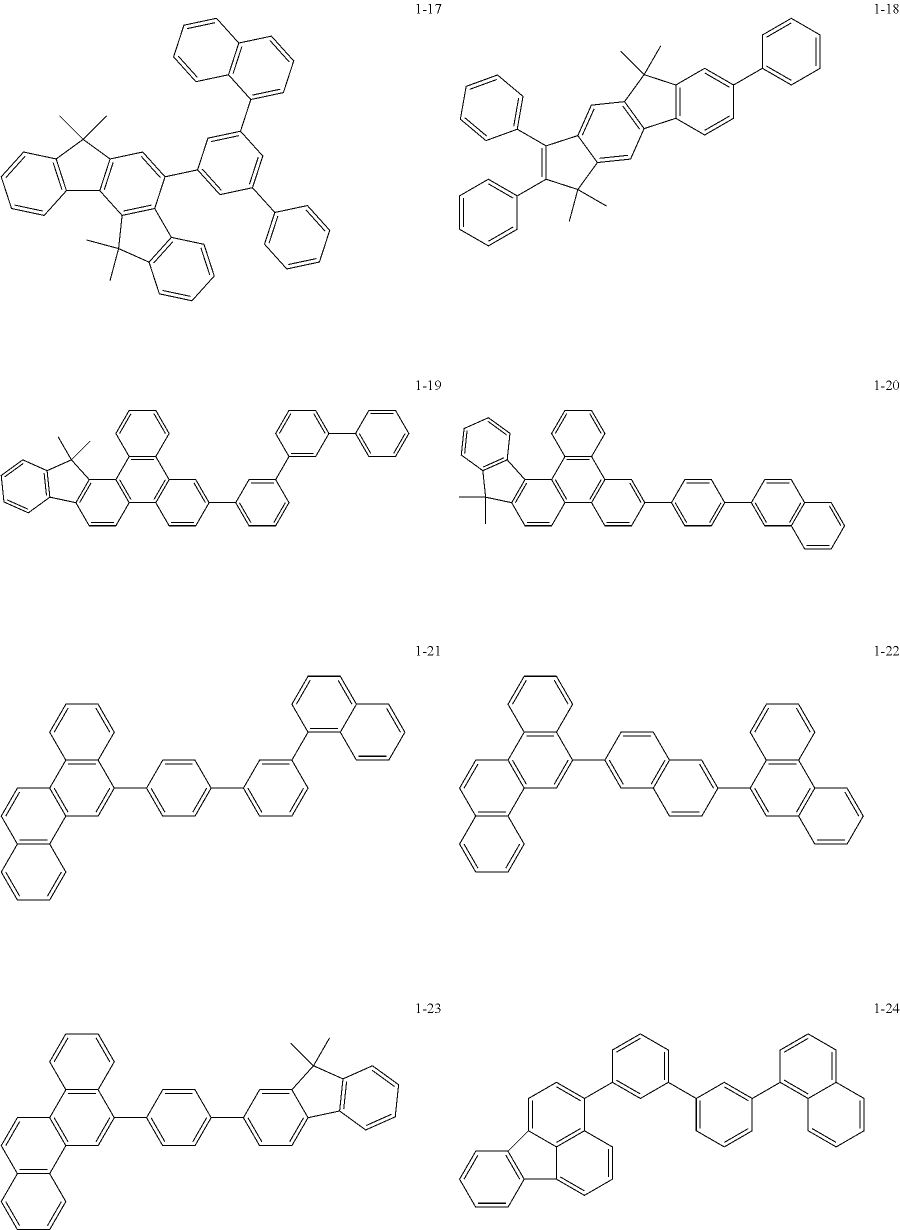

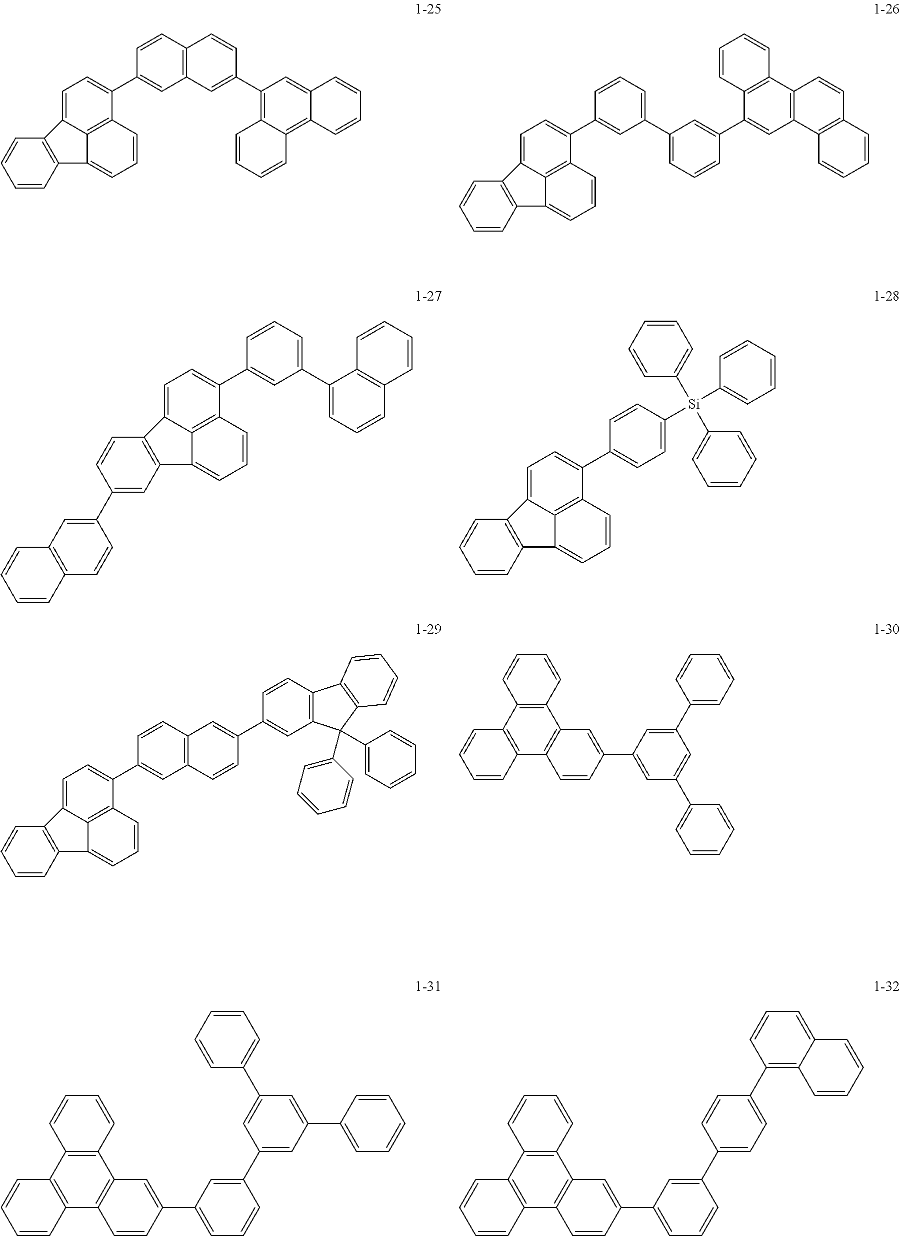

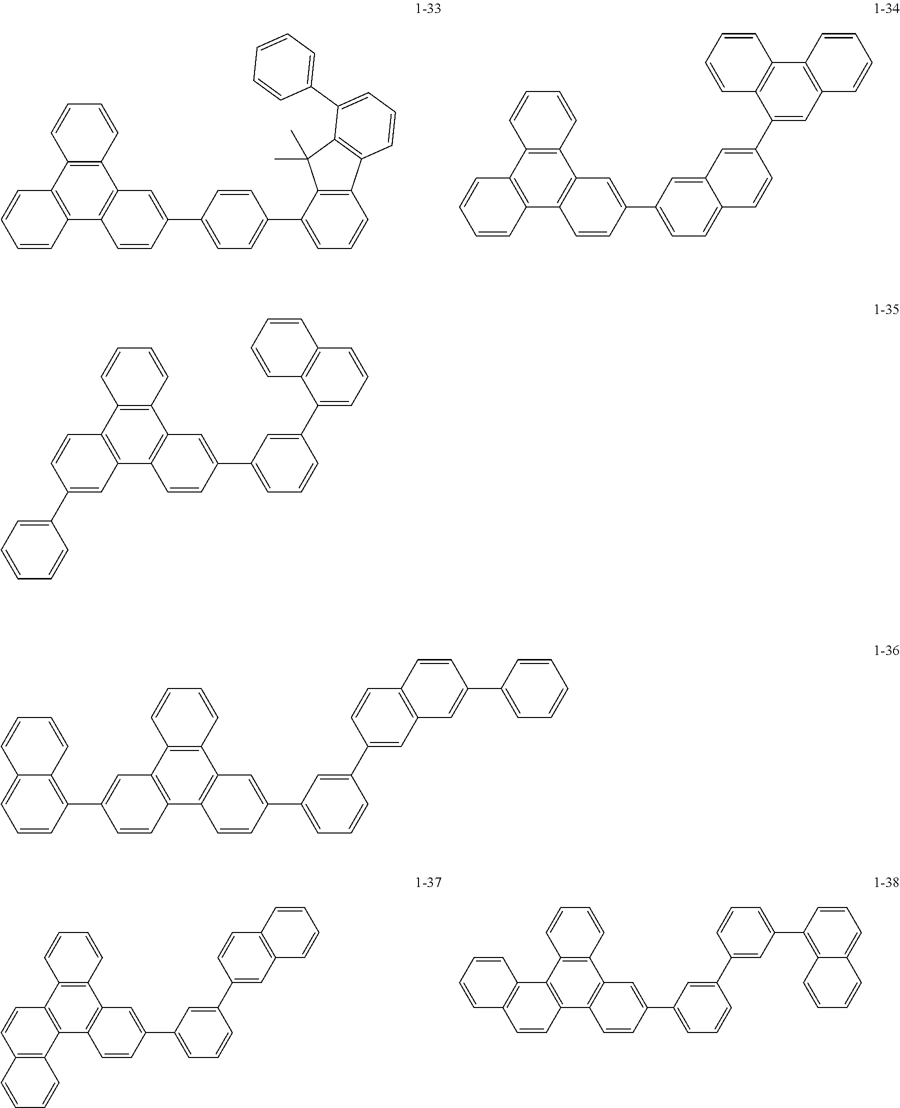

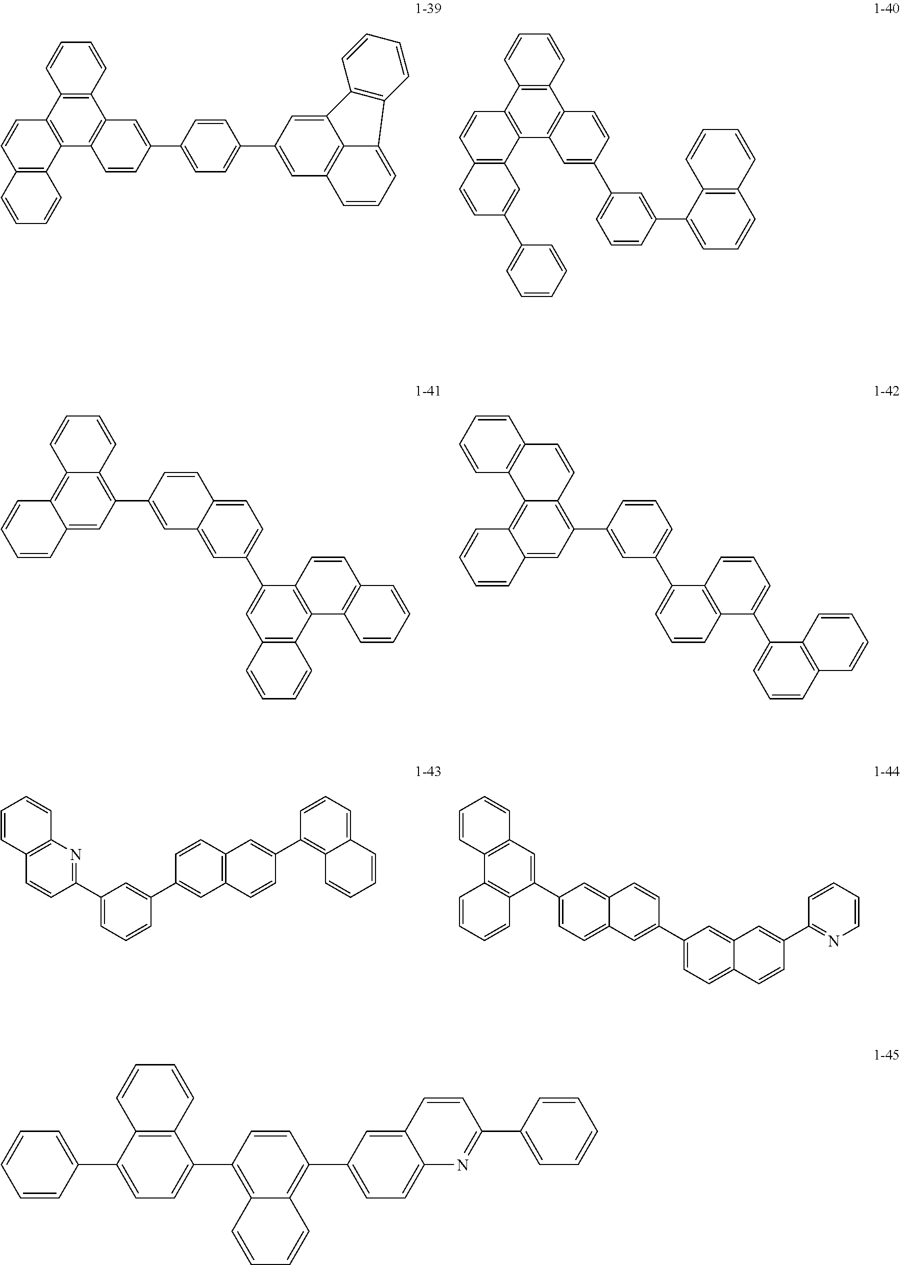

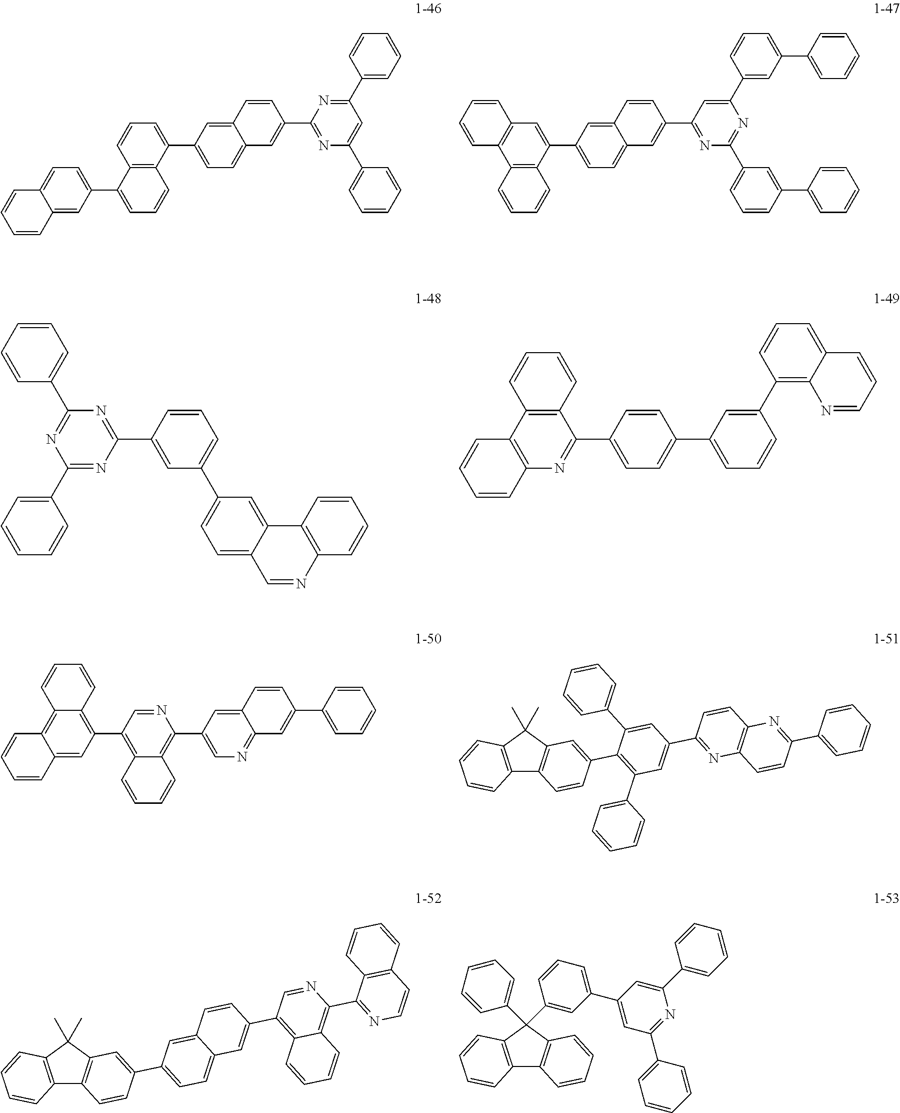

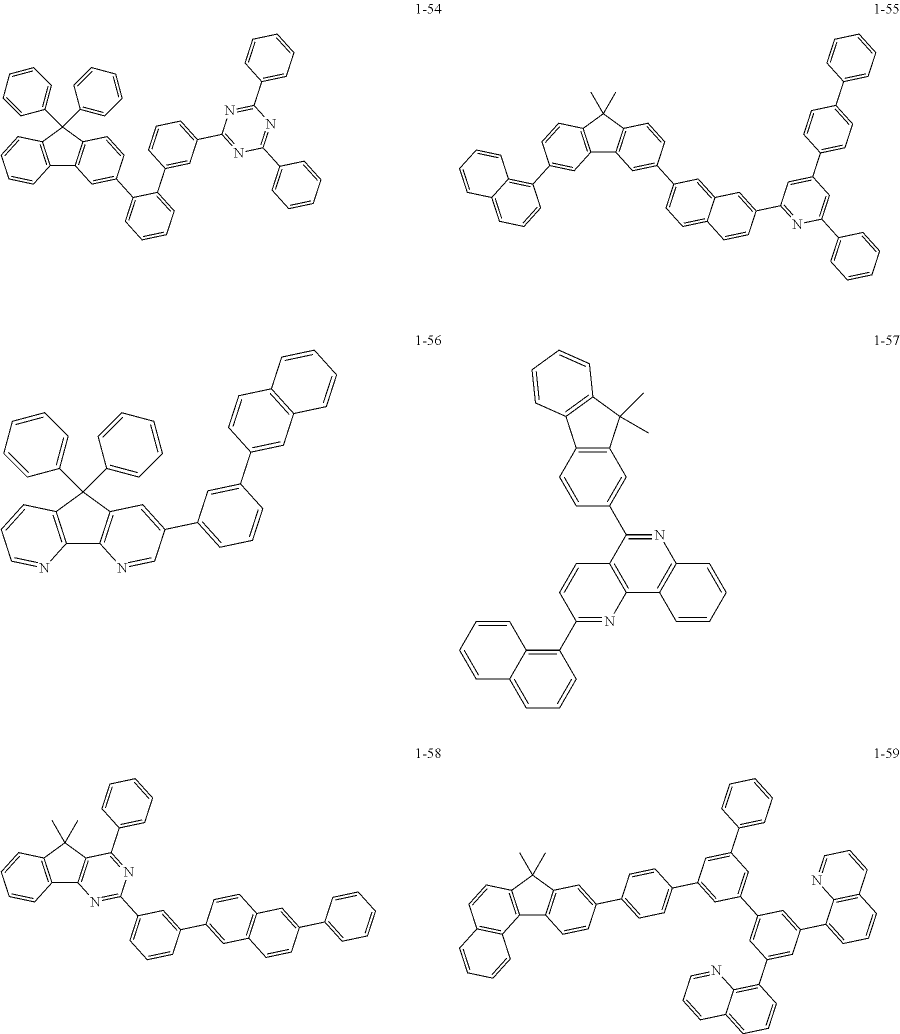

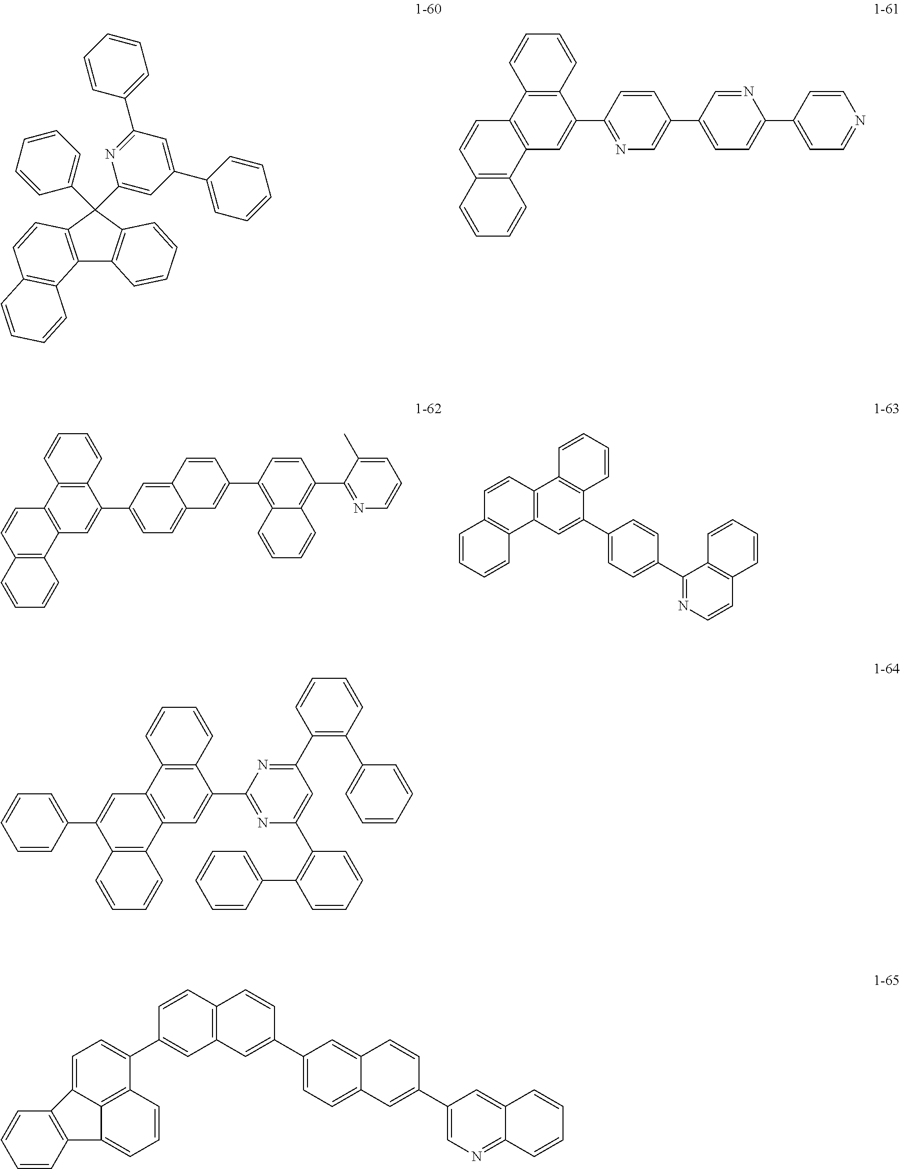 [SMILES: c1ccc(-c2cc(-c3ccccc3)nc(C3(c4ccccc4)c4ccccc4-c4c3ccc3ccccc43)c2)cc1 ; c1ccc2c(c1)ccc1c3ccccc3c(-c3ccc(-c4ccc(-c5ccncc5)nc4)cn3)cc21 ; Cc1cccnc1-c1ccc(-c2ccc3cc(-c4cc5c6ccccc6ccc5c5ccccc45)ccc3c2)c2ccccc12 ; c1ccc2c(-c3ccc(-c4cc5c6ccccc6ccc5c5ccccc45)cc3)nccc2c1 ; c1ccc(-c2ccccc2-c2cc(-c3ccccc3-c3ccccc3)nc(-c3cc4c5ccccc5c(-c5ccccc5)cc4c4ccccc34)n2)cc1 ; c1ccc2c(c1)-c1cccc3c(-c4ccc5ccc(-c6ccc7cc(-c8cnc9ccccc9c8)ccc7c6)cc5c4)ccc-2c13]

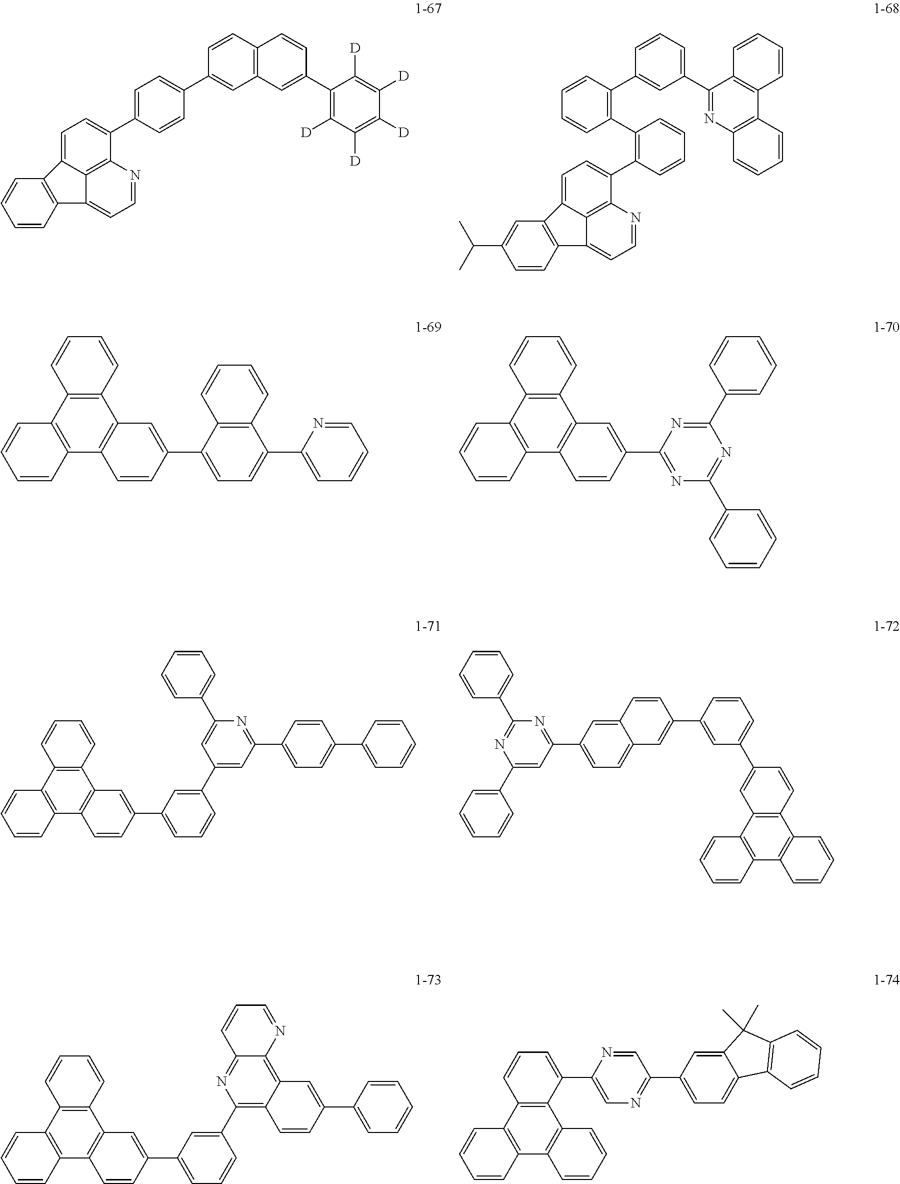

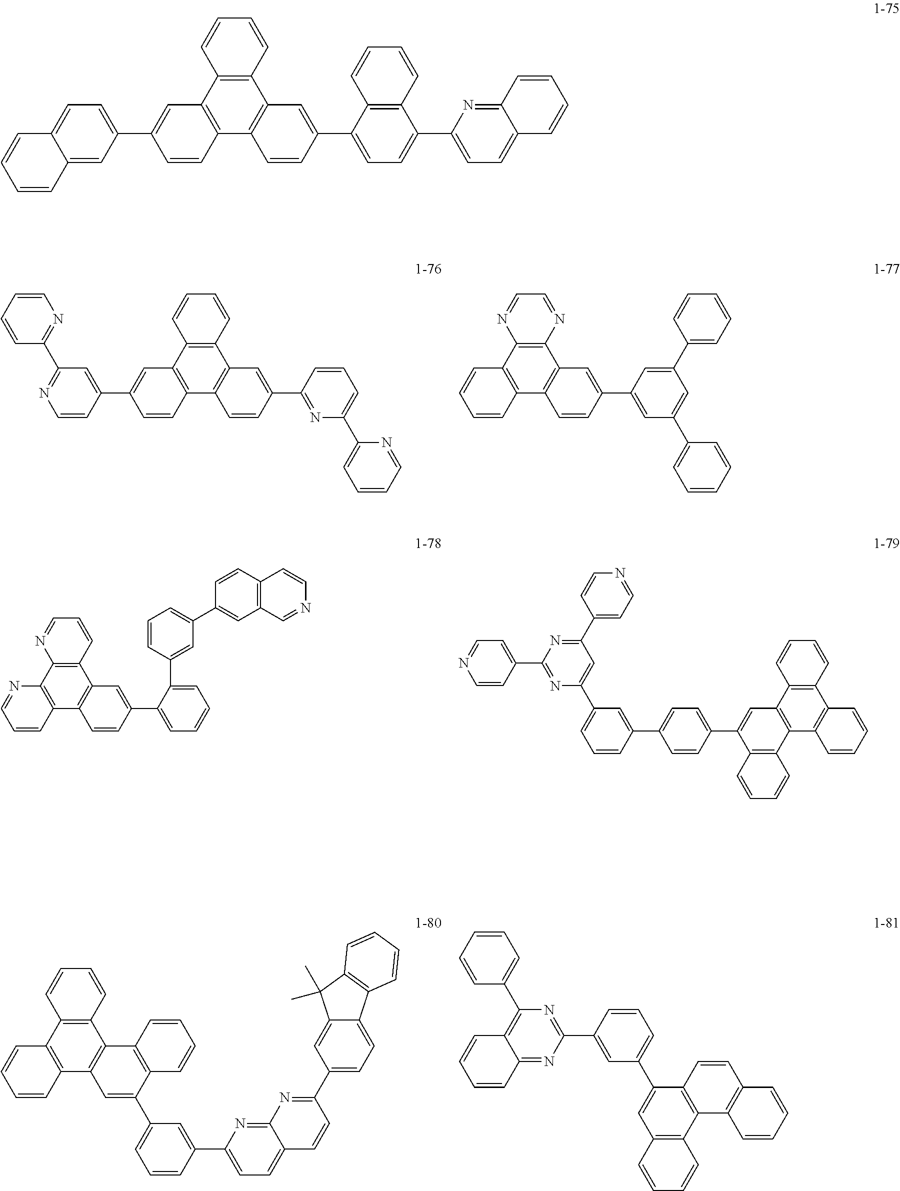

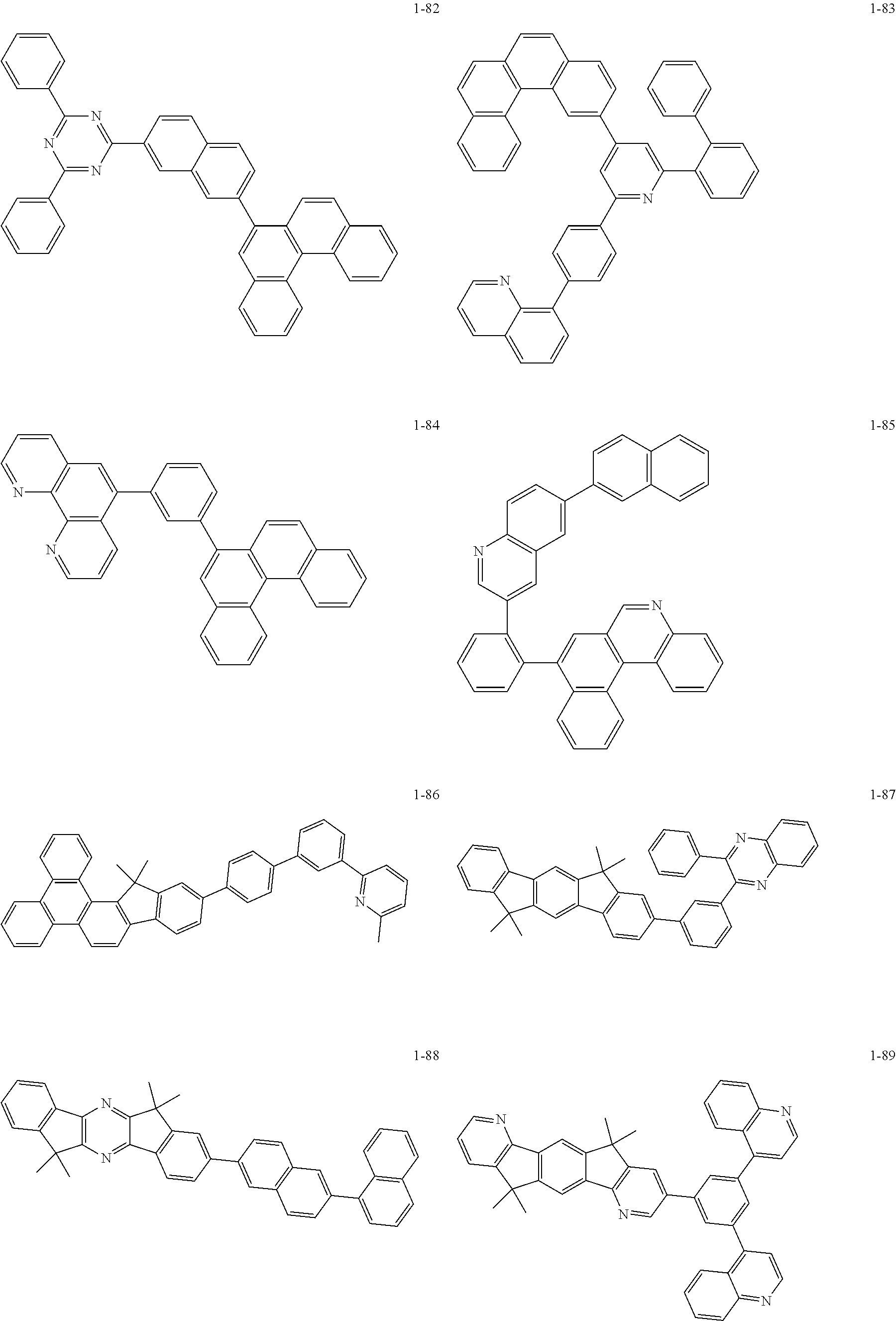

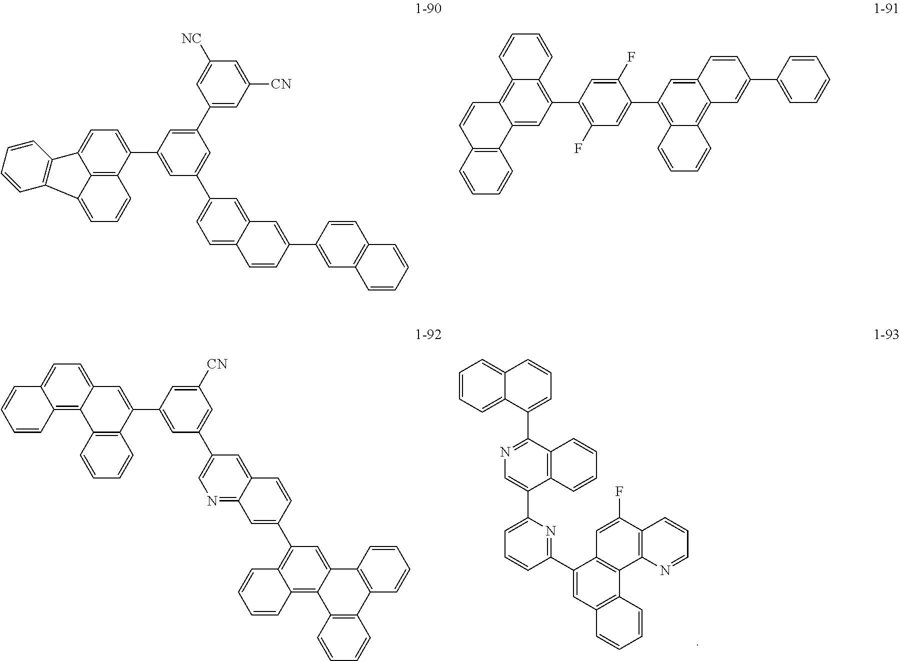 [SMILES: N#Cc1cc(C#N)cc(-c2cc(-c3ccc4ccc(-c5ccc6ccccc6c5)cc4c3)cc(-c3ccc4c5c(cccc35)-c3ccccc3-4)c2)c1 ; Fc1cc(-c2cc3c4ccccc4ccc3c3ccccc23)c(F)cc1-c1cc2ccc(-c3ccccc3)cc2c2ccccc12 ; N#Cc1cc(-c2cnc3cc(-c4cc5c6ccccc6c6ccccc6c5c5ccccc45)ccc3c2)cc(-c2cc3ccc4ccccc4c3c3ccccc23)c1 ; Fc1cc2c(-c3cccc(-c4cnc(-c5cccc6ccccc56)c5ccccc45)n3)cc3ccccc3c2c2ncccc12]

In one or more embodiments, the second compound represented by Formula 2A or 2B may be selected from Compounds 2-1a to 2-172a and 2-1 to 2-262, but embodiments of the present disclosure are not limited thereto:

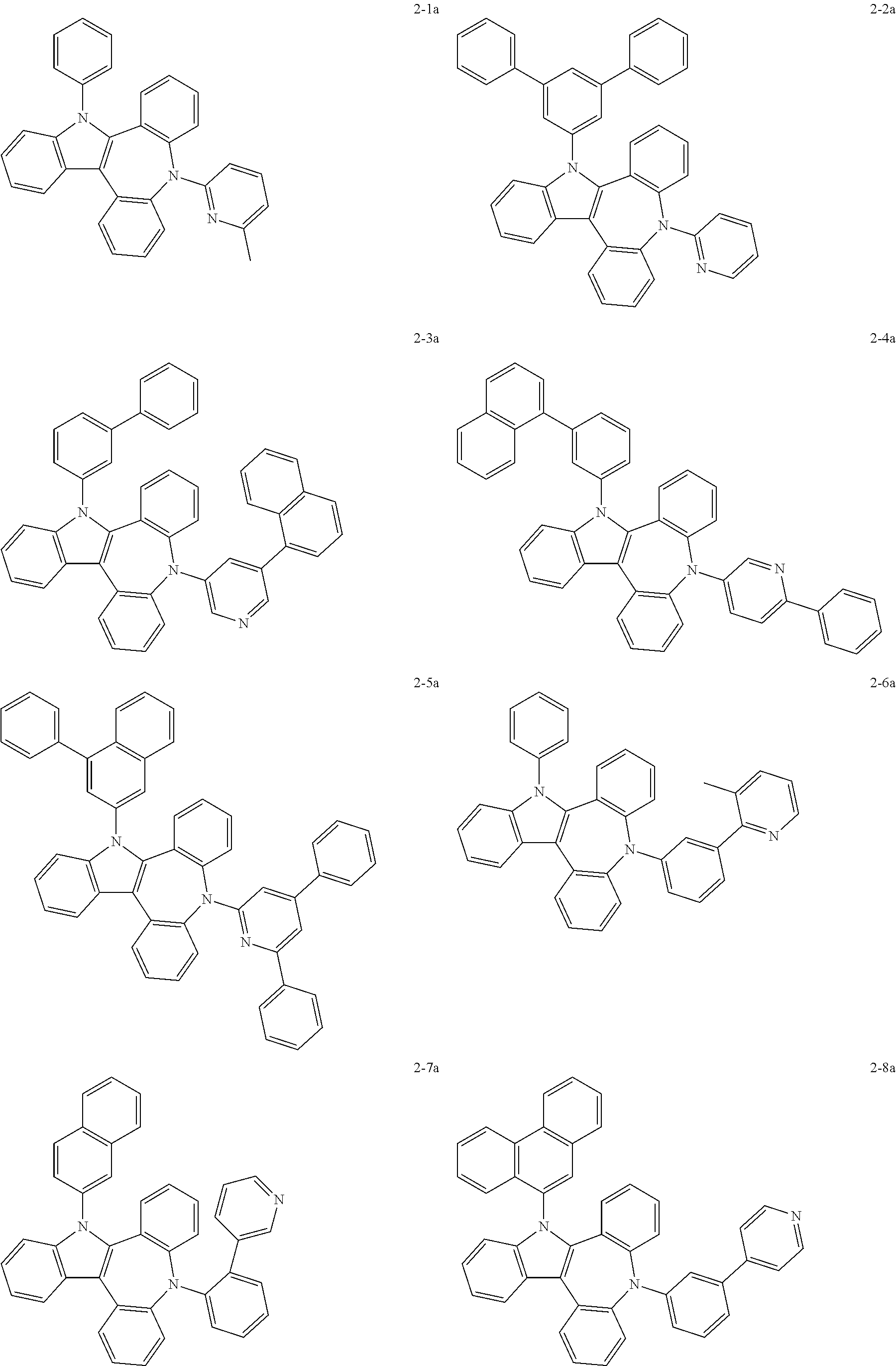

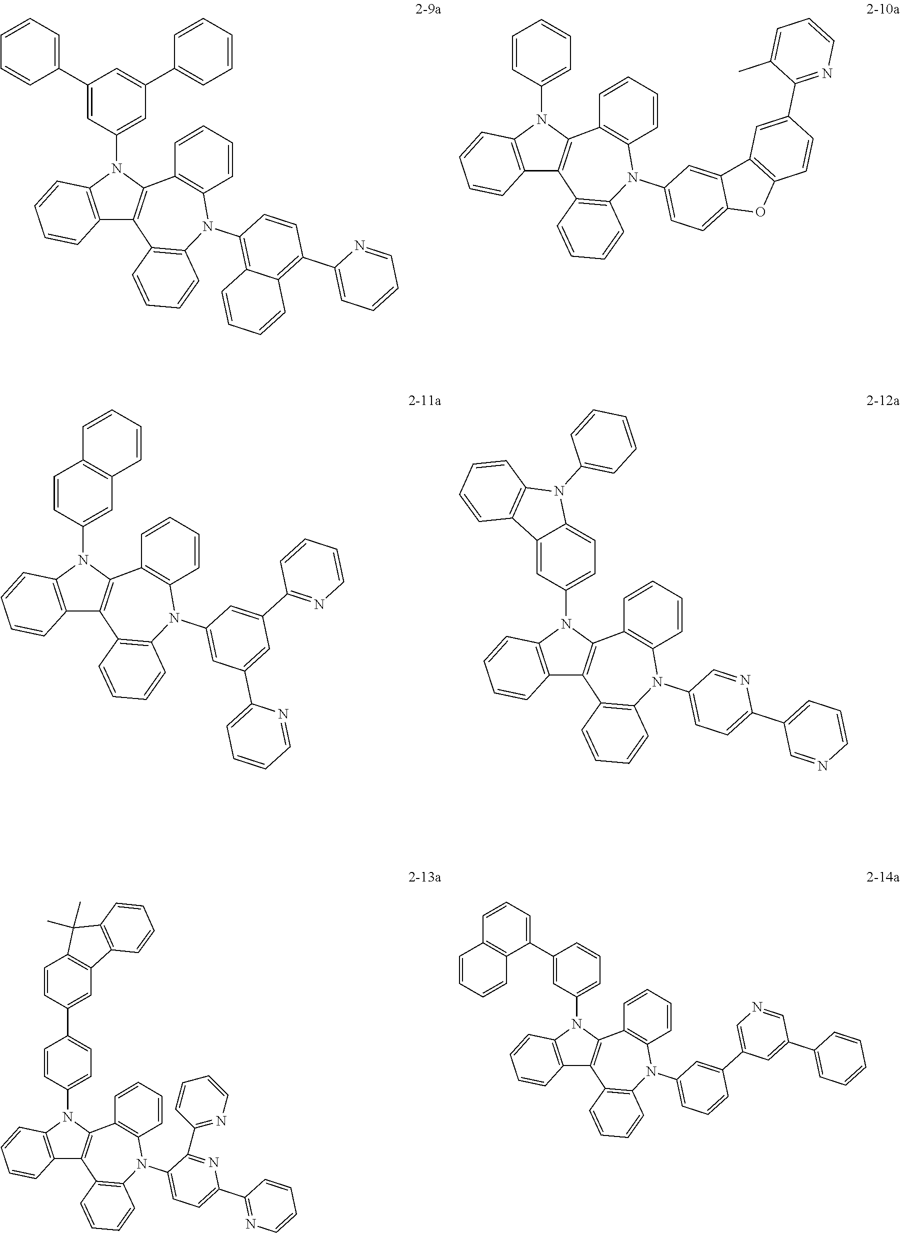

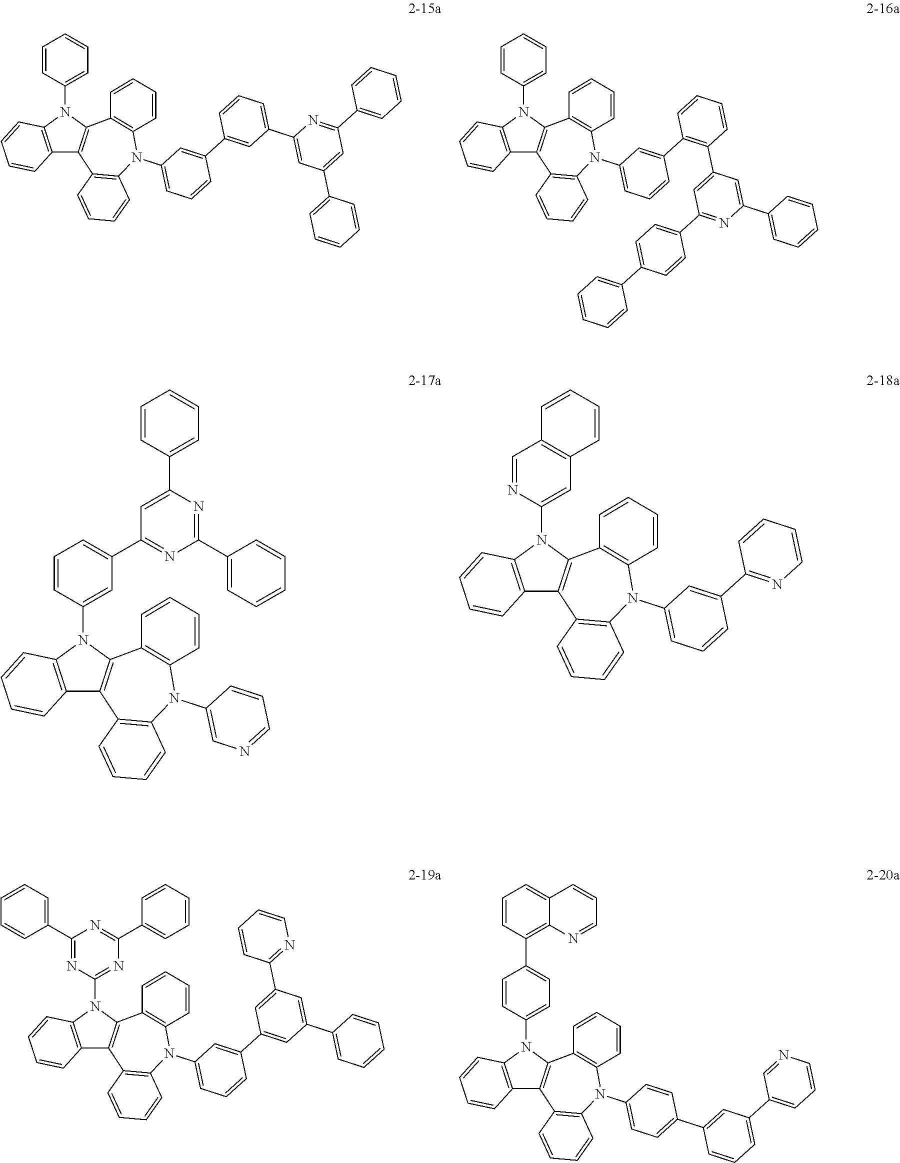

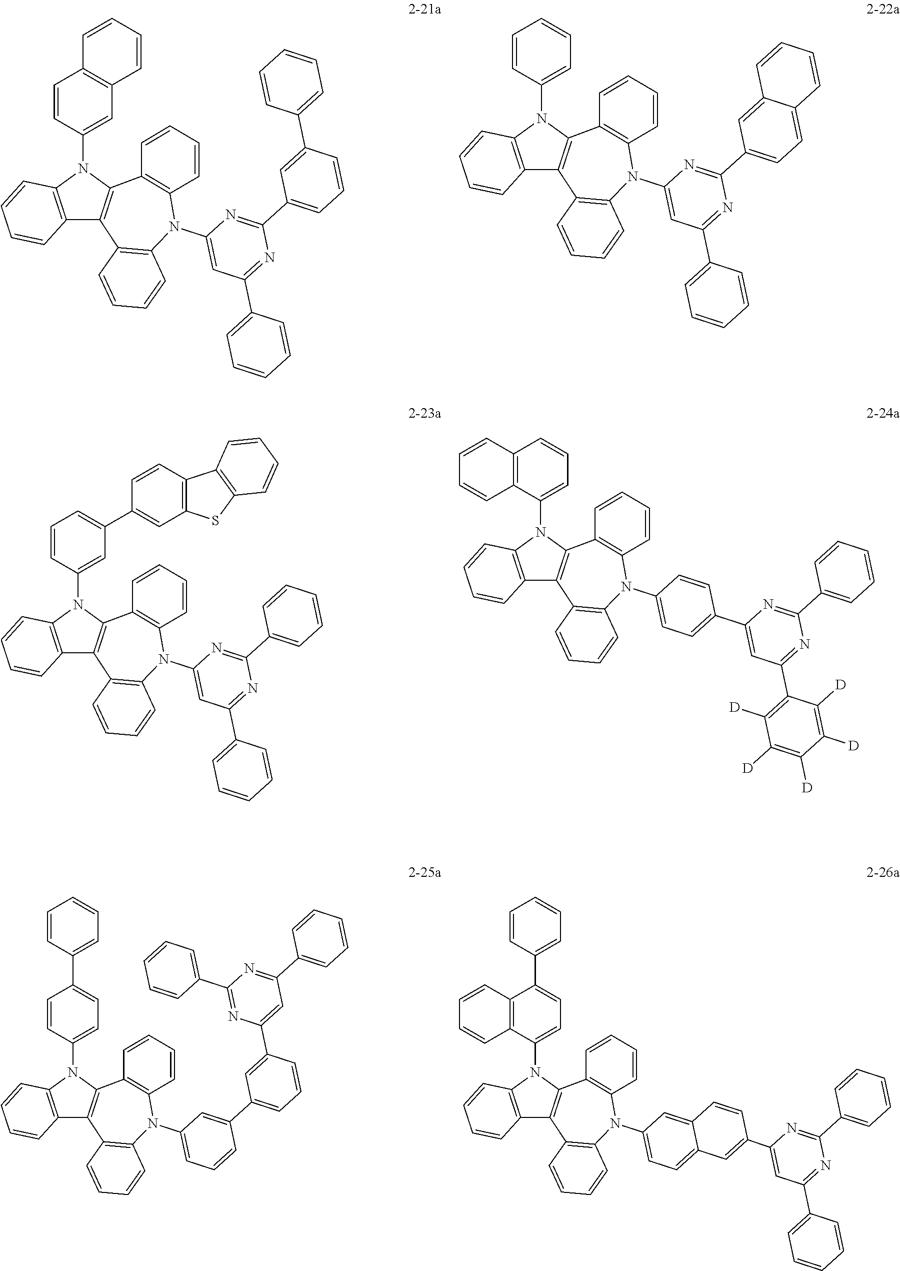

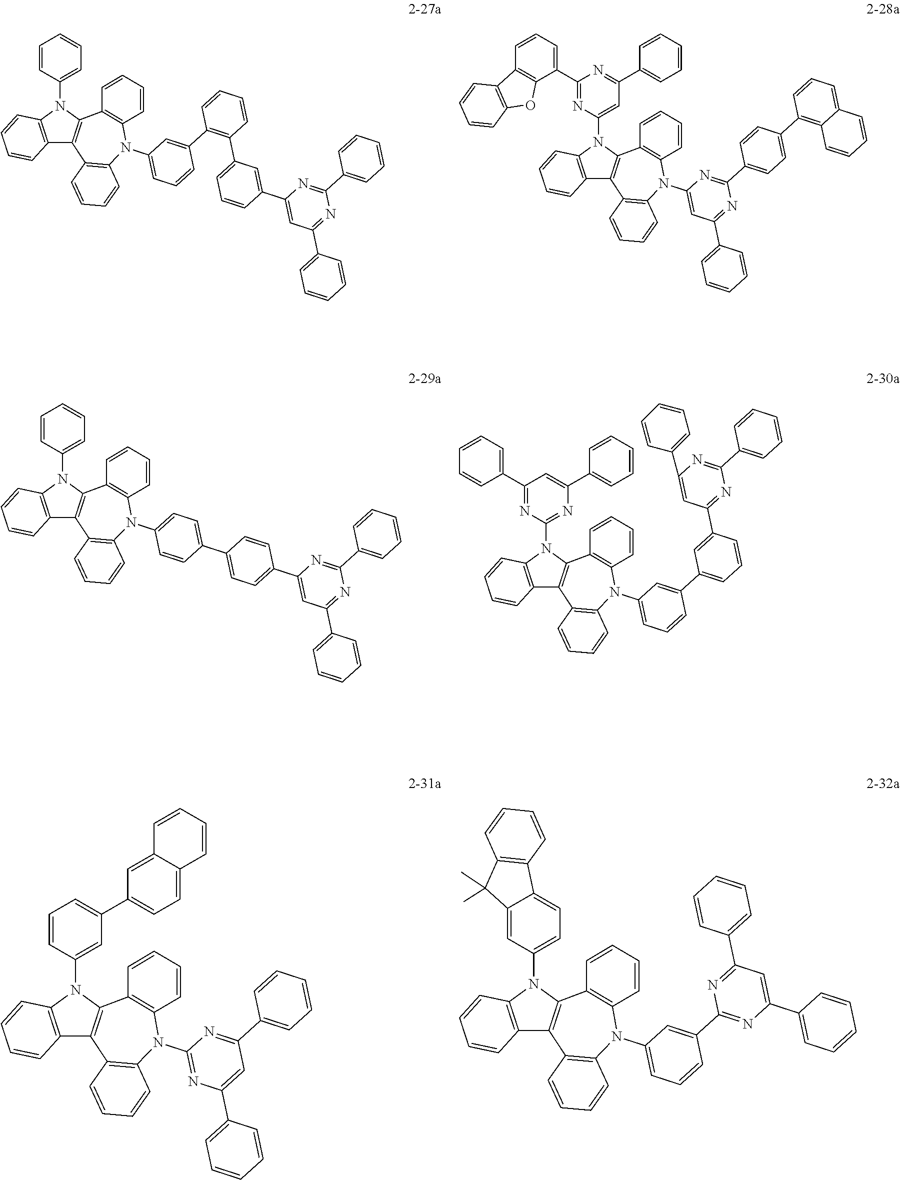

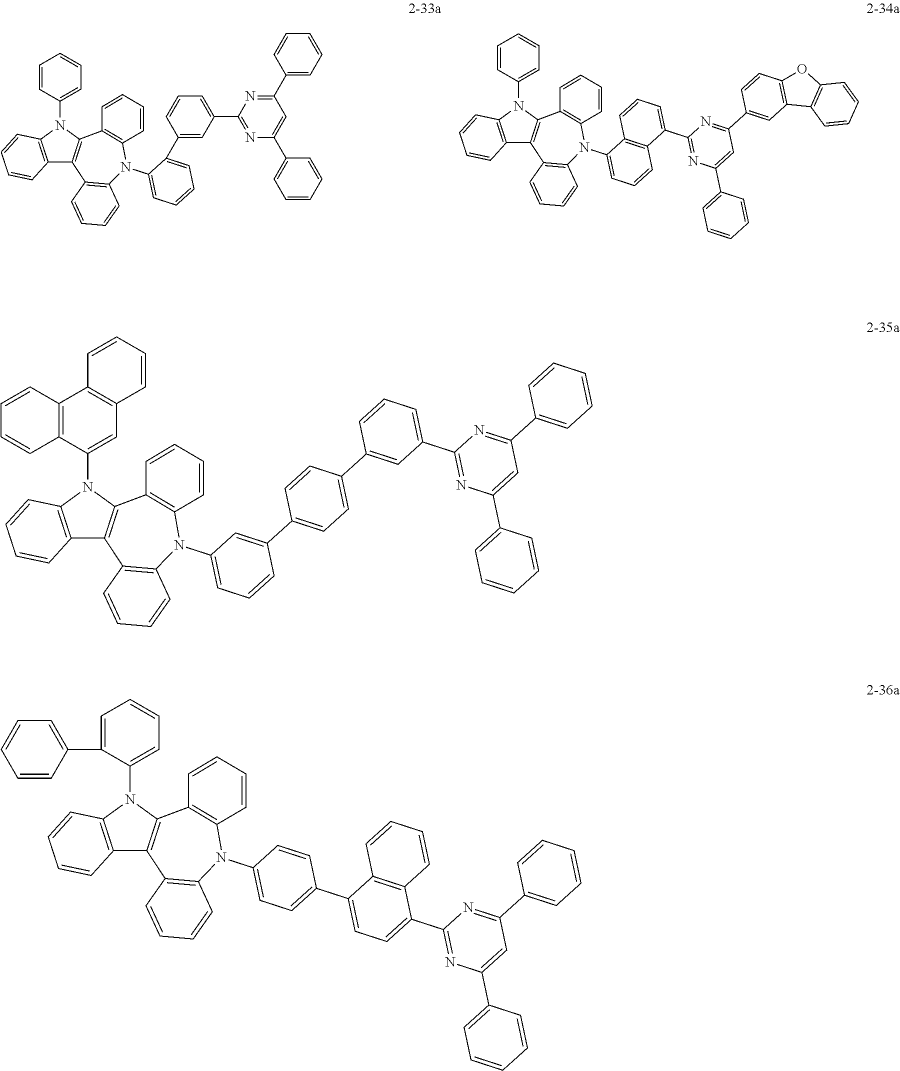 [SMILES: c1ccc(-c2cc(-c3ccccc3)nc(-c3cccc(-c4ccccc4N4c5ccccc5-c5c(n(-c6ccccc6)c6ccccc56)-c5ccccc54)c3)n2)cc1 ; c1ccc(-c2cc(-c3ccc4oc5ccccc5c4c3)nc(-c3cccc4c(N5c6ccccc6-c6c(n(-c7ccccc7)c7ccccc67)-c6ccccc65)cccc34)n2)cc1 ; c1ccc(-c2cc(-c3ccccc3)nc(-c3cccc(-c4ccc(-c5cccc(N6c7ccccc7-c7c(n(-c8cc9ccccc9c9ccccc89)c8ccccc78)-c7ccccc76)c5)cc4)c3)n2)cc1 ; c1ccc(-c2cc(-c3ccccc3)nc(-c3ccc(-c4ccc(N5c6ccccc6-c6c(n(-c7ccccc7-c7ccccc7)c7ccccc67)-c6ccccc65)cc4)c4ccccc34)n2)cc1]

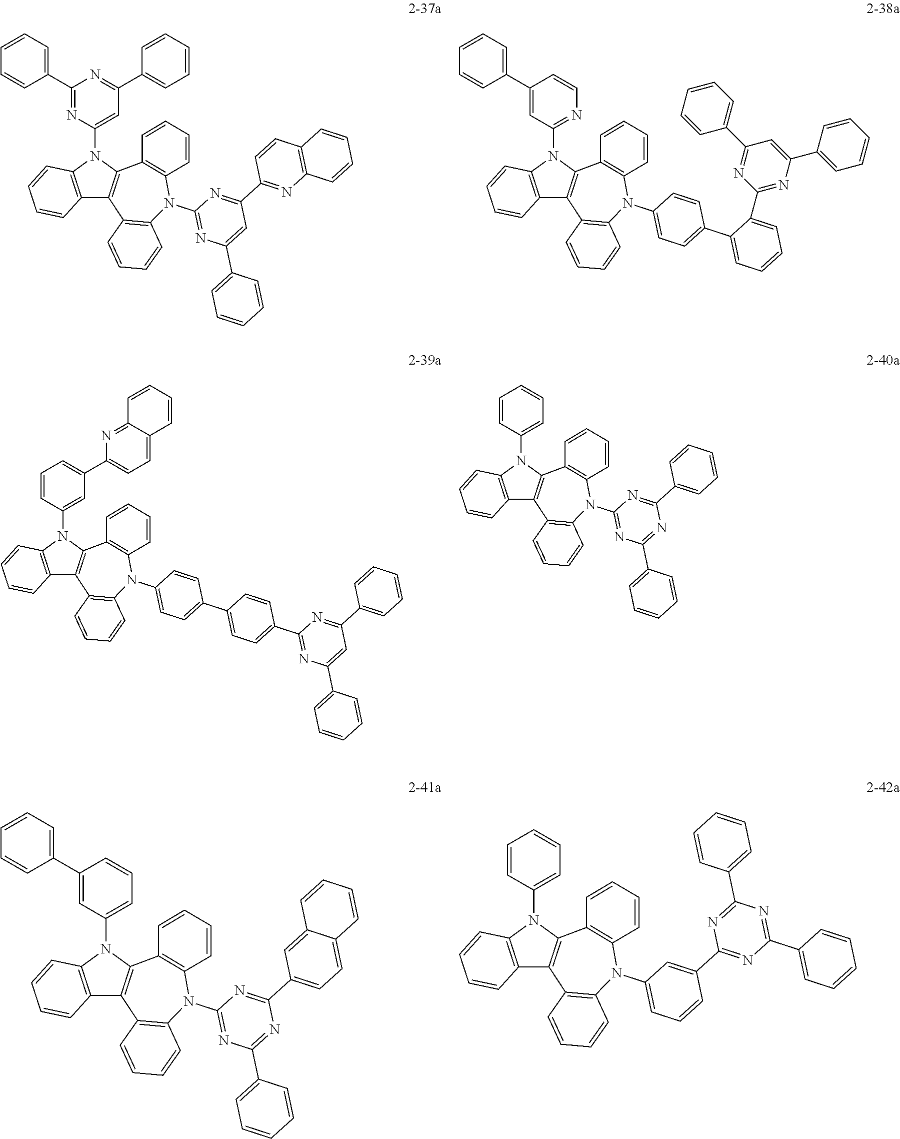

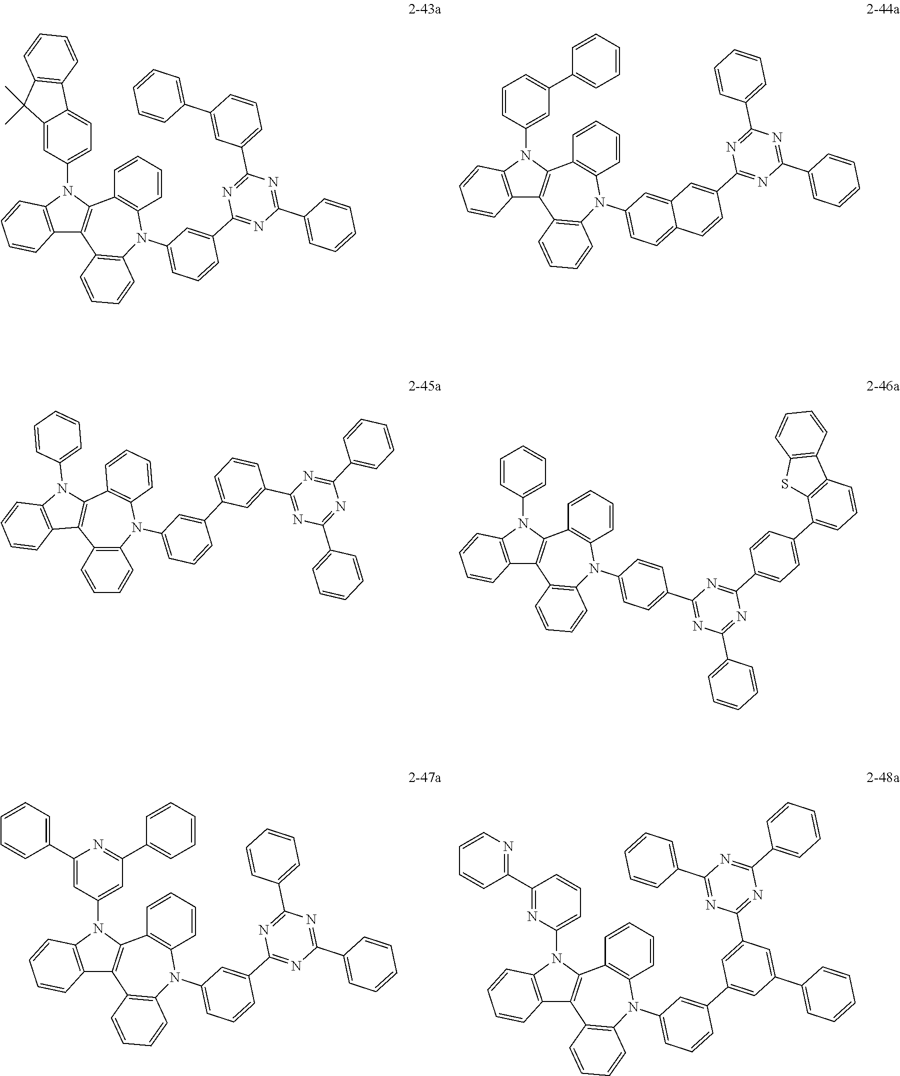

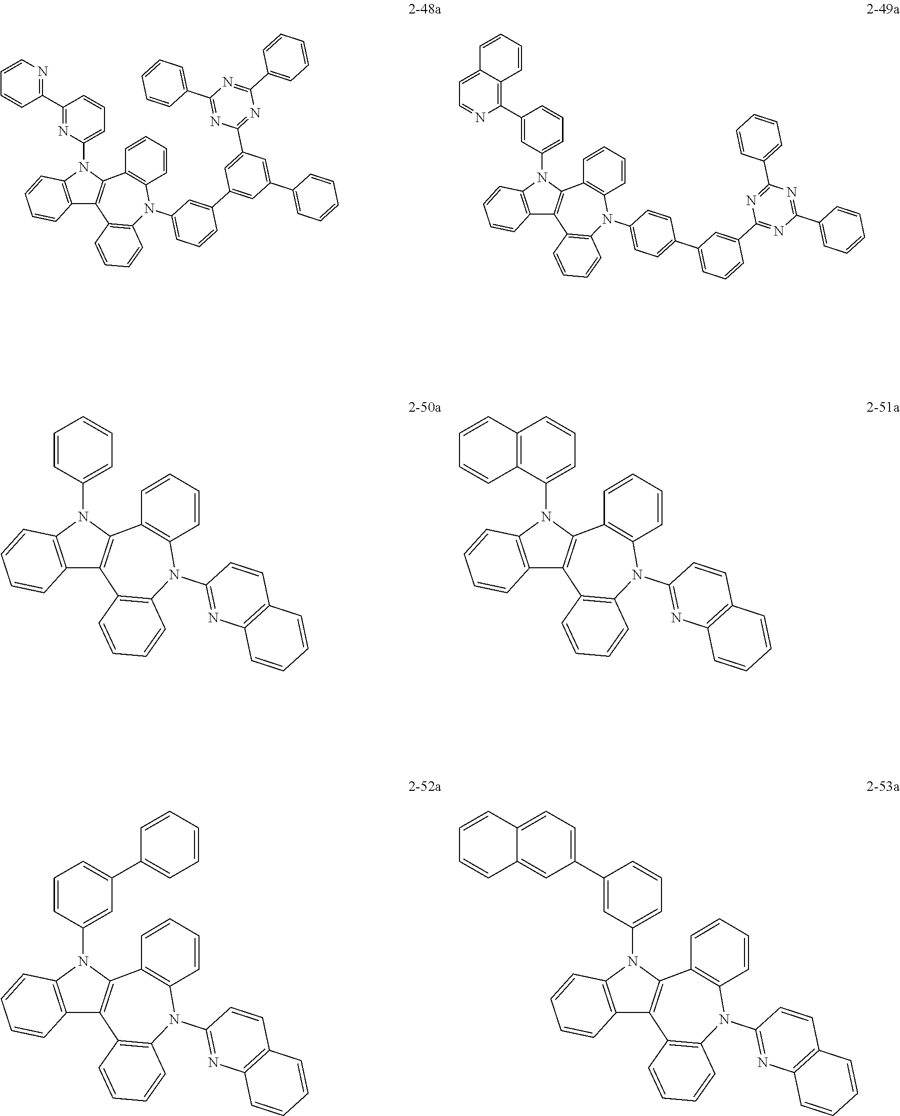

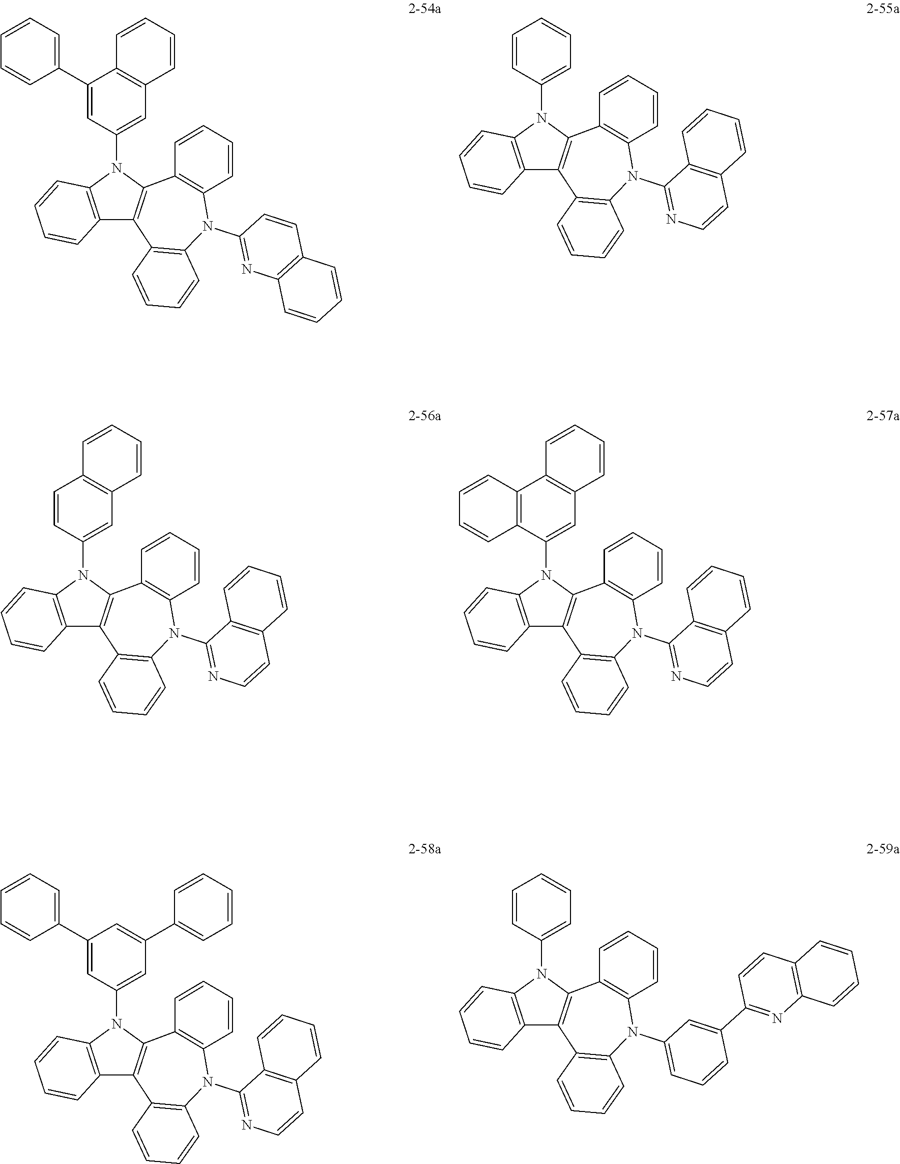 [SMILES: c1ccc(-c2cc(-n3c4c(c5ccccc53)-c3ccccc3N(c3ccc5ccccc5n3)c3ccccc3-4)cc3ccccc23)cc1 ; c1ccc(-n2c3c(c4ccccc42)-c2ccccc2N(c2nccc4ccccc24)c2ccccc2-3)cc1 ; c1ccc2c(c1)-c1c(n(-c3ccc4ccccc4c3)c3ccccc13)-c1ccccc1N2c1nccc2ccccc12 ; c1ccc2c(c1)-c1c(n(-c3cc4ccccc4c4ccccc34)c3ccccc13)-c1ccccc1N2c1nccc2ccccc12 ; c1ccc(-c2cc(-c3ccccc3)cc(-n3c4c(c5ccccc53)-c3ccccc3N(c3nccc5ccccc35)c3ccccc3-4)c2)cc1 ; c1ccc(-n2c3c(c4ccccc42)-c2ccccc2N(c2cccc(-c4ccc5ccccc5n4)c2)c2ccccc2-3)cc1]

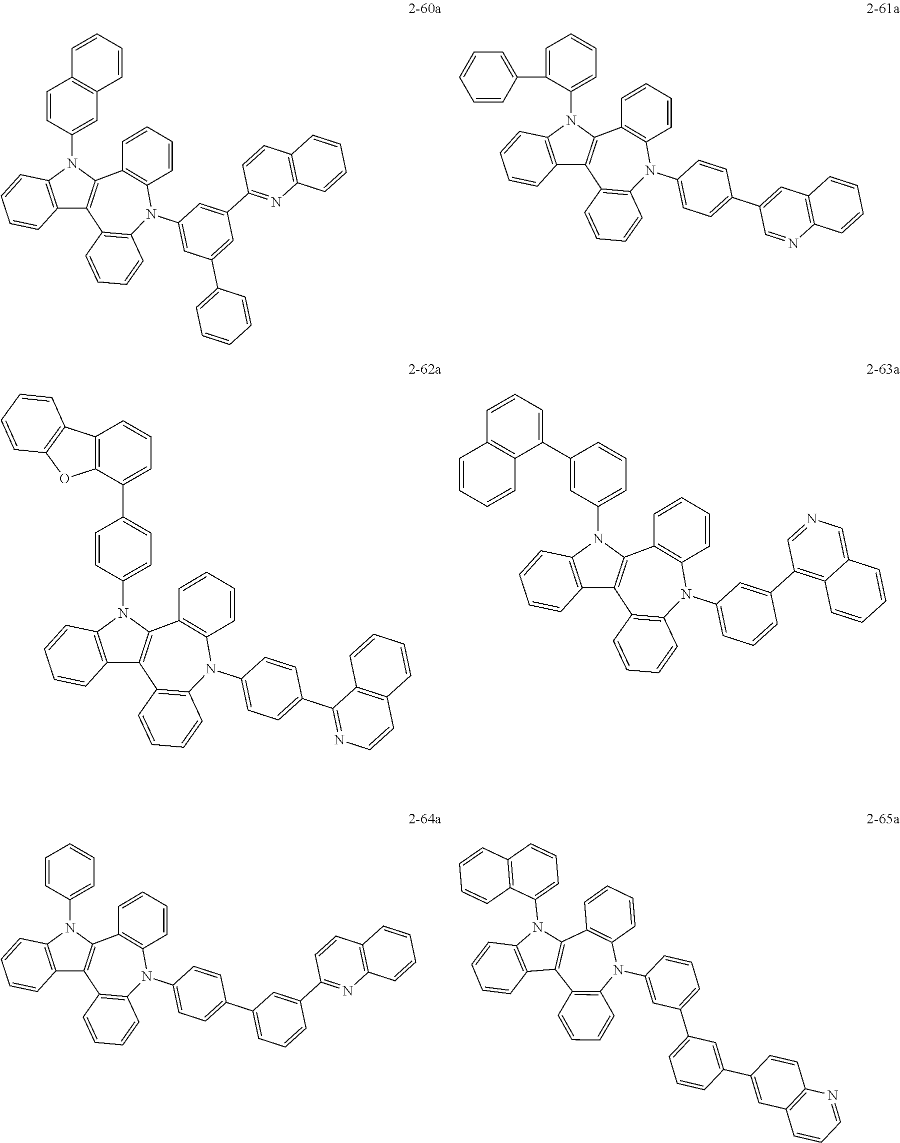

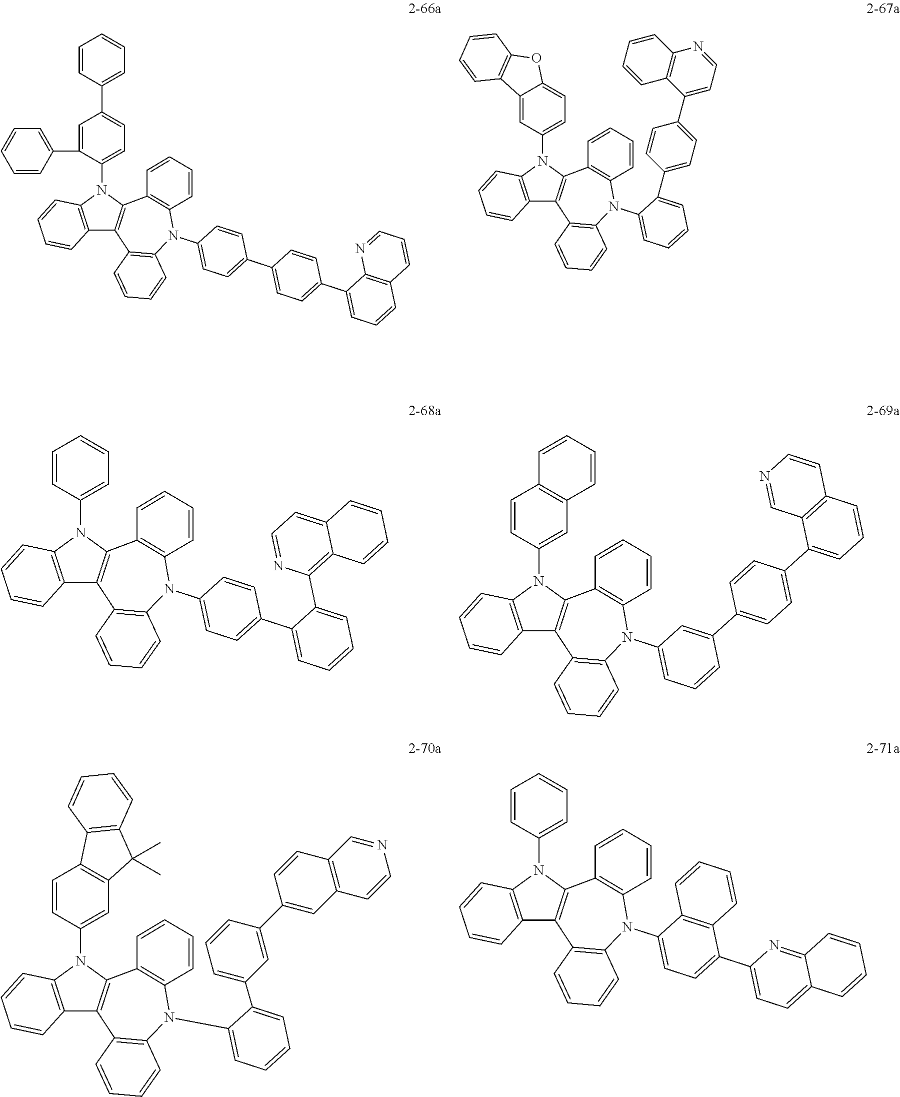

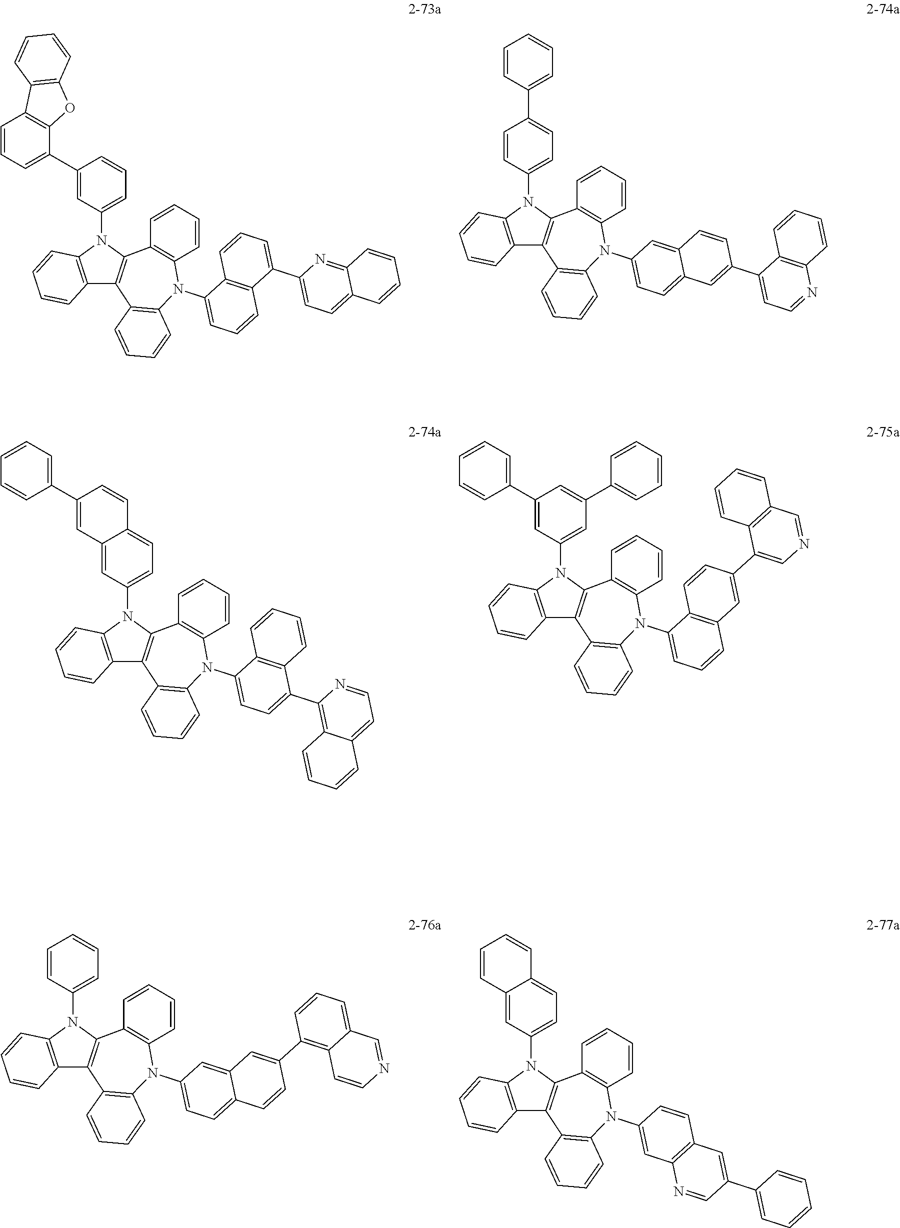

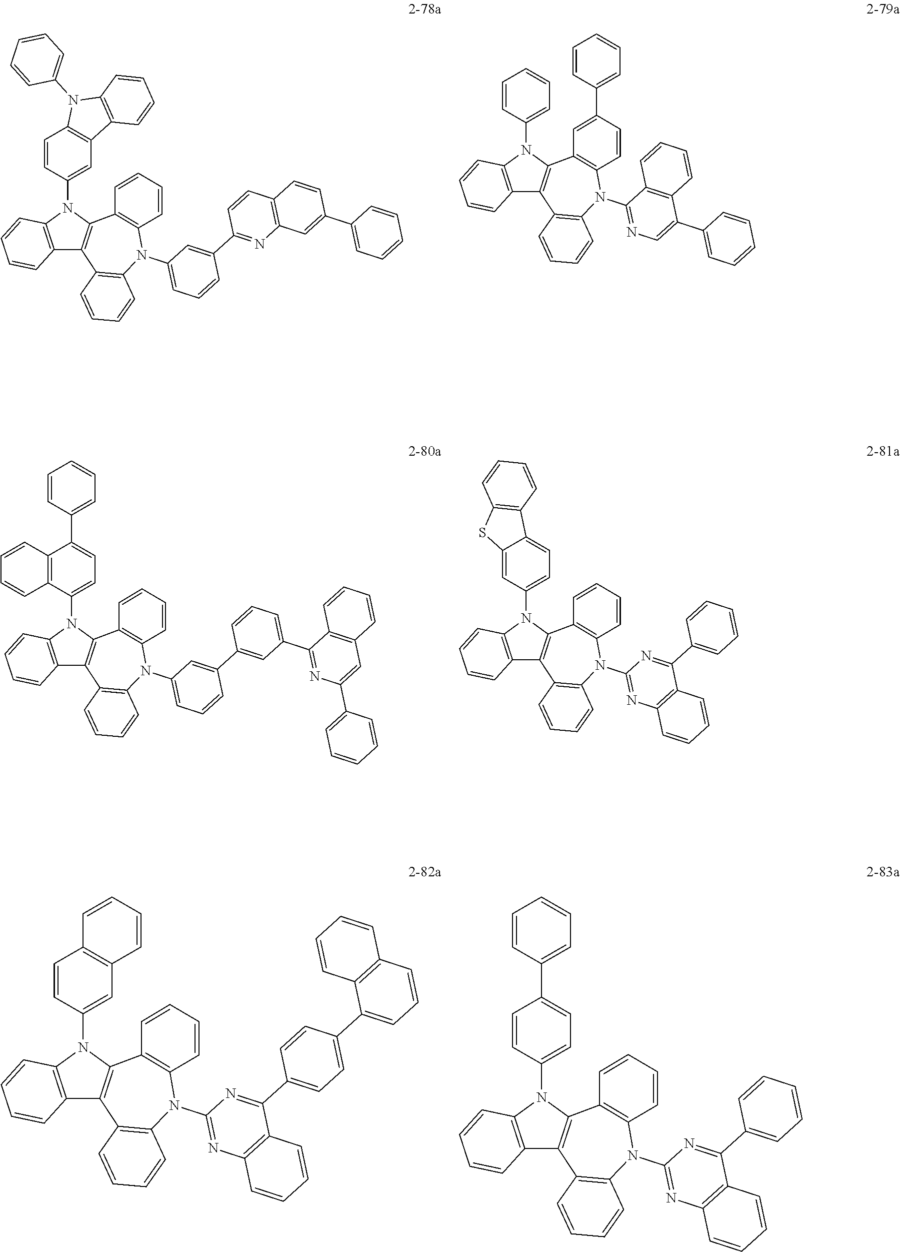

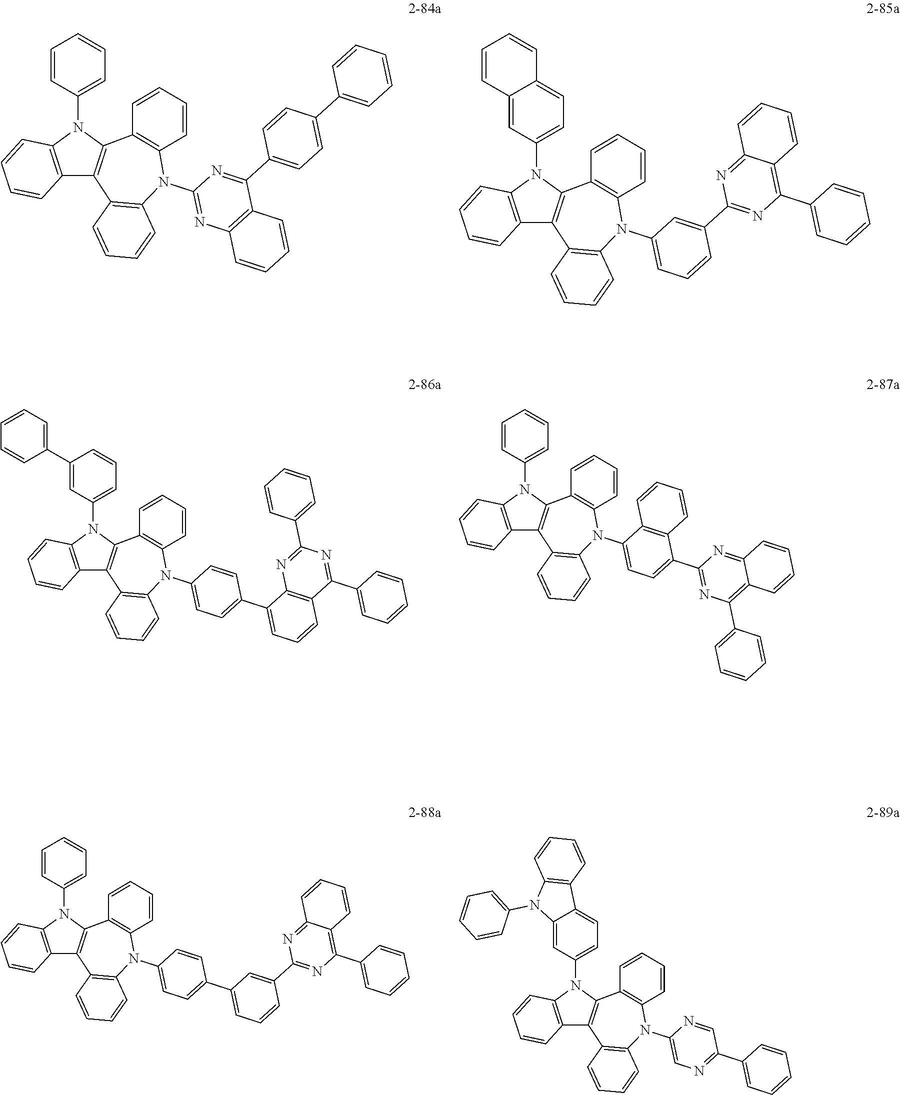

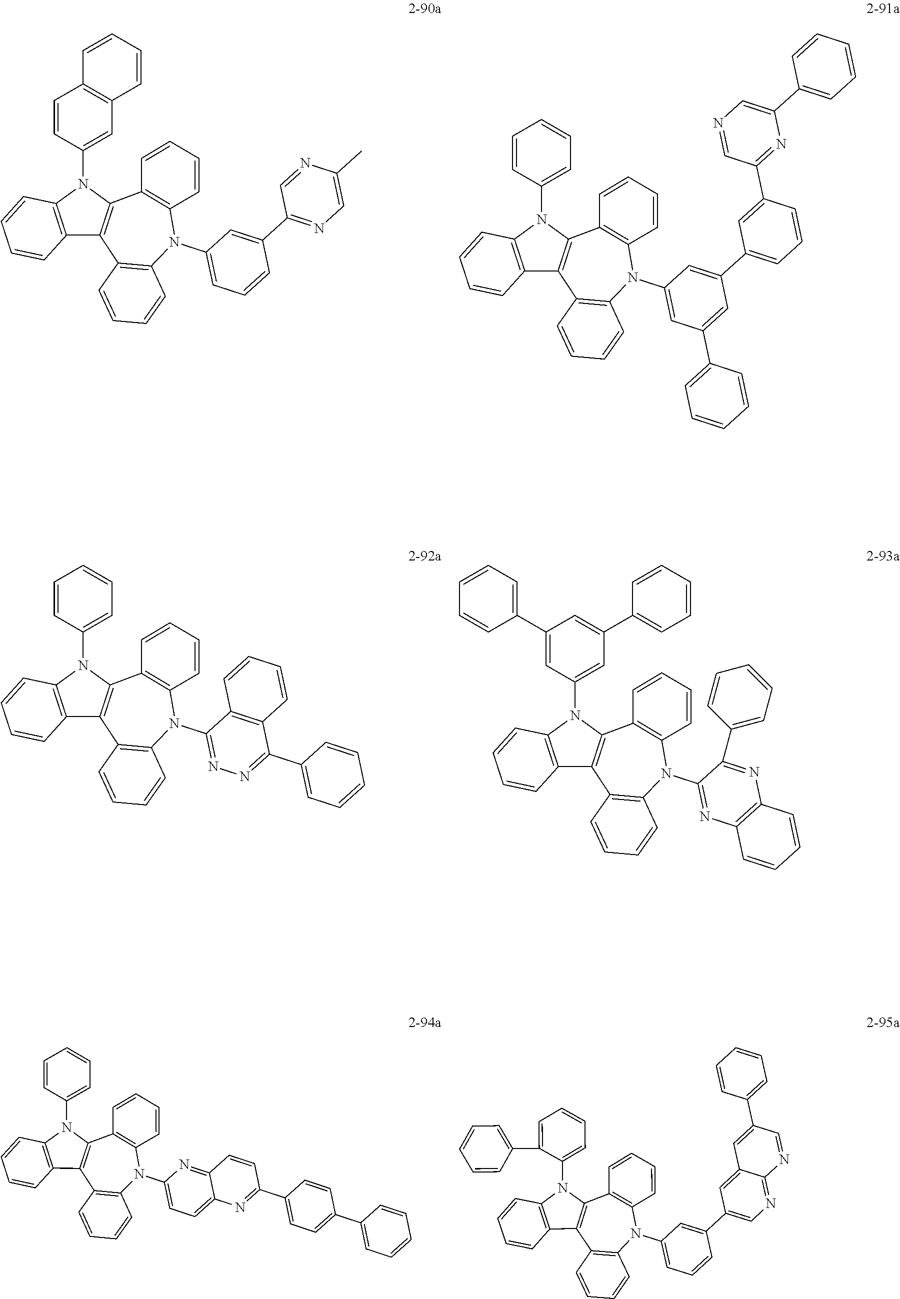

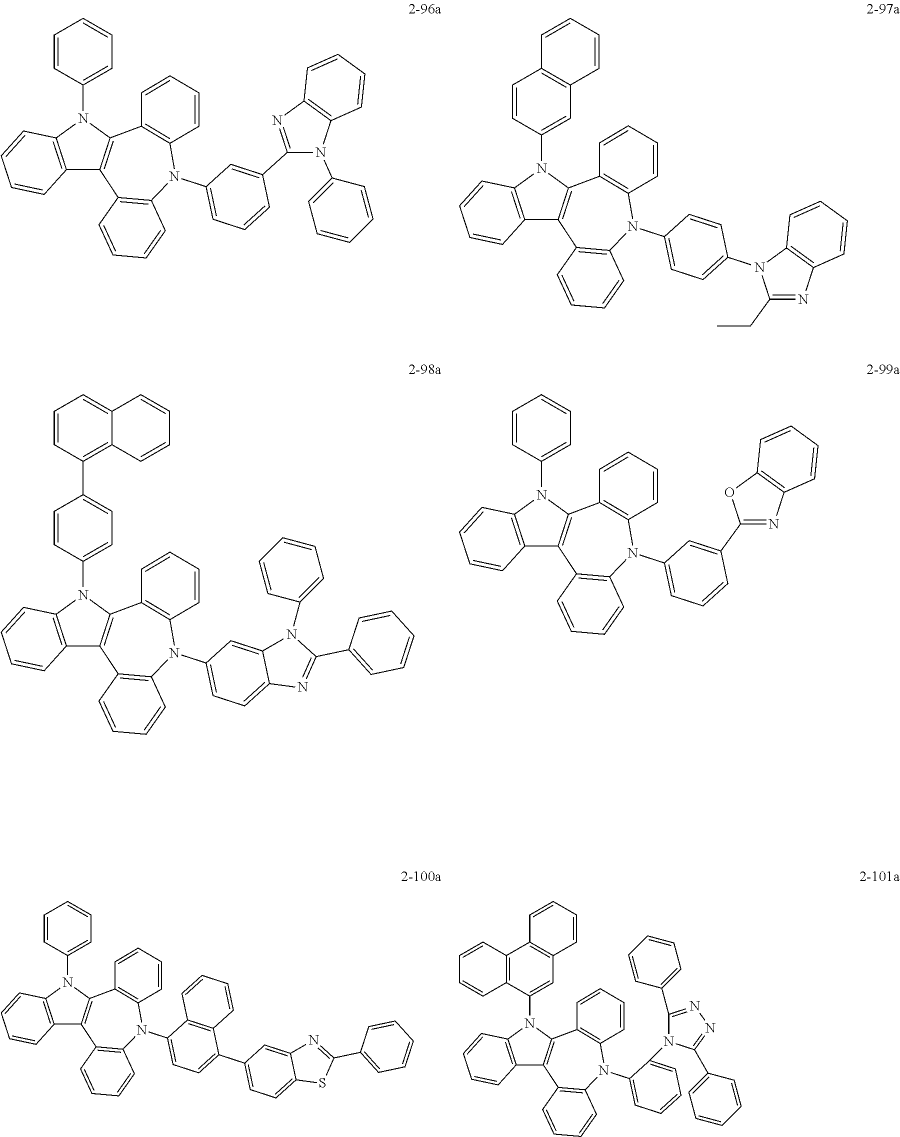

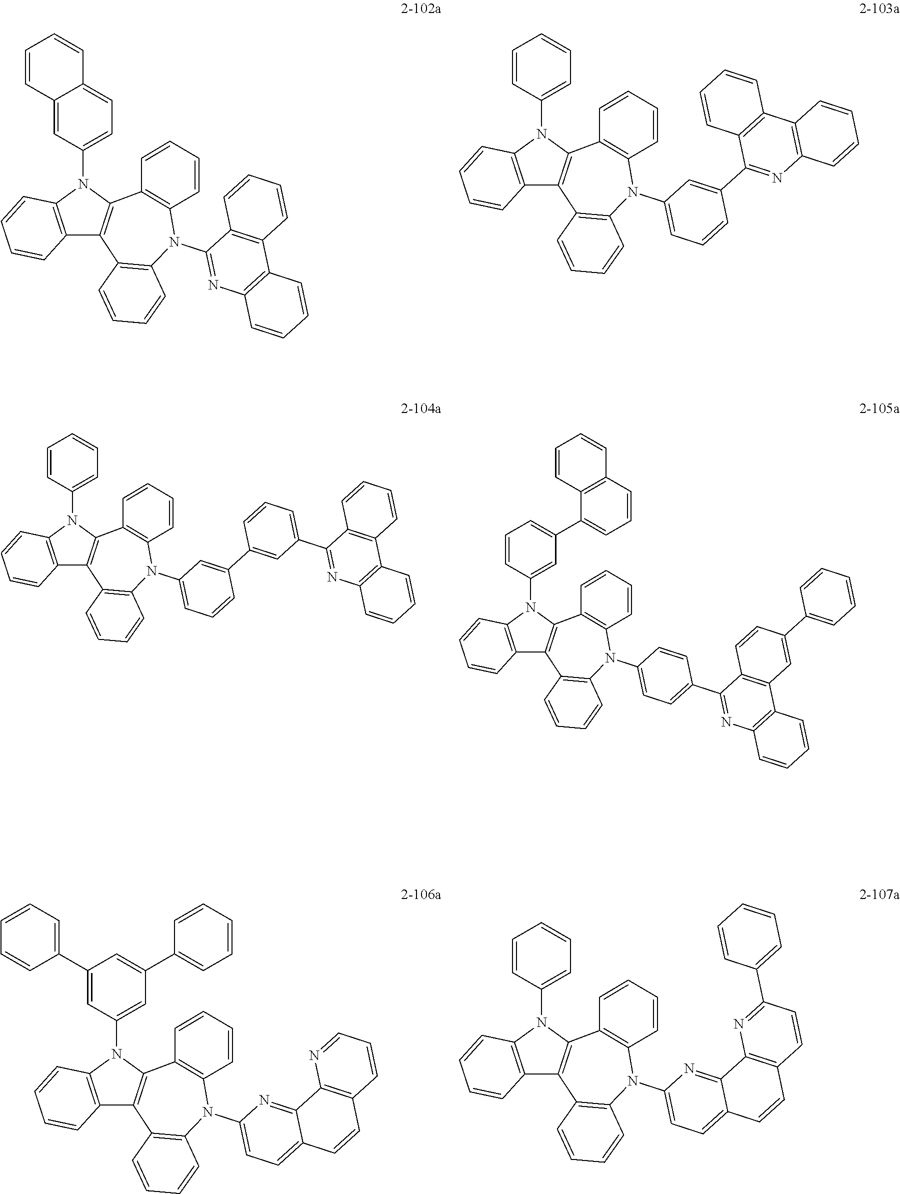

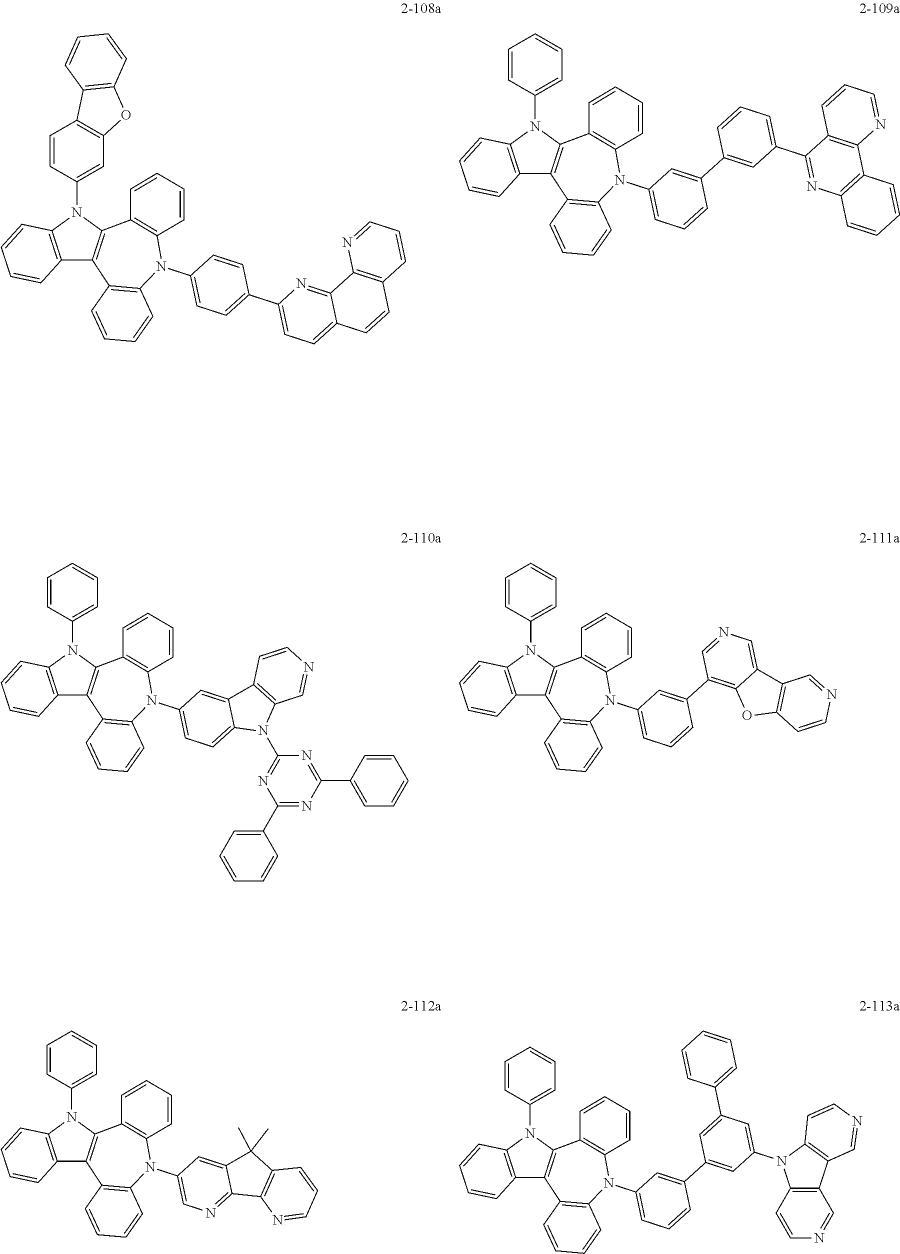

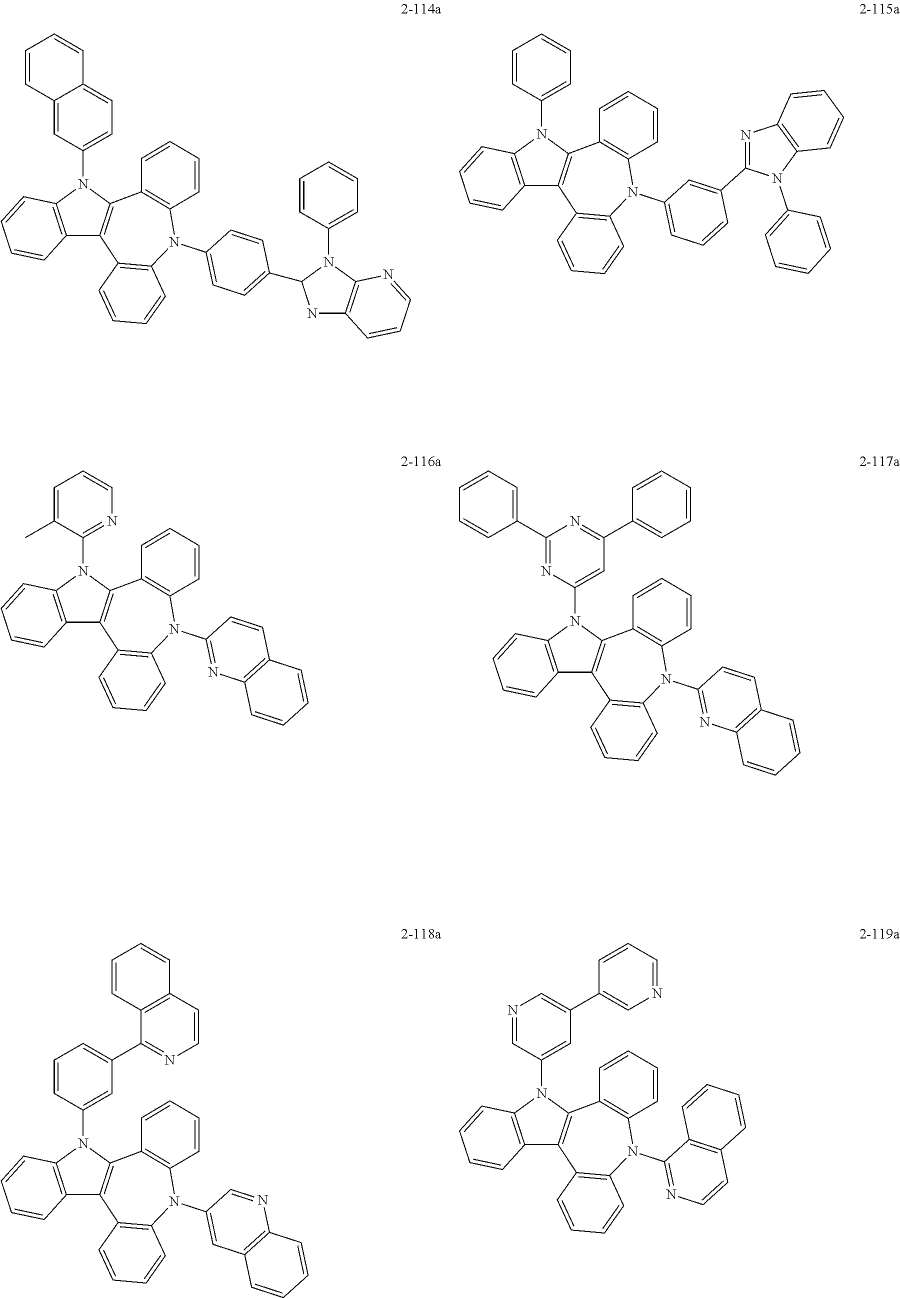 [SMILES: c1ccc(N2c3ncccc3NC2c2ccc(N3c4ccccc4-c4c(n(-c5ccc6ccccc6c5)c5ccccc45)-c4ccccc43)cc2)cc1 ; c1ccc(-n2c(-c3cccc(N4c5ccccc5-c5c(n(-c6ccccc6)c6ccccc56)-c5ccccc54)c3)nc3ccccc32)cc1 ; Cc1cccnc1-n1c2c(c3ccccc31)-c1ccccc1N(c1ccc3ccccc3n1)c1ccccc1-2 ; c1ccc(-c2cc(-n3c4c(c5ccccc53)-c3ccccc3N(c3ccc5ccccc5n3)c3ccccc3-4)nc(-c3ccccc3)n2)cc1 ; c1cc(-c2nccc3ccccc23)cc(-n2c3c(c4ccccc42)-c2ccccc2N(c2cnc4ccccc4c2)c2ccccc2-3)c1 ; c1cncc(-c2cncc(-n3c4c(c5ccccc53)-c3ccccc3N(c3nccc5ccccc35)c3ccccc3-4)c2)c1]

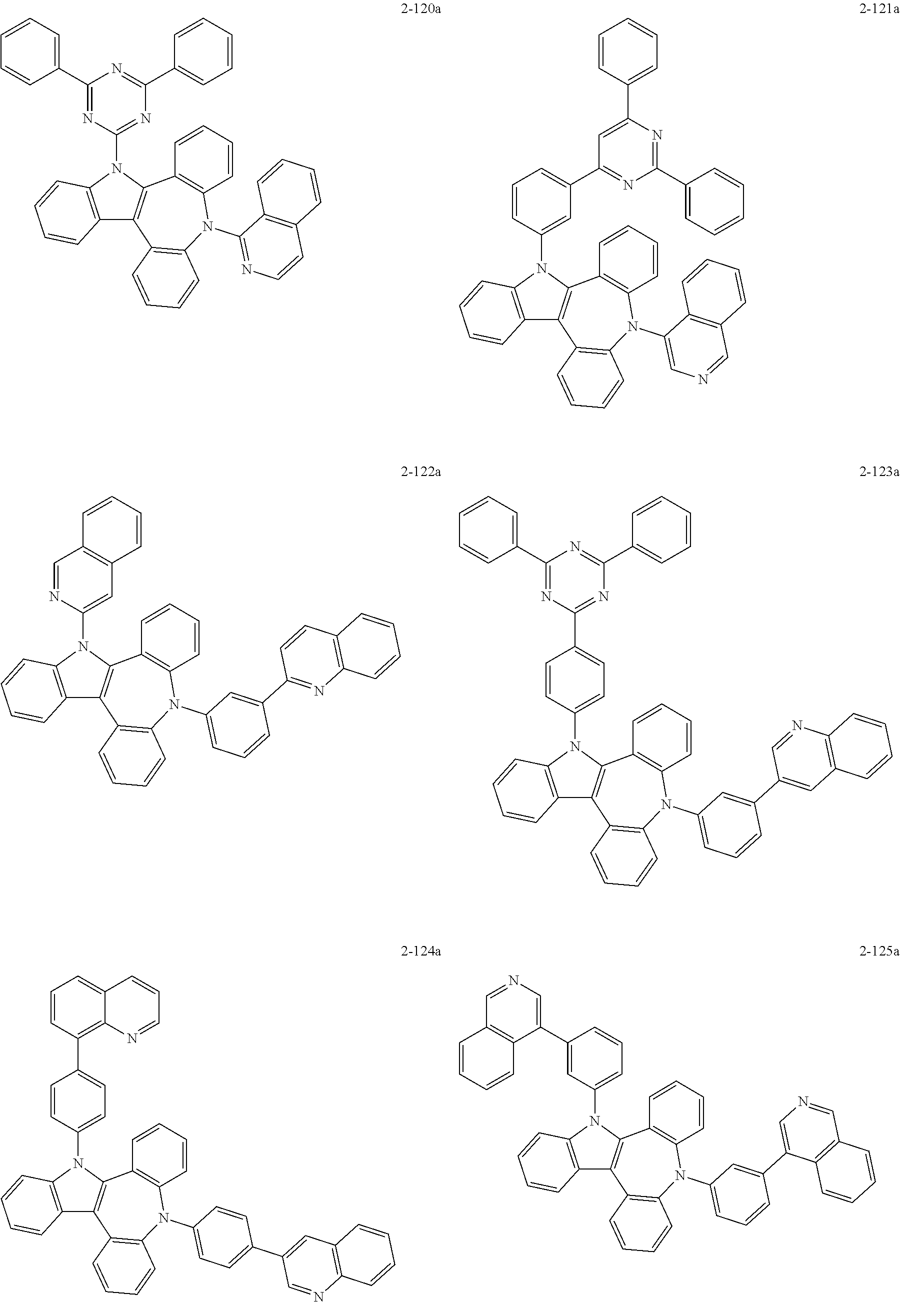

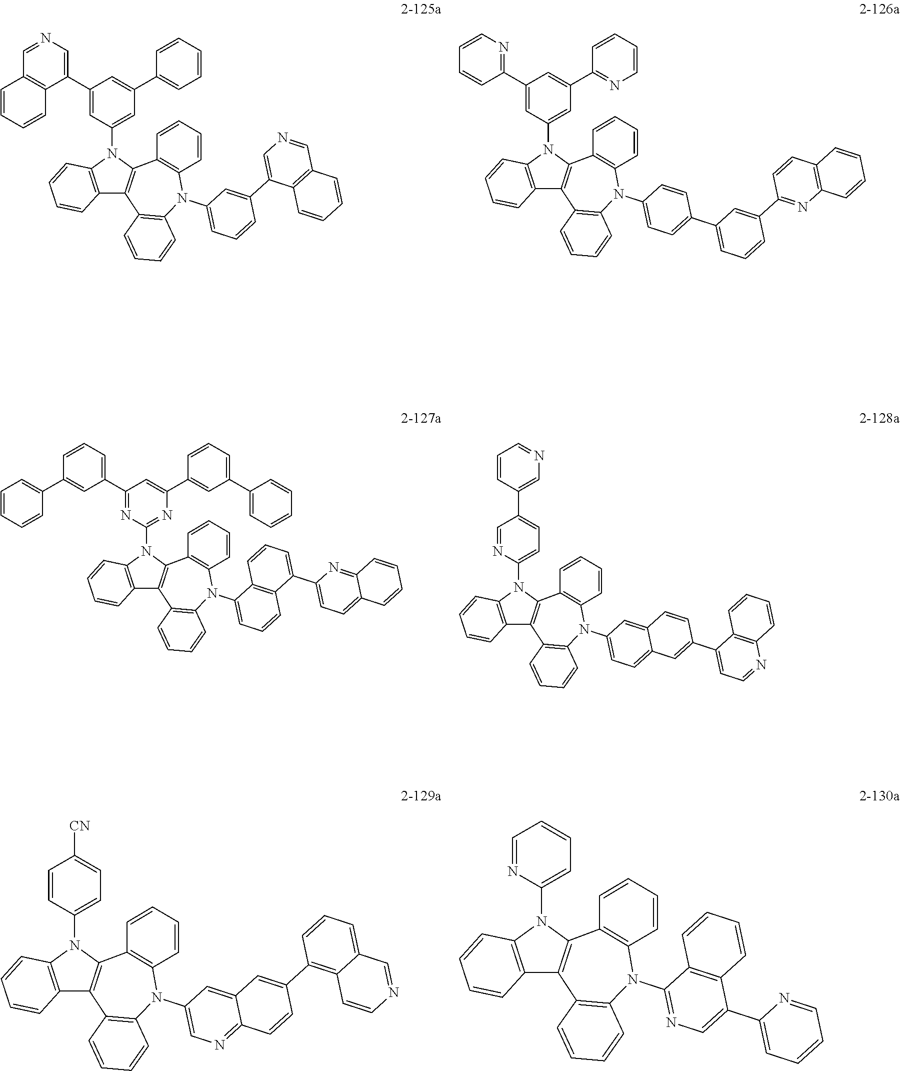

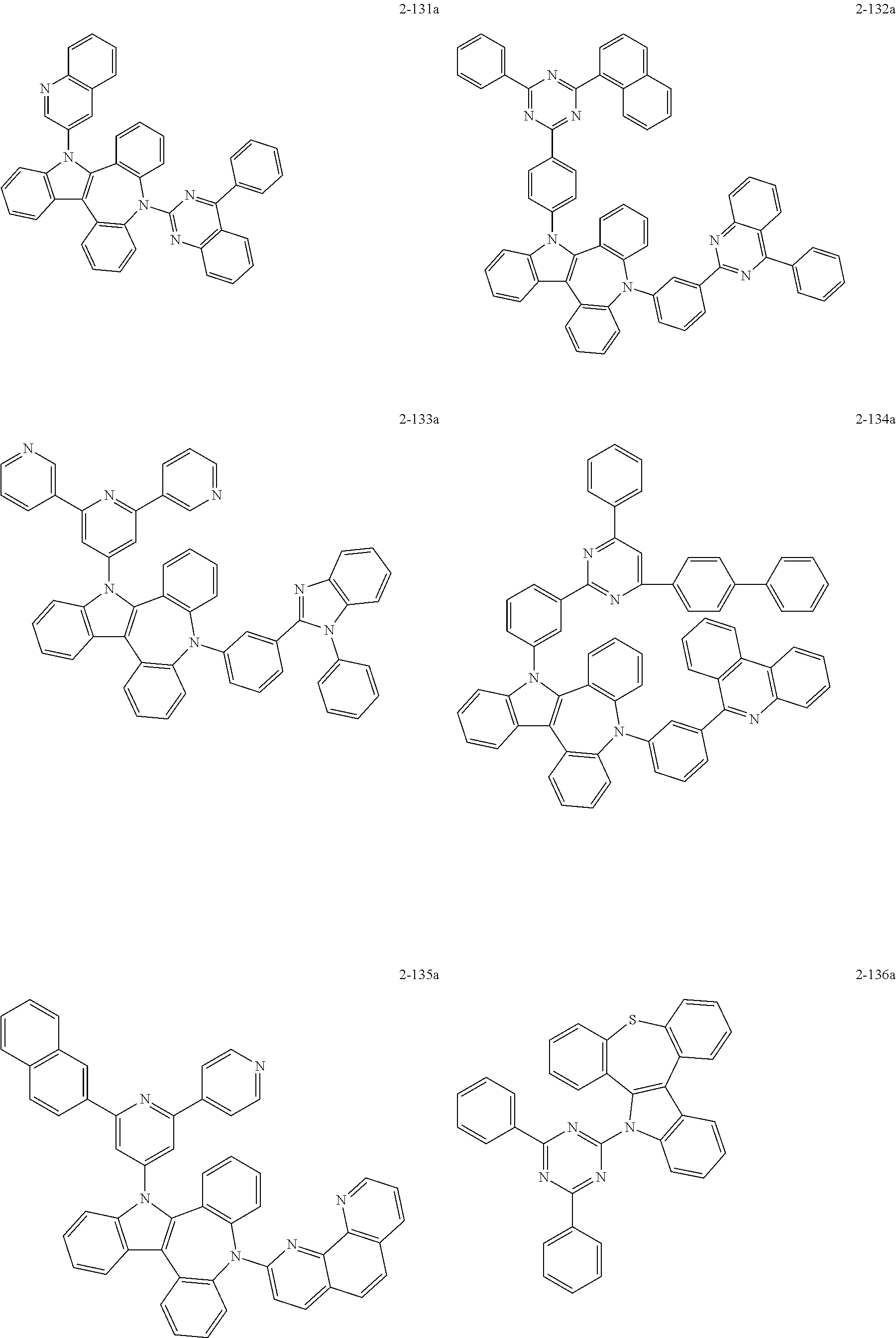

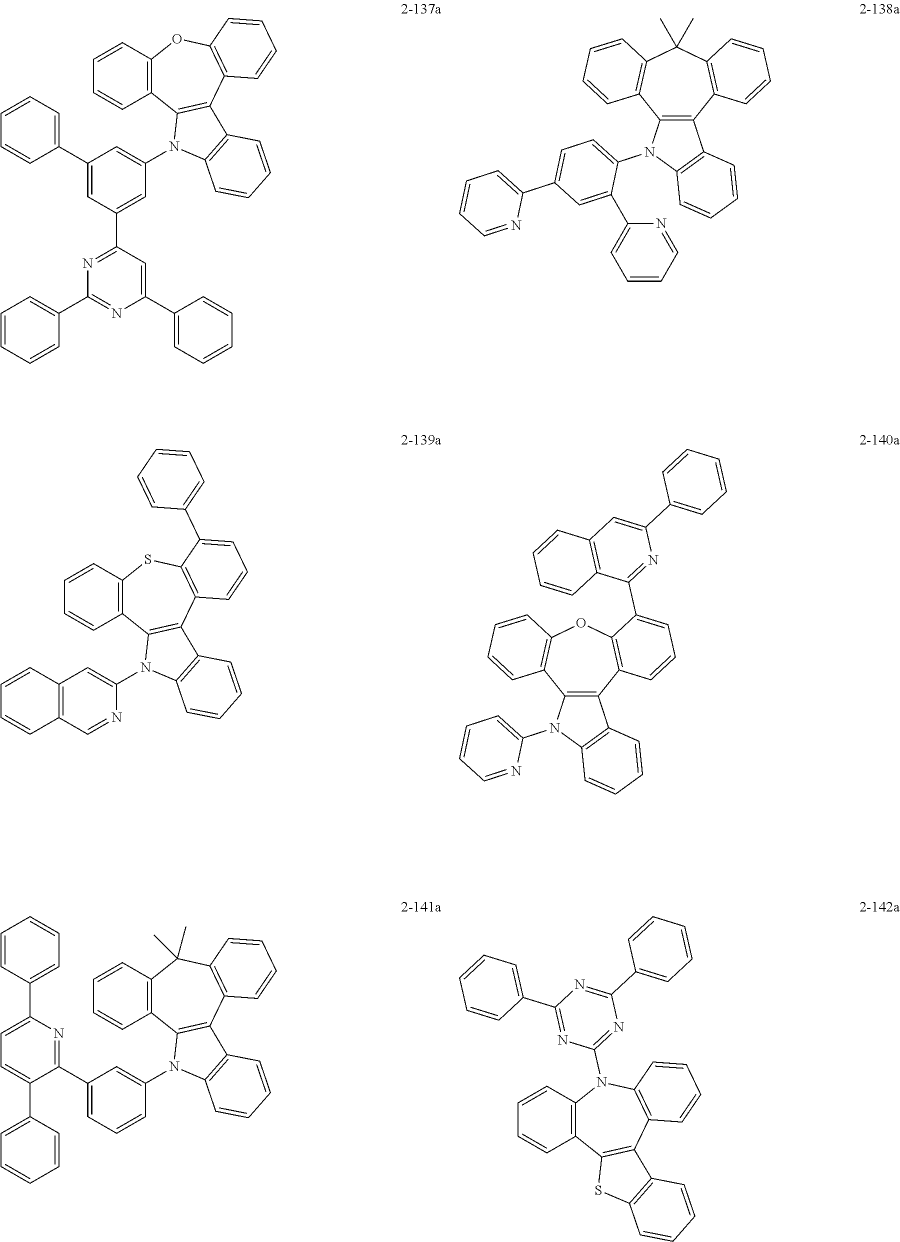 [SMILES: c1ccc(-c2cc(-c3cc(-c4ccccc4)nc(-c4ccccc4)n3)cc(-n3c4c(c5ccccc53)-c3ccccc3Oc3ccccc3-4)c2)cc1 ; CC1(C)c2ccccc2-c2c(n(-c3ccc(-c4ccccn4)cc3-c3ccccn3)c3ccccc23)-c2ccccc21 ; c1ccc(-c2cccc3c2Sc2ccccc2-c2c-3c3ccccc3n2-c2cc3ccccc3cn2)cc1 ; c1ccc(-c2cc3ccccc3c(-c3cccc4c3Oc3ccccc3-c3c-4c4ccccc4n3-c3ccccn3)n2)cc1 ; CC1(C)c2ccccc2-c2c(n(-c3cccc(-c4nc(-c5ccccc5)ccc4-c4ccccc4)c3)c3ccccc23)-c2ccccc21 ; c1ccc(-c2nc(-c3ccccc3)nc(N3c4ccccc4-c4sc5ccccc5c4-c4ccccc43)n2)cc1]

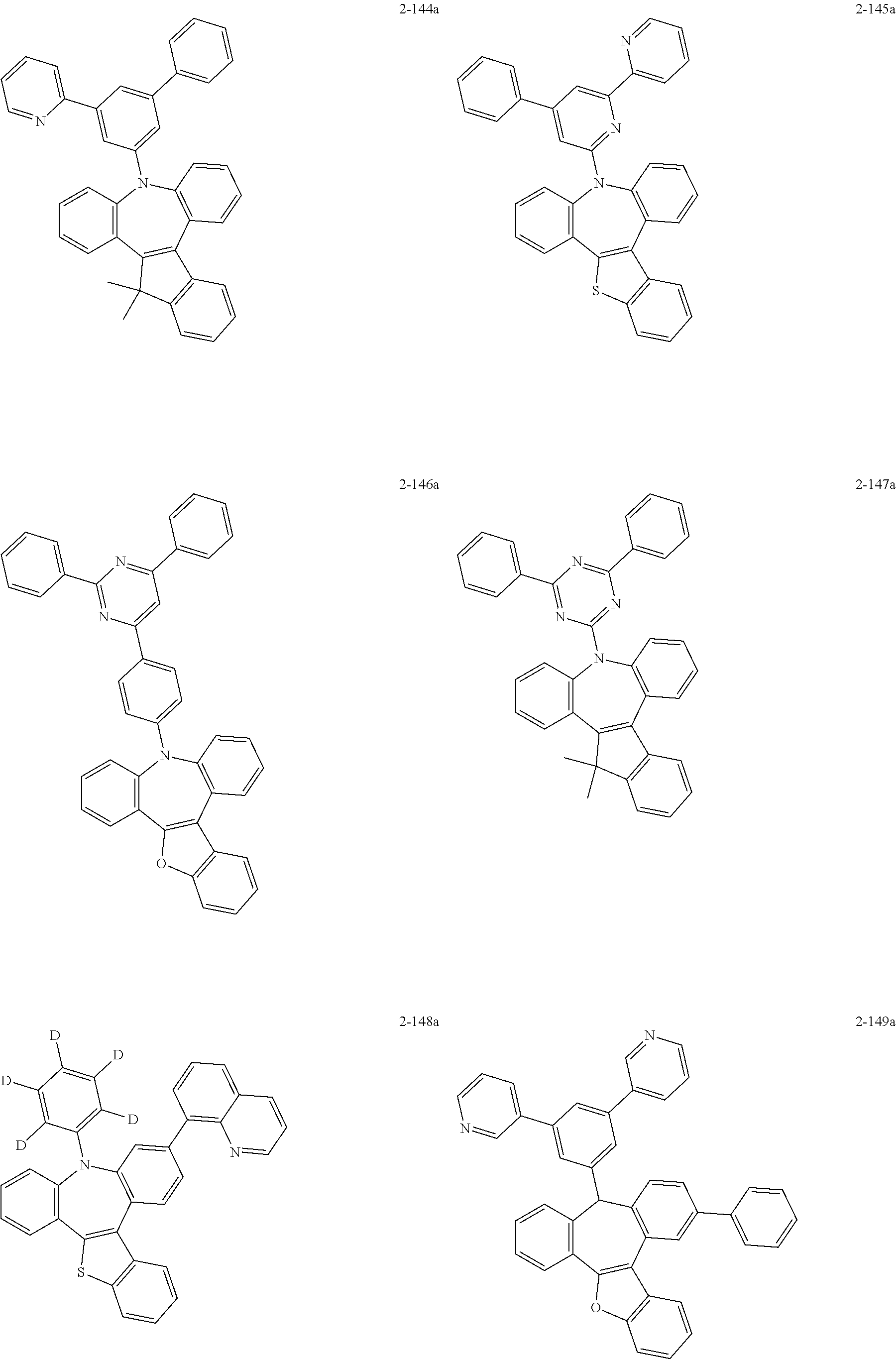 [SMILES: CC1(C)C2=C(c3ccccc3N(c3cc(-c4ccccc4)cc(-c4ccccn4)c3)c3ccccc32)c2ccccc21 ; c1ccc(-c2cc(-c3ccccn3)nc(N3c4ccccc4-c4sc5ccccc5c4-c4ccccc43)c2)cc1 ; c1ccc(-c2cc(-c3ccc(N4c5ccccc5-c5oc6ccccc6c5-c5ccccc54)cc3)nc(-c3ccccc3)n2)cc1 ; CC1(C)C2=C(c3ccccc3N(c3nc(-c4ccccc4)nc(-c4ccccc4)n3)c3ccccc32)c2ccccc21 ; [2H]c1c([2H])c([2H])c(N2c3ccccc3-c3sc4ccccc4c3-c3ccc(-c4cccc5cccnc45)cc32)c([2H])c1[2H] ; c1ccc(-c2ccc3c(c2)-c2c(oc4ccccc24)-c2ccccc2C3c2cc(-c3cccnc3)cc(-c3cccnc3)c2)cc1]

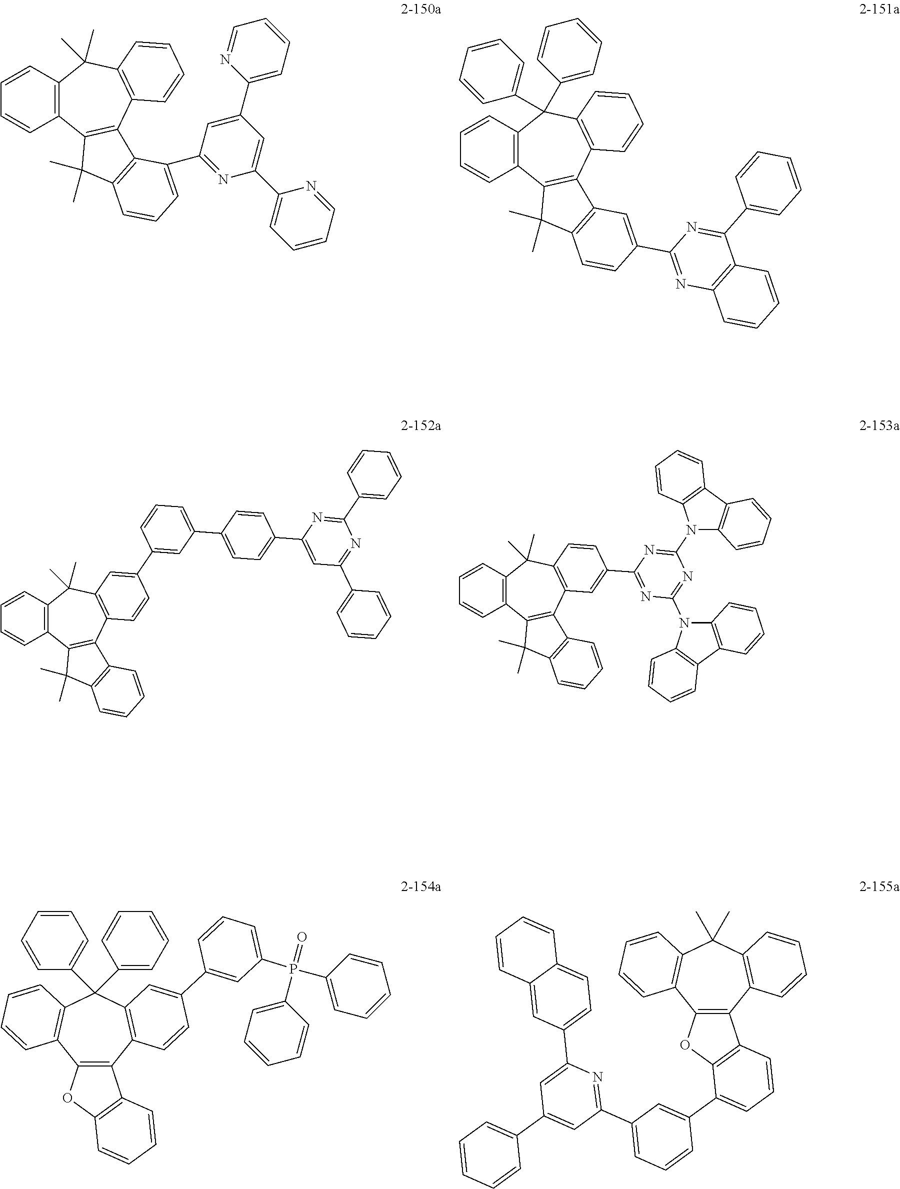

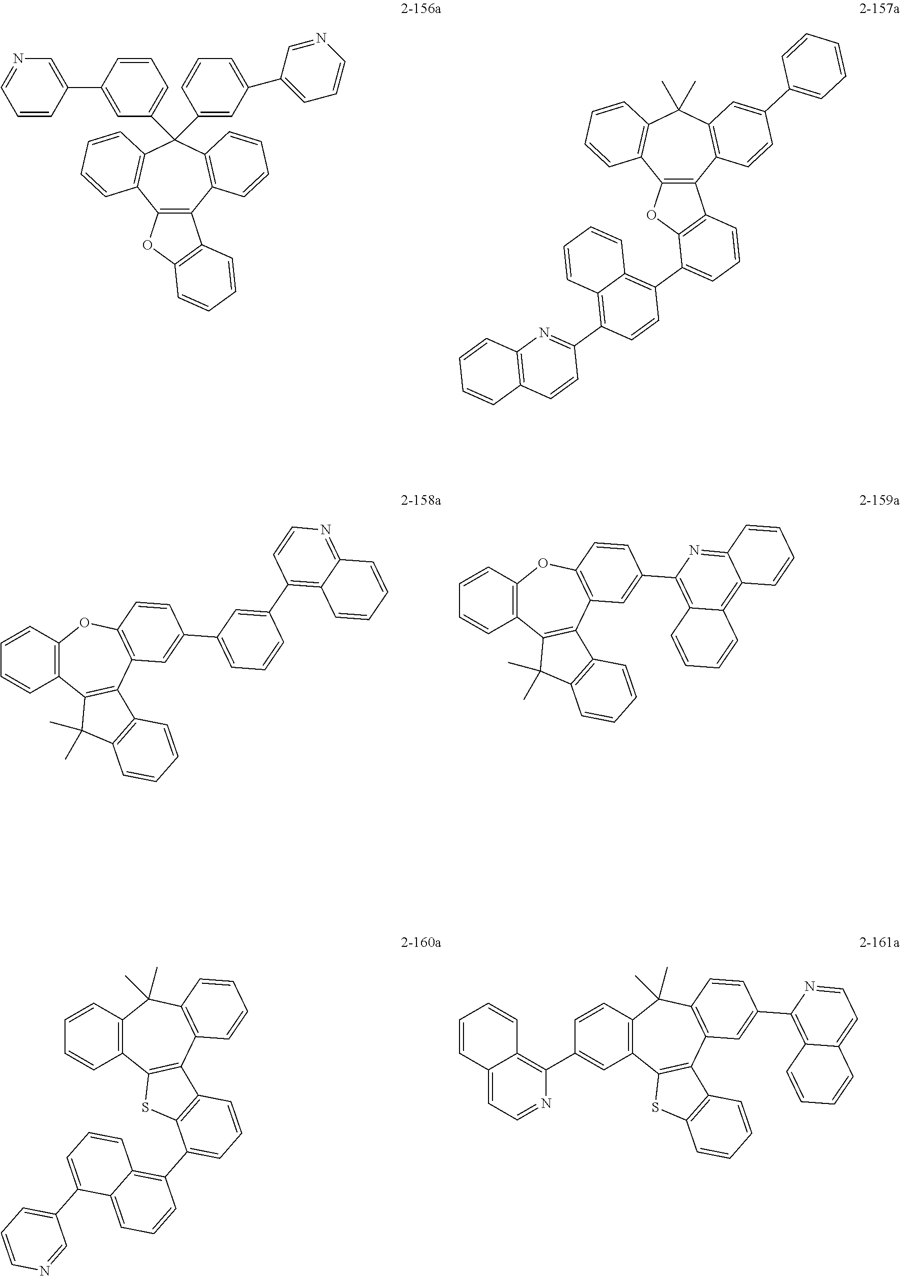 [SMILES: c1cncc(-c2cccc(C3(c4cccc(-c5cccnc5)c4)c4ccccc4-c4oc5ccccc5c4-c4ccccc43)c2)c1 ; CC1(C)c2ccccc2-c2oc3c(-c4ccc(-c5ccc6ccccc6n5)c5ccccc45)cccc3c2-c2ccc(-c3ccccc3)cc21 ; CC1(C)C2=C(c3cc(-c4cccc(-c5ccnc6ccccc56)c4)ccc3Oc3ccccc32)c2ccccc21 ; CC1(C)C2=C(c3cc(-c4nc5ccccc5c5ccccc45)ccc3Oc3ccccc32)c2ccccc21 ; CC1(C)c2ccccc2-c2sc3c(-c4cccc5c(-c6cccnc6)cccc45)cccc3c2-c2ccccc21 ; CC1(C)c2ccc(-c3nccc4ccccc34)cc2-c2sc3ccccc3c2-c2cc(-c3nccc4ccccc34)ccc21]

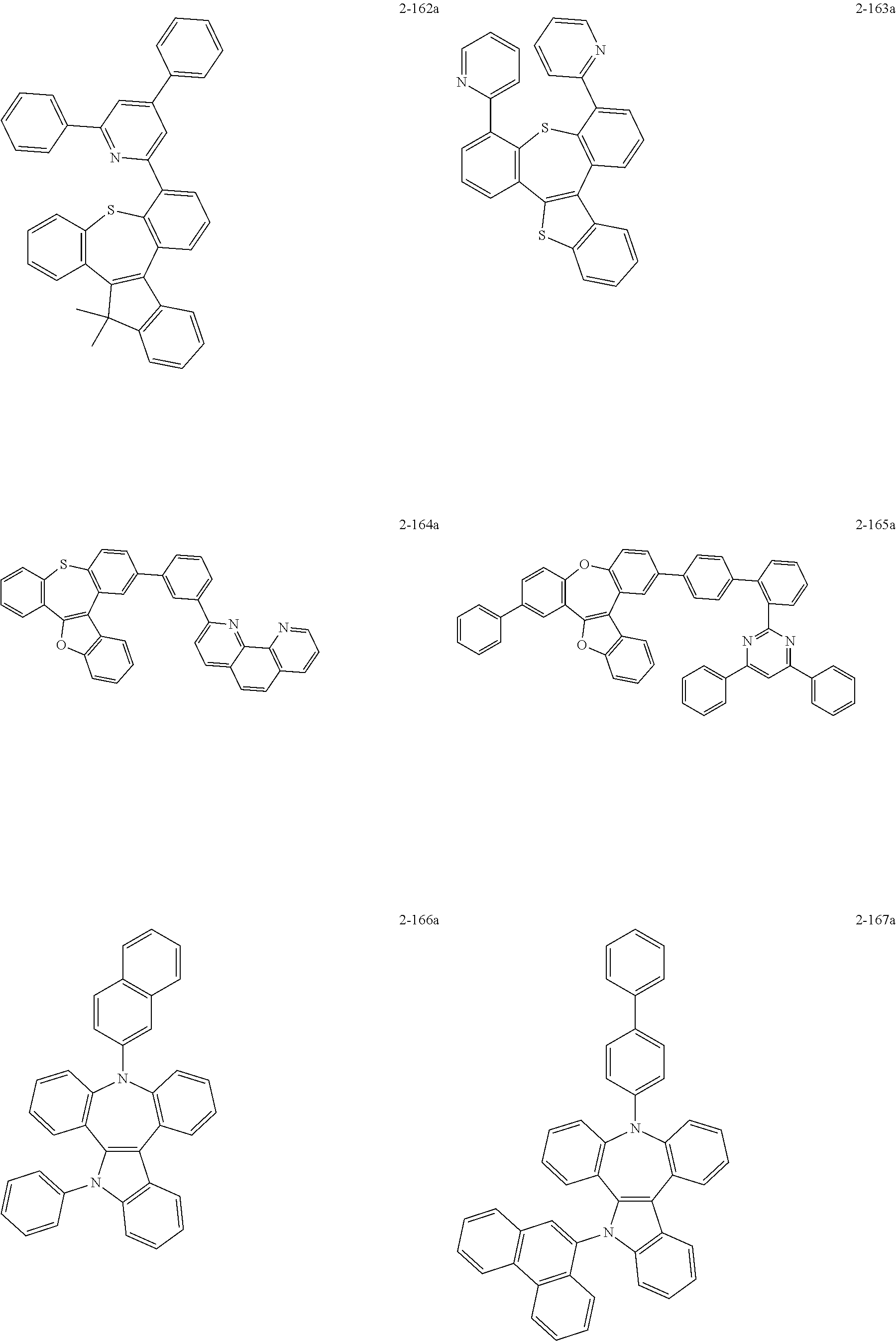 [SMILES: CC1(C)C2=C(c3ccccc31)c1cccc(-c3cc(-c4ccccc4)cc(-c4ccccc4)n3)c1Sc1ccccc12 ; c1ccc(-c2cccc3c2Sc2c(-c4ccccn4)cccc2-c2c-3sc3ccccc23)nc1 ; c1cc(-c2ccc3c(c2)-c2c(oc4ccccc24)-c2ccccc2S3)cc(-c2ccc3ccc4cccnc4c3n2)c1 ; c1ccc(-c2ccc3c(c2)-c2oc4ccccc4c2-c2cc(-c4ccc(-c5ccccc5-c5nc(-c6ccccc6)cc(-c6ccccc6)n5)cc4)ccc2O3)cc1 ; c1ccc(-n2c3c(c4ccccc42)-c2ccccc2N(c2ccc4ccccc4c2)c2ccccc2-3)cc1 ; c1ccc(-c2ccc(N3c4ccccc4-c4c(n(-c5cc6ccccc6c6ccccc56)c5ccccc45)-c4ccccc43)cc2)cc1]

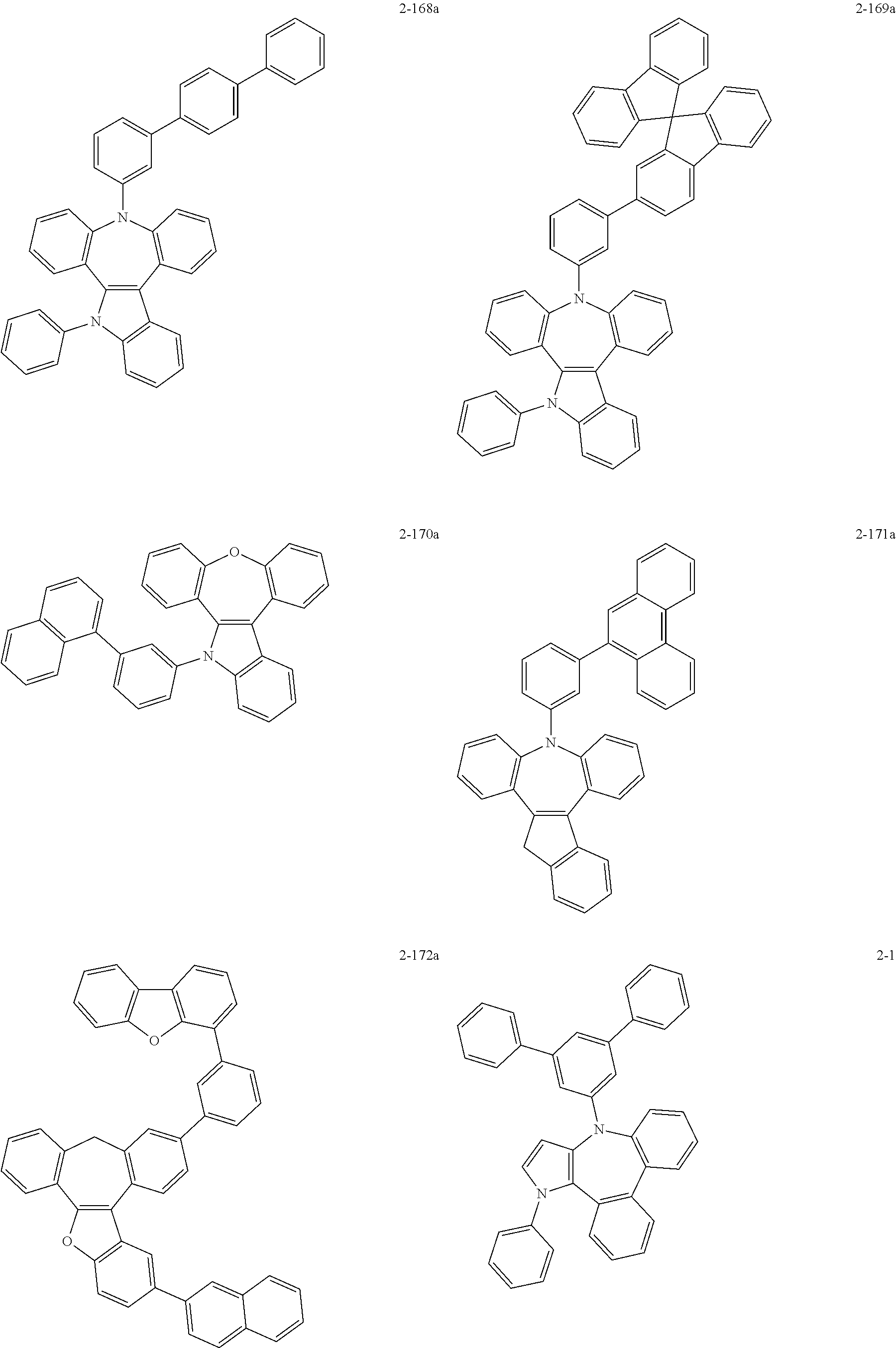 [SMILES: c1ccc(-c2ccc(-c3cccc(N4c5ccccc5-c5c(n(-c6ccccc6)c6ccccc56)-c5ccccc54)c3)cc2)cc1 ; c1ccc(-n2c3c(c4ccccc42)-c2ccccc2N(c2cccc(-c4ccc5c(c4)C4(c6ccccc6-c6ccccc64)c4ccccc4-5)c2)c2ccccc2-3)cc1 ; c1cc(-c2cccc3ccccc23)cc(-n2c3c(c4ccccc42)-c2ccccc2Oc2ccccc2-3)c1 ; c1cc(-c2cc3ccccc3c3ccccc23)cc(N2c3ccccc3C3=C(c4ccccc4C3)c3ccccc32)c1 ; c1cc(-c2ccc3c(c2)Cc2ccccc2-c2oc4ccc(-c5ccc6ccccc6c5)cc4c2-3)cc(-c2cccc3c2oc2ccccc23)c1 ; c1ccc(-c2cc(-c3ccccc3)cc(N3c4ccccc4-c4ccccc4-c4c3ccn4-c3ccccc3)c2)cc1]

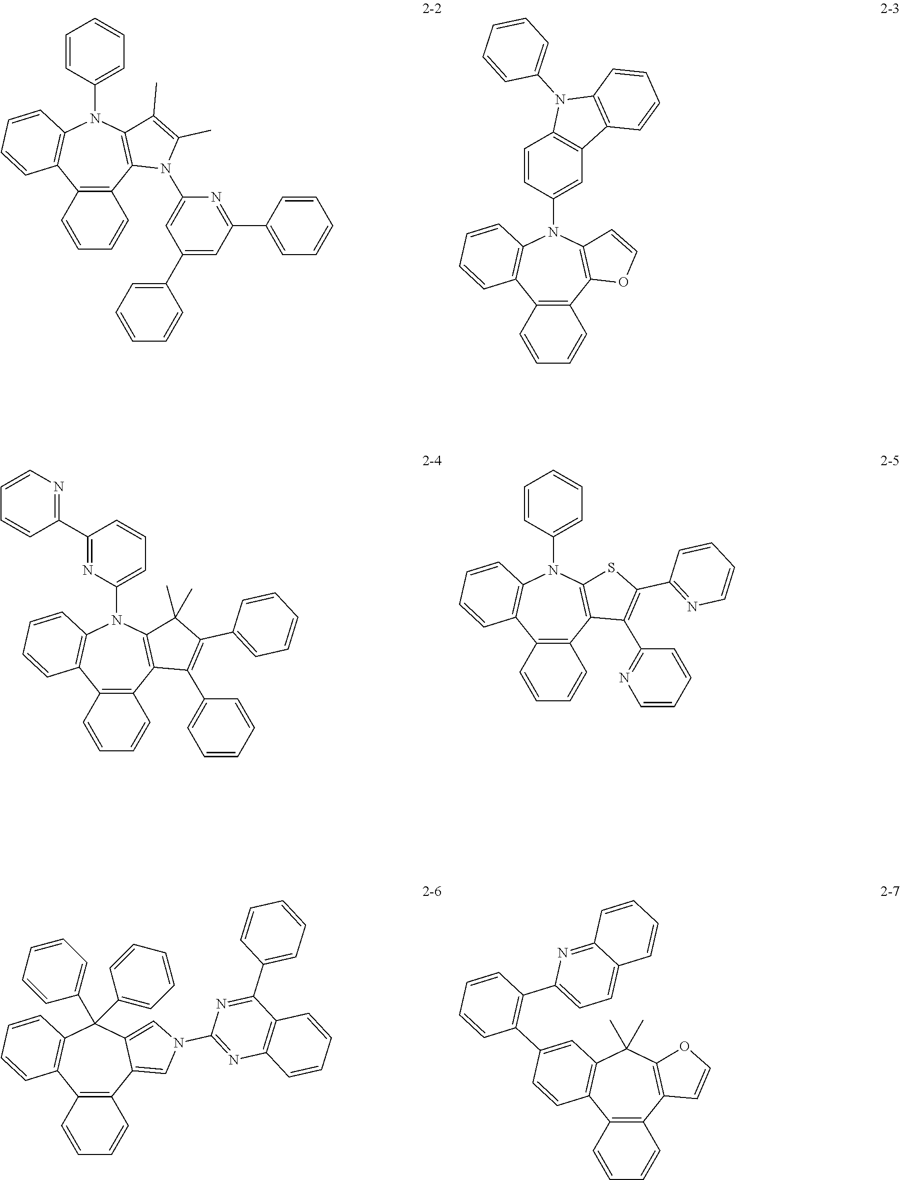 [SMILES: Cc1c2c(n(-c3cc(-c4ccccc4)cc(-c4ccccc4)n3)c1C)-c1ccccc1-c1ccccc1N2c1ccccc1 ; c1ccc(-n2c3ccccc3c3cc(N4c5ccccc5-c5ccccc5-c5occc54)ccc32)cc1 ; CC1(C)C(c2ccccc2)=C(c2ccccc2)C2=C1N(c1cccc(-c3ccccn3)n1)c1ccccc1-c1ccccc12 ; c1ccc(N2c3ccccc3-c3ccccc3-c3c2sc(-c2ccccn2)c3-c2ccccn2)cc1 ; c1ccc(-c2nc(-n3cc4c(c3)C(c3ccccc3)(c3ccccc3)c3ccccc3-c3ccccc3-4)nc3ccccc23)cc1 ; CC1(C)c2cc(-c3ccccc3-c3ccc4ccccc4n3)ccc2-c2ccccc2-c2ccoc21]

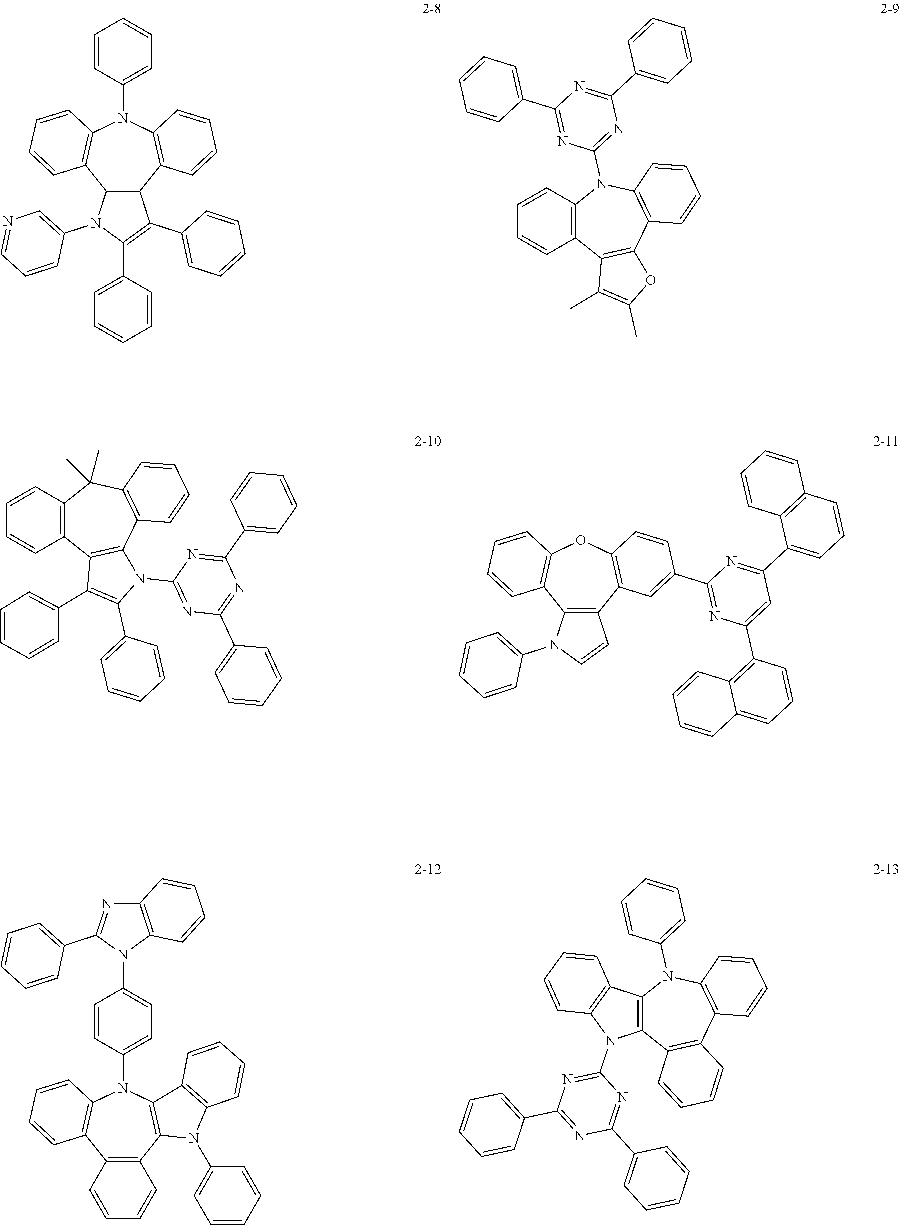 [SMILES: c1ccc(C2=C(c3ccccc3)N(c3cccnc3)C3c4ccccc4N(c4ccccc4)c4ccccc4C23)cc1 ; Cc1oc2c(c1C)-c1ccccc1N(c1nc(-c3ccccc3)nc(-c3ccccc3)n1)c1ccccc1-2 ; CC1(C)c2ccccc2-c2c(-c3ccccc3)c(-c3ccccc3)n(-c3nc(-c4ccccc4)nc(-c4ccccc4)n3)c2-c2ccccc21 ; c1ccc(-n2ccc3c2-c2ccccc2Oc2ccc(-c4nc(-c5cccc6ccccc56)cc(-c5cccc6ccccc56)n4)cc2-3)cc1 ; c1ccc(-c2nc3ccccc3n2-c2ccc(N3c4ccccc4-c4ccccc4-c4c3c3ccccc3n4-c3ccccc3)cc2)cc1 ; c1ccc(-c2nc(-c3ccccc3)nc(-n3c4c(c5ccccc53)N(c3ccccc3)c3ccccc3-c3ccccc3-4)n2)cc1]

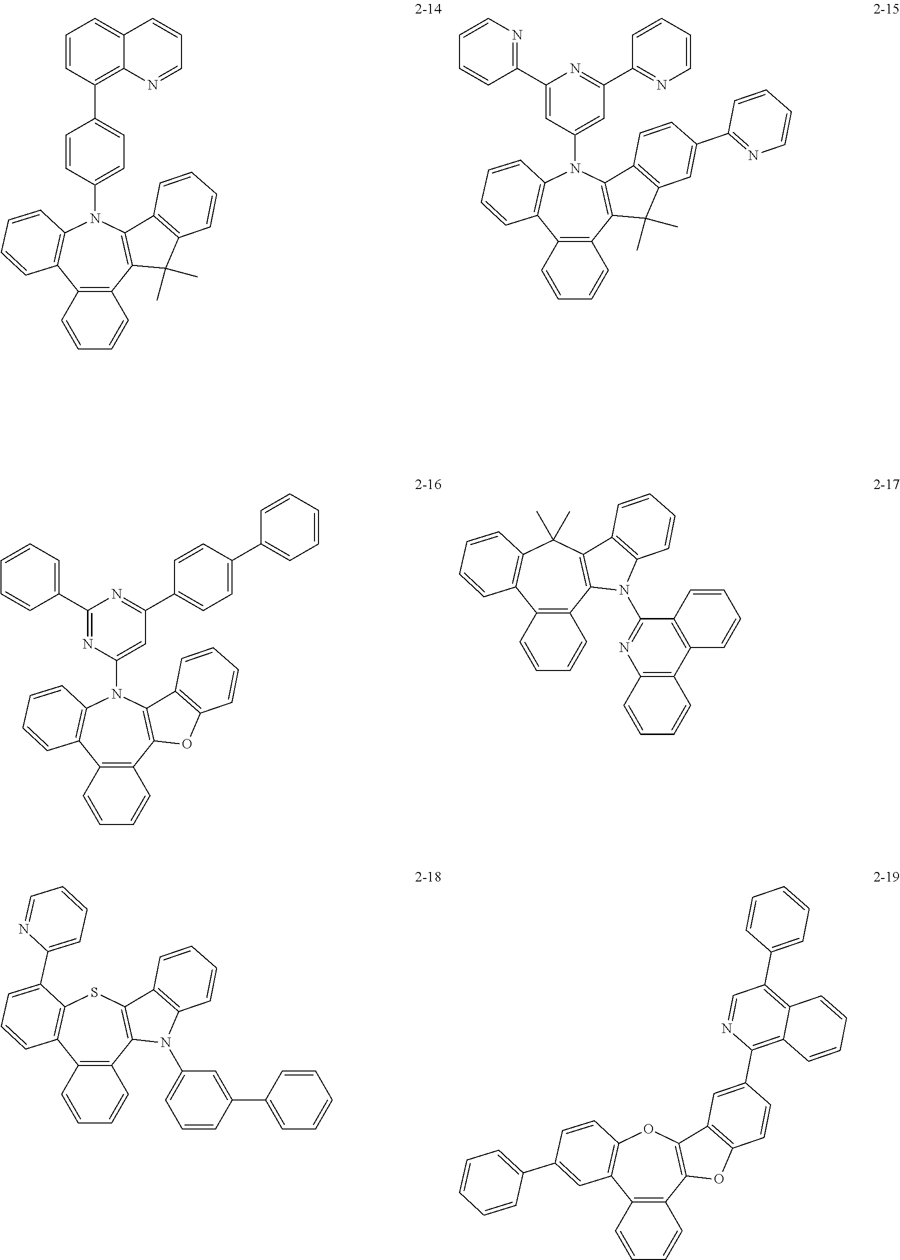 [SMILES: CC1(C)C2=C(c3ccccc31)N(c1ccc(-c3cccc4cccnc34)cc1)c1ccccc1-c1ccccc12 ; CC1(C)C2=C(c3ccc(-c4ccccn4)cc31)N(c1cc(-c3ccccn3)nc(-c3ccccn3)c1)c1ccccc1-c1ccccc12 ; c1ccc(-c2ccc(-c3cc(N4c5ccccc5-c5ccccc5-c5oc6ccccc6c54)nc(-c4ccccc4)n3)cc2)cc1 ; CC1(C)c2ccccc2-c2ccccc2-c2c1c1ccccc1n2-c1nc2ccccc2c2ccccc12 ; c1ccc(-c2cccc(-n3c4c(c5ccccc53)Sc3c(-c5ccccn5)cccc3-c3ccccc3-4)c2)cc1 ; c1ccc(-c2ccc3c(c2)-c2ccccc2-c2oc4ccc(-c5ncc(-c6ccccc6)c6ccccc56)cc4c2O3)cc1]

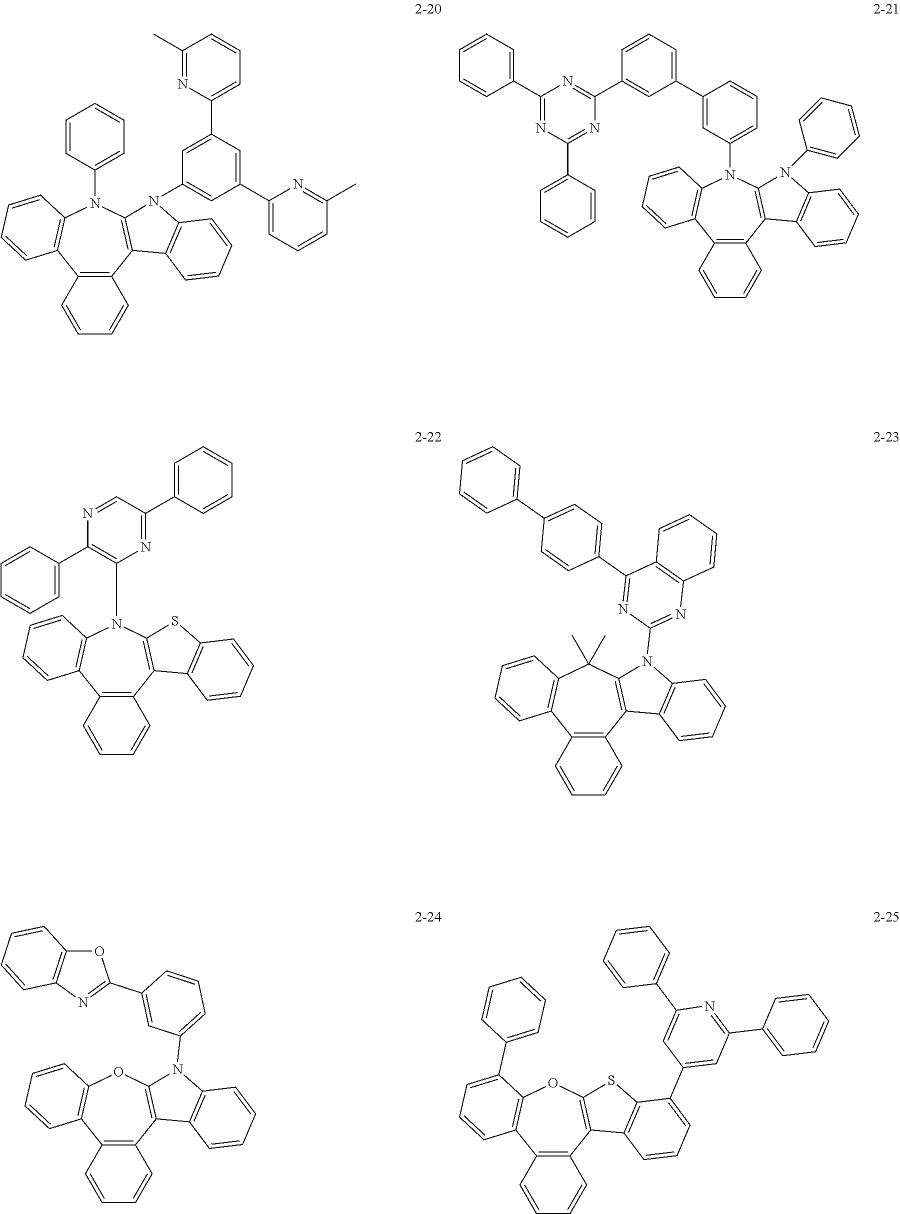

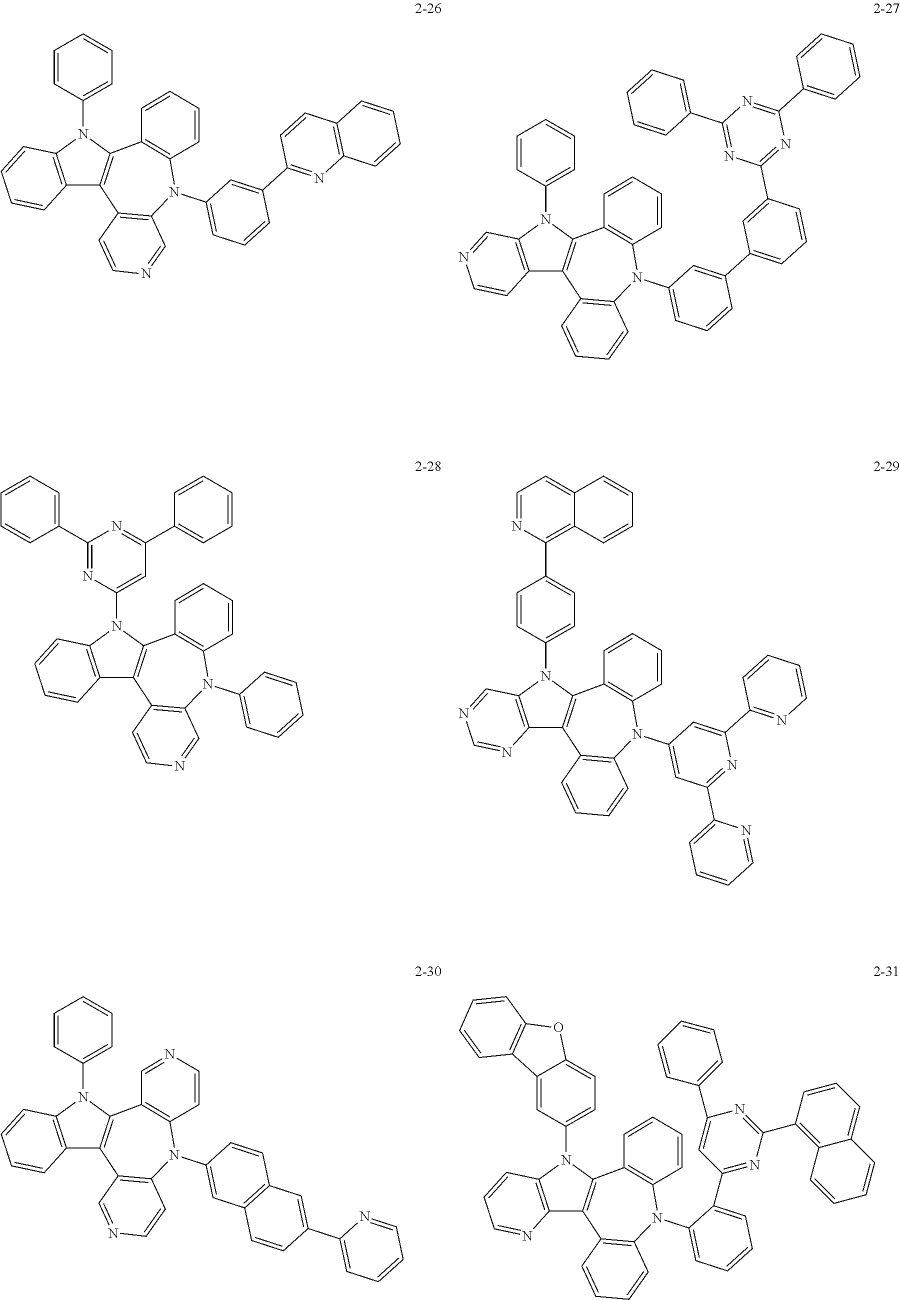

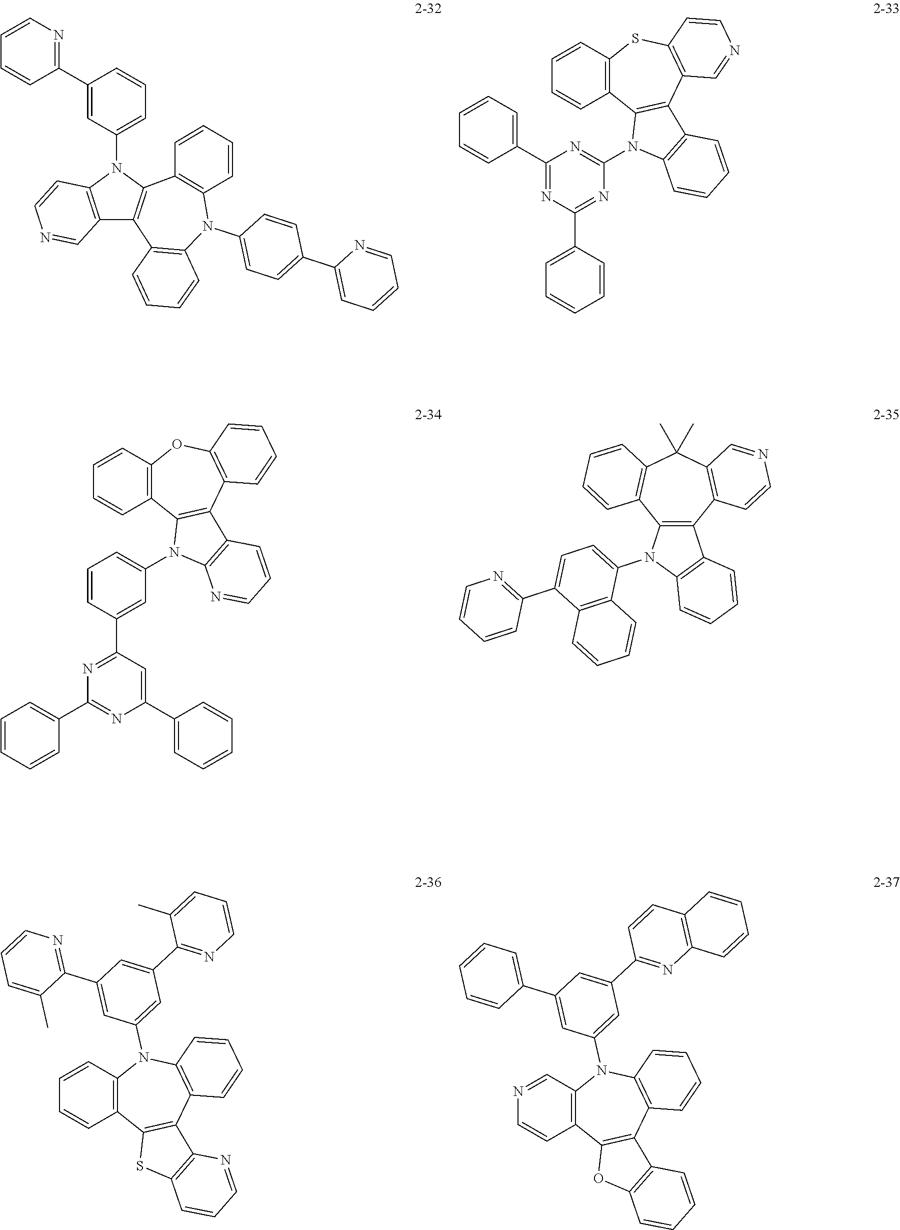 [SMILES: c1ccc(-c2ccc(N3c4ccccc4-c4c(n(-c5cccc(-c6ccccn6)c5)c5ccncc45)-c4ccccc43)cc2)nc1 ; c1ccc(-c2nc(-c3ccccc3)nc(-n3c4c(c5ccccc53)-c3cnccc3Sc3ccccc3-4)n2)cc1 ; c1ccc(-c2cc(-c3cccc(-n4c5c(c6cccnc64)-c4ccccc4Oc4ccccc4-5)c3)nc(-c3ccccc3)n2)cc1 ; CC1(C)c2cnccc2-c2c(n(-c3ccc(-c4ccccn4)c4ccccc34)c3ccccc23)-c2ccccc21 ; Cc1cccnc1-c1cc(-c2ncccc2C)cc(N2c3ccccc3-c3sc4cccnc4c3-c3ccccc32)c1 ; c1ccc(-c2cc(-c3ccc4ccccc4n3)cc(N3c4cnccc4-c4oc5ccccc5c4-c4ccccc43)c2)cc1]

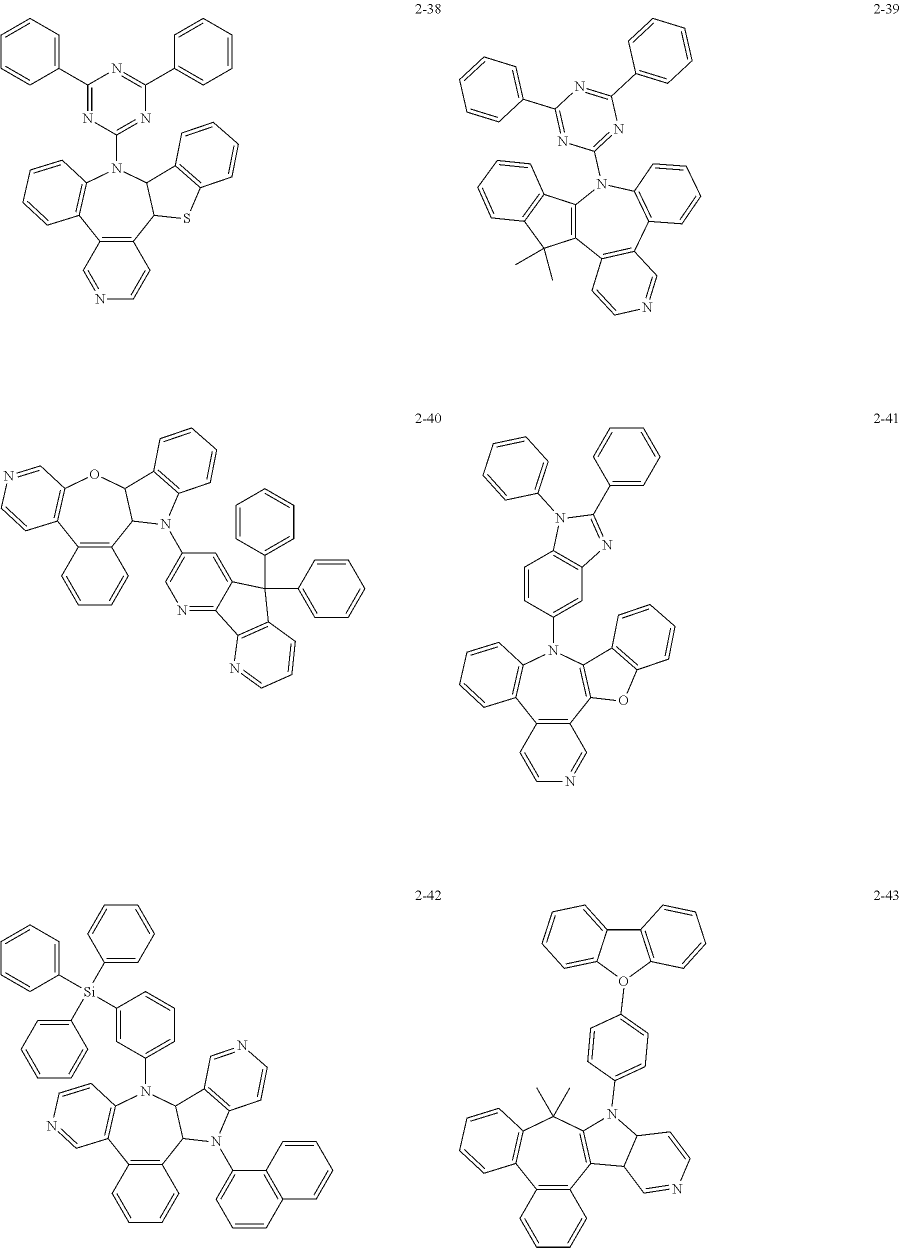

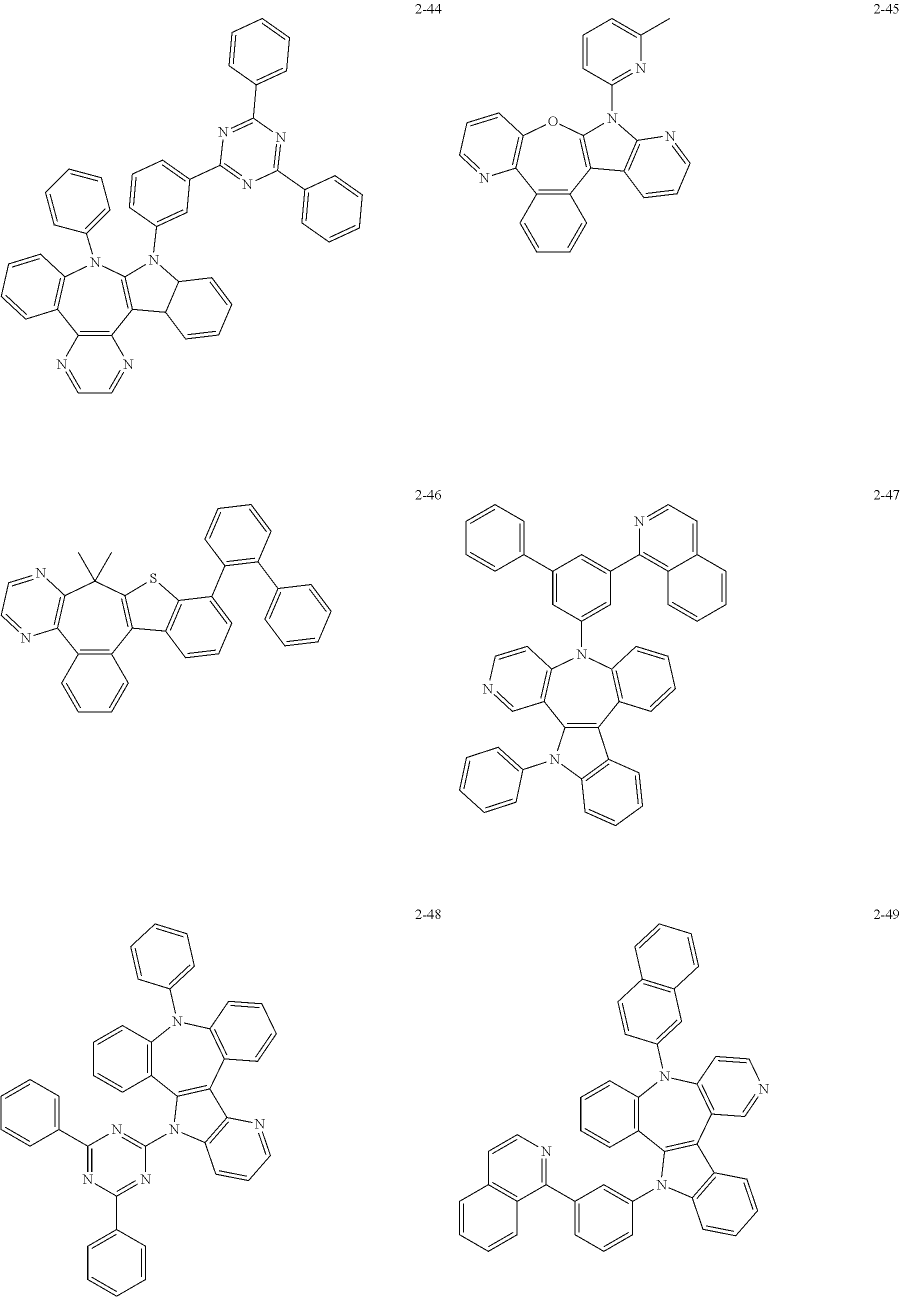 [SMILES: C1=CC2C3=C(N(c4ccccc4)c4ccccc4-c4nccnc43)N(c3cccc(-c4nc(-c5ccccc5)nc(-c5ccccc5)n4)c3)C2C=C1 ; Cc1cccc(-n2c3c(c4cccnc42)-c2ccccc2-c2ncccc2O3)n1 ; CC1(C)c2nccnc2-c2ccccc2-c2c1sc1c(-c3ccccc3-c3ccccc3)cccc21 ; c1ccc(-c2cc(-c3nccc4ccccc34)cc(N3c4ccccc4-c4c(n(-c5ccccc5)c5ccccc45)-c4cnccc43)c2)cc1 ; c1ccc(-c2nc(-c3ccccc3)nc(-n3c4c(c5ncccc53)-c3ccccc3N(c3ccccc3)c3ccccc3-4)n2)cc1 ; c1cc(-c2nccc3ccccc23)cc(-n2c3c(c4ccccc42)-c2cnccc2N(c2ccc4ccccc4c2)c2ccccc2-3)c1]

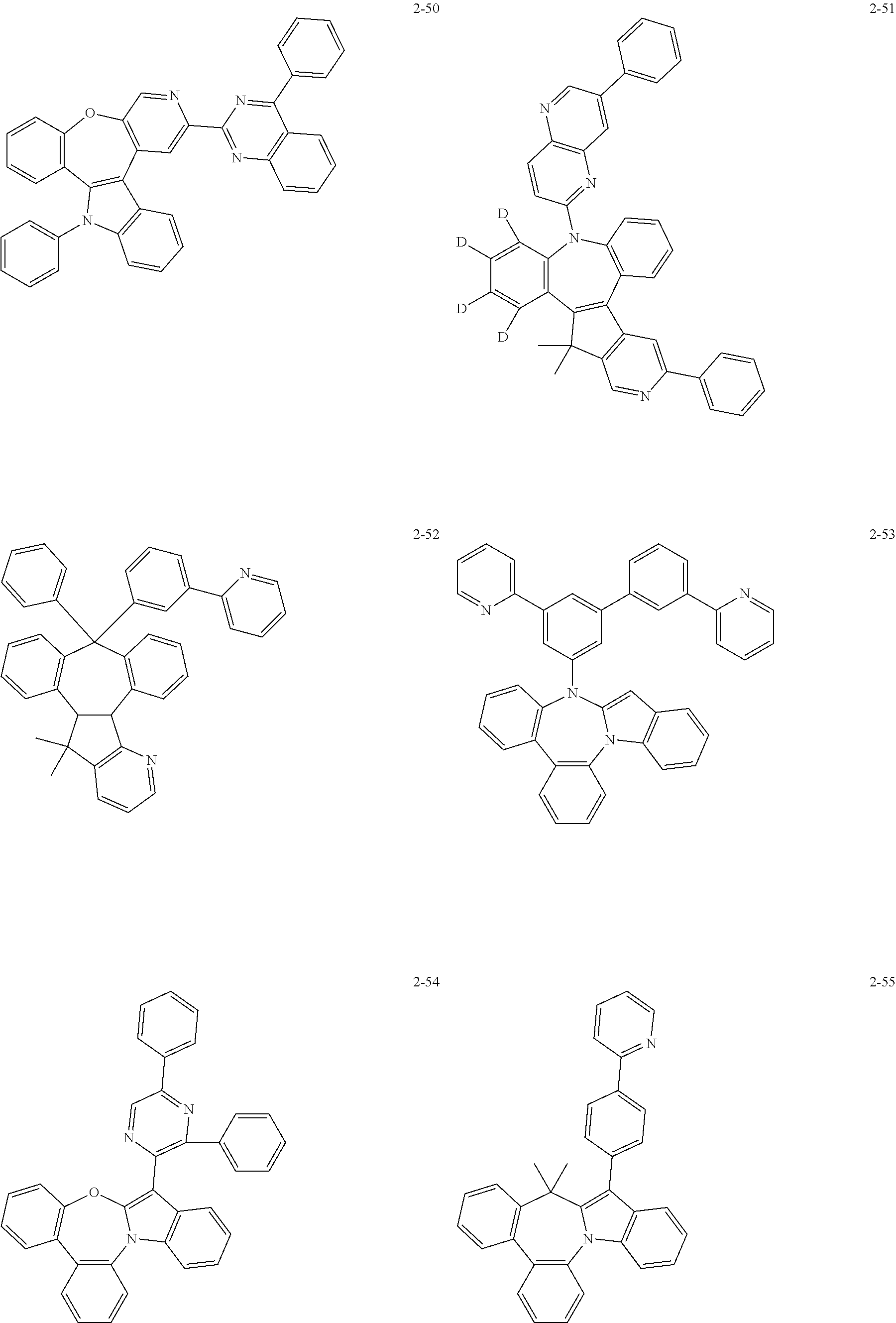 [SMILES: c1ccc(-c2nc(-c3cc4c(cn3)Oc3ccccc3-c3c-4c4ccccc4n3-c3ccccc3)nc3ccccc23)cc1 ; [2H]c1c([2H])c([2H])c2c(c1[2H])C1=C(c3ccccc3N2c2ccc3ncc(-c4ccccc4)cc3n2)c2cc(-c3ccccc3)ncc2C1(C)C ; CC1(C)c2cccnc2C2c3ccccc3C(c3ccccc3)(c3cccc(-c4ccccn4)c3)c3ccccc3C21 ; c1ccc(-c2cccc(-c3cc(-c4ccccn4)cc(N4c5ccccc5-c5ccccc5-n5c4cc4ccccc45)c3)c2)nc1 ; c1ccc(-c2cnc(-c3c4n(c5ccccc35)-c3ccccc3-c3ccccc3O4)c(-c3ccccc3)n2)cc1 ; CC1(C)c2ccccc2-c2ccccc2-n2c1c(-c1ccc(-c3ccccn3)cc1)c1ccccc12]

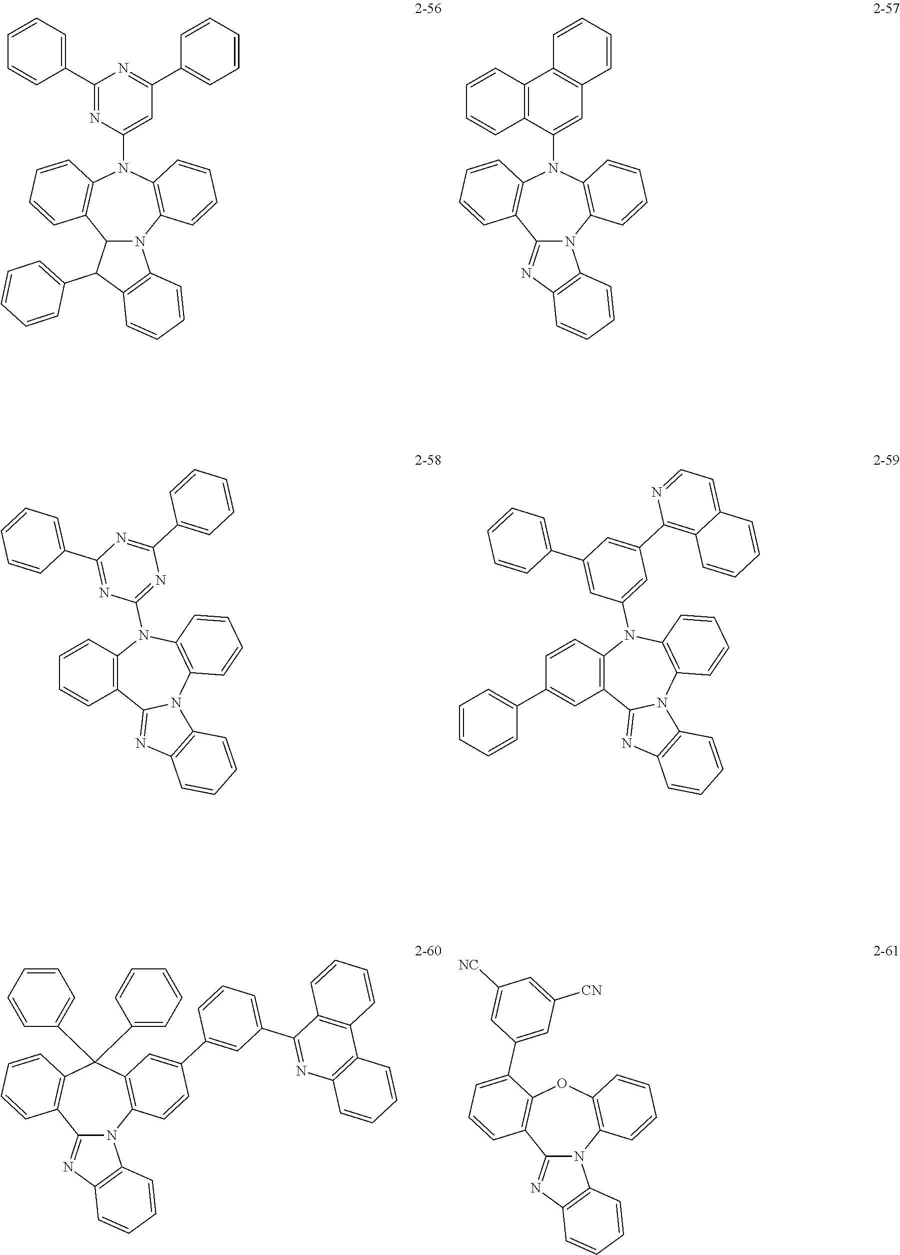 [SMILES: c1ccc(-c2cc(N3c4ccccc4C4C(c5ccccc5)c5ccccc5N4c4ccccc43)nc(-c3ccccc3)n2)cc1 ; c1ccc2c(c1)-c1nc3ccccc3n1-c1ccccc1N2c1cc2ccccc2c2ccccc12 ; c1ccc(-c2nc(-c3ccccc3)nc(N3c4ccccc4-c4nc5ccccc5n4-c4ccccc43)n2)cc1 ; c1ccc(-c2cc(-c3nccc4ccccc34)cc(N3c4ccc(-c5ccccc5)cc4-c4nc5ccccc5n4-c4ccccc43)c2)cc1 ; c1ccc(C2(c3ccccc3)c3ccccc3-c3nc4ccccc4n3-c3ccc(-c4cccc(-c5nc6ccccc6c6ccccc56)c4)cc32)cc1 ; N#Cc1cc(C#N)cc(-c2cccc3c2Oc2ccccc2-n2c-3nc3ccccc32)c1]

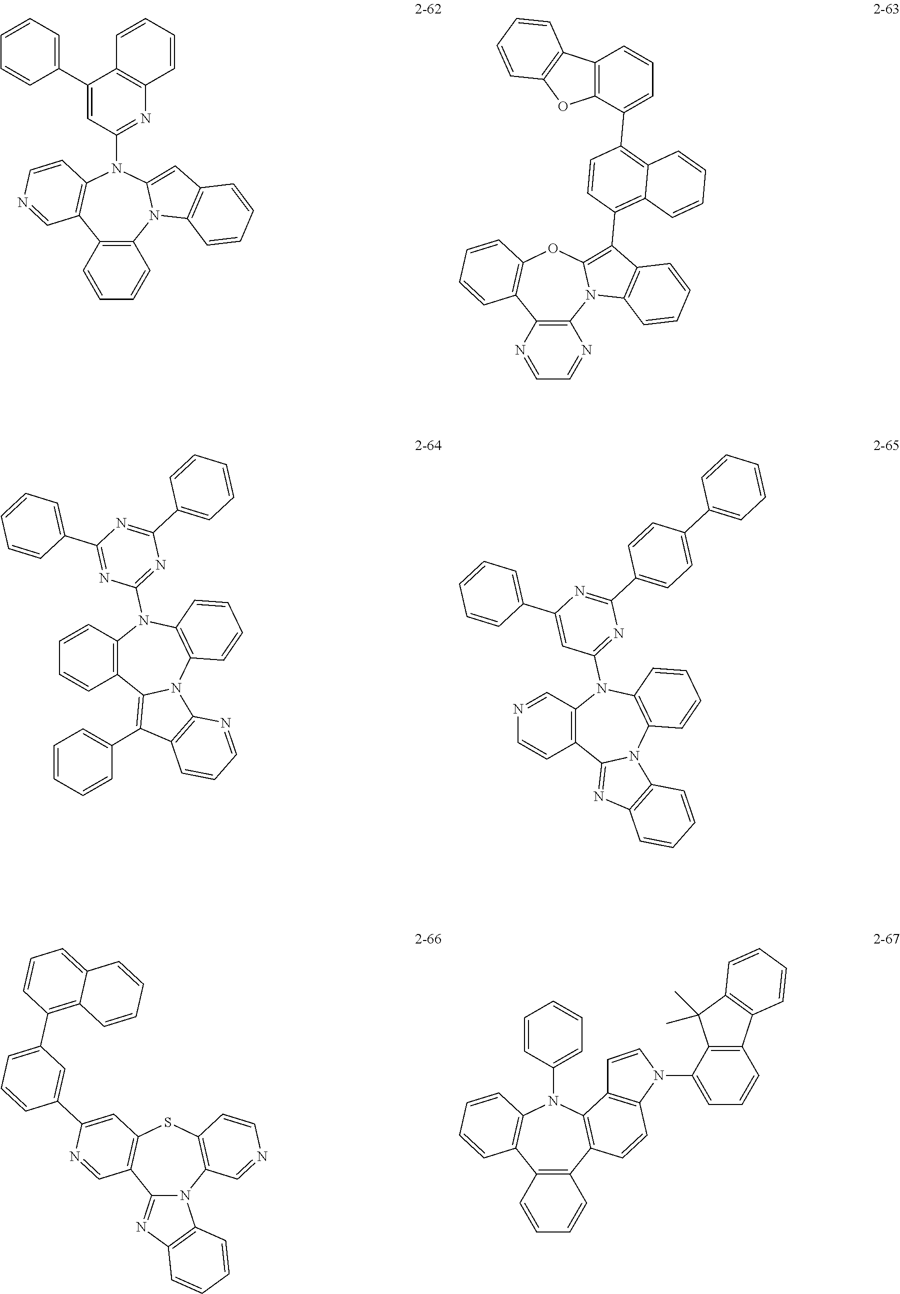 [SMILES: c1ccc(-c2cc(N3c4ccncc4-c4ccccc4-n4c3cc3ccccc34)nc3ccccc23)cc1 ; c1ccc2c(c1)Oc1c(-c3ccc(-c4cccc5c4oc4ccccc45)c4ccccc34)c3ccccc3n1-c1nccnc1-2 ; c1ccc(-c2nc(-c3ccccc3)nc(N3c4ccccc4-c4c(-c5ccccc5)c5cccnc5n4-c4ccccc43)n2)cc1 ; c1ccc(-c2ccc(-c3nc(-c4ccccc4)cc(N4c5cnccc5-c5nc6ccccc6n5-c5ccccc54)n3)cc2)cc1 ; c1cc(-c2cc3c(cn2)-c2nc4ccccc4n2-c2cnccc2S3)cc(-c2cccc3ccccc23)c1 ; CC1(C)c2ccccc2-c2cccc(-n3ccc4c5c(ccc43)-c3ccccc3-c3ccccc3N5c3ccccc3)c21]

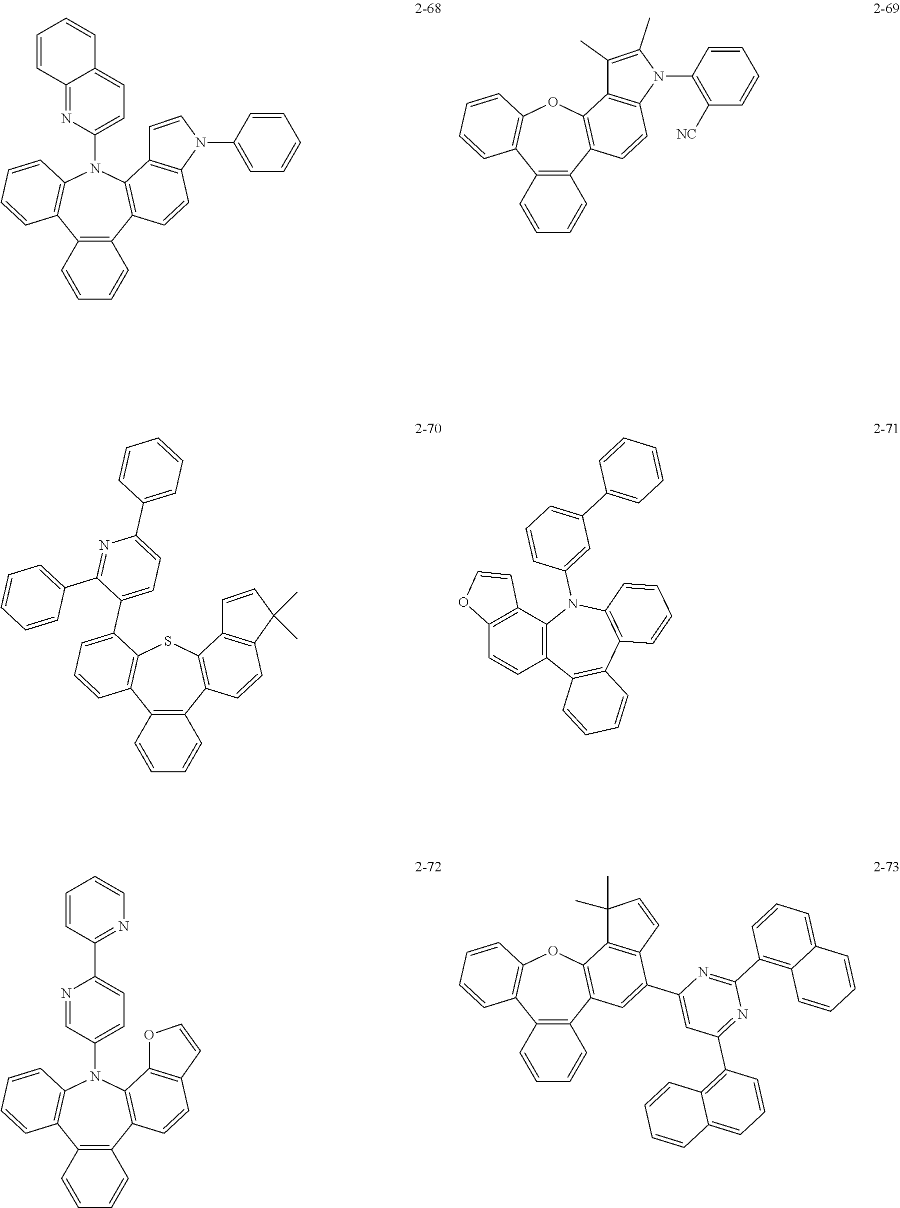 [SMILES: c1ccc(-n2ccc3c4c(ccc32)-c2ccccc2-c2ccccc2N4c2ccc3ccccc3n2)cc1 ; Cc1c(C)n(-c2ccccc2C#N)c2ccc3c(c12)Oc1ccccc1-c1ccccc1-3 ; CC1(C)C=Cc2c1ccc1c2Sc2c(cccc2-c2ccc(-c3ccccc3)nc2-c2ccccc2)-c2ccccc2-1 ; c1ccc(-c2cccc(N3c4ccccc4-c4ccccc4-c4ccc5occc5c43)c2)cc1 ; c1ccc(-c2ccc(N3c4ccccc4-c4ccccc4-c4ccc5ccoc5c43)cn2)nc1 ; CC1(C)C=Cc2c(-c3cc(-c4cccc5ccccc45)nc(-c4cccc5ccccc45)n3)cc3c(c21)Oc1ccccc1-c1ccccc1-3]

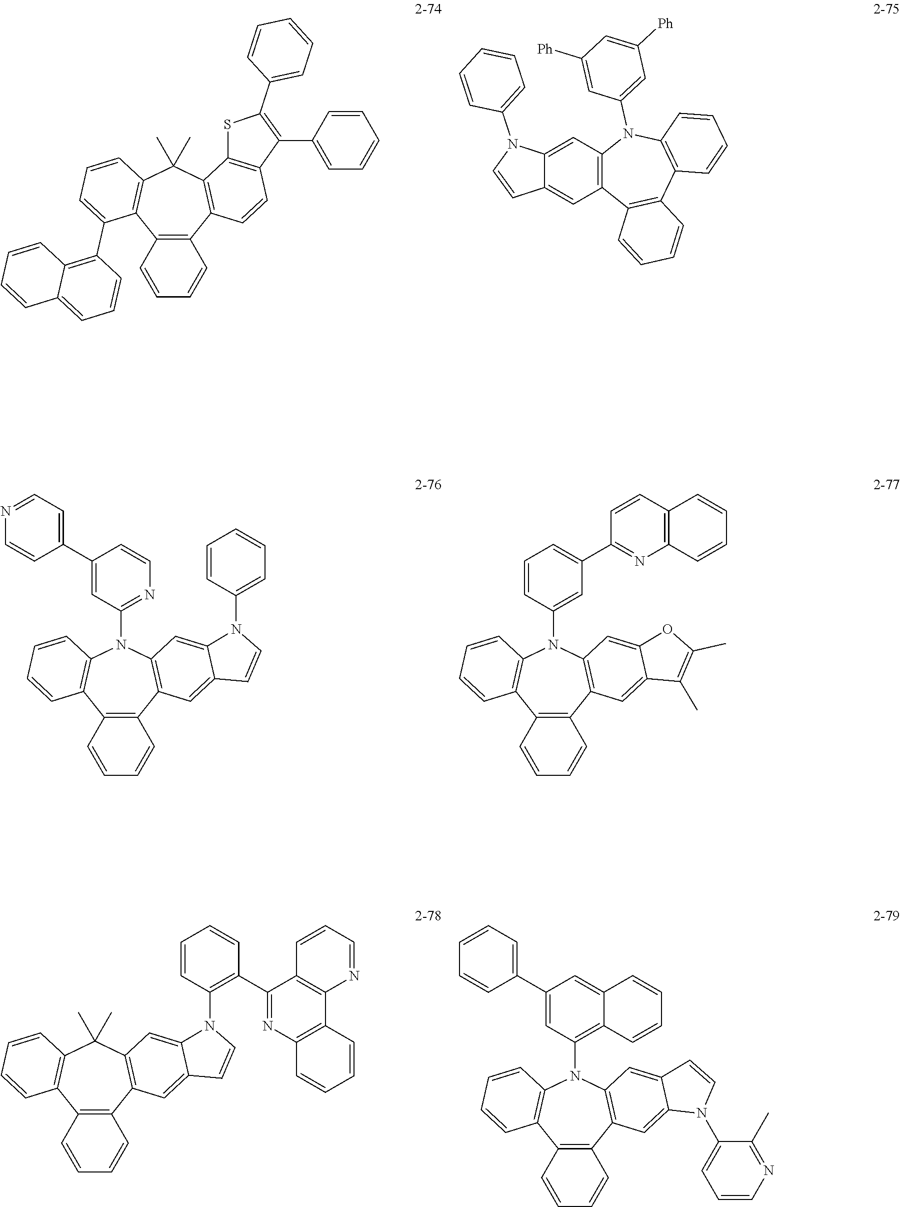 [SMILES: CC1(C)c2cccc(-c3cccc4ccccc34)c2-c2ccccc2-c2ccc3c(-c4ccccc4)c(-c4ccccc4)sc3c21 ; c1ccc(-c2cc(-c3ccccc3)cc(N3c4ccccc4-c4ccccc4-c4cc5ccn(-c6ccccc6)c5cc43)c2)cc1 ; c1ccc(-n2ccc3cc4c(cc32)N(c2cc(-c3ccncc3)ccn2)c2ccccc2-c2ccccc2-4)cc1 ; Cc1oc2cc3c(cc2c1C)-c1ccccc1-c1ccccc1N3c1cccc(-c2ccc3ccccc3n2)c1 ; CC1(C)c2ccccc2-c2ccccc2-c2cc3ccn(-c4ccccc4-c4nc5ccccc5c5ncccc45)c3cc21 ; Cc1ncccc1-n1ccc2cc3c(cc21)-c1ccccc1-c1ccccc1N3c1cc(-c2ccccc2)cc2ccccc12]

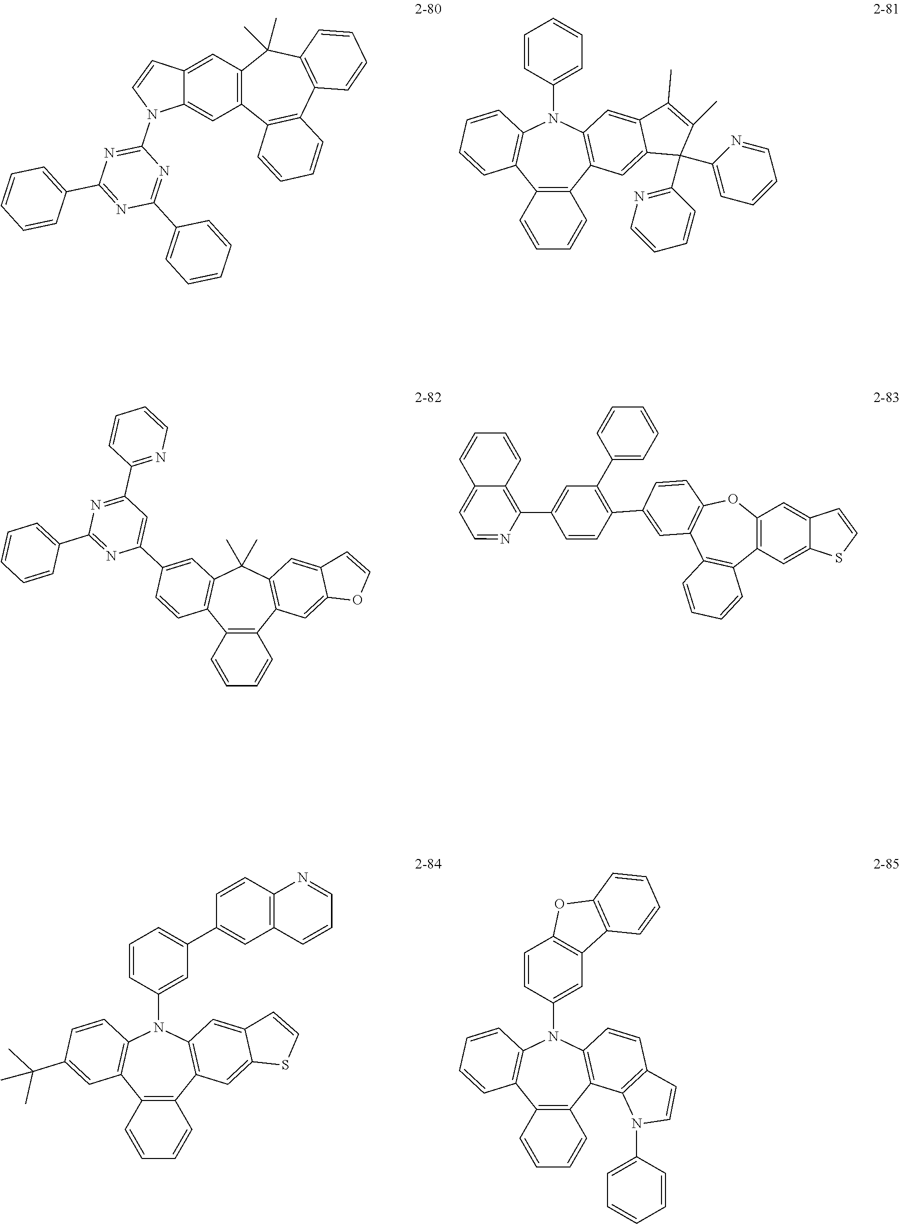 [SMILES: CC1(C)c2ccccc2-c2ccccc2-c2cc3c(ccn3-c3nc(-c4ccccc4)nc(-c4ccccc4)n3)cc21 ; CC1=C(C)C(c2ccccn2)(c2ccccn2)c2cc3c(cc21)N(c1ccccc1)c1ccccc1-c1ccccc1-3 ; CC1(C)c2cc(-c3cc(-c4ccccn4)nc(-c4ccccc4)n3)ccc2-c2ccccc2-c2cc3occc3cc21 ; c1ccc(-c2cc(-c3nccc4ccccc34)ccc2-c2ccc3c(c2)-c2ccccc2-c2cc4sccc4cc2O3)cc1 ; CC(C)(C)c1ccc2c(c1)-c1ccccc1-c1cc3sccc3cc1N2c1cccc(-c2ccc3ncccc3c2)c1 ; c1ccc(-n2ccc3ccc4c(c32)-c2ccccc2-c2ccccc2N4c2ccc3oc4ccccc4c3c2)cc1]

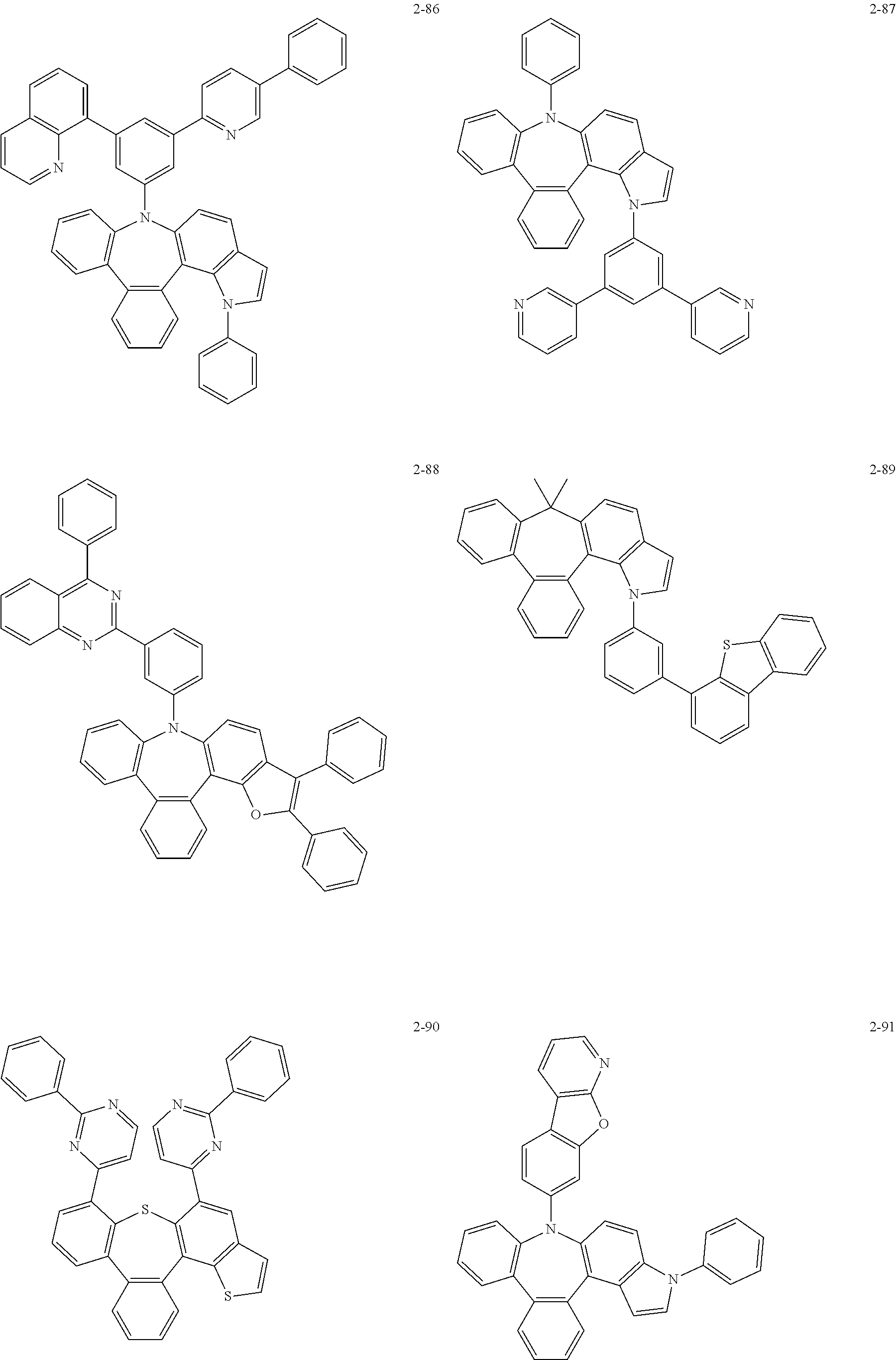 [SMILES: c1ccc(-c2ccc(-c3cc(-c4cccc5cccnc45)cc(N4c5ccccc5-c5ccccc5-c5c4ccc4ccn(-c6ccccc6)c54)c3)nc2)cc1 ; c1ccc(N2c3ccccc3-c3ccccc3-c3c2ccc2ccn(-c4cc(-c5cccnc5)cc(-c5cccnc5)c4)c32)cc1 ; c1ccc(-c2oc3c4c(ccc3c2-c2ccccc2)N(c2cccc(-c3nc(-c5ccccc5)c5ccccc5n3)c2)c2ccccc2-c2ccccc2-4)cc1 ; CC1(C)c2ccccc2-c2ccccc2-c2c1ccc1ccn(-c3cccc(-c4cccc5c4sc4ccccc45)c3)c21 ; c1ccc(-c2nccc(-c3cccc4c3Sc3c(-c5ccnc(-c6ccccc6)n5)cc5ccsc5c3-c3ccccc3-4)n2)cc1 ; c1ccc(-n2ccc3c4c(ccc32)N(c2ccc3c(c2)oc2ncccc23)c2ccccc2-c2ccccc2-4)cc1]

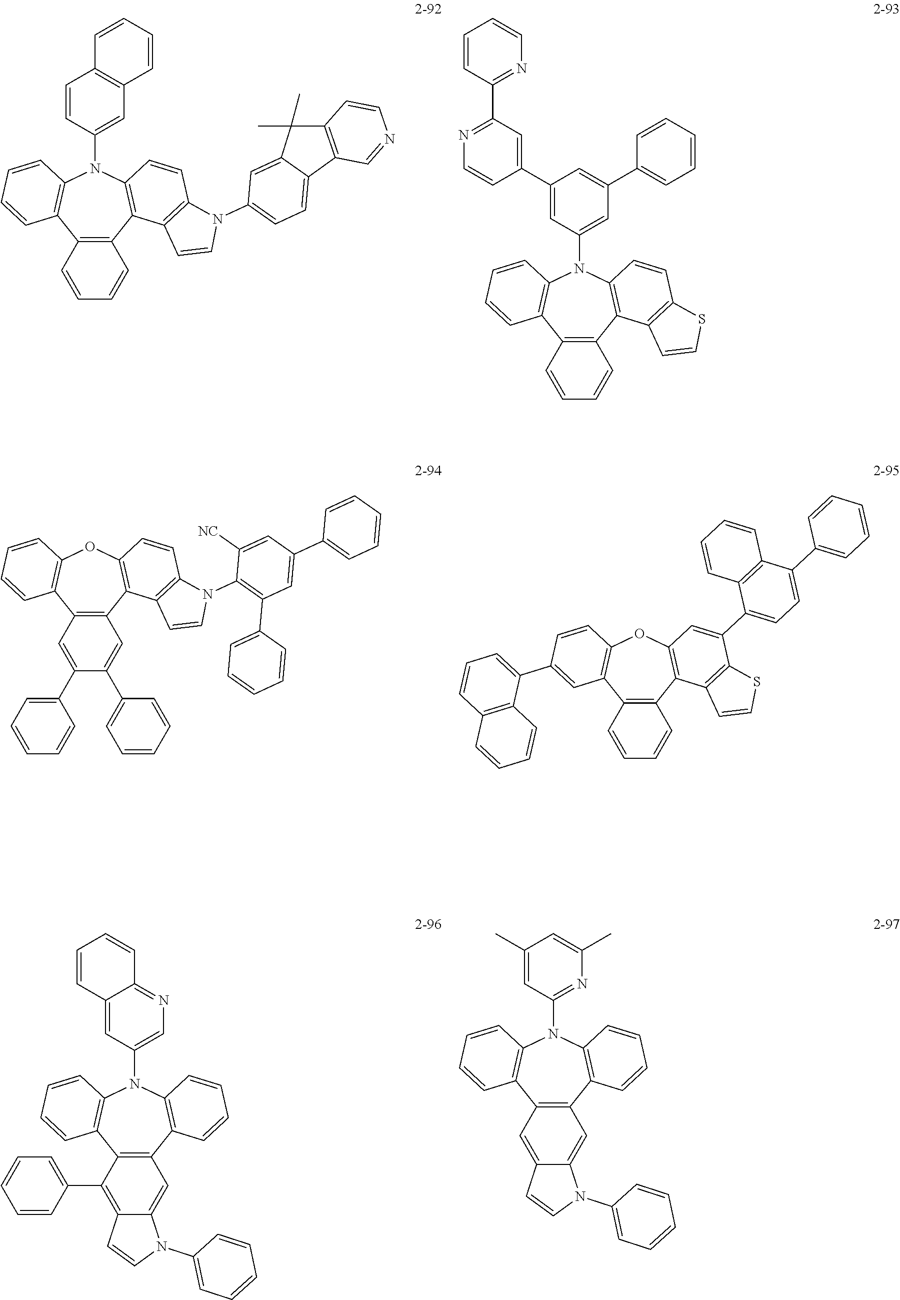 [SMILES: CC1(C)c2ccncc2-c2ccc(-n3ccc4c5c(ccc43)N(c3ccc4ccccc4c3)c3ccccc3-c3ccccc3-5)cc21 ; c1ccc(-c2cc(-c3ccnc(-c4ccccn4)c3)cc(N3c4ccccc4-c4ccccc4-c4c3ccc3sccc43)c2)cc1 ; N#Cc1cc(-c2ccccc2)cc(-c2ccccc2)c1-n1ccc2c3c(ccc21)Oc1ccccc1-c1cc(-c2ccccc2)c(-c2ccccc2)cc1-3 ; c1ccc(-c2ccc(-c3cc4c(c5ccsc35)-c3ccccc3-c3cc(-c5cccc6ccccc56)ccc3O4)c3ccccc23)cc1 ; c1ccc(-c2c3c(cc4c2ccn4-c2ccccc2)-c2ccccc2N(c2cnc4ccccc4c2)c2ccccc2-3)cc1 ; Cc1cc(C)nc(N2c3ccccc3-c3cc4ccn(-c5ccccc5)c4cc3-c3ccccc32)c1]

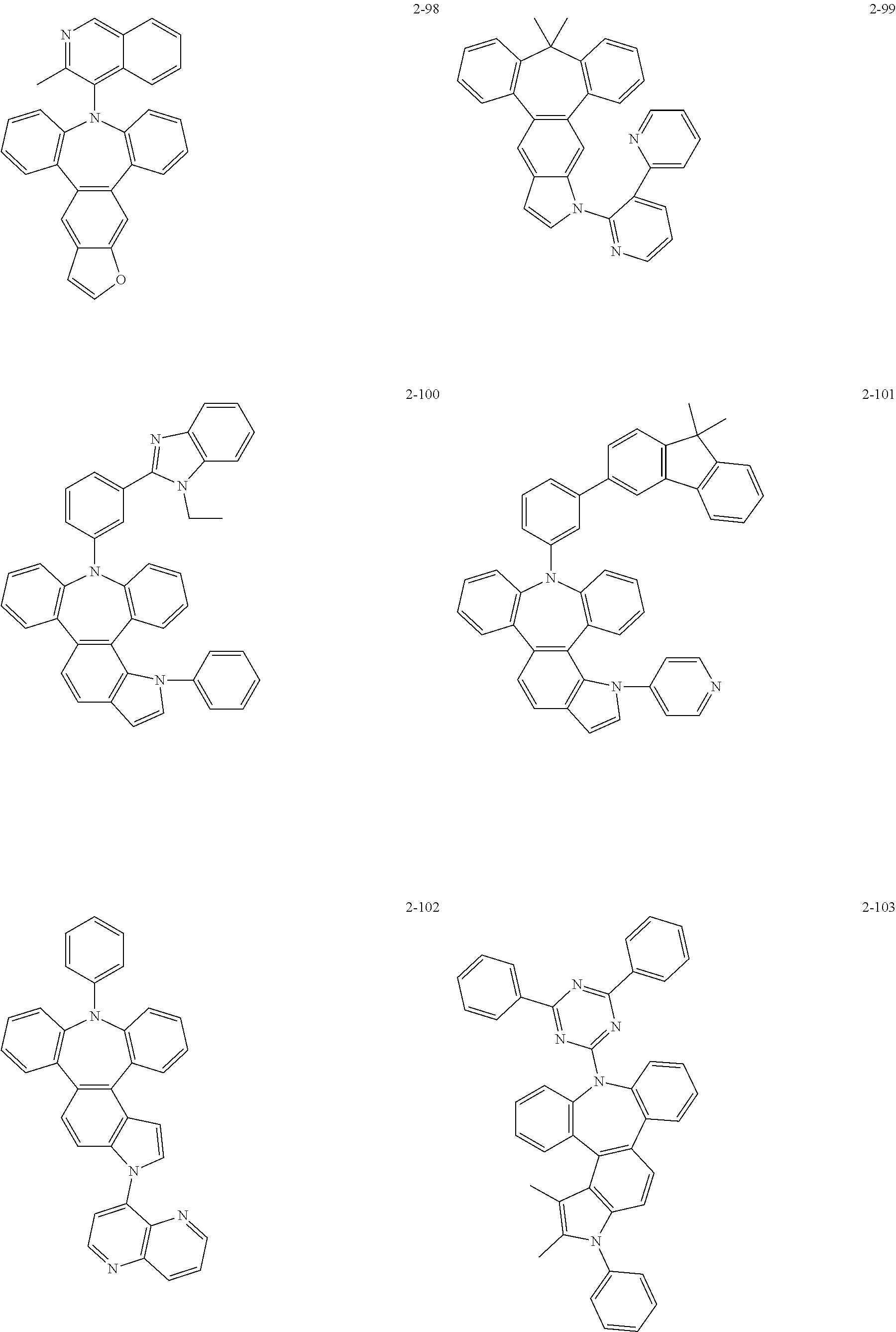 [SMILES: Cc1ncc2ccccc2c1N1c2ccccc2-c2cc3ccoc3cc2-c2ccccc21 ; CC1(C)c2ccccc2-c2cc3ccn(-c4ncccc4-c4ccccn4)c3cc2-c2ccccc21 ; CCn1c(-c2cccc(N3c4ccccc4-c4ccc5ccn(-c6ccccc6)c5c4-c4ccccc43)c2)nc2ccccc21 ; CC1(C)c2ccccc2-c2cc(-c3cccc(N4c5ccccc5-c5ccc6ccn(-c7ccncc7)c6c5-c5ccccc54)c3)ccc21 ; c1ccc(N2c3ccccc3-c3ccc4c(ccn4-c4ccnc5cccnc45)c3-c3ccccc32)cc1 ; Cc1c(C)n(-c2ccccc2)c2ccc3c(c12)-c1ccccc1N(c1nc(-c2ccccc2)nc(-c2ccccc2)n1)c1ccccc1-3]

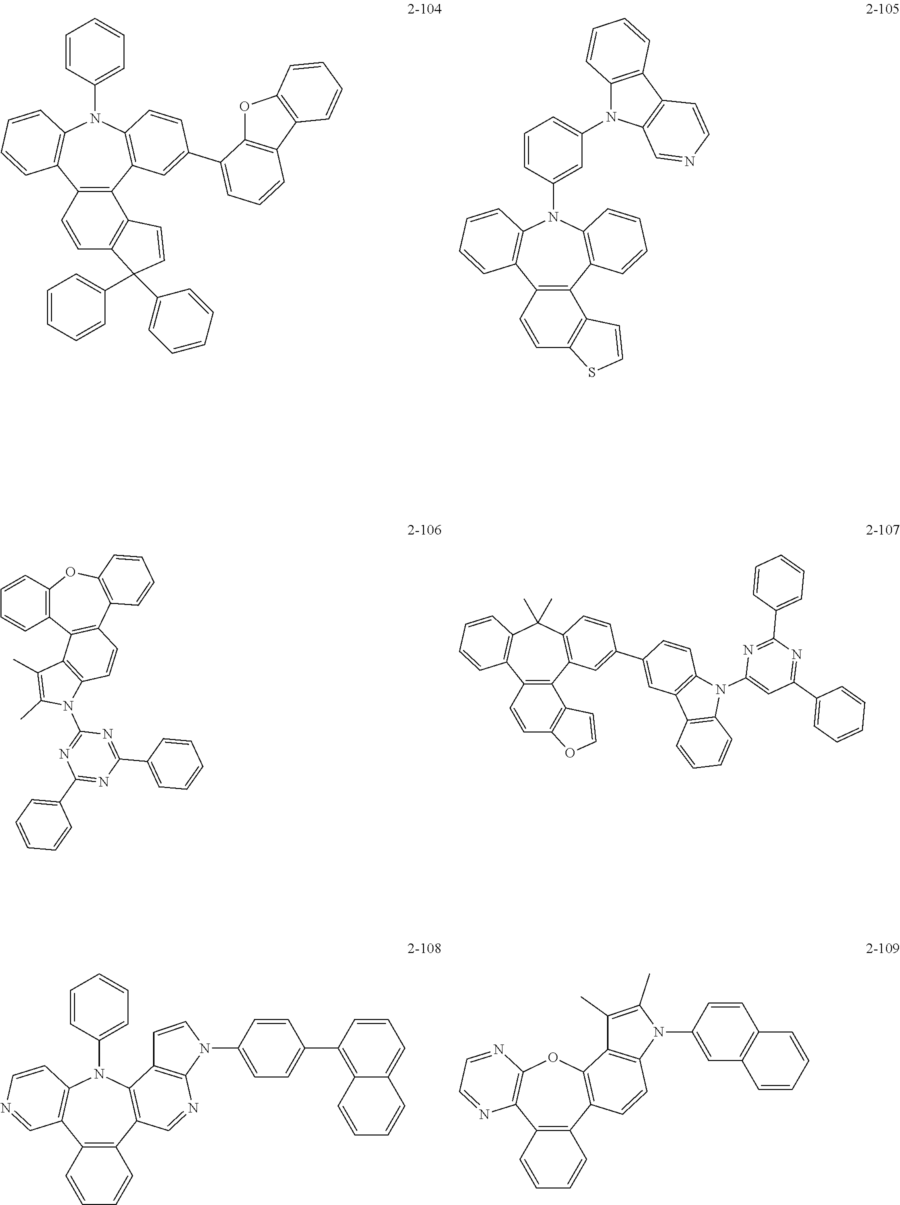 [SMILES: C1=CC(c2ccccc2)(c2ccccc2)c2ccc3c(c21)-c1cc(-c2cccc4c2oc2ccccc24)ccc1N(c1ccccc1)c1ccccc1-3 ; c1cc(N2c3ccccc3-c3ccc4sccc4c3-c3ccccc32)cc(-n2c3ccccc3c3ccncc32)c1 ; Cc1c(C)n(-c2nc(-c3ccccc3)nc(-c3ccccc3)n2)c2ccc3c(c12)-c1ccccc1Oc1ccccc1-3 ; CC1(C)c2ccccc2-c2ccc3occc3c2-c2cc(-c3ccc4c(c3)c3ccccc3n4-c3cc(-c4ccccc4)nc(-c4ccccc4)n3)ccc21 ; c1ccc(N2c3ccncc3-c3ccccc3-c3cnc4c(ccn4-c4ccc(-c5cccc6ccccc56)cc4)c32)cc1 ; Cc1c(C)n(-c2ccc3ccccc3c2)c2ccc3c(c12)Oc1nccnc1-c1ccccc1-3]

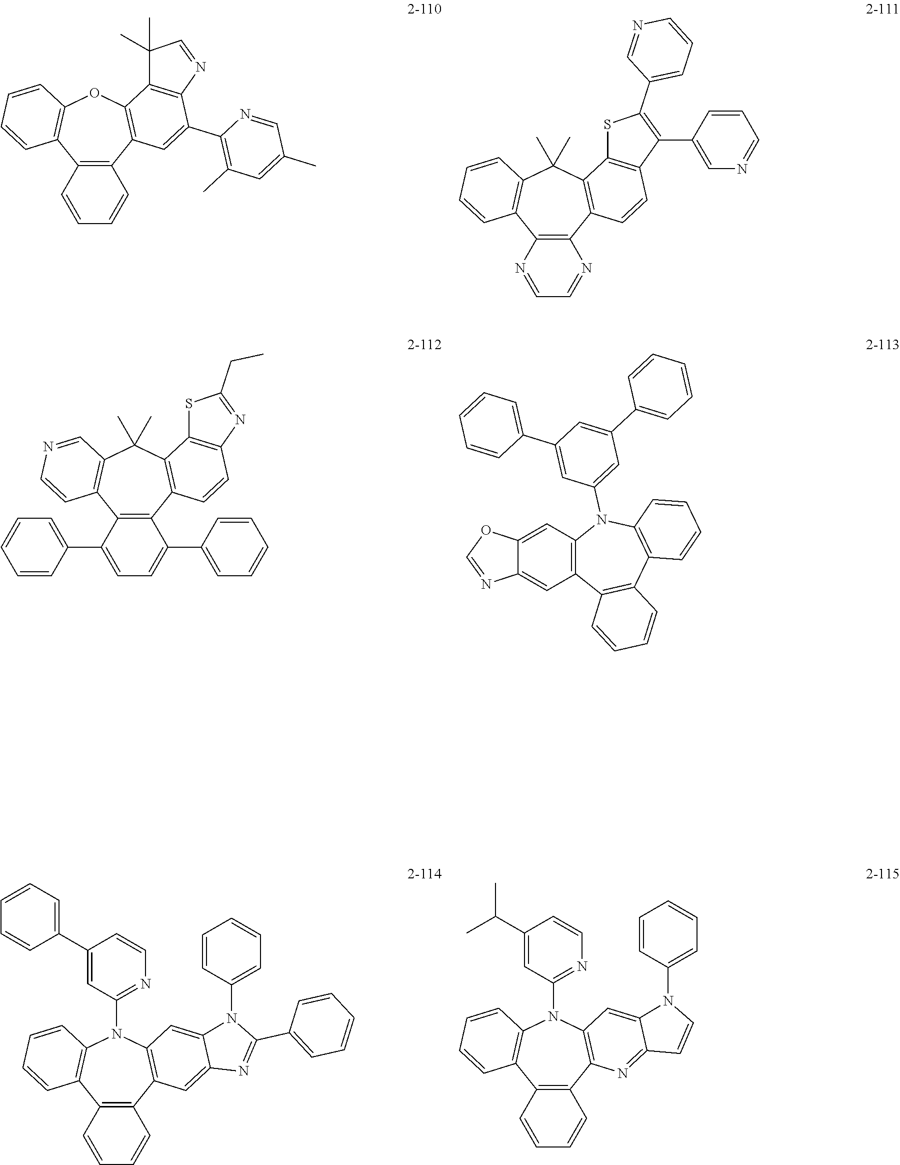 [SMILES: Cc1cnc(-c2cc3c(c4c2N=CC4(C)C)Oc2ccccc2-c2ccccc2-3)c(C)c1 ; CC1(C)c2ccccc2-c2nccnc2-c2ccc3c(-c4cccnc4)c(-c4cccnc4)sc3c21 ; CCc1nc2ccc3c(c2s1)C(C)(C)c1cnccc1-c1c(-c2ccccc2)ccc(-c2ccccc2)c1-3 ; c1ccc(-c2cc(-c3ccccc3)cc(N3c4ccccc4-c4ccccc4-c4cc5ncoc5cc43)c2)cc1 ; c1ccc(-c2ccnc(N3c4ccccc4-c4ccccc4-c4cc5nc(-c6ccccc6)n(-c6ccccc6)c5cc43)c2)cc1 ; CC(C)c1ccnc(N2c3ccccc3-c3ccccc3-c3nc4ccn(-c5ccccc5)c4cc32)c1]

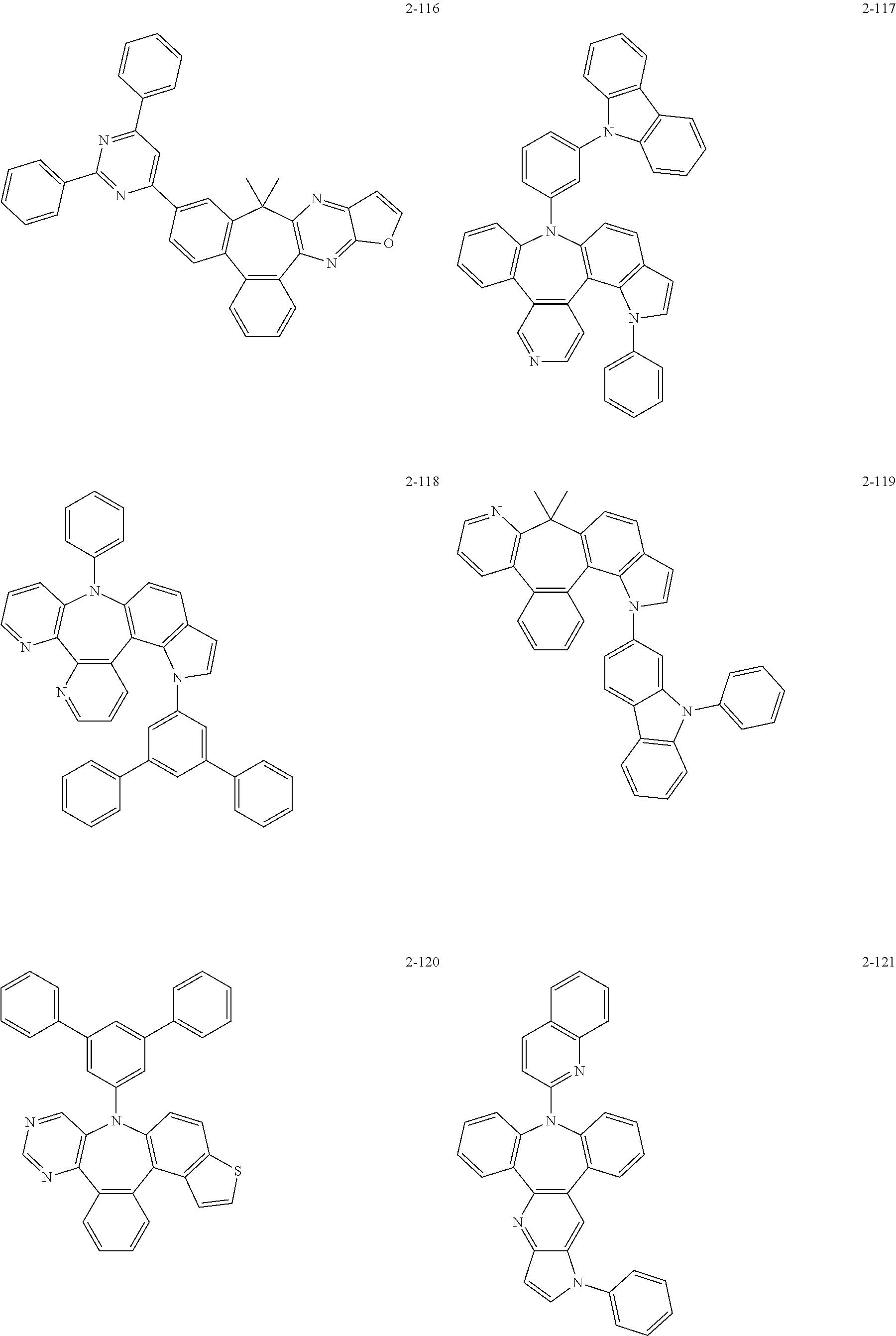 [SMILES: CC1(C)c2cc(-c3cc(-c4ccccc4)nc(-c4ccccc4)n3)ccc2-c2ccccc2-c2nc3occc3nc21 ; c1ccc(-n2ccc3ccc4c(c32)-c2ccncc2-c2ccccc2N4c2cccc(-n3c4ccccc4c4ccccc43)c2)cc1 ; c1ccc(-c2cc(-c3ccccc3)cc(-n3ccc4ccc5c(c43)-c3cccnc3-c3ncccc3N5c3ccccc3)c2)cc1 ; CC1(C)c2ccc3ccn(-c4ccc5c6ccccc6n(-c6ccccc6)c5c4)c3c2-c2ccccc2-c2cccnc21 ; c1ccc(-c2cc(-c3ccccc3)cc(N3c4cncnc4-c4ccccc4-c4c3ccc3sccc43)c2)cc1 ; c1ccc(-n2ccc3nc4c(cc32)-c2ccccc2N(c2ccc3ccccc3n2)c2ccccc2-4)cc1]

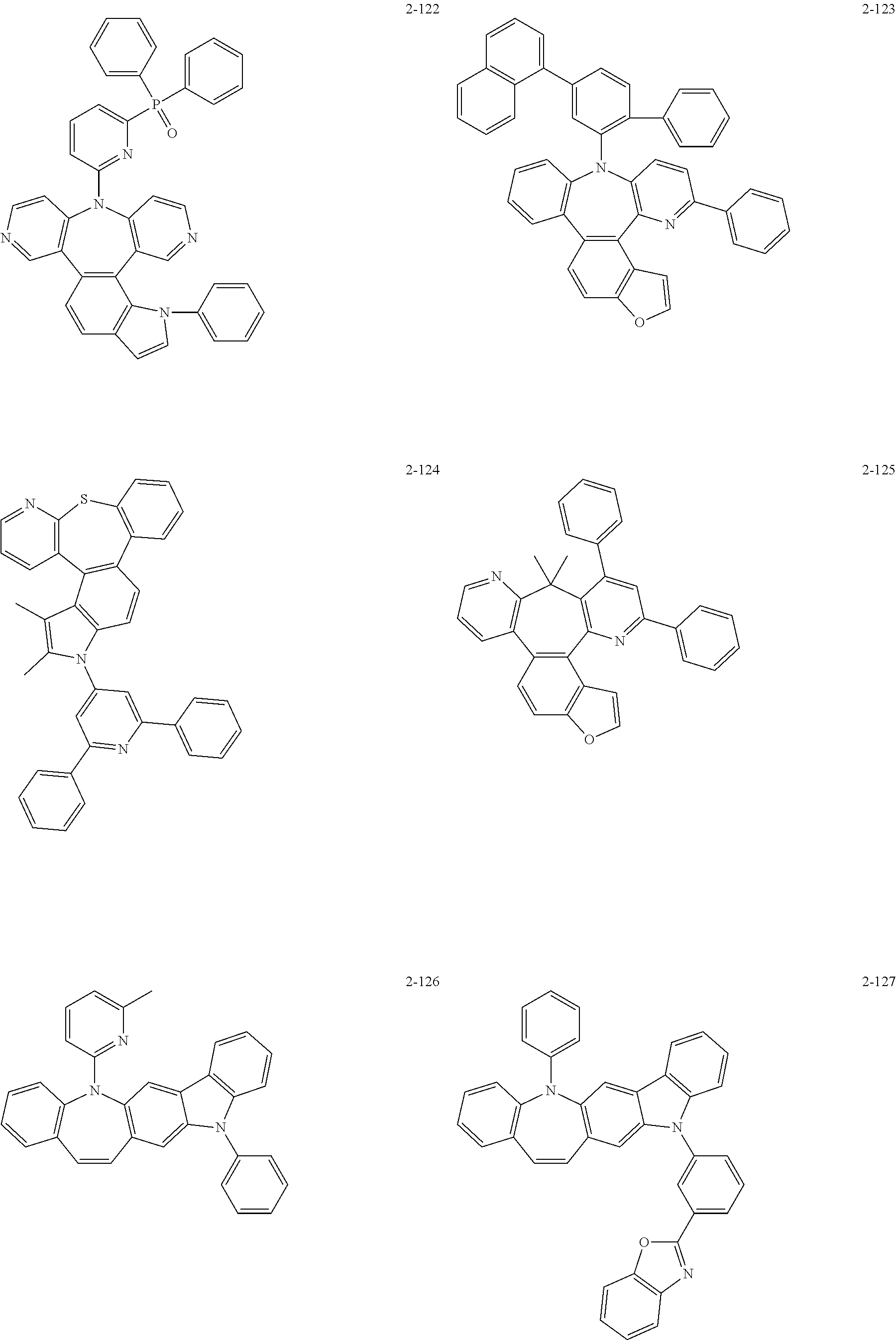 [SMILES: O=P(c1ccccc1)(c1ccccc1)c1cccc(N2c3ccncc3-c3ccc4ccn(-c5ccccc5)c4c3-c3cnccc32)n1 ; c1ccc(-c2ccc3c(n2)-c2c(ccc4occc24)-c2ccccc2N3c2cc(-c3cccc4ccccc34)ccc2-c2ccccc2)cc1 ; Cc1c(C)n(-c2cc(-c3ccccc3)nc(-c3ccccc3)c2)c2ccc3c(c12)-c1cccnc1Sc1ccccc1-3 ; CC1(C)c2ncccc2-c2ccc3occc3c2-c2nc(-c3ccccc3)cc(-c3ccccc3)c21 ; Cc1cccc(N2c3ccccc3C=Cc3cc4c(cc32)c2ccccc2n4-c2ccccc2)n1 ; C1=Cc2cc3c(cc2N(c2ccccc2)c2ccccc21)c1ccccc1n3-c1cccc(-c2nc3ccccc3o2)c1]

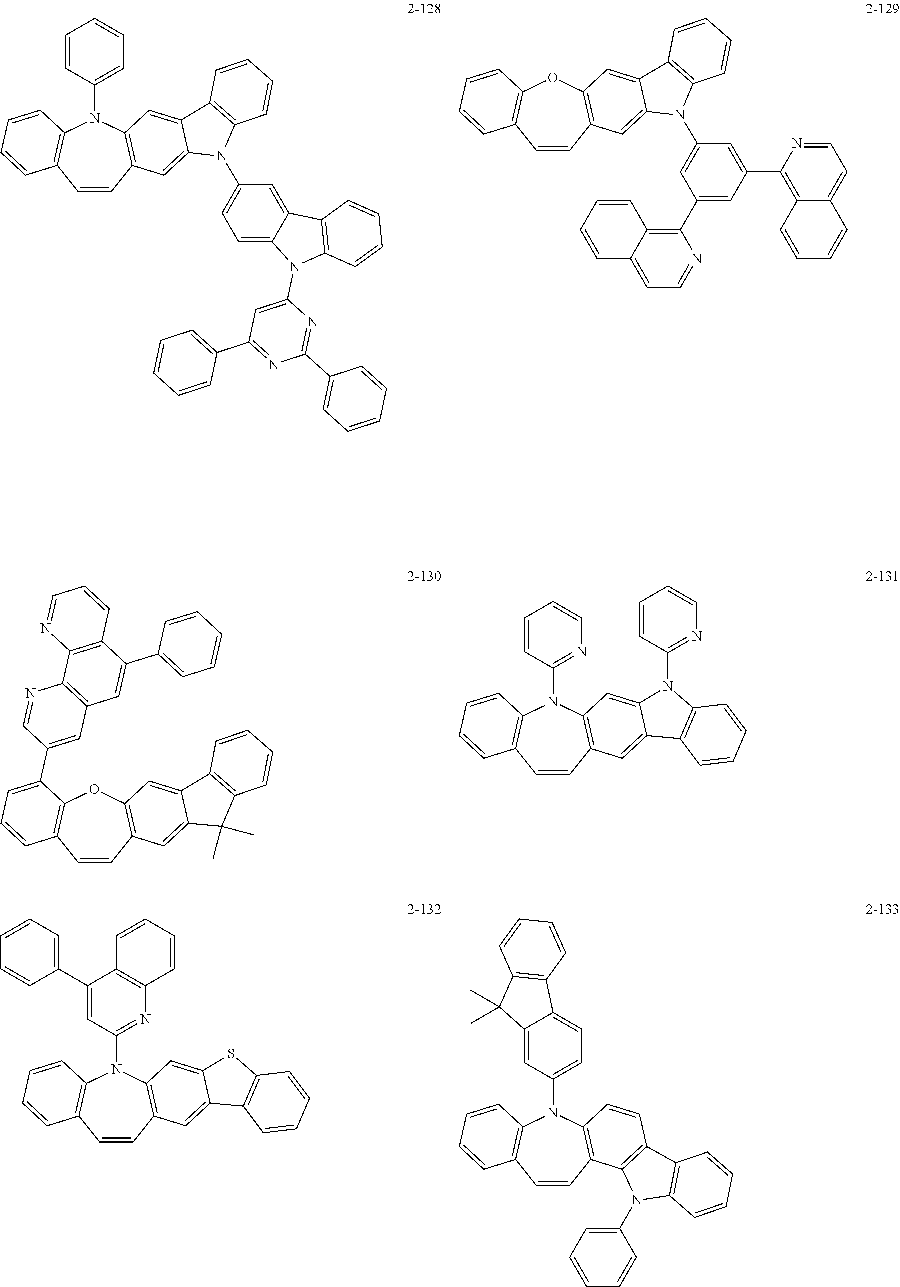 [SMILES: C1=Cc2cc3c(cc2N(c2ccccc2)c2ccccc21)c1ccccc1n3-c1ccc2c(c1)c1ccccc1n2-c1cc(-c2ccccc2)nc(-c2ccccc2)n1 ; C1=Cc2cc3c(cc2Oc2ccccc21)c1ccccc1n3-c1cc(-c2nccc3ccccc23)cc(-c2nccc3ccccc23)c1 ; CC1(C)c2ccccc2-c2cc3c(cc21)C=Cc1cccc(-c2cnc4c(c2)cc(-c2ccccc2)c2cccnc24)c1O3 ; C1=Cc2cc3c4ccccc4n(-c4ccccn4)c3cc2N(c2ccccn2)c2ccccc21 ; C1=Cc2cc3c(cc2N(c2cc(-c4ccccc4)c4ccccc4n2)c2ccccc21)sc1ccccc13 ; CC1(C)c2ccccc2-c2ccc(N3c4ccccc4C=Cc4c3ccc3c5ccccc5n(-c5ccccc5)c43)cc21]

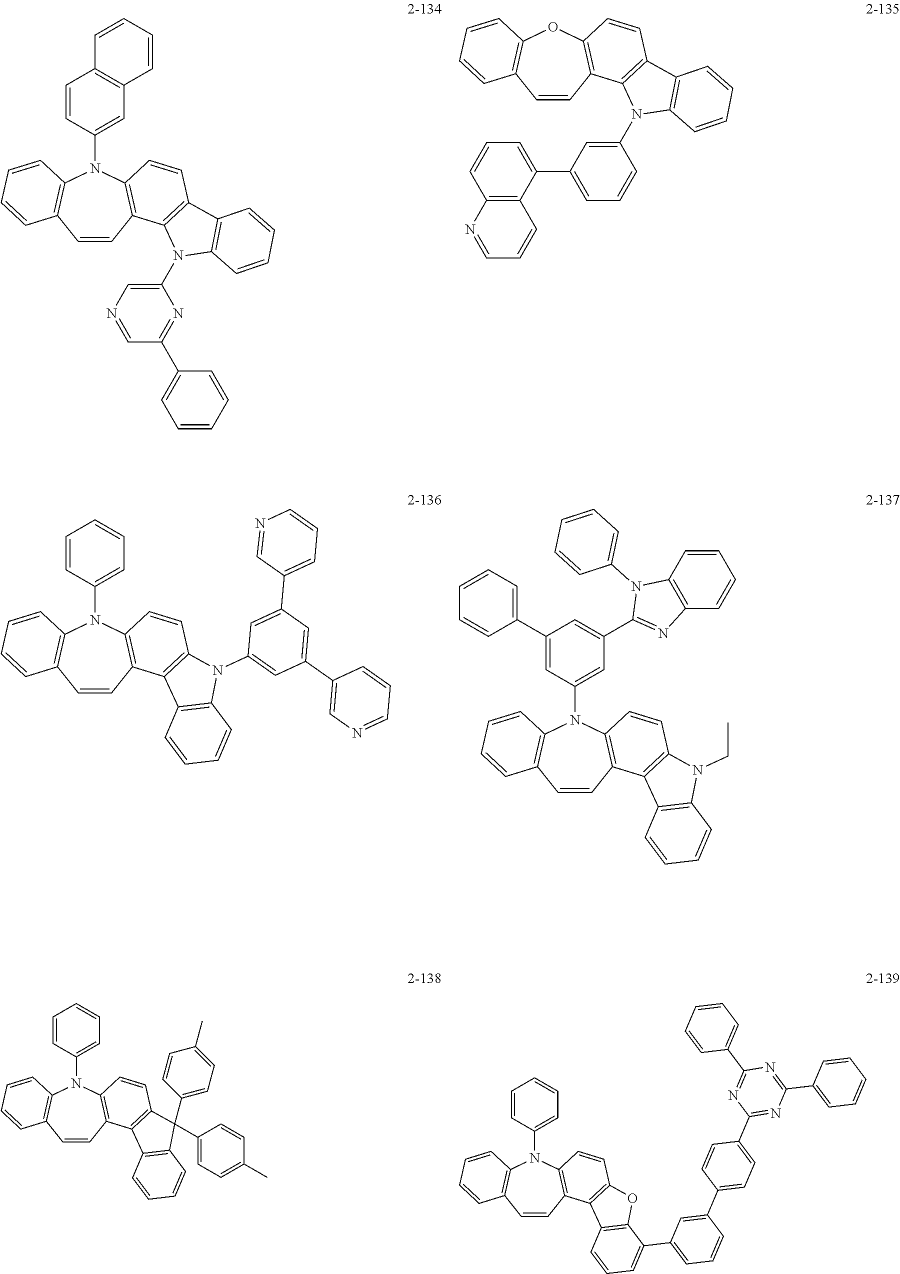 [SMILES: C1=Cc2c(ccc3c4ccccc4n(-c4cncc(-c5ccccc5)n4)c23)N(c2ccc3ccccc3c2)c2ccccc21 ; C1=Cc2c(ccc3c4ccccc4n(-c4cccc(-c5cccc6ncccc56)c4)c23)Oc2ccccc21 ; C1=Cc2c(ccc3c2c2ccccc2n3-c2cc(-c3cccnc3)cc(-c3cccnc3)c2)N(c2ccccc2)c2ccccc21 ; CCn1c2ccccc2c2c3c(ccc21)N(c1cc(-c2ccccc2)cc(-c2nc4ccccc4n2-c2ccccc2)c1)c1ccccc1C=C3 ; Cc1ccc(C2(c3ccc(C)cc3)c3ccccc3-c3c2ccc2c3C=Cc3ccccc3N2c2ccccc2)cc1 ; C1=Cc2c(ccc3oc4c(-c5cccc(-c6ccc(-c7nc(-c8ccccc8)nc(-c8ccccc8)n7)cc6)c5)cccc4c23)N(c2ccccc2)c2ccccc21]

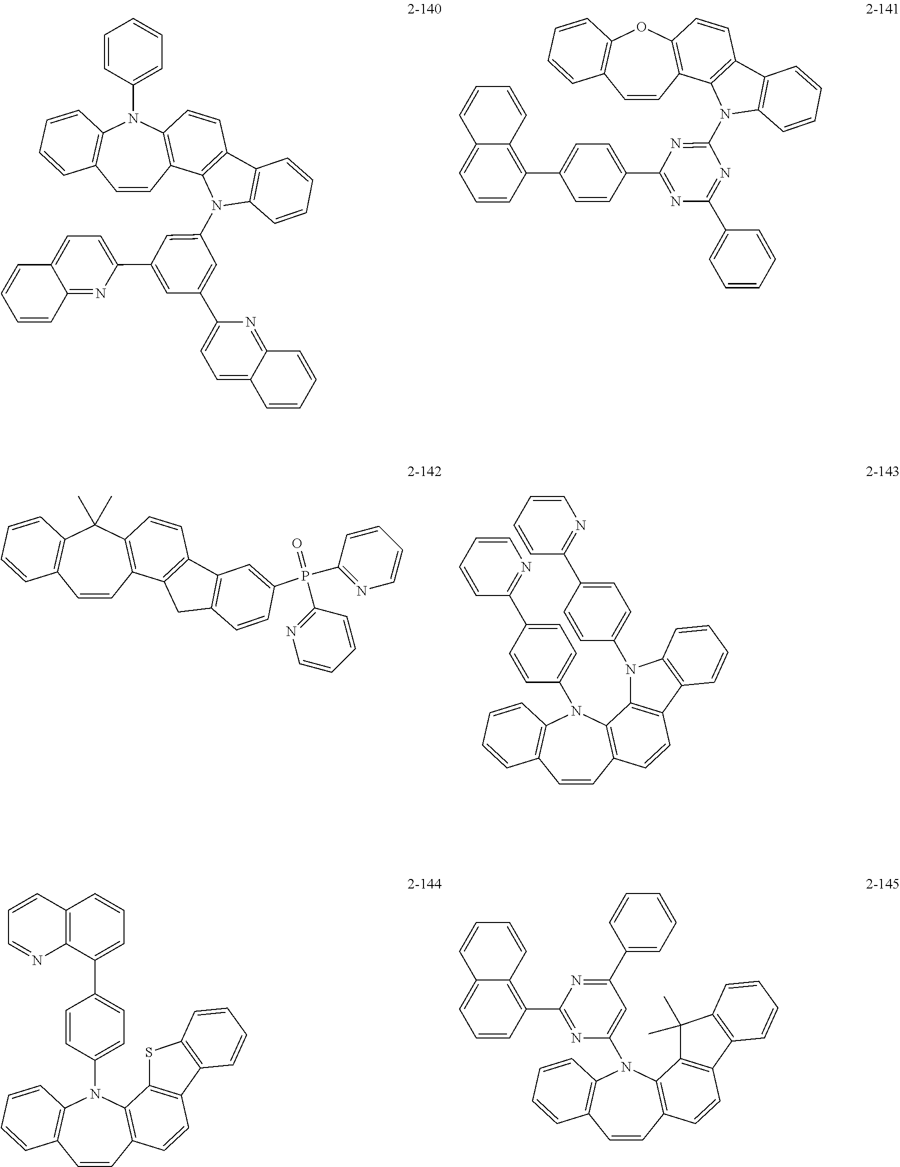 [SMILES: C1=Cc2c(ccc3c4ccccc4n(-c4cc(-c5ccc6ccccc6n5)cc(-c5ccc6ccccc6n5)c4)c23)N(c2ccccc2)c2ccccc21 ; C1=Cc2c(ccc3c4ccccc4n(-c4nc(-c5ccccc5)nc(-c5ccc(-c6cccc7ccccc67)cc5)n4)c23)Oc2ccccc21 ; CC1(C)c2ccccc2C=Cc2c1ccc1c2Cc2ccc(P(=O)(c3ccccn3)c3ccccn3)cc2-1 ; C1=Cc2ccc3c4ccccc4n(-c4ccc(-c5ccccn5)cc4)c3c2N(c2ccc(-c3ccccn3)cc2)c2ccccc21 ; C1=Cc2ccc3c(sc4ccccc43)c2N(c2ccc(-c3cccc4cccnc34)cc2)c2ccccc21 ; CC1(C)c2ccccc2-c2ccc3c(c21)N(c1cc(-c2ccccc2)nc(-c2cccc4ccccc24)n1)c1ccccc1C=C3]

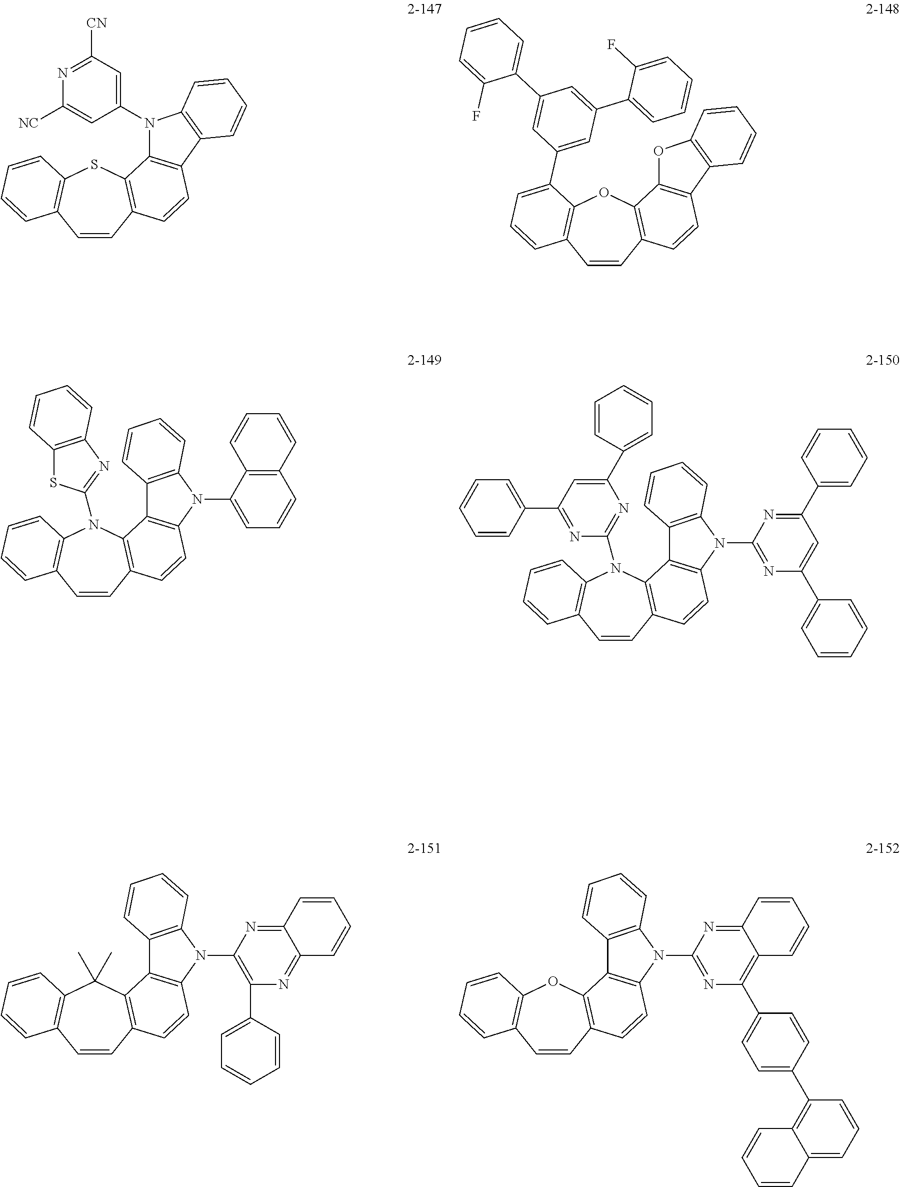 [SMILES: N#Cc1cc(-n2c3ccccc3c3ccc4c(c32)Sc2ccccc2C=C4)cc(C#N)n1 ; Fc1ccccc1-c1cc(-c2ccccc2F)cc(-c2cccc3c2Oc2c(ccc4c2oc2ccccc24)C=C3)c1 ; C1=Cc2ccc3c(c2N(c2nc4ccccc4s2)c2ccccc21)c1ccccc1n3-c1cccc2ccccc12 ; C1=Cc2ccc3c(c2N(c2nc(-c4ccccc4)cc(-c4ccccc4)n2)c2ccccc21)c1ccccc1n3-c1nc(-c2ccccc2)cc(-c2ccccc2)n1 ; CC1(C)c2ccccc2C=Cc2ccc3c(c21)c1ccccc1n3-c1nc2ccccc2nc1-c1ccccc1 ; C1=Cc2ccc3c(c2Oc2ccccc21)c1ccccc1n3-c1nc(-c2ccc(-c3cccc4ccccc34)cc2)c2ccccc2n1]

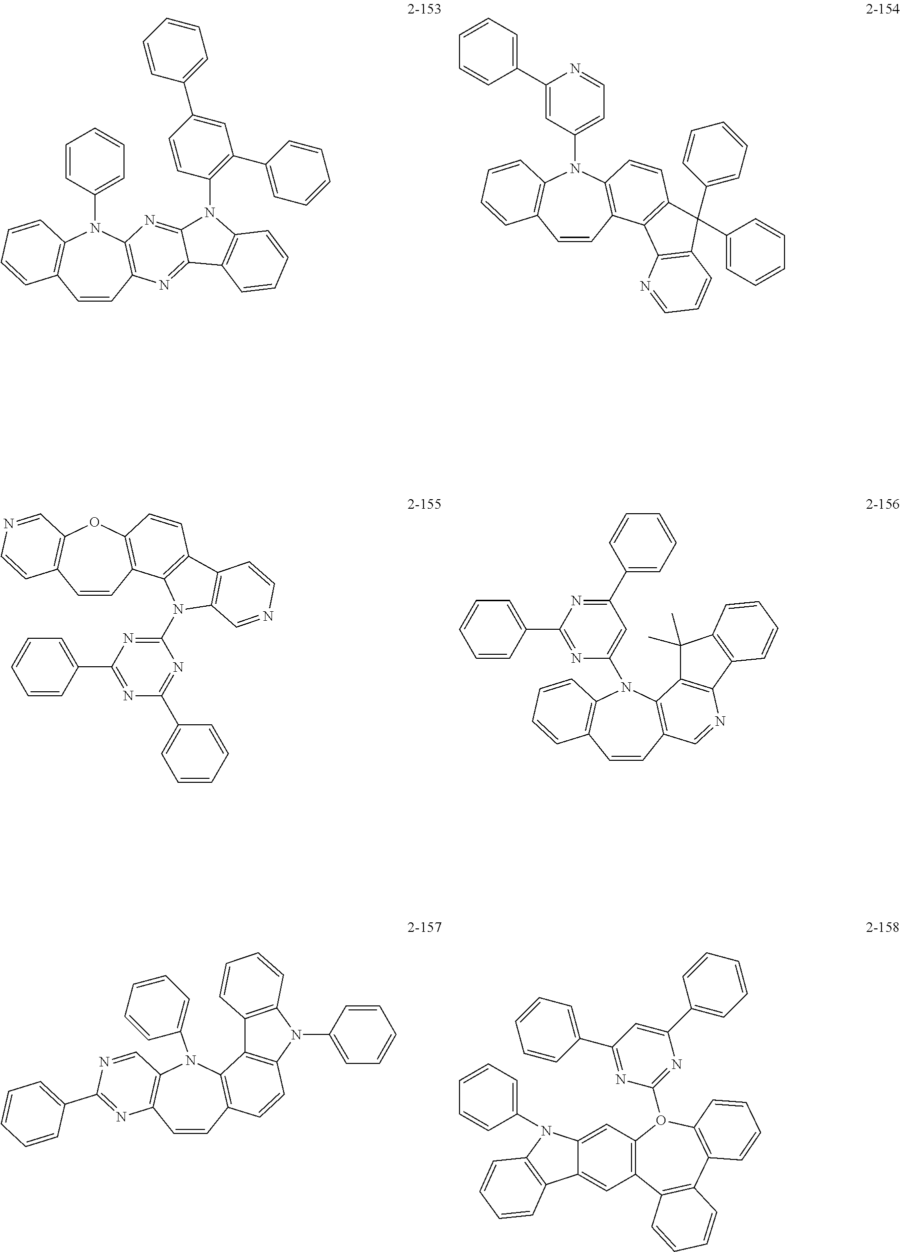

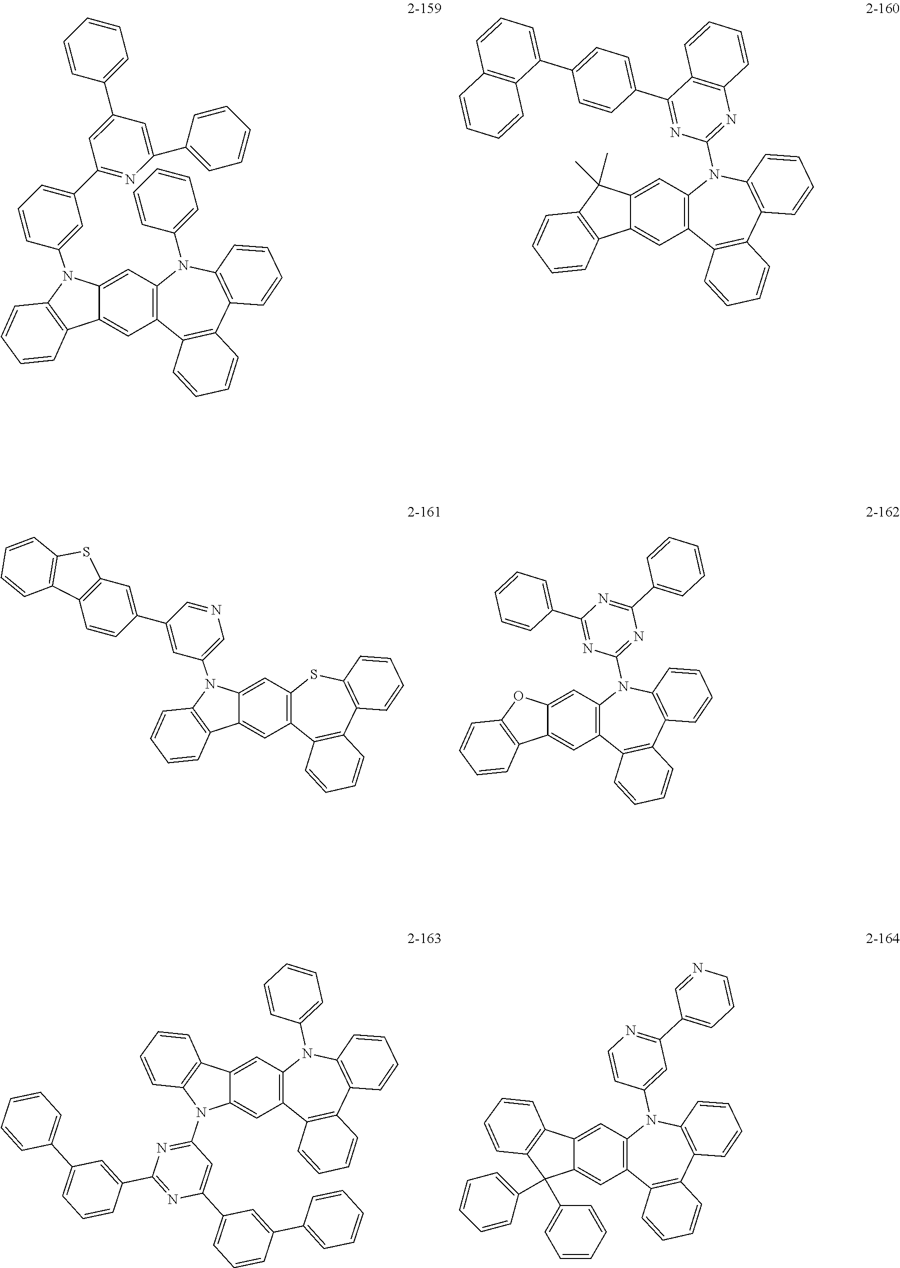

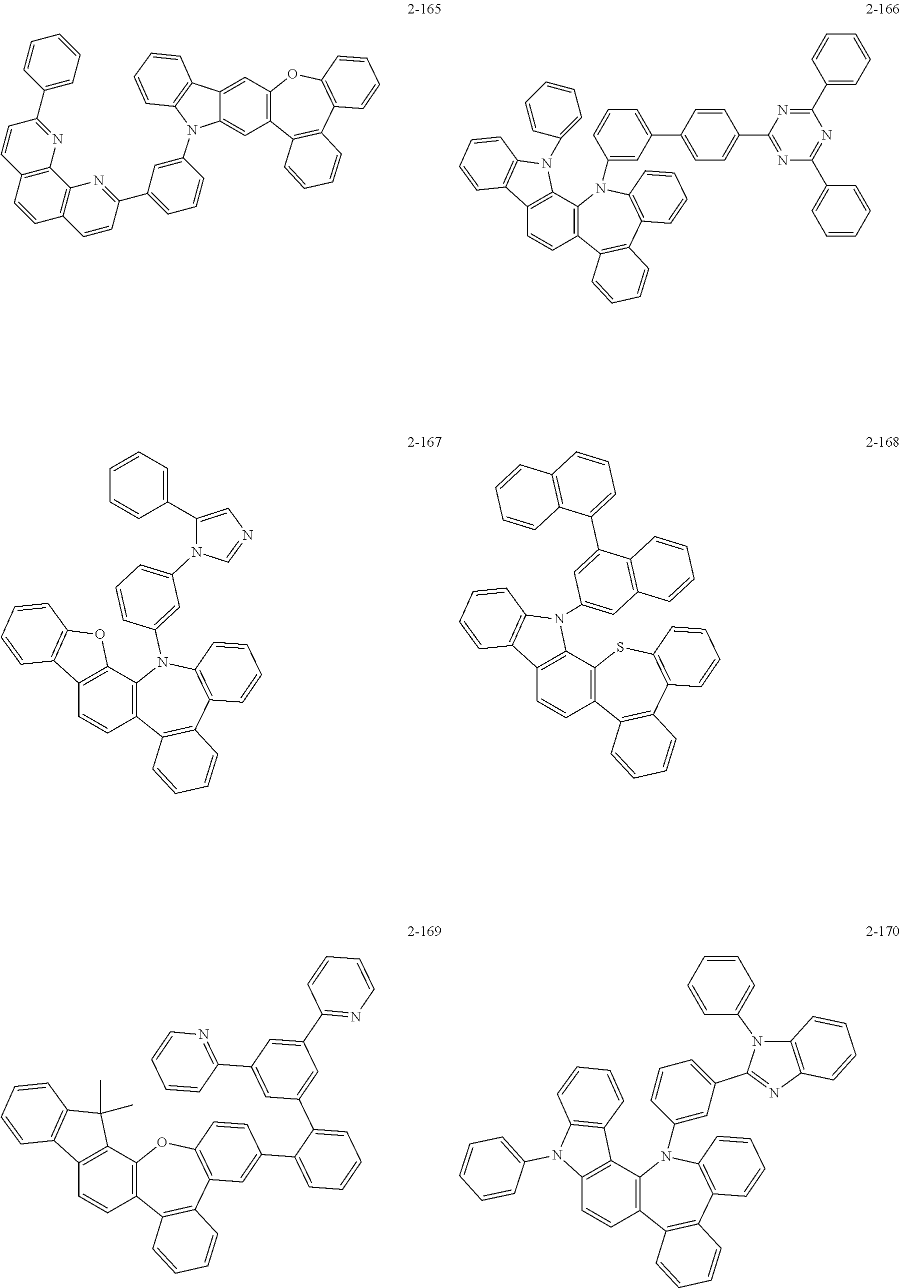

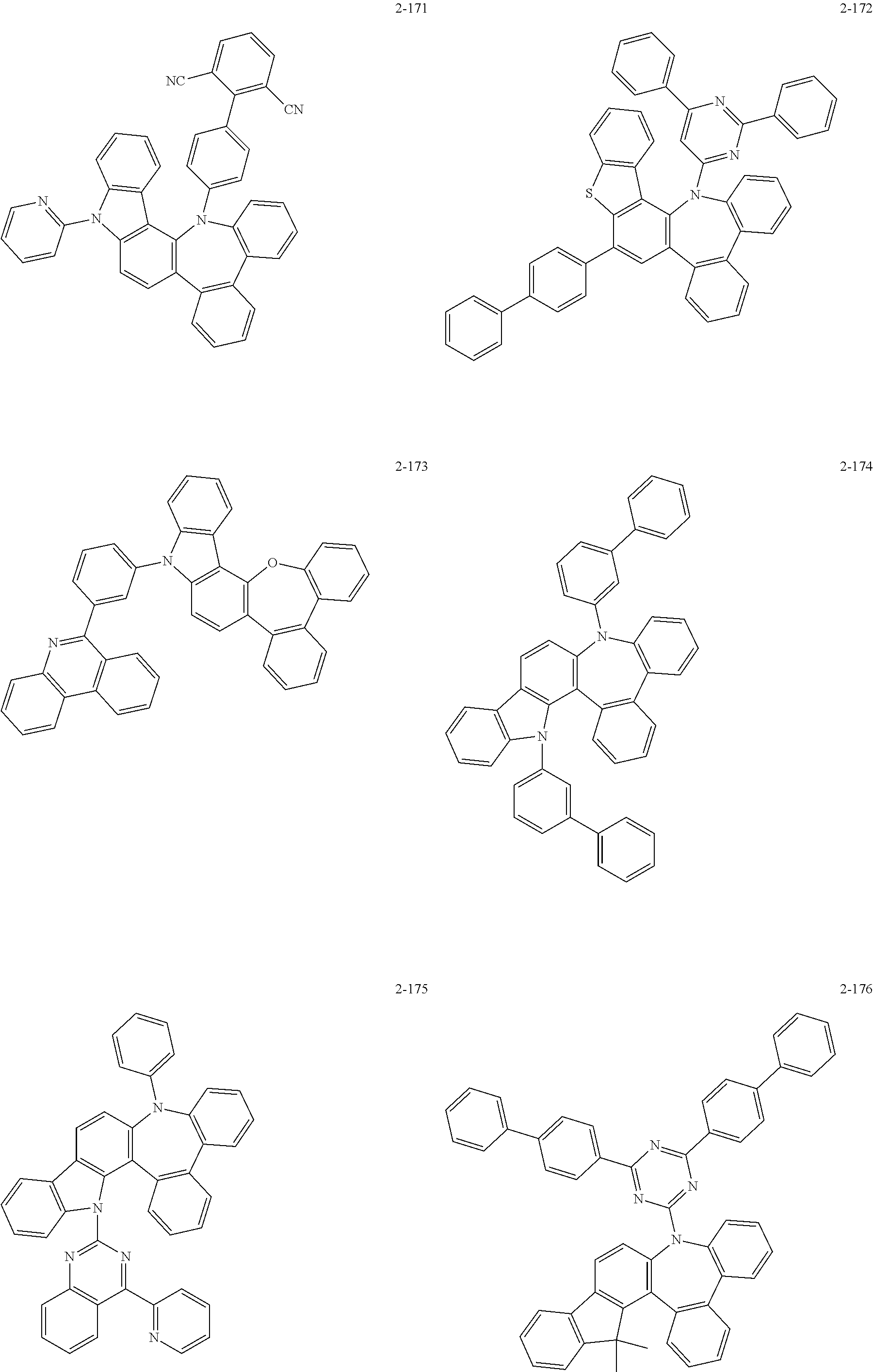

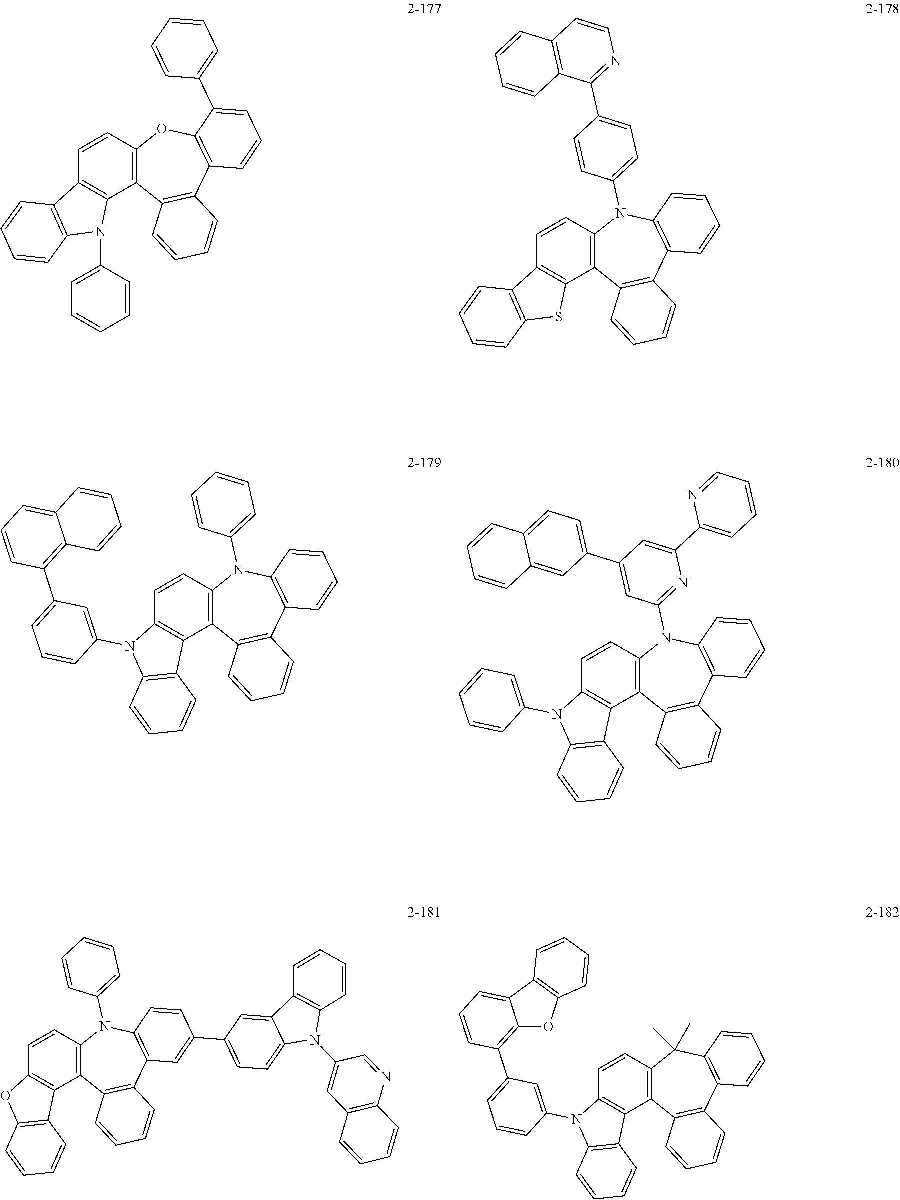 [SMILES: c1ccc(-c2cccc3c2Oc2ccc4c5ccccc5n(-c5ccccc5)c4c2-c2ccccc2-3)cc1 ; c1ccc2c(c1)-c1ccccc1N(c1ccc(-c3nccc4ccccc34)cc1)c1ccc3c(sc4ccccc43)c1-2 ; c1ccc(N2c3ccccc3-c3ccccc3-c3c2ccc2c3c3ccccc3n2-c2cccc(-c3cccc4ccccc34)c2)cc1 ; c1ccc(-n2c3ccccc3c3c4c(ccc32)N(c2cc(-c3ccc5ccccc5c3)cc(-c3ccccn3)n2)c2ccccc2-c2ccccc2-4)cc1 ; c1ccc(N2c3ccc(-c4ccc5c(c4)c4ccccc4n5-c4cnc5ccccc5c4)cc3-c3ccccc3-c3c2ccc2oc4ccccc4c32)cc1 ; CC1(C)c2ccccc2-c2ccccc2-c2c1ccc1c2c2ccccc2n1-c1cccc(-c2cccc3c2oc2ccccc23)c1]

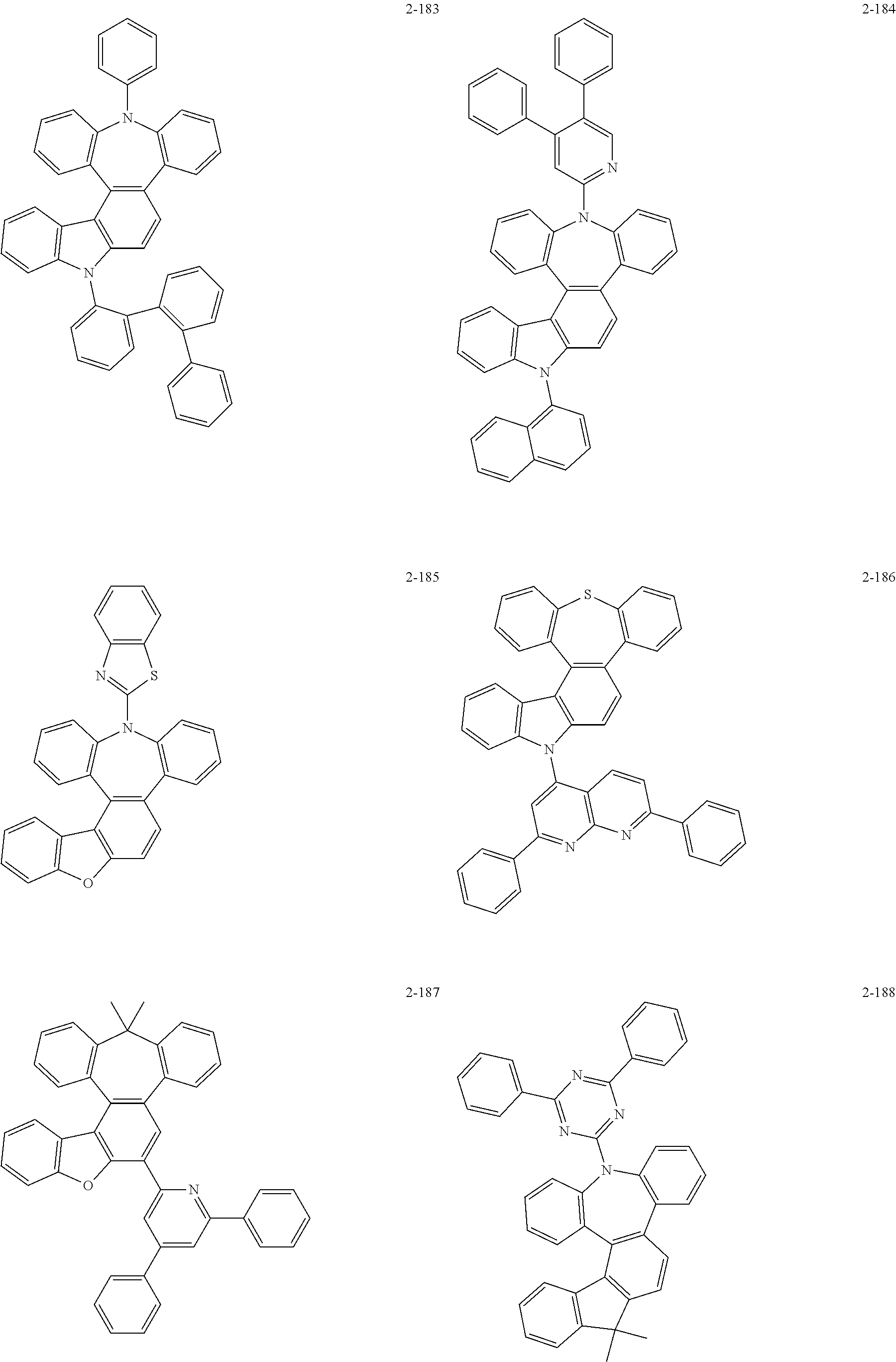 [SMILES: c1ccc(-c2ccccc2-c2ccccc2-n2c3ccccc3c3c4c(ccc32)-c2ccccc2N(c2ccccc2)c2ccccc2-4)cc1 ; c1ccc(-c2cnc(N3c4ccccc4-c4ccc5c(c4-c4ccccc43)c3ccccc3n5-c3cccc4ccccc34)cc2-c2ccccc2)cc1 ; c1ccc2c(c1)-c1ccc3oc4ccccc4c3c1-c1ccccc1N2c1nc2ccccc2s1 ; c1ccc(-c2ccc3c(-n4c5ccccc5c5c6c(ccc54)-c4ccccc4Sc4ccccc4-6)cc(-c4ccccc4)nc3n2)cc1 ; CC1(C)c2ccccc2-c2cc(-c3cc(-c4ccccc4)cc(-c4ccccc4)n3)c3oc4ccccc4c3c2-c2ccccc21 ; CC1(C)c2ccccc2-c2c1ccc1c2-c2ccccc2N(c2nc(-c3ccccc3)nc(-c3ccccc3)n2)c2ccccc2-1]

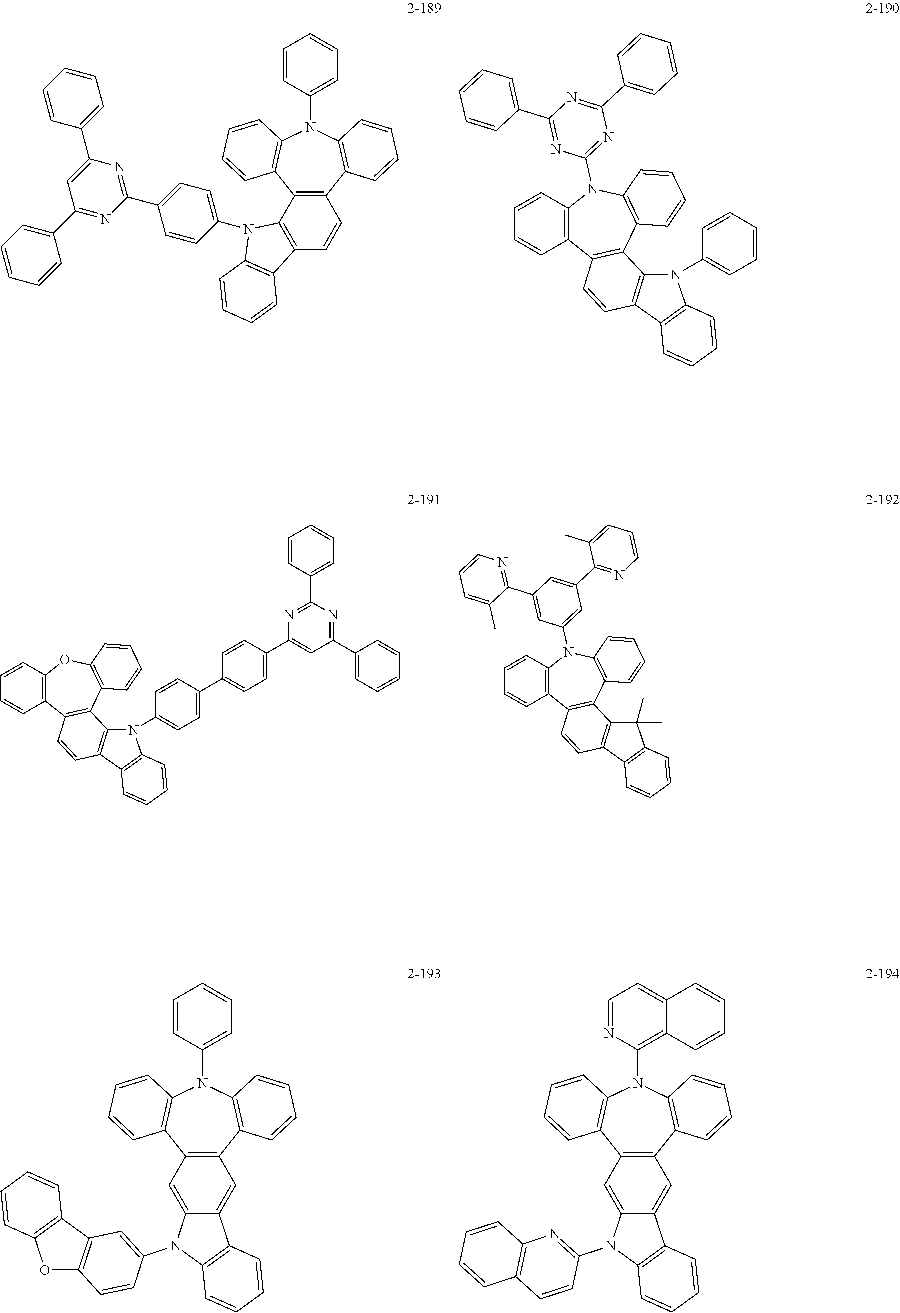

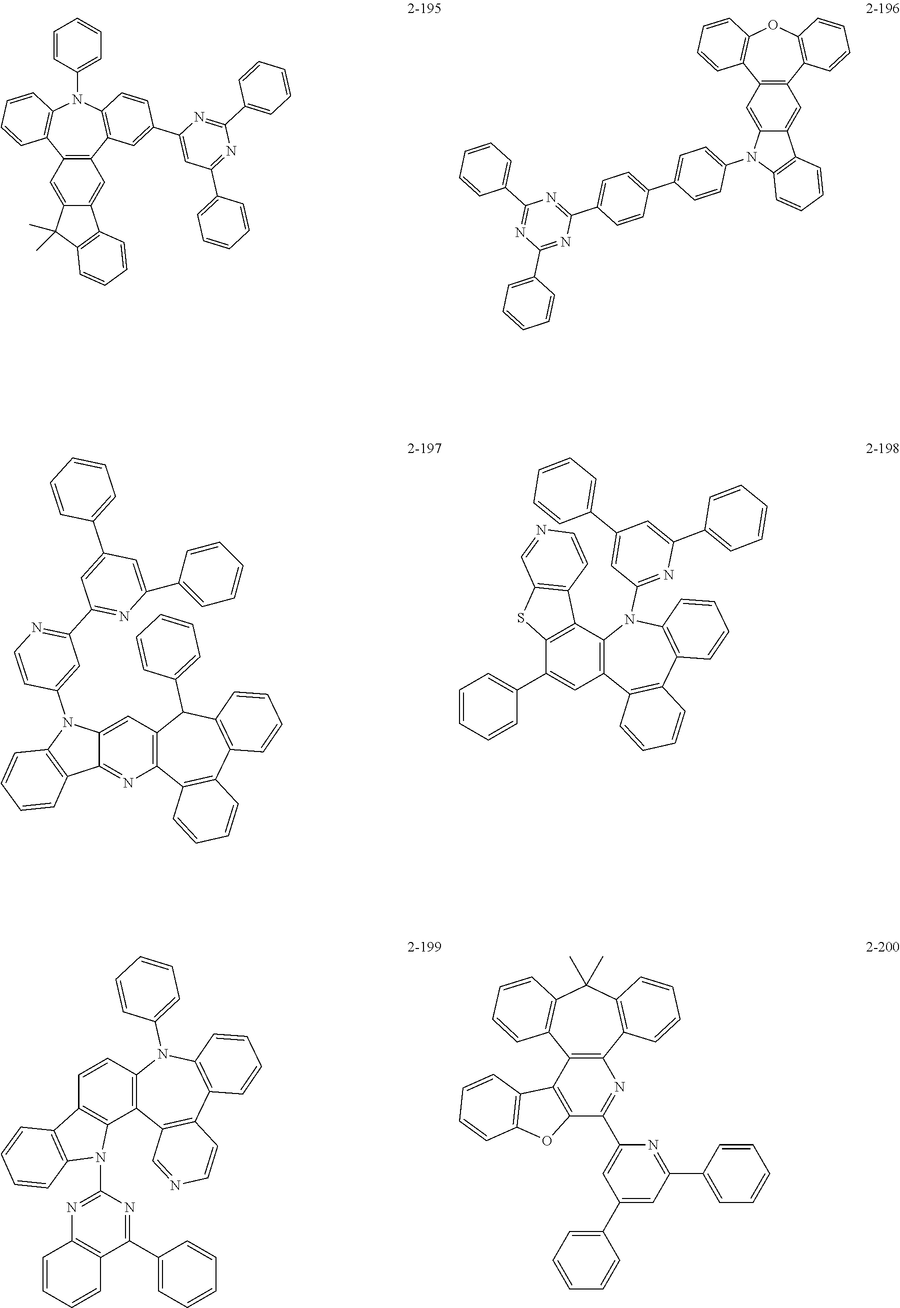

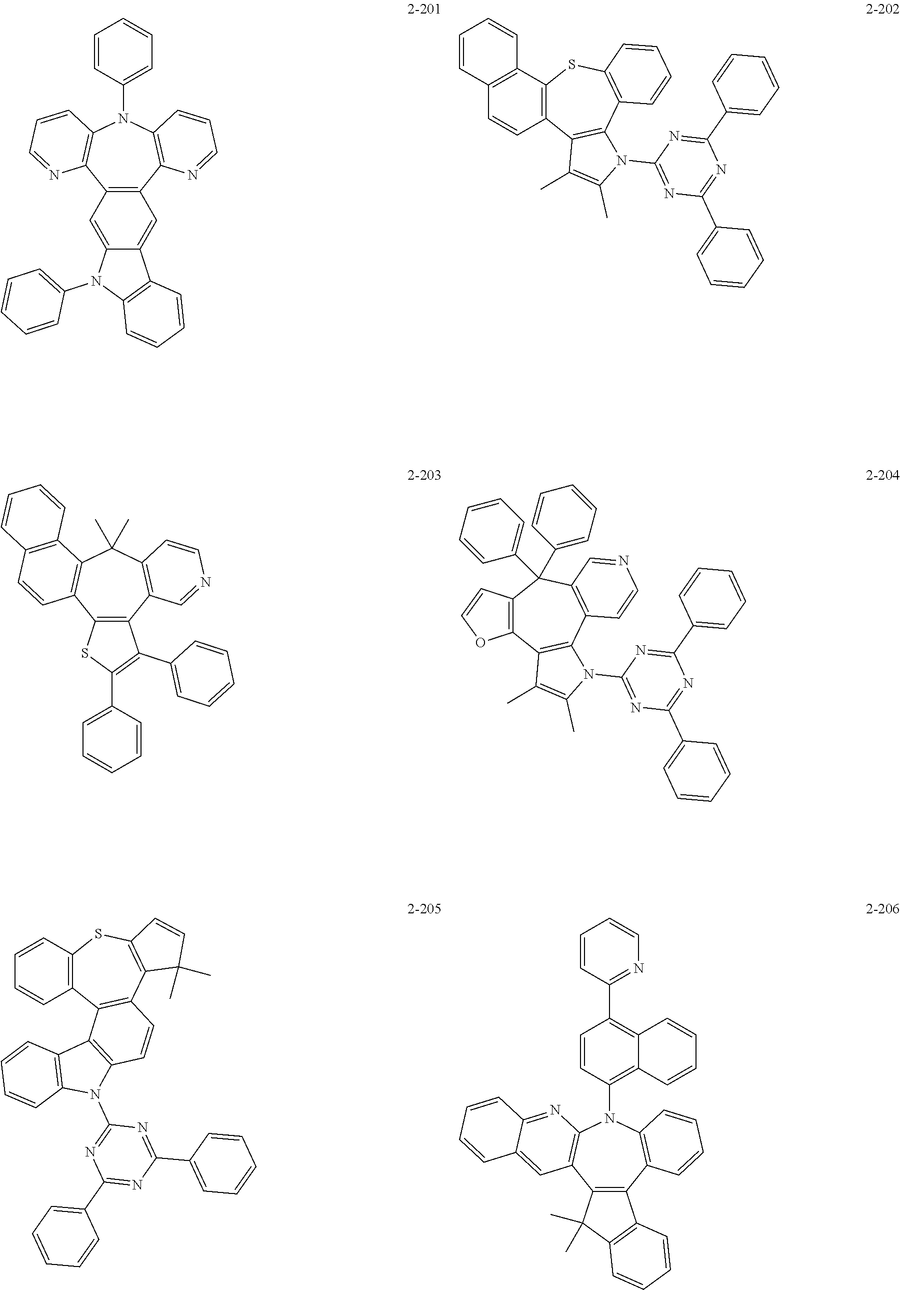 [SMILES: c1ccc(N2c3cccnc3-c3cc4c5ccccc5n(-c5ccccc5)c4cc3-c3ncccc32)cc1 ; Cc1c2c(n(-c3nc(-c4ccccc4)nc(-c4ccccc4)n3)c1C)-c1ccccc1Sc1c-2ccc2ccccc12 ; CC1(C)c2ccncc2-c2c(sc(-c3ccccc3)c2-c2ccccc2)-c2ccc3ccccc3c21 ; Cc1c2c(n(-c3nc(-c4ccccc4)nc(-c4ccccc4)n3)c1C)-c1ccncc1C(c1ccccc1)(c1ccccc1)c1ccoc1-2 ; CC1(C)C=CC2=C1c1ccc3c(c1-c1ccccc1S2)c1ccccc1n3-c1nc(-c2ccccc2)nc(-c2ccccc2)n1 ; CC1(C)C2=C(c3ccccc3N(c3ccc(-c4ccccn4)c4ccccc34)c3nc4ccccc4cc32)c2ccccc21]

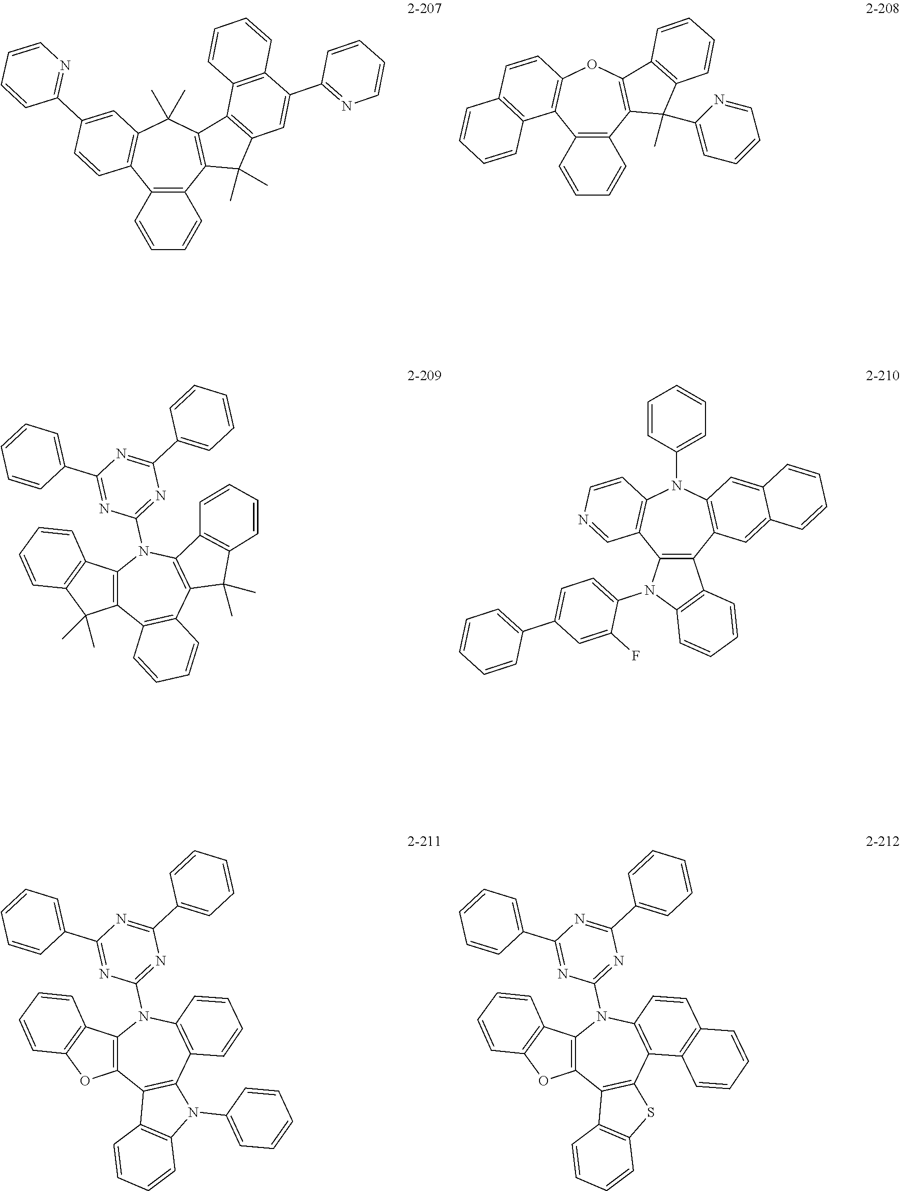 [SMILES: CC1(C)C2=C(c3ccccc3-c3ccc(-c4ccccn4)cc31)C(C)(C)c1cc(-c3ccccn3)c3ccccc3c12 ; CC1(c2ccccn2)C2=C(Oc3ccc4ccccc4c3-c3ccccc32)c2ccccc21 ; CC1(C)C2=C(c3ccccc31)N(c1nc(-c3ccccc3)nc(-c3ccccc3)n1)C1=C(c3ccccc32)C(C)(C)c2ccccc21 ; Fc1cc(-c2ccccc2)ccc1-n1c2c(c3ccccc31)-c1cc3ccccc3cc1N(c1ccccc1)c1ccncc1-2 ; c1ccc(-c2nc(-c3ccccc3)nc(N3c4ccccc4-c4c(c5ccccc5n4-c4ccccc4)-c4oc5ccccc5c43)n2)cc1 ; c1ccc(-c2nc(-c3ccccc3)nc(N3c4ccc5ccccc5c4-c4sc5ccccc5c4-c4oc5ccccc5c43)n2)cc1]

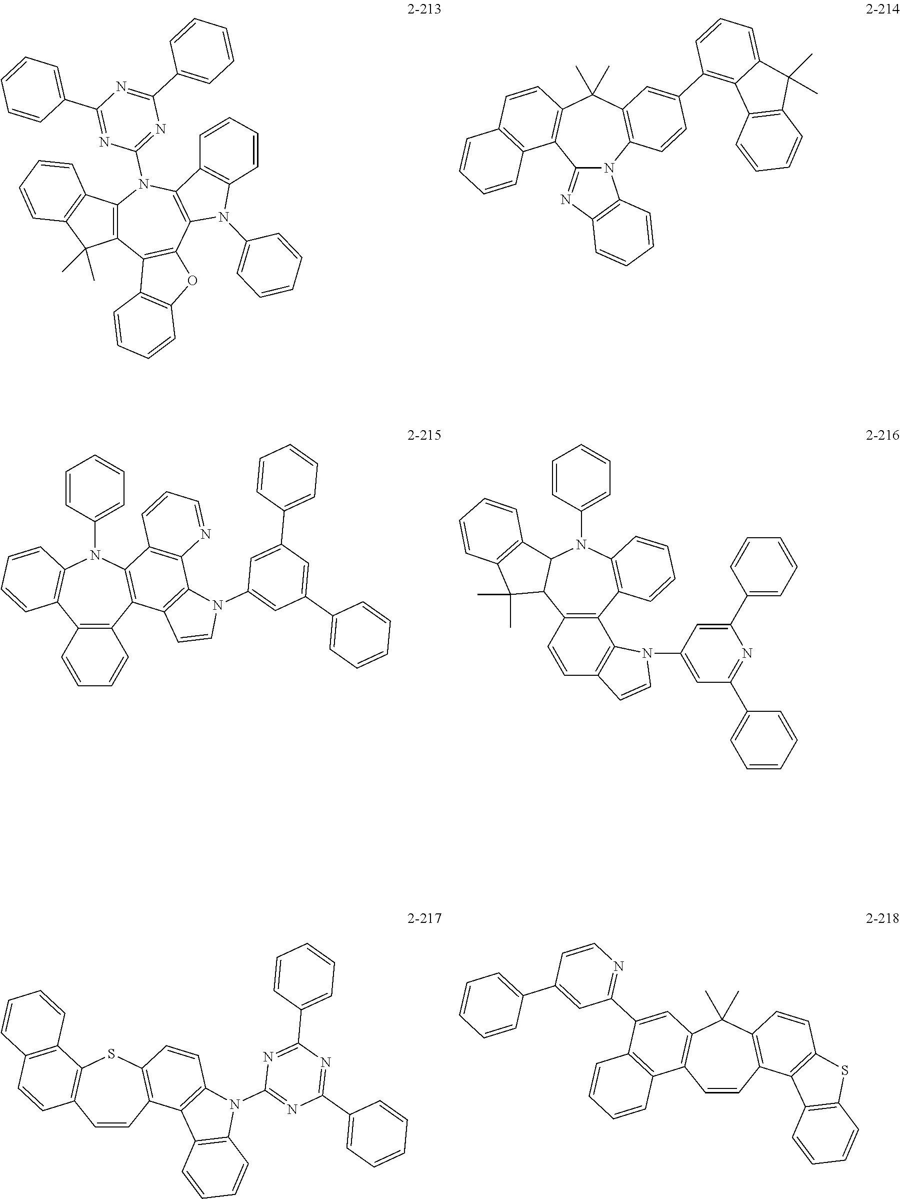 [SMILES: CC1(C)C2=C(c3ccccc31)N(c1nc(-c3ccccc3)nc(-c3ccccc3)n1)c1c(n(-c3ccccc3)c3ccccc13)-c1oc3ccccc3c12 ; CC1(C)c2ccccc2-c2c(-c3ccc4c(c3)C(C)(C)c3ccc5ccccc5c3-c3nc5ccccc5n3-4)cccc21 ; c1ccc(-c2cc(-c3ccccc3)cc(-n3ccc4c5c(c6cccnc6c43)N(c3ccccc3)c3ccccc3-c3ccccc3-5)c2)cc1 ; CC1(C)c2ccccc2C2C1c1ccc3ccn(-c4cc(-c5ccccc5)nc(-c5ccccc5)c4)c3c1-c1ccccc1N2c1ccccc1 ; C1=Cc2c(ccc3c2c2ccccc2n3-c2nc(-c3ccccc3)nc(-c3ccccc3)n2)Sc2c1ccc1ccccc21 ; CC1(C)c2cc(-c3cc(-c4ccccc4)ccn3)c3ccccc3c2C=Cc2c1ccc1sc3ccccc3c21]

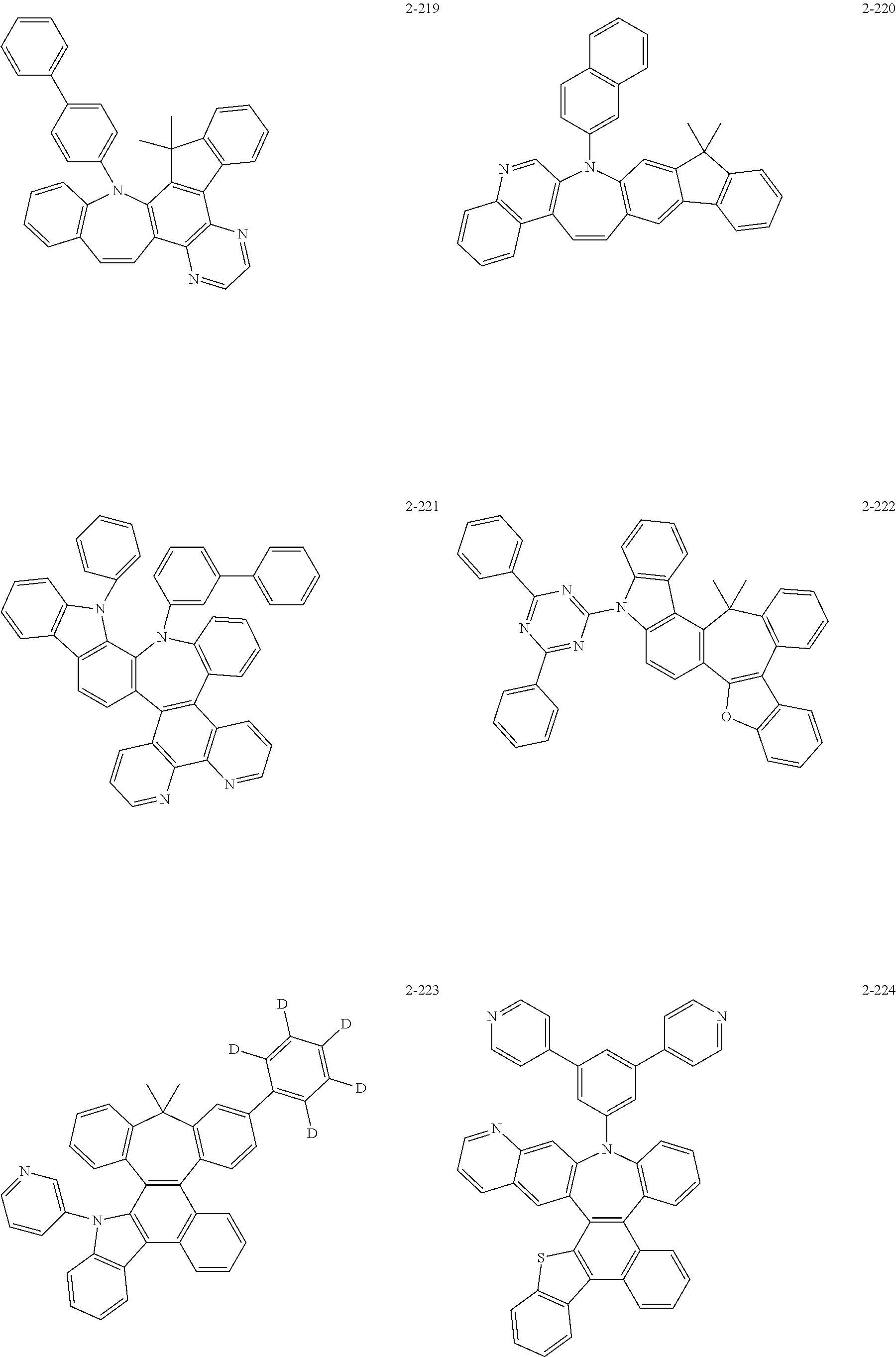 [SMILES: CC1(C)c2ccccc2-c2c1c1c(c3nccnc23)C=Cc2ccccc2N1c1ccc(-c2ccccc2)cc1 ; CC1(C)c2ccccc2-c2cc3c(cc21)N(c1ccc2ccccc2c1)c1cnc2ccccc2c1C=C3 ; c1ccc(-c2cccc(N3c4ccccc4-c4c(c5cccnc5c5ncccc45)-c4ccc5c6ccccc6n(-c6ccccc6)c5c43)c2)cc1 ; CC1(C)c2ccccc2-c2c(oc3ccccc23)-c2ccc3c(c21)c1ccccc1n3-c1nc(-c2ccccc2)nc(-c2ccccc2)n1 ; [2H]c1c([2H])c([2H])c(-c2ccc3c(c2)C(C)(C)c2ccccc2-c2c-3c3ccccc3c3c4ccccc4n(-c4cccnc4)c23)c([2H])c1[2H] ; c1ccc2c(c1)-c1c(c3sc4ccccc4c3c3ccccc13)-c1cc3cccnc3cc1N2c1cc(-c2ccncc2)cc(-c2ccncc2)c1]

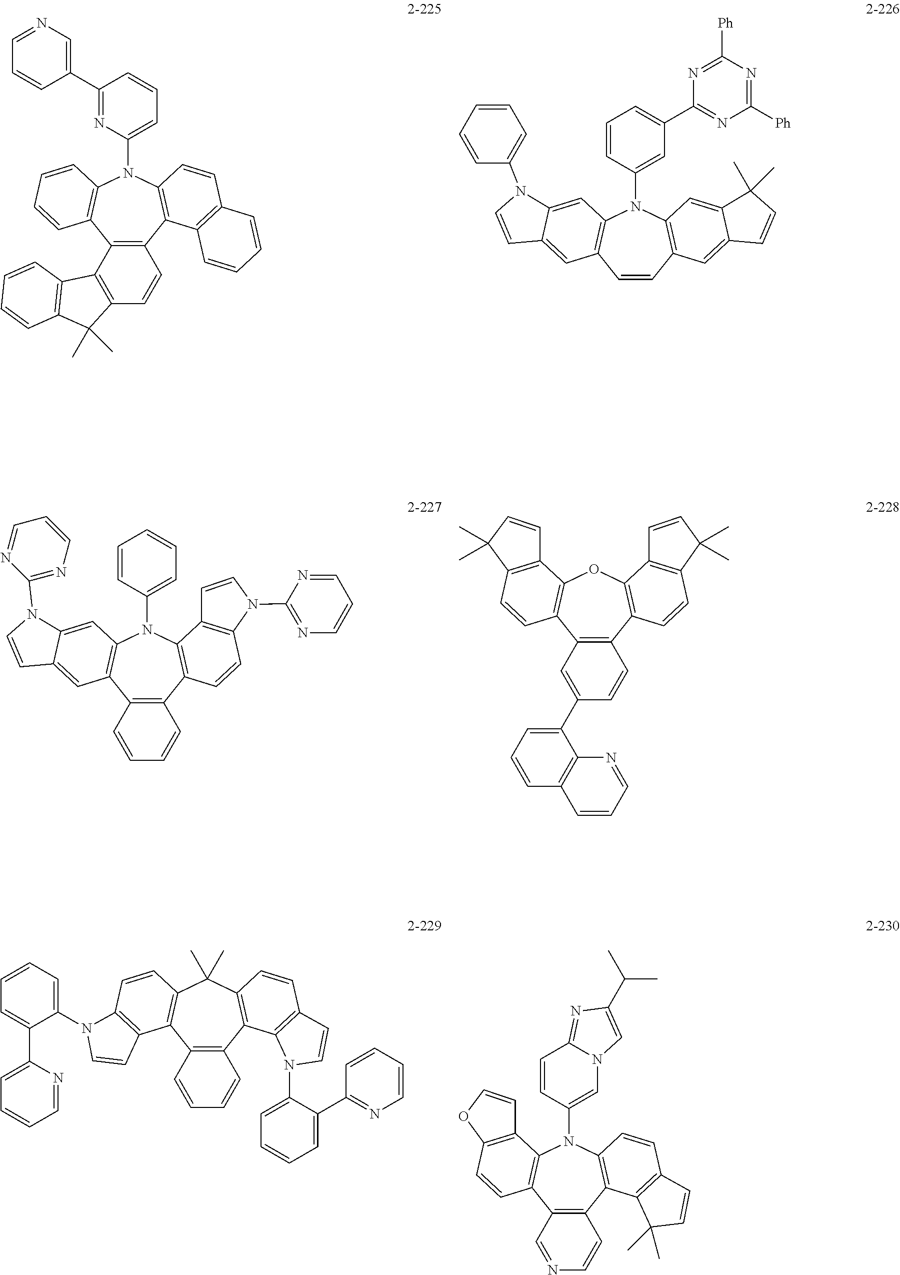

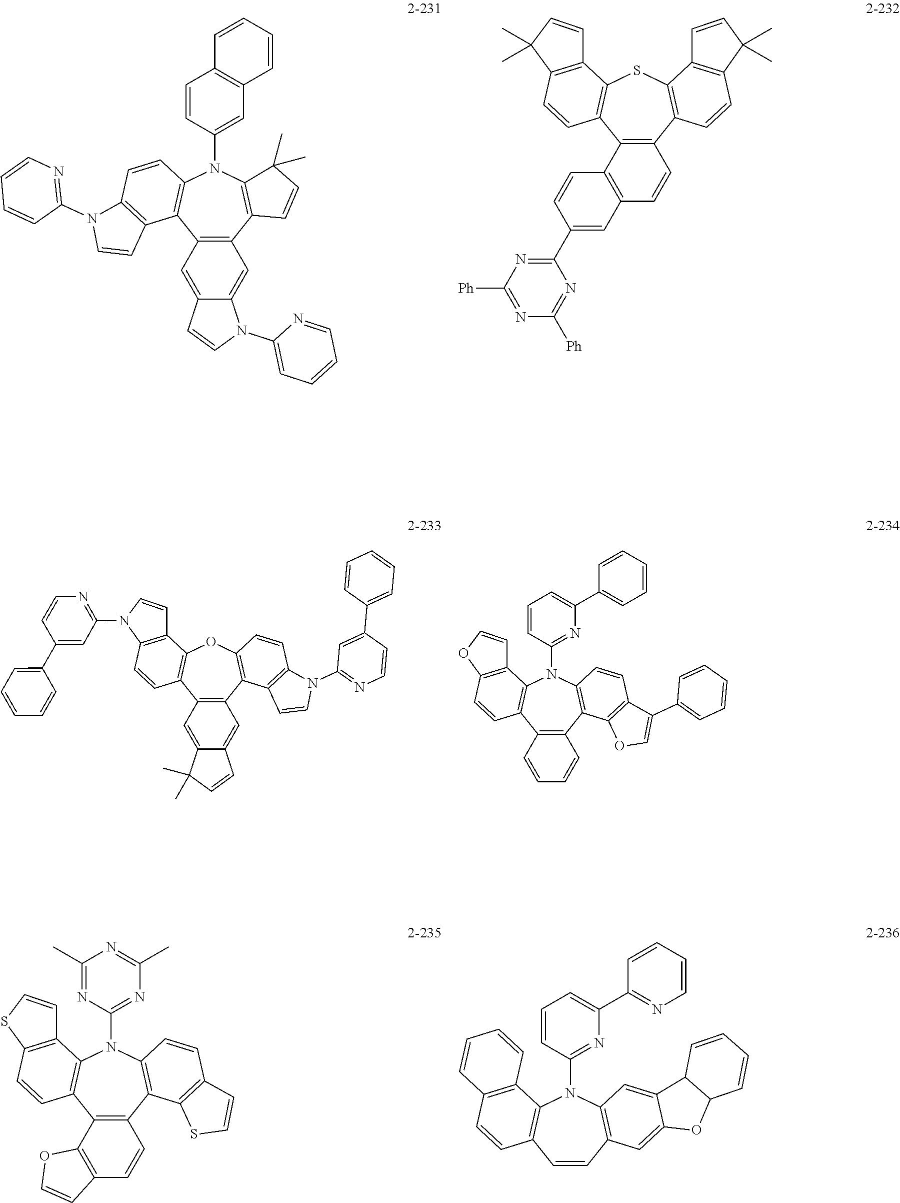 [SMILES: CC1(C)C=CC2=C1N(c1ccc3ccccc3c1)c1ccc3c(ccn3-c3ccccn3)c1-c1cc3ccn(-c4ccccn4)c3cc12 ; CC1(C)C=Cc2c1ccc1c2Sc2c(ccc3c2C=CC3(C)C)-c2c-1ccc1cc(-c3nc(-c4ccccc4)nc(-c4ccccc4)n3)ccc21 ; CC1(C)C=Cc2cc3c(cc21)-c1ccc2c(ccn2-c2cc(-c4ccccc4)ccn2)c1Oc1ccc2c(ccn2-c2cc(-c4ccccc4)ccn2)c1-3 ; c1ccc(-c2cccc(N3c4ccc5c(-c6ccccc6)coc5c4-c4ccccc4-c4ccc5occc5c43)n2)cc1 ; Cc1nc(C)nc(N2c3ccc4ccsc4c3-c3ccc4ccoc4c3-c3ccc4sccc4c32)n1 ; C1=CC2Oc3cc4c(cc3C2C=C1)N(c1cccc(-c2ccccn2)n1)c1c(ccc2ccccc12)C=C4]

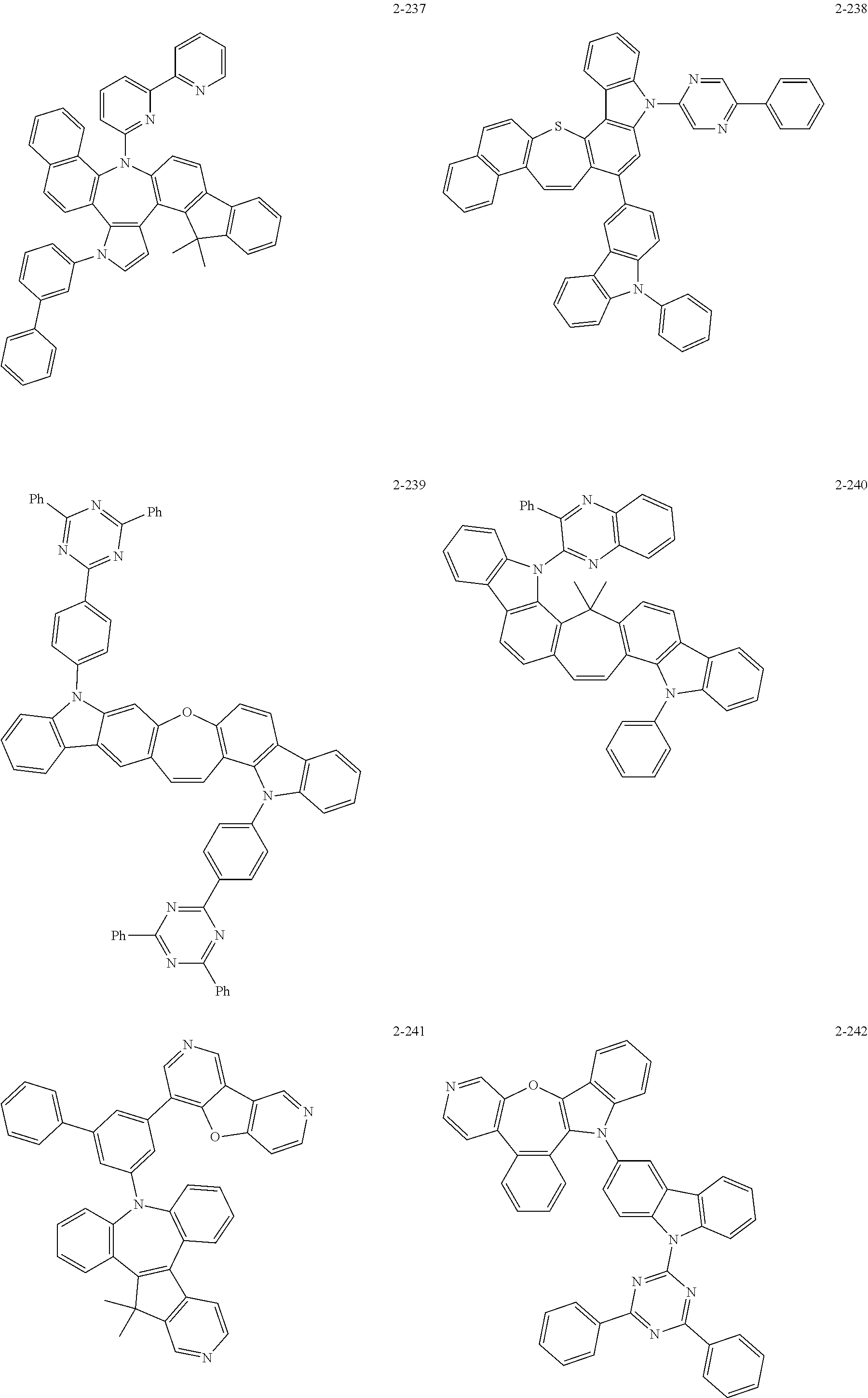

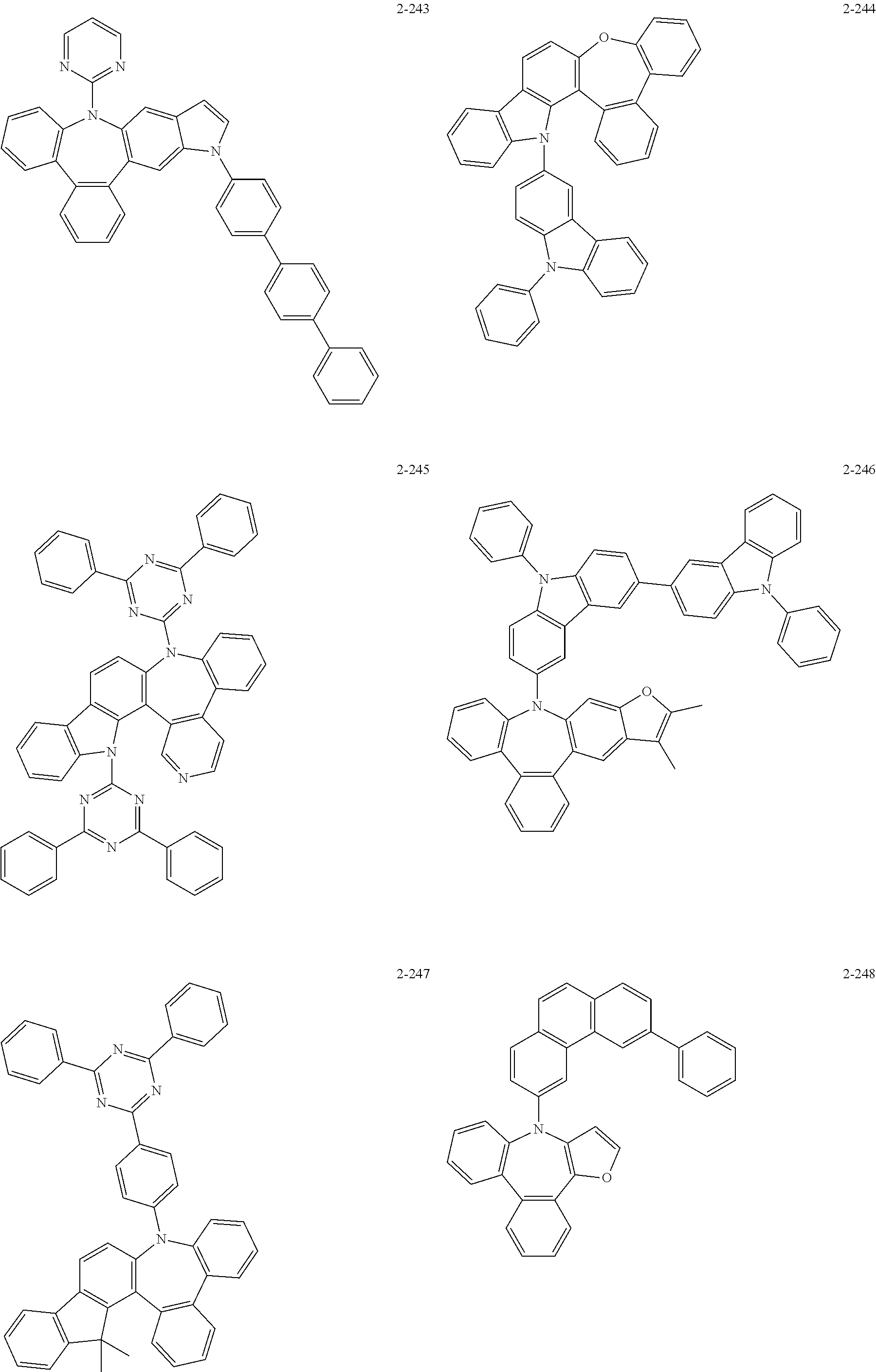

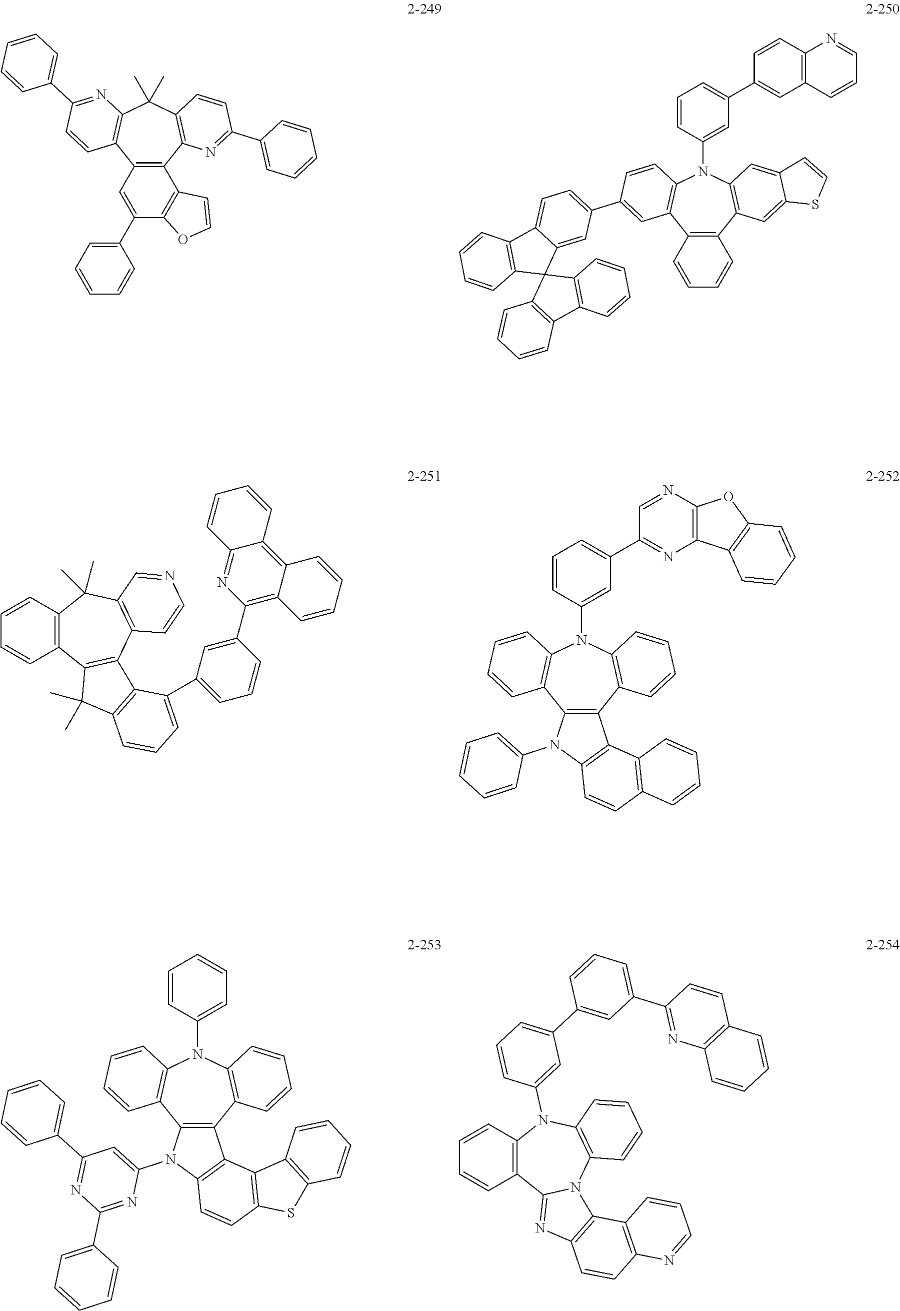

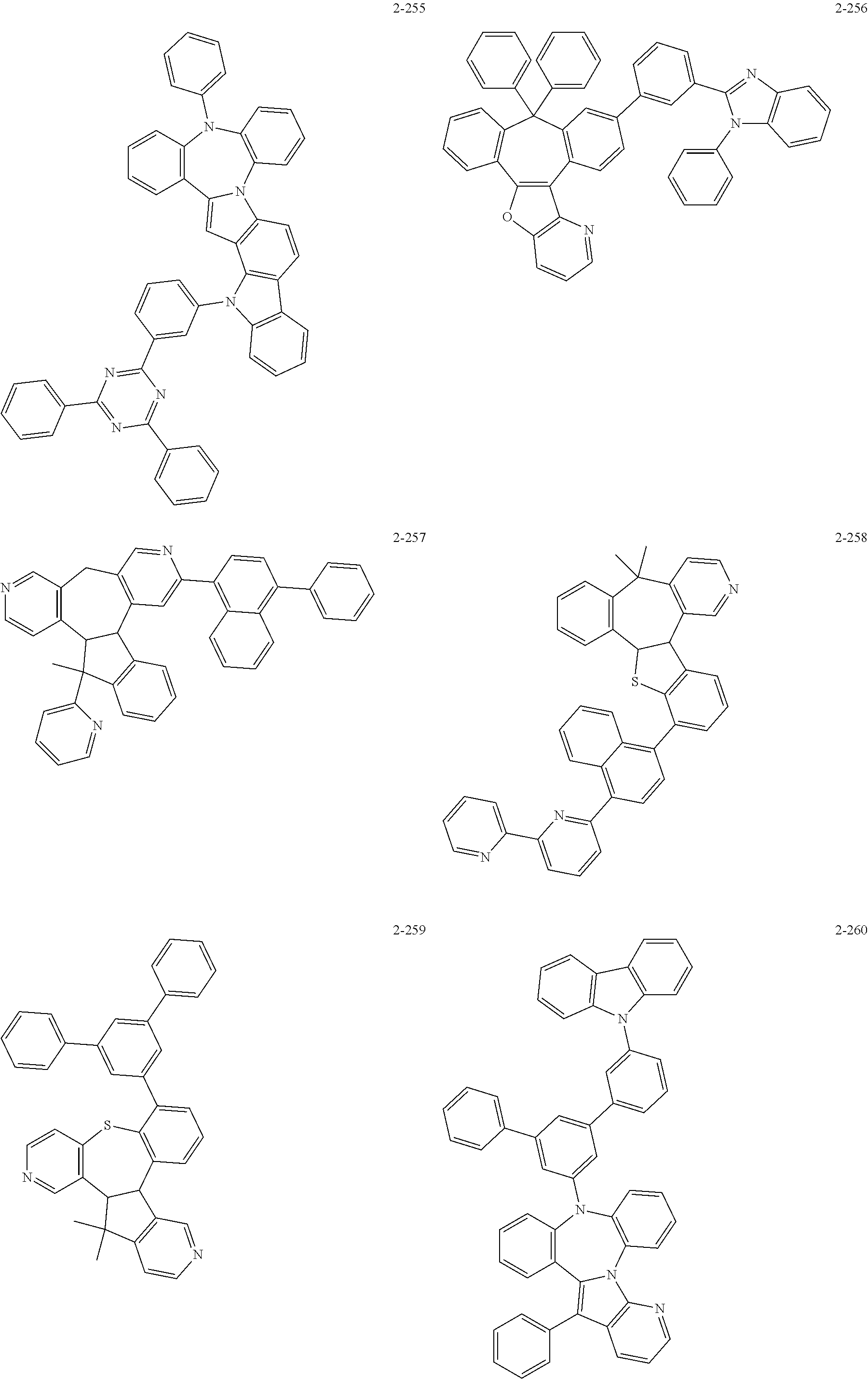

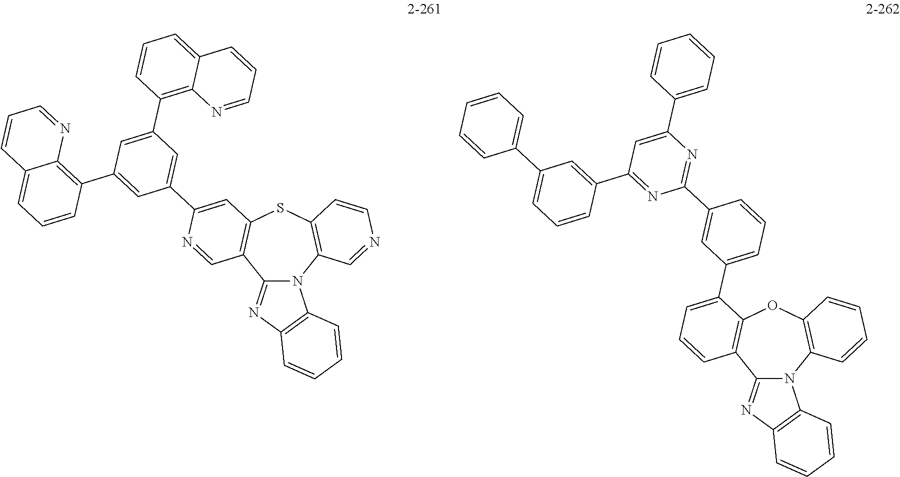 [SMILES: c1cnc2c(-c3cc(-c4cc5c(cn4)-c4nc6ccccc6n4-c4cnccc4S5)cc(-c4cccc5cccnc45)c3)cccc2c1 ; c1ccc(-c2cccc(-c3cc(-c4ccccc4)nc(-c4cccc(-c5cccc6c5Oc5ccccc5-n5c-6nc6ccccc65)c4)n3)c2)cc1]

In Formulae 1A to 1E, any suitable combination of ring A₁₁, ring A₁₂, ring A₁₃, X₁₁, X₁₂, L₁ to L₉, a1 to a9, R₁ to R₉, b1 to b9, and c1 to c9 may be used within the scope described herein.

In Formulae 2A and 2B, any suitable combination of ring A₂₁, ring A₂₂, ring A₂₃, X₂₁, and T₁₁ to T₁₄ may be used within the scope described herein. Regarding *-[(L₂₂)ₐ₂₂-(R₂₂)_{b22}], C(R₂₃)(R₂₄), Si(R₂₃)(R₂₄), and N-[(L₂₁)ₐ₂₁-(R₂₁)_{b21}], any suitable combination of L₂₁, L₂₂, a21, a22, R₂₁ to R₂₄, b21, and b22 may be used within the scope described herein.

In the organic light-emitting device, the emission layer may include the first compound, and at least one selected from the hole transport region and the electron transport region may include the second compound represented by Formula 2A or 2B. Accordingly, electrons and/or holes injected into or transported to the emission layer may be easily balanced to prevent current leakage, thereby enabling low driving voltage and high efficiency characteristics.

In one embodiment, the second compound represented by Formula 2A or 2B may have a triplet energy of 2.2 eV or more, for example, 2.3 eV or more, and in some embodiments, 2.4 eV or more.

When the second compound represented by Formula 2A or 2B satisfies these triplet energy ranges, for example, the luminescent efficiency of a fluorescent organic light-emitting device may be improved due to triplet-triplet fusion (TTF), or triplet excitons formed in the emission layer of a phosphorescent organic light-emitting device may not be transitioned (e.g., the probability of triplet exciton loss may be reduced), thereby preventing or reducing a decrease in efficiency of an organic light-emitting device.

In one embodiment, the emission layer may include the first compound represented by one selected from Formulae 1A to 1E as a first host.

In one embodiment, the emission layer may further include, in addition to the first host, a second host that is different from the first host.

In one embodiment, the hole transport region may include an emission auxiliary layer, the emission auxiliary layer may directly contact the emission layer, and the emission auxiliary layer may include the second compound represented by Formula 2A or 2B.

In one or more embodiments, the electron transport region may include a buffer layer, the buffer layer may directly contact the emission layer, and the buffer layer may include the second compound represented by Formula 2A or 2B, but embodiments of the hole transport region and the electron transport region are not limited thereto.

When each of the hole transport region and the electron transport region in the organic light-emitting device includes the second compound represented by Formula 2A or 2B, the second compound included in the hole transport region may be identical to or different from the second compound included in the electron transport region.

The emission layer may include a dopant, and the dopant may be an organometallic complex.

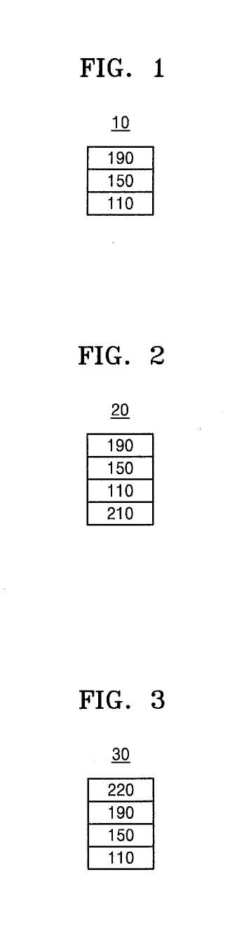

### Description of FIG. 1

FIG. 1 is a schematic view of an organic light-emitting device 10 according to an embodiment of the present disclosure. The organic light-emitting device 10 includes a first electrode 110, an organic layer 150, and a second electrode 190.

Hereinafter, the structure of the organic light-emitting device 10 according to an embodiment of the present disclosure and a method of manufacturing the organic light-emitting device 10 will be described in connection with FIG. 1.

### First Electrode 110

In FIG. 1, a substrate may be under the first electrode 110 or above the second electrode 190. The substrate may be a glass substrate or a plastic substrate, each having excellent mechanical strength, thermal stability, transparency, surface smoothness, ease of handling, and/or water-resistance.

The first electrode 110 may be formed by depositing and/or sputtering a material for forming the first electrode 110 on the substrate. When the first electrode 110 is an anode, the material for forming the first electrode 110 may be selected from materials with a high work function in order to facilitate hole injection.

The first electrode 110 may be a reflective electrode, a semi-transmissive electrode, or a transmissive electrode. When the first electrode 110 is a transmissive electrode, the material for forming the first electrode may be selected from indium tin oxide (ITO), indium zinc oxide (IZO), tin oxide (SnO₂), zinc oxide (ZnO), and combinations thereof, but embodiments of the present disclosure are not limited thereto. When the first electrode 110 is a semi-transmissive electrode or a reflective electrode, the material for forming the first electrode 110 may be selected from magnesium (Mg), silver (Ag), aluminum (Al), aluminum-lithium (Al—Li), calcium (Ca), magnesium-indium (Mg—In), magnesium-silver (Mg—Ag), and combinations thereof. However, embodiments of the material for forming the first electrode 110 are not limited thereto.

The first electrode 110 may have a single-layer structure, or a multi-layer structure including two or more layers. For example, the first electrode 110 may have a three-layered structure of ITO/Ag/ITO, but embodiments of the structure of the first electrode 110 are not limited thereto.

### Organic Layer 150

The organic layer 150 is on the first electrode 110. The organic layer 150 may include an emission layer.

The organic layer 150 may include a hole transport region between the first electrode 110 and the emission layer, and an electron transport region between the emission layer and the second electrode 190.

### Hole Transport Region in Organic Layer 150

The hole transport region may have i) a single-layered structure including a single layer including a single material, ii) a single-layered structure including a single layer including a plurality of different materials, or iii) a multi-layered structure having a plurality of layers including a plurality of different materials.

The hole transport region may include at least one layer selected from a hole injection layer, a hole transport layer, an emission auxiliary layer, and an electron blocking layer.

For example, the hole transport region may have a single-layer structure including a single layer including a plurality of different materials, or a multi-layer structure having a structure of hole injection layer/hole transport layer, hole injection layer/hole transport layer/emission auxiliary layer, hole injection layer/emission auxiliary layer, hole transport layer/emission auxiliary layer, or hole injection layer/hole transport layer/electron blocking layer, wherein layers of each structure are sequentially stacked on the first electrode 110 in each stated order, but embodiments of the structure of the hole transport region are not limited thereto.

The hole transport region may include the second compound represented by Formula 2A or 2B as described above.

In one embodiment, the hole transport region may include an emission auxiliary layer. The emission auxiliary layer may directly contact the emission layer.

In one or more embodiments, the hole transport region may include a hole injection layer and a hole transport layer stacked in this stated order on the first electrode 110, a hole injection layer and an emission auxiliary layer stacked in this stated order on the first electrode 110, or a hole injection layer, a hole transport layer, and an emission auxiliary layer, stacked in this stated order on the first electrode 110, but embodiments of the present disclosure are not limited thereto.

When the hole transport region includes an emission auxiliary layer, the emission auxiliary layer may further include the second compound represented by Formula 2A or 2B.

The hole transport region may include at least one selected from m-MTDATA, TDATA, 2-TNATA, NPB(NPD), β-NPB, TPD, Spiro-TPD, Spiro-NPB, methylated NPB, TAPC, HMTPD, 4,4′,4″-tris(N-carbazolyl)triphenylamine (TCTA), polyaniline/dodecylbenzenesulfonic acid (PAN I/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), a compound represented by Formula 201, and a compound represented by Formula 202:

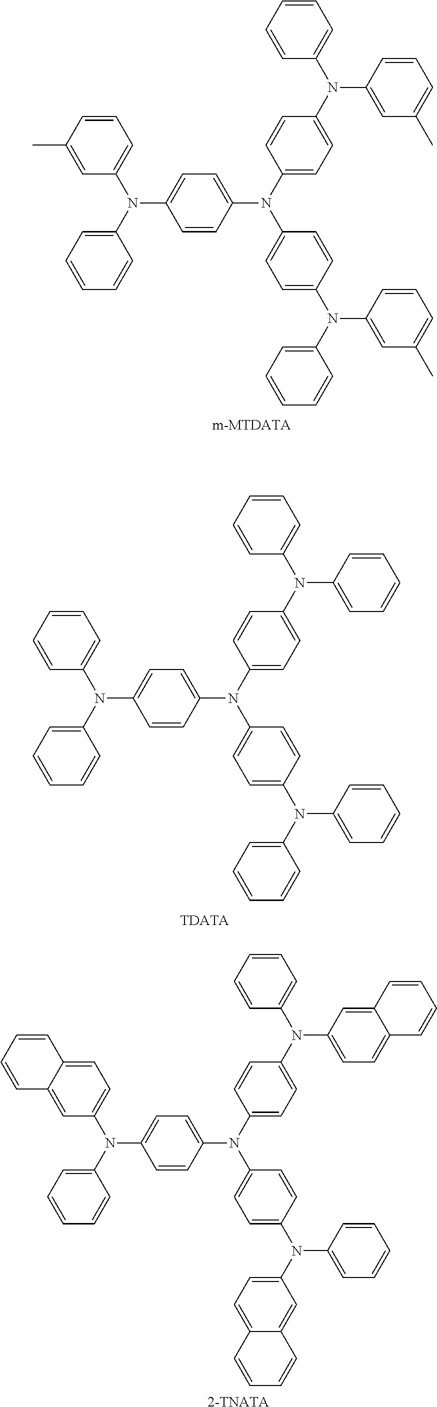

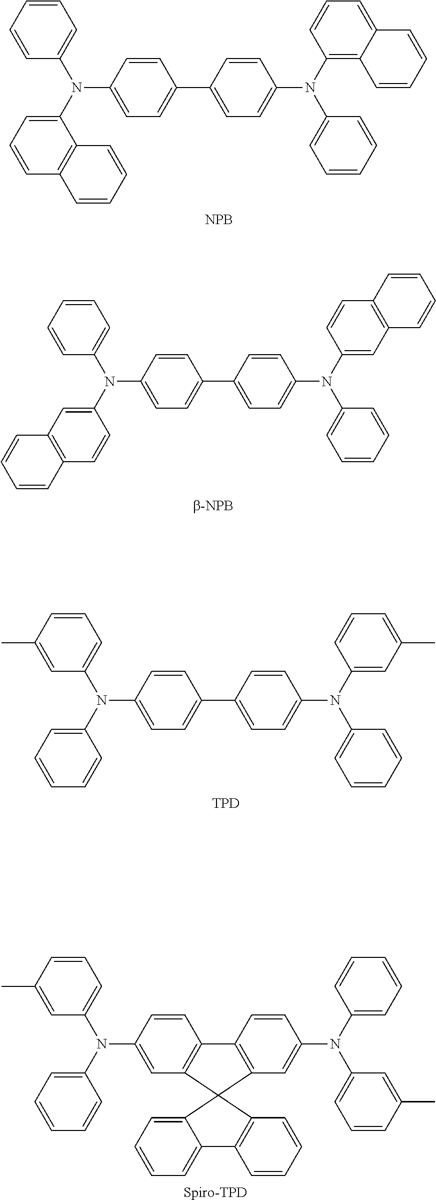

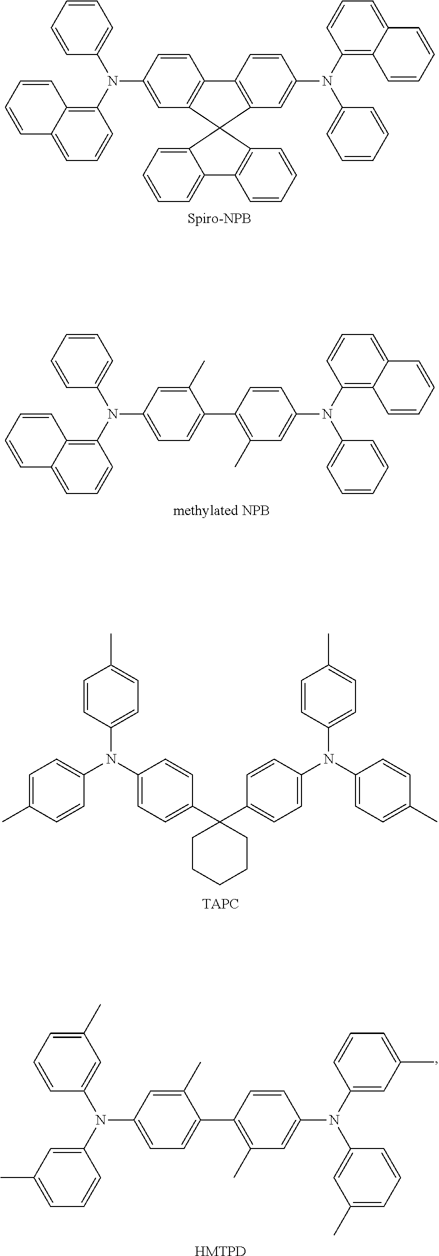

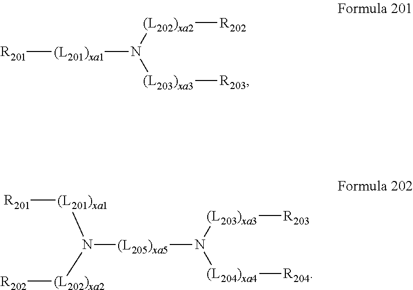

In Formulae 201 and 202,

L₂₀₁ to L₂₀₄ may each independently be selected from a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed heteropolycyclic group,

L₂₀₅ may be selected from *—O—*′, *—S—*′, *—N(Q₂₀₁)-*′, a substituted or unsubstituted C₁-C₂₀ alkylene group, a substituted or unsubstituted C₂-C₂₀ alkenylene group, a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed heteropolycyclic group,

xa1 to xa4 may each independently be an integer selected from 0 to 3,

xa5 may be an integer selected from 1 to 10, and

R₂₀₁ to R₂₀₄ and Q₂₀₁ may each independently be selected from a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group.

For example, R₂₀₁ and R₂₀₂ in Formula 202 may be optionally linked (e.g., coupled) via a single bond, a dimethyl-methylene group, or a diphenyl-methylene group, and R₂₀₃ and R₂₀₄ may be optionally linked (e.g., coupled) via a single bond, a dimethyl-methylene group, or a diphenyl-methylene group.

In one embodiment, in Formulae 201 and 202,

L₂₀₁ to L₂₀₅ may each independently be selected from the group consisting of:

a phenylene group, a pentalenylene group, an indenylene group, a naphthylene group, an azulenylene group, a heptalenylene group, an indacenylene group, an acenaphthylene group, a fluorenylene group, a spiro-bifluorenylene group, a benzofluorenylene group, a dibenzofluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, a pentacenylene group, a rubicenylene group, a coronenylene group, an ovalenylene group, a thiophenylene group, a furanylene group, a carbazolylene group, an indolylene group, an isoindolylene group, a benzofuranylene group, a benzothiophenylene group, a dibenzofuranylene group, a dibenzothiophenylene group, a benzocarbazolylene group, a dibenzocarbazolylene group, a dibenzosilolylene group, and a pyridinylene group; and

a phenylene group, a pentalenylene group, an indenylene group, a naphthylene group, an azulenylene group, a heptalenylene group, an indacenylene group, an acenaphthylene group, a fluorenylene group, a spiro-bifluorenylene group, a benzofluorenylene group, a dibenzofluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, a pentacenylene group, a rubicenylene group, a coronenylene group, an ovalenylene group, a thiophenylene group, a furanylene group, a carbazolylene group, an indolylene group, an isoindolylene group, a benzofuranylene group, a benzothiophenylene group, a dibenzofuranylene group, a dibenzothiophenylene group, a benzocarbazolylene group, a dibenzocarbazolylene group, a dibenzosilolylene group, and a pyridinylene group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a biphenyl group, a terphenyl group, a phenyl group substituted with a C₁-C₁₀ alkyl group, a phenyl group substituted with —F, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, —Si(Q₃₁)(Q₃₂)(Q₃₃), and —N(Q₃₁)(Q₃₂),

wherein Q₃₁ to Q₃₃ may each independently be selected from a C₁-C₁₀ alkyl group, a C₁-C₁₀ alkoxy group, a phenyl group, a biphenyl group, a terphenyl group, and a naphthyl group.

In one or more embodiments, xa1 to xa4 may each independently be an integer selected from 0, 1, or 2.

In one or more embodiments, xa5 may be 1, 2, 3, or 4.

In one or more embodiments, R₂₀₁ to R₂₀₄ and Q₂₀₁ may each independently be selected from a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, and a pyridinyl group; and

a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, and a pyridinyl group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a biphenyl group, a terphenyl group, a phenyl group substituted with a C₁-C₁₀ alkyl group, a phenyl group substituted with —F, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, —Si(Q₃₁)(Q₃₂)(Q₃₃), and —N(Q₃₁)(Q₃₂), and

Q₃₁ to Q₃₃ may each independently be the same as described above.

In one or more embodiments, at least one selected from R₂₀₁ to R₂₀₃ in Formula 201 may be selected from the group consisting of:

a fluorenyl group, a spiro-bifluorenyl group, a carbazolyl group, a dibenzofuranyl group, and a dibenzothiophenyl group; and

a fluorenyl group, a spiro-bifluorenyl group, a carbazolyl group, a dibenzofuranyl group, and a dibenzothiophenyl group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a biphenyl group, a terphenyl group, a phenyl group substituted with a C₁-C₁₀ alkyl group, a phenyl group substituted with —F, a naphthyl group, a fluorenyl group, a spiro-bifluorenyl group, a carbazolyl group, a dibenzofuranyl group, and a dibenzothiophenyl group, but embodiments of the present disclosure are not limited thereto.

In one or more embodiments, in Formula 202, i) R₂₀₁ and R₂₀₂ may be linked (e.g., coupled) via a single bond, and/or ii) R₂₀₃ and R₂₀₄ may be linked (e.g., coupled) via a single bond.

In one or more embodiments, at least one selected from R₂₀₁ to R₂₀₄ in Formula 202 may be selected from the group consisting of:

a carbazolyl group; and

a carbazolyl group substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a biphenyl group, a terphenyl group, a phenyl group substituted with a C₁-C₁₀ alkyl group, a phenyl group substituted with —F, a naphthyl group, a fluorenyl group, a spiro-bifluorenyl group, a carbazolyl group, a dibenzofuranyl group, and a dibenzothiophenyl group, but embodiments of the present disclosure are not limited thereto.

A compound represented by Formula 201 may be represented by Formula 201A:

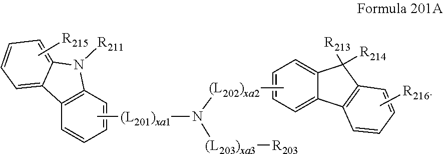

For example, the compound represented by Formula 201 may be represented by Formula 201A(1), but embodiments of the present disclosure are not limited thereto:

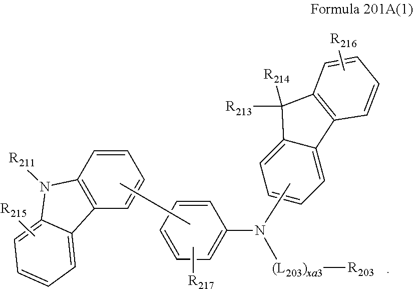

In one or more embodiments, the compound represented by Formula 201 may be represented by Formula 201A-1, but embodiments of the present disclosure are not limited thereto:

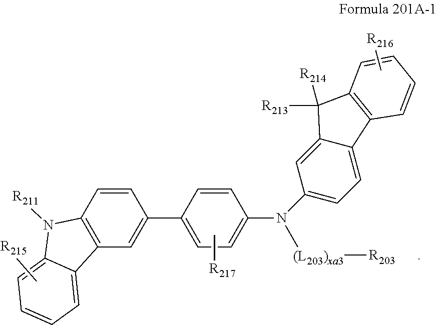

A compound represented by Formula 202 may be represented by Formula 202A:

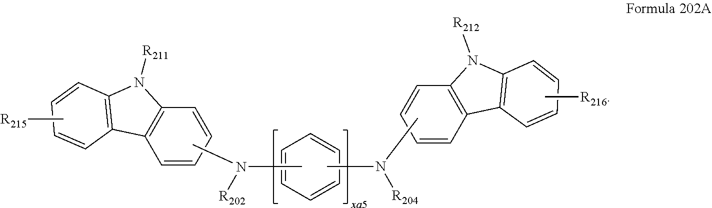

In one or more embodiments, the compound represented by Formula 202 may be represented by Formula 202A-1:

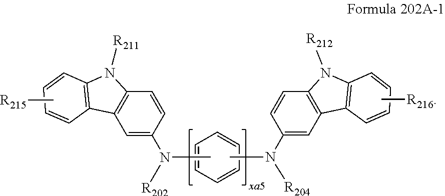

In Formulae 201A, 201A(1), 201A-1, 202A, and 202A-1,

L₂₀₁ to L₂₀₃, xa1 to xa3, xa5, and R₂₀₂ to R₂₀₄ may each independently be the same as described above,

R₂₁₁ and R₂₁₂ may each independently be the same as described herein in connection with R₂₀₃,

R₂₁₃ to R₂₁₇ may each independently be selected from hydrogen, deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a biphenyl group, a terphenyl group, a phenyl group substituted with a C₁-C₁₀ alkyl group, a phenyl group substituted with —F, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, and a pyridinyl group.

The hole transport region may include at least one compound selected from Compounds HT1 to HT39, but embodiments of the material to be included in the hole transport region are not limited thereto:

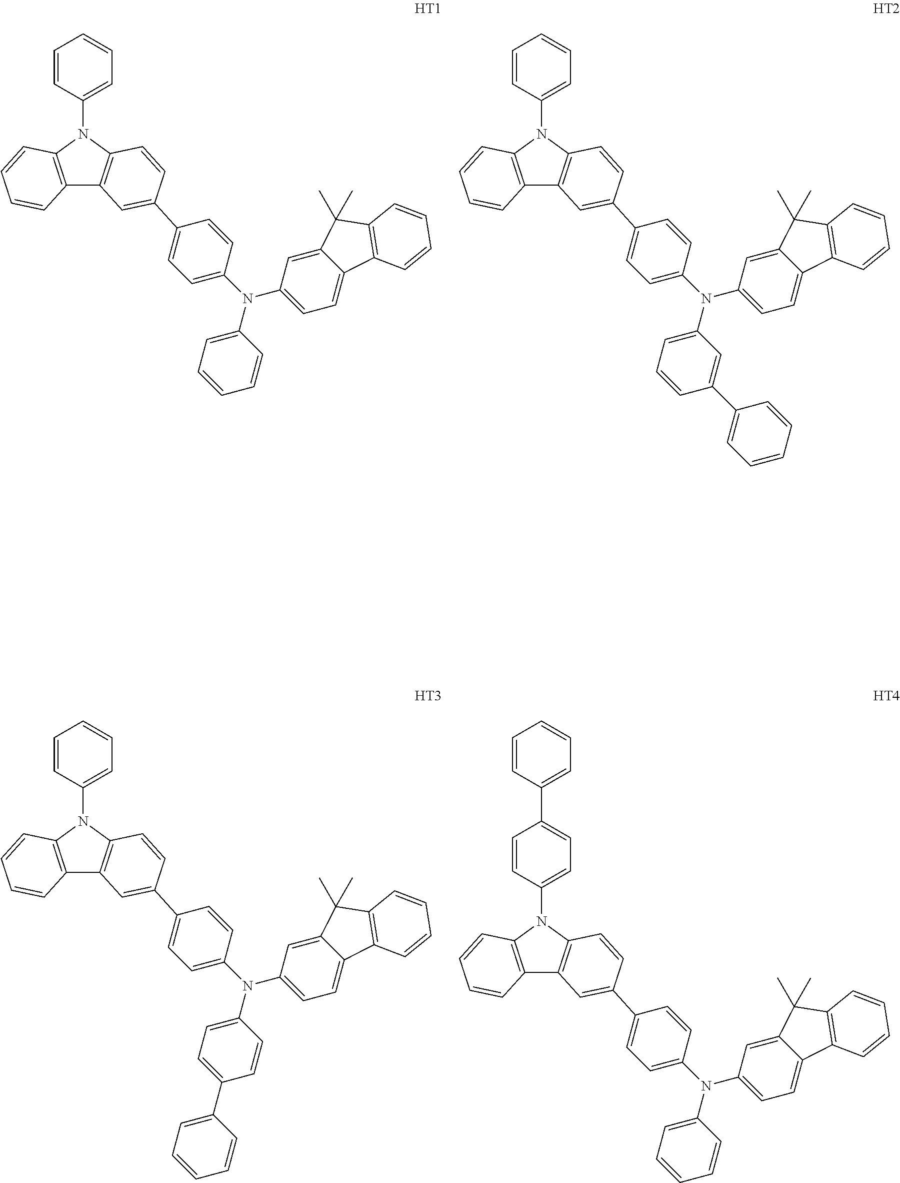

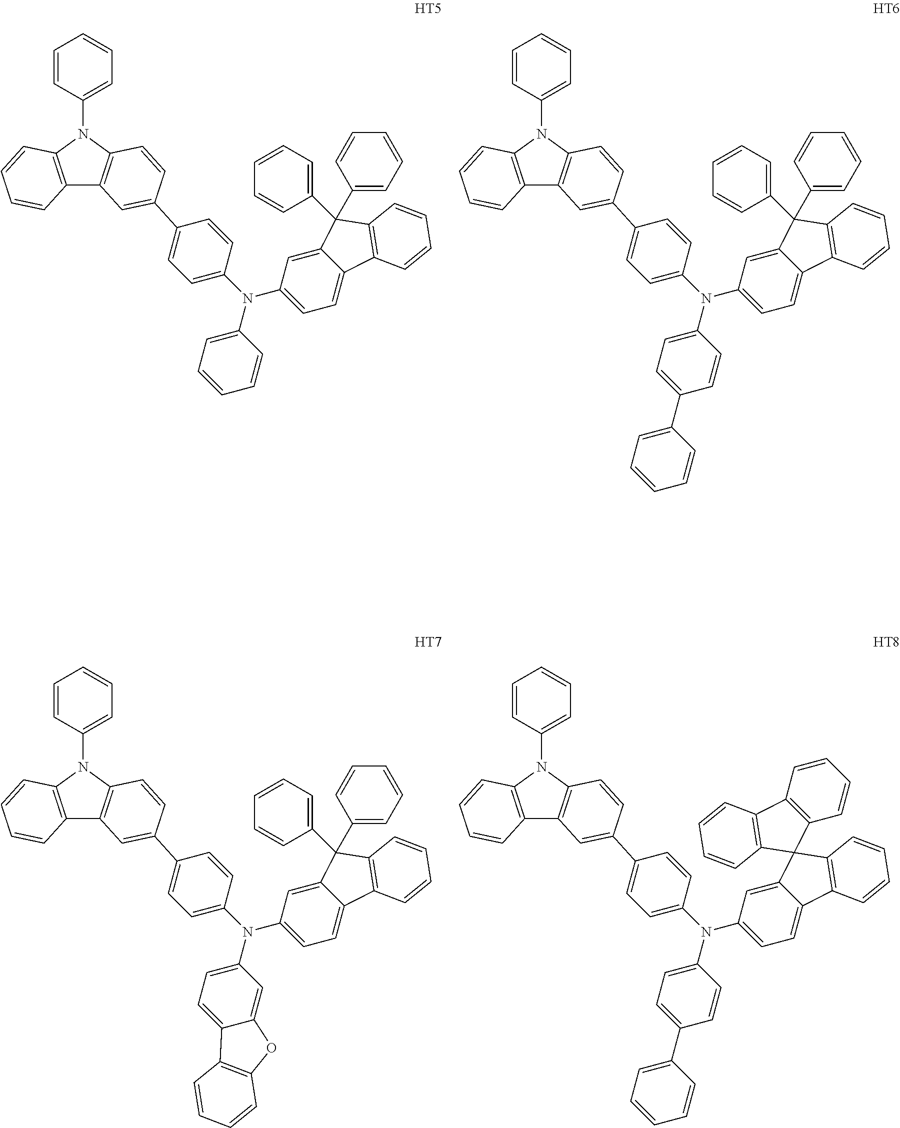

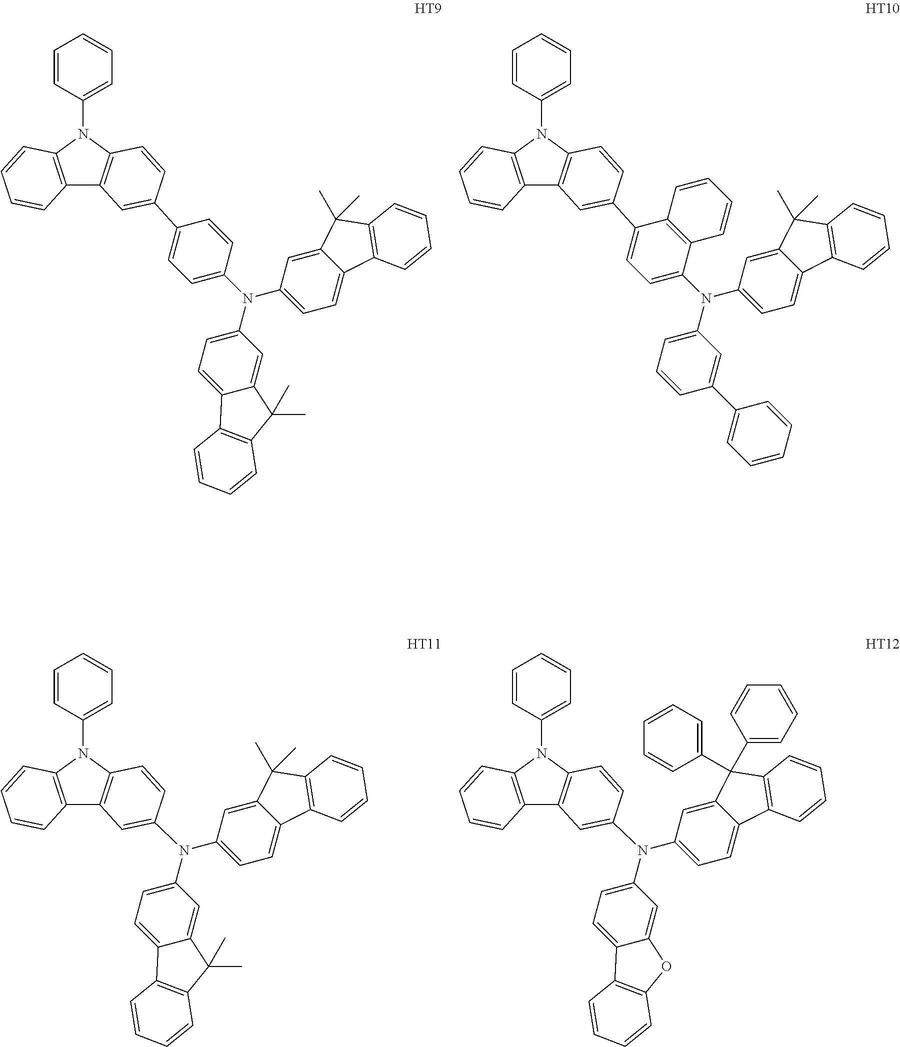

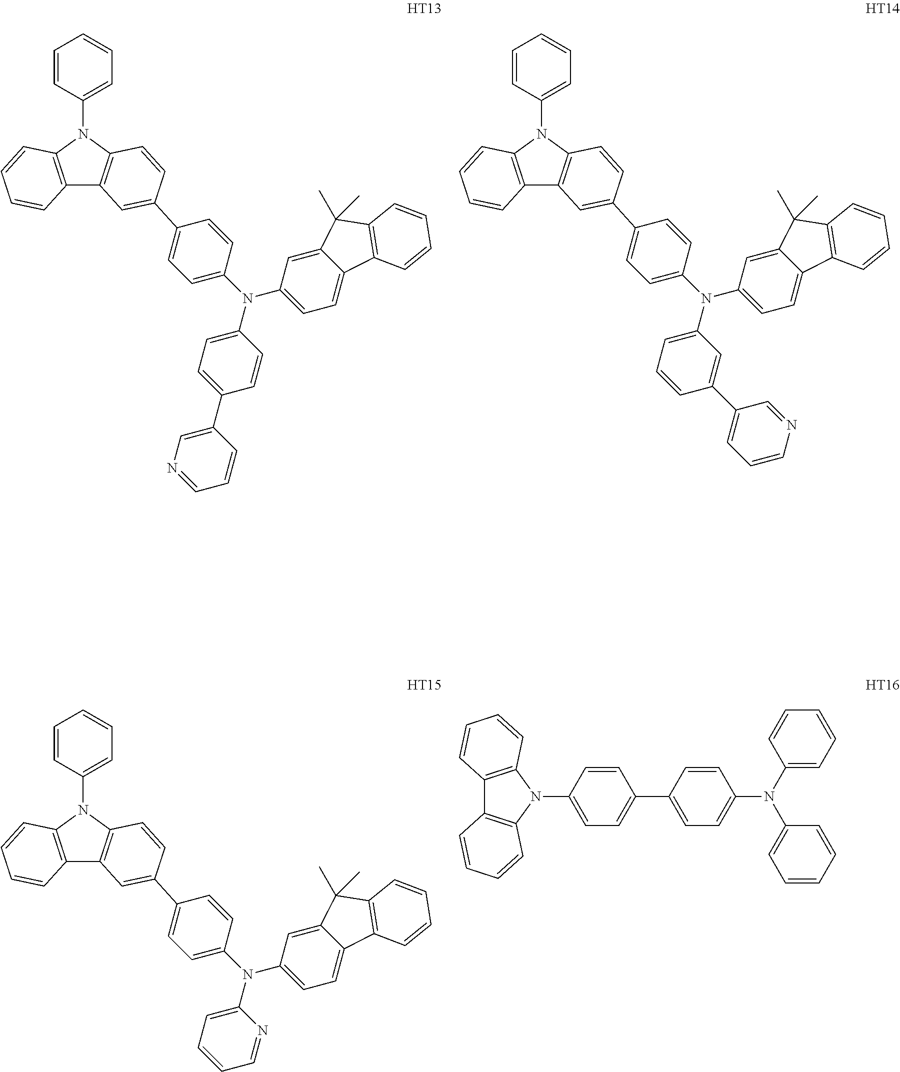

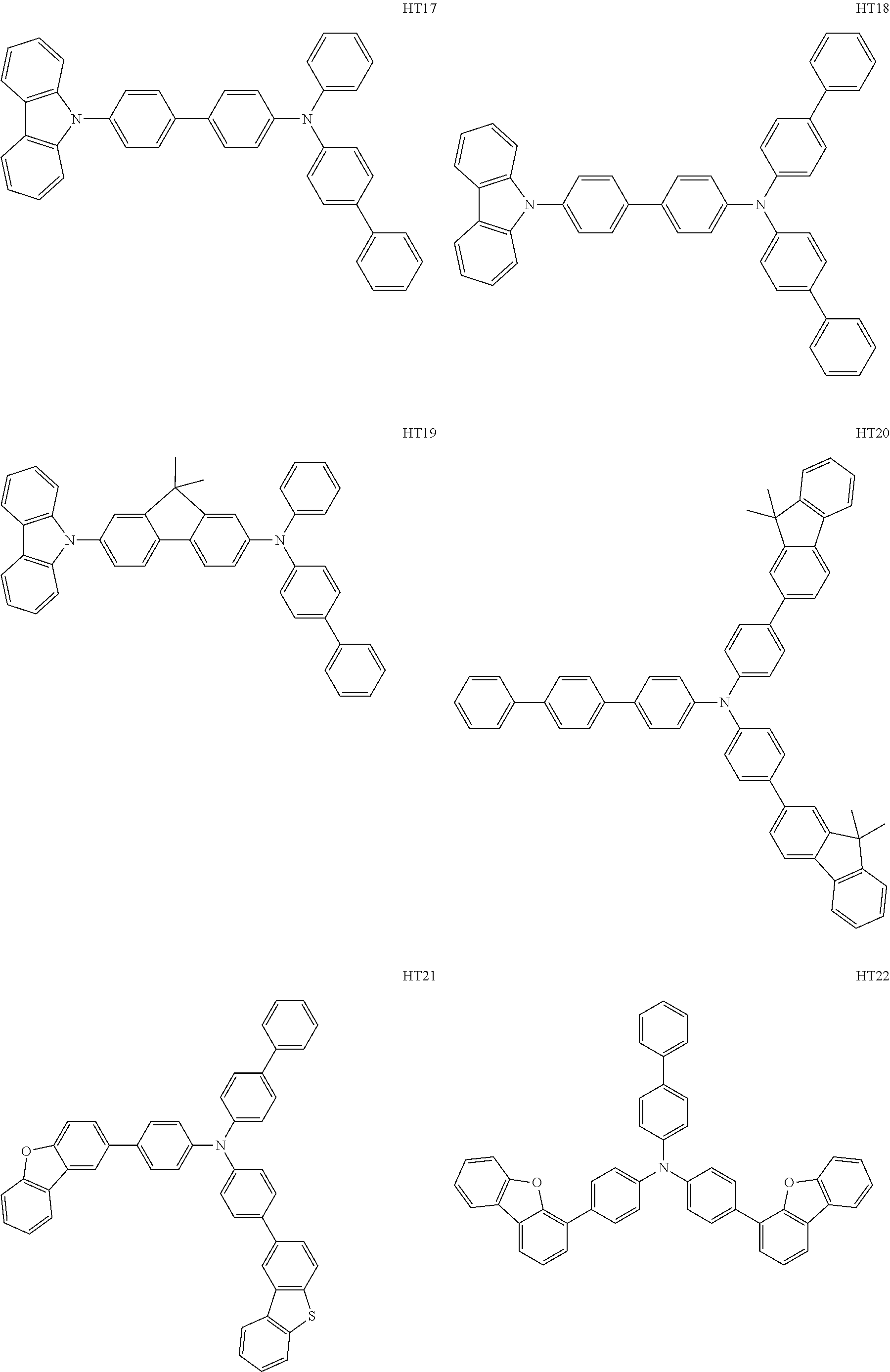

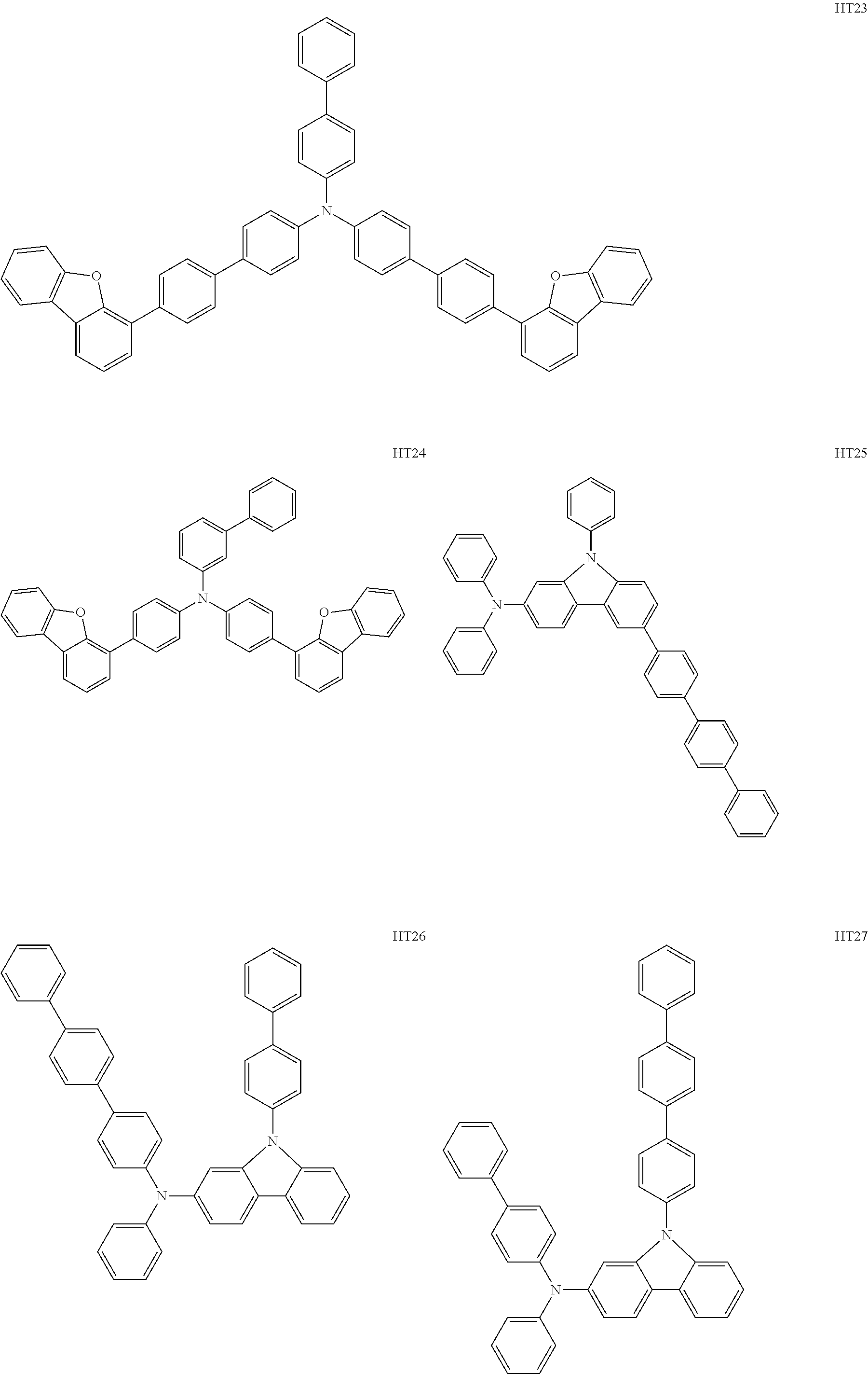 [SMILES: c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1 ; c1ccc(-c2cccc(N(c3ccc(-c4cccc5c4oc4ccccc45)cc3)c3ccc(-c4cccc5c4oc4ccccc45)cc3)c2)cc1 ; c1ccc(-c2ccc(-c3ccc(-c4ccc5c(c4)c4ccc(N(c6ccccc6)c6ccccc6)cc4n5-c4ccccc4)cc3)cc2)cc1 ; c1ccc(-c2ccc(-c3ccc(N(c4ccccc4)c4ccc5c6ccccc6n(-c6ccc(-c7ccccc7)cc6)c5c4)cc3)cc2)cc1 ; c1ccc(-c2ccc(-c3ccc(-n4c5ccccc5c5ccc(N(c6ccccc6)c6ccc(-c7ccccc7)cc6)cc54)cc3)cc2)cc1]

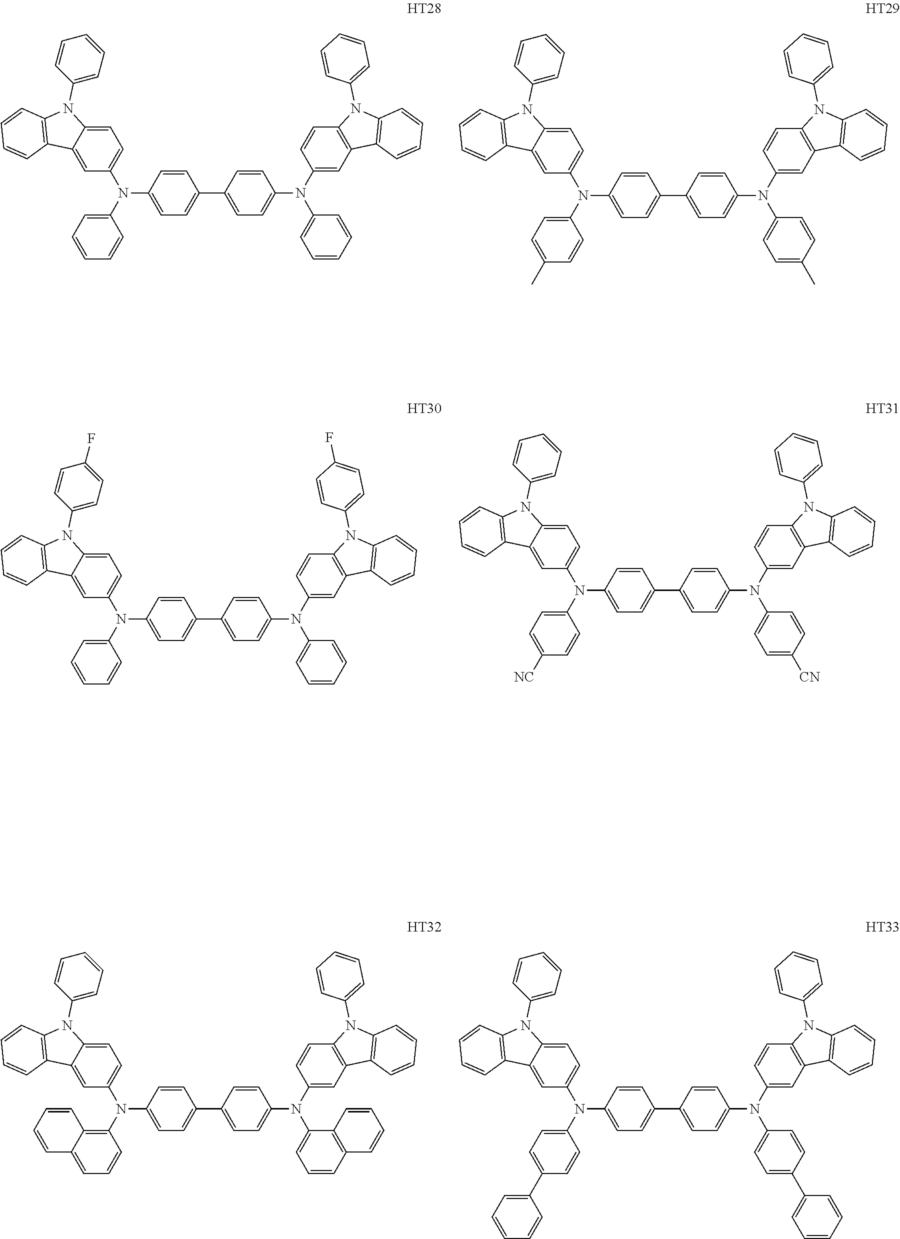

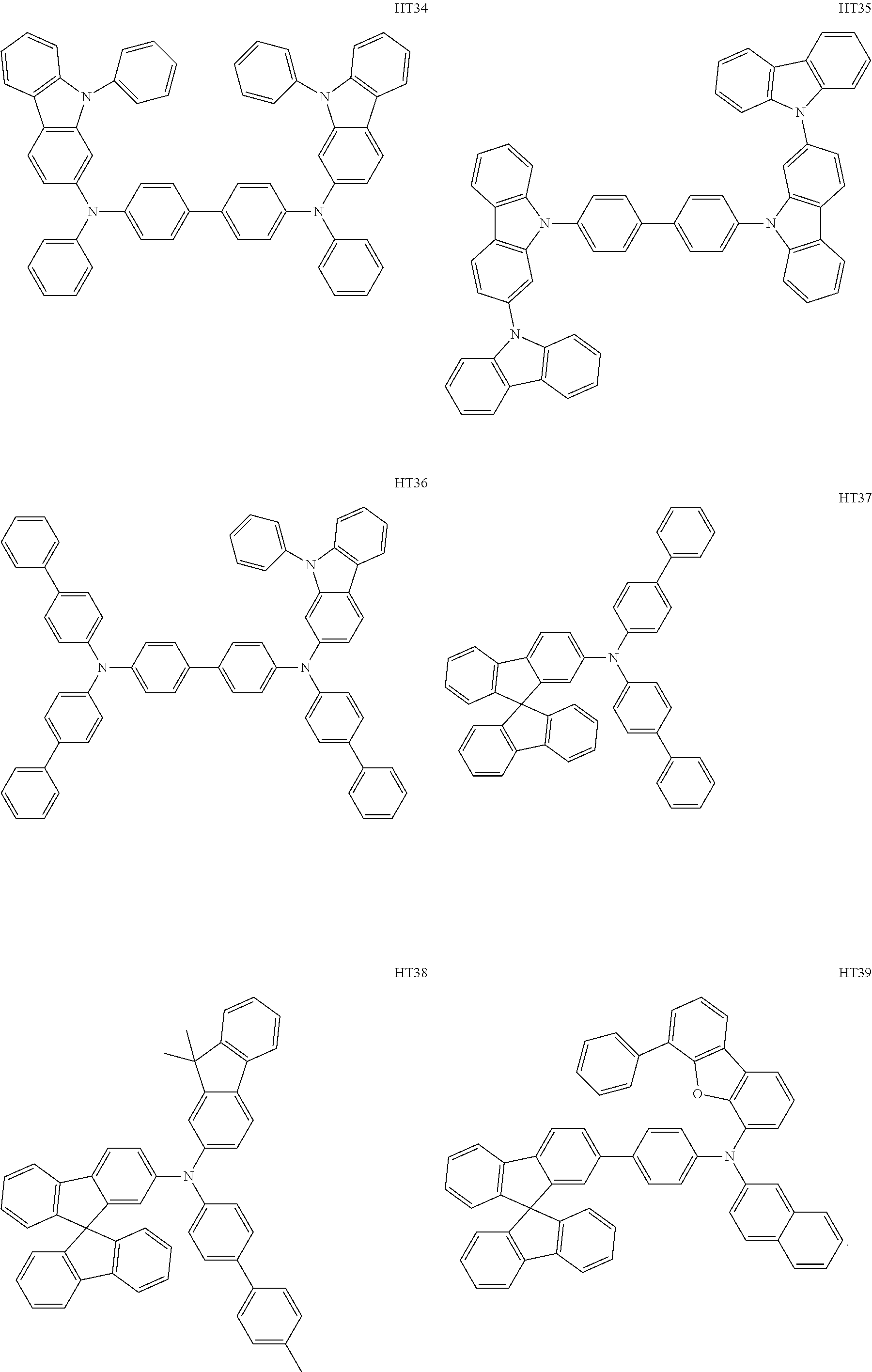

The thickness of the hole transport region may be about 100 Å to about 10,000 Å, and in some embodiments, about 100 Å to about 1,000 Å. When the hole transport region includes at least one selected from a hole injection layer and a hole transport layer, the thickness of the hole injection layer may be about 100 Å to about 9,000 Å, and in some embodiments, about 100 Å to about 1,000 Å; the thickness of the hole transport layer may be about 50 Å to about 2,000 Å, and in some embodiments, about 100 Å to about 1,500 Å. When the thicknesses of the hole transport region, the hole injection layer, and the hole transport layer are each within these ranges, satisfactory hole transporting characteristics may be obtained without a substantial increase in driving voltage.

The emission auxiliary layer may increase the light-emission efficiency of the device by compensating for an optical resonance distance according to the wavelength of light emitted by an emission layer (e.g., by adjusting the optical resonance distance to match the wavelength of light emitted from the emission layer), and the electron blocking layer may block or reduce the flow of electrons from an electron transport region. The emission auxiliary layer and the electron blocking layer may each include those materials as described above.

p-Dopant

The hole transport region may further include, in addition to these materials, a charge-generation material for the improvement of conductive properties. The charge-generation material may be homogeneously or non-homogeneously dispersed in the hole transport region.

The charge-generation material may be, for example, a p-dopant.

The doping concentration of the p-dopant may be 0.1 wt % to 20 wt %, for example, 0.5 wt % to 10 wt %.

In one embodiment, the p-dopant may have a lowest unoccupied molecular orbital (LUMO) of −3.5 eV or less.

The p-dopant may include at least one selected from a quinone derivative, a metal oxide, and a cyano group-containing compound, but embodiments of the present disclosure are not limited thereto.

For example, the p-dopant may include at least one selected from the group consisting of:

a quinone derivative (such as tetracyanoquinodimethane (TCNQ) and/or 2,3,5,6-tetrafluoro-7,7,8,8-tetracyanoquinodimethane (F4-TCNQ));

a metal oxide (such as tungsten oxide and/or molybdenum oxide);

1,4,5,8,9,11-hexaazatriphenylene-hexacarbonitrile (HAT-CN); and

a compound represented by Formula 221, but embodiments of the present disclosure are not limited thereto:

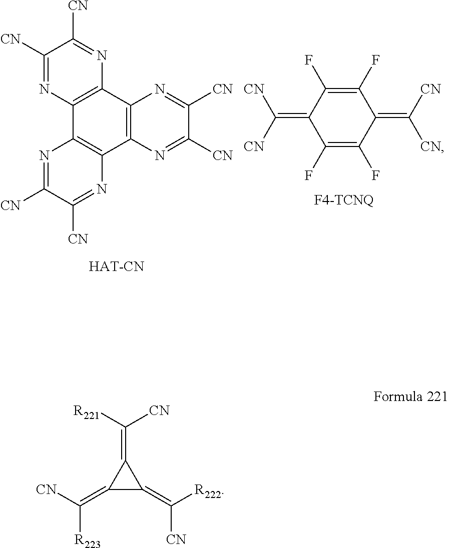

In Formula 221,

R₂₂₁ to R₂₂₃ may each independently be selected from a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group, wherein at least one selected from R₂₂₁ to R₂₂₃ has at least one substituent selected from a cyano group, —F, —Cl, —Br, —I, a C₁-C₂₀ alkyl group substituted with —F, a C₁-C₂₀ alkyl group substituted with —Cl, a C₁-C₂₀ alkyl group substituted with —Br, and a C₁-C₂₀ alkyl group substituted with —I.

### Emission Layer in Organic Layer 150

When the organic light-emitting device 10 is a full color organic light-emitting device, the emission layer may be patterned into a red emission layer, a green emission layer, and/or a blue emission layer, according to a sub pixel. In one or more embodiments, the emission layer may have a stacked structure of two or more layers selected from a red emission layer, a green emission layer, and a blue emission layer, in which the two or more layers may contact each other or may be separated from each other. In one or more embodiments, the emission layer may include two or more materials selected from a red-light emission material, a green-light emission material, and a blue-light emission material, in which the two or more materials may be mixed together in a single layer to thereby emit white light.

In one embodiment, the emission layer of the organic light-emitting device 10 may be a first-color-light emitting-emission layer,

the organic light-emitting device 10 may further include i) at least one second-color-light emitting-emission layer, or ii) at least one second-color-light emitting-emission layer and at least one third-color-light emitting-emission layer, each between the first electrode 110 and the second electrode 190,

a maximum emission wavelength of the first-color-light emitting-emission layer, a maximum emission wavelength of the second-color-light emitting-emission layer, and a maximum emission wavelength of the third-color-light emitting-emission layer may be identical to or different from each other, and

the organic light-emitting device 10 may emit a mixed light including a first-color-light and a second-color-light, or a mixed light including the first-color-light, the second-color-light, and a third-color-light, but embodiments of the present disclosure are not limited thereto.

For example, the maximum emission wavelength of the first-color-light emitting-emission layer may be different from the maximum emission wavelength of the second-color-light emitting-emission layer, and the mixed light including the first-color-light and the second-color-light may be white light, but embodiments of the present disclosure are not limited thereto.

In one or more embodiments, the maximum emission wavelength of the first-color-light emitting-emission layer, the maximum emission wavelength of the second-color-light emitting-emission layer, and the maximum emission wavelength of the third-color-light emitting-emission layer may be different from one another, and the mixed light including the first-color-light, the second-color-light, and the third-color-light may be white light. However, embodiments of the present disclosure are not limited thereto.

The emission layer may include a host and a dopant. The dopant may include at least one selected from a phosphorescent dopant and a fluorescent dopant.

The amount of the dopant in the emission layer may be about 0.01 to about 15 parts by weight based on 100 parts by weight of the host, but embodiments of the present disclosure are not limited thereto.

The thickness of the emission layer may be about 100 Å to about 1,000 Å, and in some embodiments, about 200 Å to about 600 Å. When the thickness of the emission layer is within these ranges, excellent light-emission characteristics may be obtained without a substantial increase in driving voltage.

### Host in Emission Layer

The emission layer may include the first compound represented by one selected from Formulae 1A to 1E as a host. The first compound may be the same as described above.

The emission layer may include the first compound represented by one selected from Formulae 1A to 1E as a first host, and may further include a second host that is different from the first host.

For example, the second host may be selected from compounds described above as an example of the first compound represented by one selected from Formulae 1A to 1E.

In one or more embodiments, the second host may be selected from 9,10-di(2-naphthyl)anthracene (ADN), 2-methyl-9,10-bis(naphthalen-2-yl)anthracene (MADN), 9,10-di-(2-naphthyl)-2-t-butyl-anthracene (TBADN), 4,4′-bis(N-carbazolyl)-1,1-biphenyl (CBP), 1,3-di-9-carbazolylbenzene (mCP), and 1,3,5-tri(carbazol-9-yl)benzene (TCP), but embodiments of the present disclosure are not limited thereto.

A weight ratio of the first host to the second host in the emission layer may be, for example, 90:10 to 10:90, and in some embodiments, 80:20 to 20:80, and in some embodiments, 50:50, but embodiments of the present disclosure are not limited thereto.

### Phosphorescent Dopant Included in Emission Layer in Organic Layer 150

The phosphorescent dopant may include an organometallic complex represented by Formula 401 below:

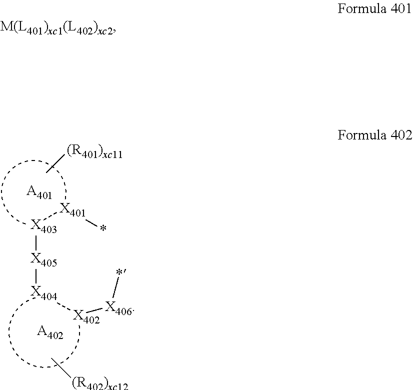

In Formulae 401 and 402,

M may be selected from iridium (Ir), platinum (Pt), palladium (Pd), osmium (Os), titanium (Ti), zirconium (Zr), hafnium (Hf), europium (Eu), terbium (Tb), rhodium (Rh), and thulium (Tm),

L₄₀₁ may be a ligand represented by Formula 402, xc1 may be 1, 2, or 3, and when xc1 is two or more, two or more L₄₀₁(s) may be identical to or different from each other,

L₄₀₂ may be an organic ligand, xc2 may be an integer selected from 0 to 4, and when xc2 is two or more, two or more L₄₀₂(s) may be identical to or different from each other,

X₄₀₁ to X₄₀₄ may each independently be nitrogen or carbon,

X₄₀₁ may be linked to (e.g., coupled) to X₄₀₃ via a single bond or a double bond, and X₄₀₂ may be linked to (e.g., coupled) to X₄₀₄ via a single bond or a double bond,

A₄₀₁ and A₄₀₂ may each independently be a C₅-C₆₀ carbocyclic group or a C₁-C₆₀ heterocyclic group,

X₄₀₅ may be a single bond, *—O—*′, *—S—*′, *—C(═O)—*′, *—N(Q₄₁₁)-*′, *—C(Q₄₁₁)(Q₄₁₂)-*′, *—C(Q₄₁₁)=C(Q₄₁₂)-*′, *—C(Q₄₁₁)=*′, or *═C(Q₄₁₁)=*′, and Q₄₁₁ and Q₄₁₂ may each independently be hydrogen, deuterium, a C₁-C₂₀ alkyl group, a C₁-C₂₀ alkoxy group, a phenyl group, a biphenyl group, a terphenyl group, or a naphthyl group,

X₄₀₆ may be a single bond, O, or S,

R₄₀₁ and R₄₀₂ may each independently be selected from hydrogen, deuterium, —F, —Cl, —Br, —I, —CD₃, —CF₃, a hydroxyl group, a cyano group, a nitro group, an amidino group, a hydrazino group, a hydrazono group, a substituted or unsubstituted C₁-C₂₀ alkyl group, a substituted or unsubstituted C₁-C₂₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group and a substituted or unsubstituted monovalent non-aromatic condensed heteropolycyclic group —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), and —P(═O)(Q₄₀₁)(Q₄₀₂), wherein Q₄₀₁ to Q₄₀₃ may each independently be selected from a C₁-C₁₀ alkyl group, a C₁-C₁₀ alkoxy group, a C₆-C₂₀ aryl group, and a C₁-C₂₀ heteroaryl group,

xc11 and xc12 may each independently be an integer selected from 0 to 10, and

* and *′ in Formula 402 may each independently indicate a binding site to M in Formula 401.

In one embodiment, A₄₀₁ and A₄₀₂ in Formula 402 may each independently be selected from a benzene group, a naphthalene group, a fluorene group, a spiro-bifluorene group, an indene group, a pyrrole group, a thiophene group, a furan group, an imidazole group, a pyrazole group, a thiazole group, an isothiazole group, an oxazole group, an isoxazole group, a pyridine group, a pyrazine group, a pyrimidine group, a pyridazine group, a quinoline group, an isoquinoline group, a benzoquinoline group, a quinoxaline group, a quinazoline group, a carbazole group, a benzimidazole group, a benzofuran group, a benzothiophene group, an isobenzothiophene group, a benzoxazole group, an isobenzoxazole group, a triazole group, a tetrazole group, an oxadiazole group, a triazine group, a dibenzofuran group, and a dibenzothiophene group.

In one or more embodiments, in Formula 402, i) X₄₀₁ may be nitrogen, and X₄₀₂ may be carbon, or ii) X₄₀₁ and X₄₀₂ may both (e.g., simultaneously) be nitrogen.

In one or more embodiments, R₄₀₁ and R₄₀₂ in Formula 402 may each independently be selected from the group consisting of:

hydrogen, deuterium, —F, —Cl, —Br, —I, a hydroxyl group, a cyano group, a nitro group, an amidino group, a hydrazino group, a hydrazono group, a C₁-C₂₀ alkyl group, and a C₁-C₂₀ alkoxy group;

a C₁-C₂₀ alkyl group and a C₁-C₂₀ alkoxy group, each substituted with at least one selected from deuterium, —F, —Cl, —Br, —I, a hydroxyl group, a cyano group, a nitro group, an amidino group, a hydrazino group, a hydrazono group, a phenyl group, a naphthyl group, a cyclopentyl group, a cyclohexyl group, an adamantyl group, a norbornanyl group, and a norbornenyl group;

a cyclopentyl group, a cyclohexyl group, an adamantyl group, a norbornanyl group, a norbornenyl group, a phenyl group, a biphenyl group, a terphenyl group, a naphthyl group, a fluorenyl group, a pyridinyl group, a pyrazinyl group, a pyrimidinyl group, a pyridazinyl group, a triazinyl group, a quinolinyl group, an isoquinolinyl group, a quinoxalinyl group, a quinazolinyl group, a carbazolyl group, a dibenzofuranyl group, and a dibenzothiophenyl group;

a cyclopentyl group, a cyclohexyl group, an adamantyl group, a norbornanyl group, a norbornenyl group a phenyl group, a biphenyl group, a terphenyl group, a naphthyl group, a fluorenyl group, a pyridinyl group, a pyrazinyl group, a pyrimidinyl group, a pyridazinyl group, a triazinyl group, a quinolinyl group, an isoquinolinyl group, a quinoxalinyl group, a quinazolinyl group, a carbazolyl group, a dibenzofuranyl group, and a dibenzothiophenyl group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a cyclopentyl group, a cyclohexyl group, an adamantyl group, a norbornanyl group, a norbornenyl group, a phenyl group, a biphenyl group, a terphenyl group, a naphthyl group, a fluorenyl group, a pyridinyl group, a pyrazinyl group, a pyrimidinyl group, a pyridazinyl group, a triazinyl group, a quinolinyl group, an isoquinolinyl group, a quinoxalinyl group, a quinazolinyl group, a carbazolyl group, a dibenzofuranyl group, and a dibenzothiophenyl group; and

—Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), and —P(═O)(Q₄₀₁)(Q₄₀₂),

wherein Q₄₀₁ to Q₄₀₃ may each independently be selected from a C₁-C₁₀ alkyl group, a C₁-C₁₀ alkoxy group, a phenyl group, a biphenyl group, and a naphthyl group, but embodiments of the present disclosure are not limited thereto.

In one or more embodiments, when xc1 in Formula 401 is two or more, two A₄₀₁(s) in two or more L₄₀₁(s) may be optionally linked (e.g., coupled) via a linking group X₄₀₇, and two A₄₀₂(s) in two or more L₄₀₁(s) may be optionally linked (e.g., coupled) via a linking group X₄₀₈ (see Compounds PD1 to PD4 and PD7). X₄₀₇ and X₄₀₈ may each independently be a single bond, *—O—*′, *—S—*′, *—C(═O)—*′, *—N(Q₄₁₃)-*′, *—C(Q₄₁₃)(Q₄₁₄)-*′, or *—C(Q₄₁₃)=C(Q₄₁₄)-*′ (wherein Q₄₁₃ and Q₄₁₄ may each independently be hydrogen, deuterium, a C₁-C₂₀ alkyl group, a C₁-C₂₀ alkoxy group, a phenyl group, a biphenyl group, a terphenyl group, or a naphthyl group), but embodiments of the present disclosure are not limited thereto.

L₄₀₂ in Formula 401 may be a monovalent, divalent, or trivalent organic ligand. For example, L₄₀₂ may be selected from halogen, diketone (for example, acetylacetonate), a carboxylic acid (for example, picolinate), —C(═O), an isonitrile, —CN, and a phosphorus-based ligand (for example, phosphine or phosphite), but embodiments of the present disclosure are not limited thereto.

In one or more embodiments, the phosphorescent dopant may be selected from, for example, Compounds PD1 to PD25, but embodiments of the present disclosure are not limited thereto:

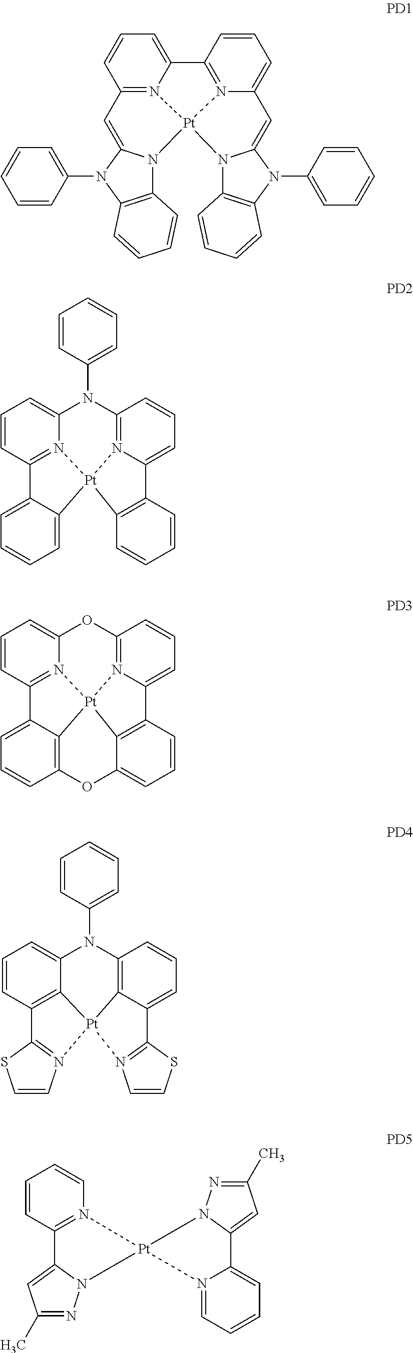

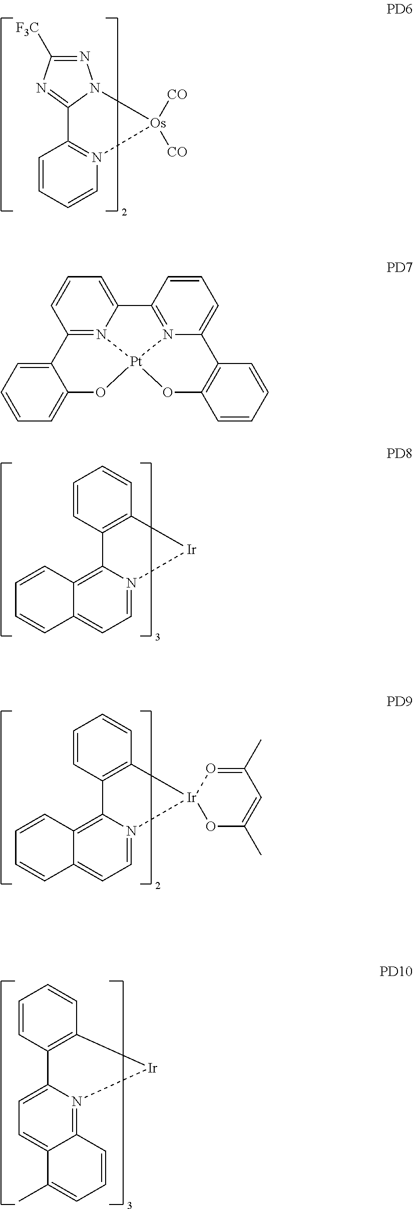

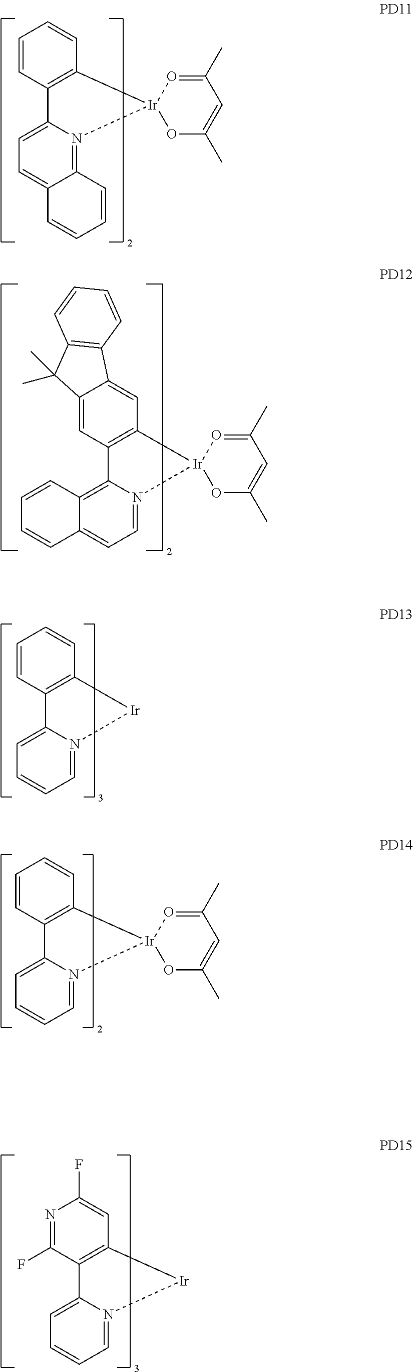

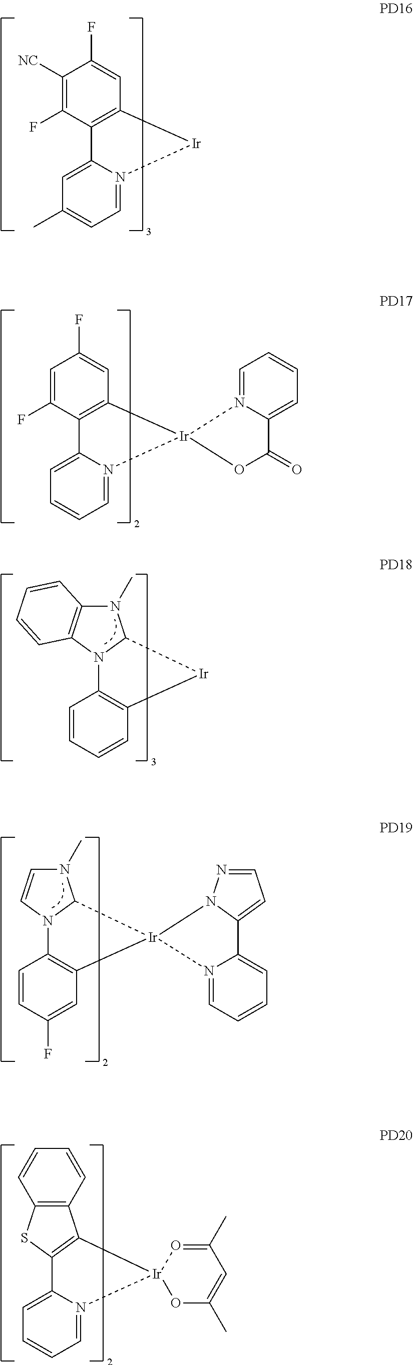

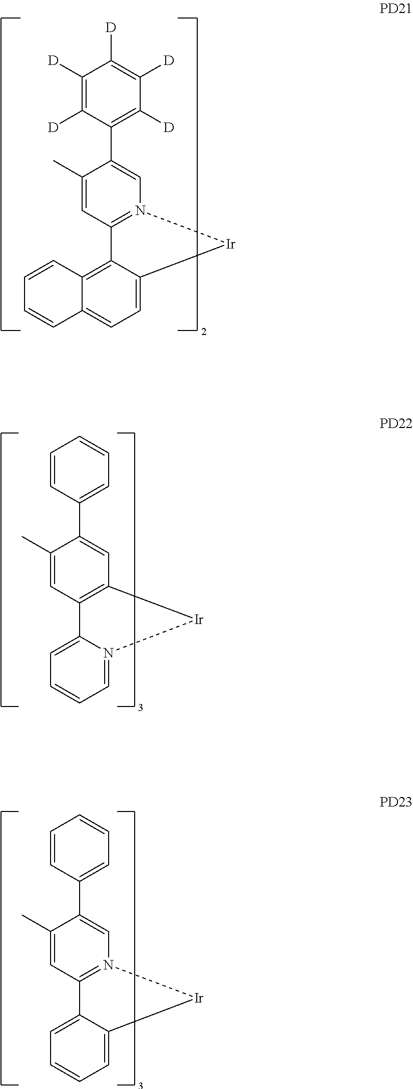

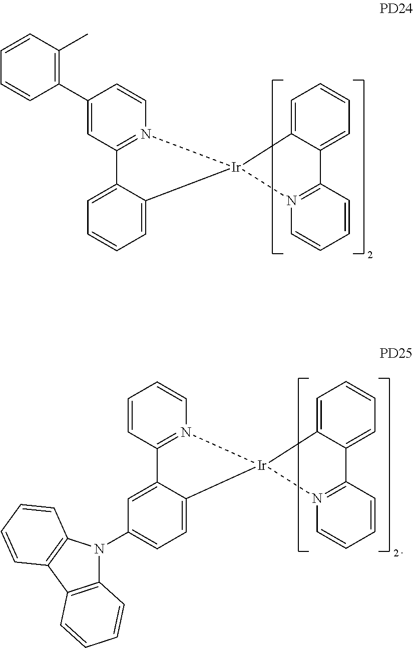

### Fluorescent Dopant in Emission Layer

The fluorescent dopant may include an arylamine compound or a styrylamine compound.

In one or more embodiments, the fluorescent dopant may include a compound represented by Formula 501:

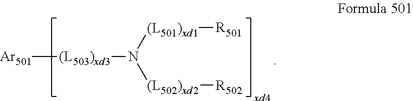

In Formula 501,

Ar₅₀₁ may be a substituted or unsubstituted C₅-C₆₀ carbocyclic group or a substituted or unsubstituted C₁-C₆₀ heterocyclic group,

L₅₀₁ to L₅₀₃ may each independently be selected from a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed heteropolycyclic group,

xd1 to xd3 may each independently be an integer selected from 0 to 3,

R₅₀₁ and R₅₀₂ may each independently be selected from a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group,

xd4 may be an integer selected from 1 to 6.

In one embodiment, Ar₅₀₁ in Formula 501 may be selected from the group consisting of:

a naphthalene group, a heptalene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, naphthacene group, a picene group, a perylene group, a pentaphene group, an indenoanthracene group, and an indenophenanthrene group; and

a naphthalene group, a heptalene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, naphthacene group, a picene group, a perylene group, a pentaphene group, an indenoanthracene group, and an indenophenanthrene group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, and a naphthyl group.

In one or more embodiments, L₅₀₁ to L₅₀₃ in Formula 501 may each independently be selected from a phenylene group, a naphthylene group, a fluorenylene group, a spiro-bifluorenylene group, a benzofluorenylene group, a dibenzofluorenylene group, a phenanthrenylene group, an anthracenylene group, a fluoranthenylene group, a triphenylenylene group, a pyrenylene group, a chrysenylene group, a perylenylene group, a pentaphenylene group, a hexacenylene group, a pentacenylene group, a thiophenylene group, a furanylene group, a carbazolylene group, an indolylene group, an isoindolylene group, a benzofuranylene group, a benzothiophenylene group, a dibenzofuranylene group, a dibenzothiophenylene group, a benzocarbazolylene group, a dibenzocarbazolylene group, a dibenzosilolylene group, and a pyridinylene group; and

a phenylene group, a naphthylene group, a fluorenylene group, a spiro-bifluorenylene group, a benzofluorenylene group, a dibenzofluorenylene group, a phenanthrenylene group, an anthracenylene group, a fluoranthenylene group, a triphenylenylene group, a pyrenylene group, a chrysenylene group, a perylenylene group, a pentaphenylene group, a hexacenylene group, a pentacenylene group, a thiophenylene group, a furanylene group, a carbazolylene group, an indolylene group, an isoindolylene group, a benzofuranylene group, a benzothiophenylene group, a dibenzofuranylene group, a dibenzothiophenylene group, a benzocarbazolylene group, a dibenzocarbazolylene group, a dibenzosilolylene group, and a pyridinylene group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, and a pyridinyl group.

In one or more embodiments, R₅₀₁ and R₅₀₂ in Formula 501 may each independently be selected from the group consisting of:

a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, and a pyridinyl group; and

a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, and a pyridinyl group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, and —Si(Q₃₁)(Q₃₂)(Q₃₃),

wherein Q₃₁ to Q₃₃ may each independently be selected from a C₁-C₁₀ alkyl group, a C₁-C₁₀ alkoxy group, a phenyl group, a biphenyl group, a terphenyl group, and a naphthyl group.

In one or more embodiments, xd4 in Formula 501 may be 2, but embodiments of the present disclosure are not limited thereto.

For example, the fluorescent dopant may be selected from Compounds FD1 to FD22:

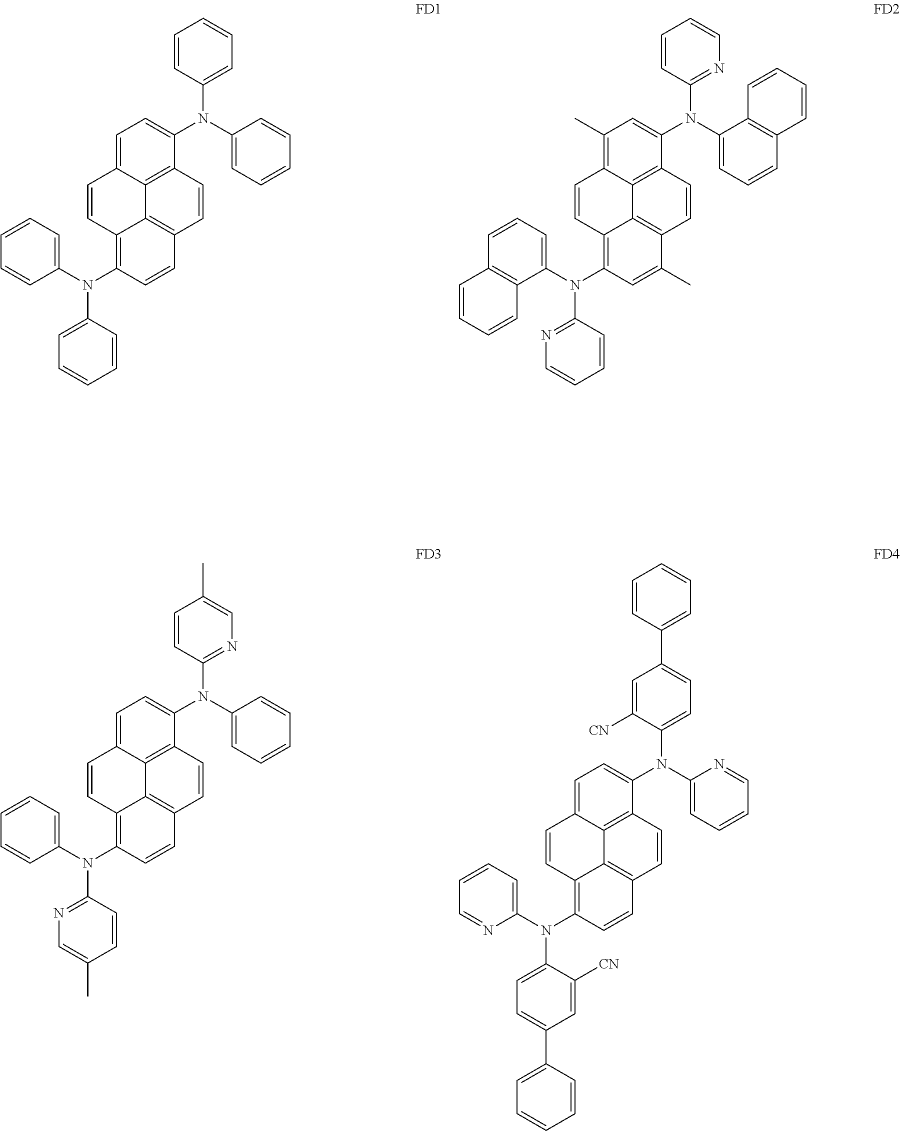

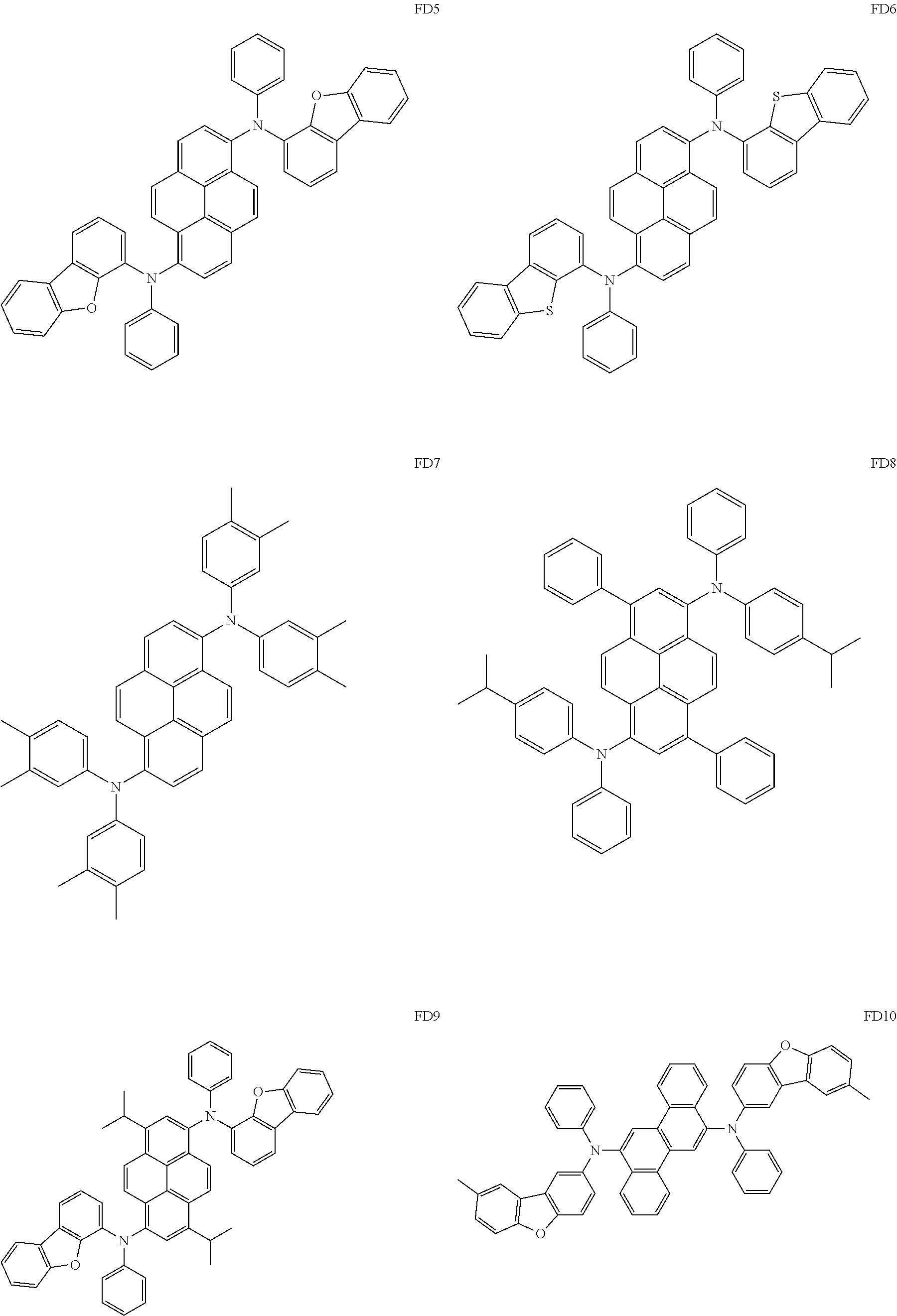

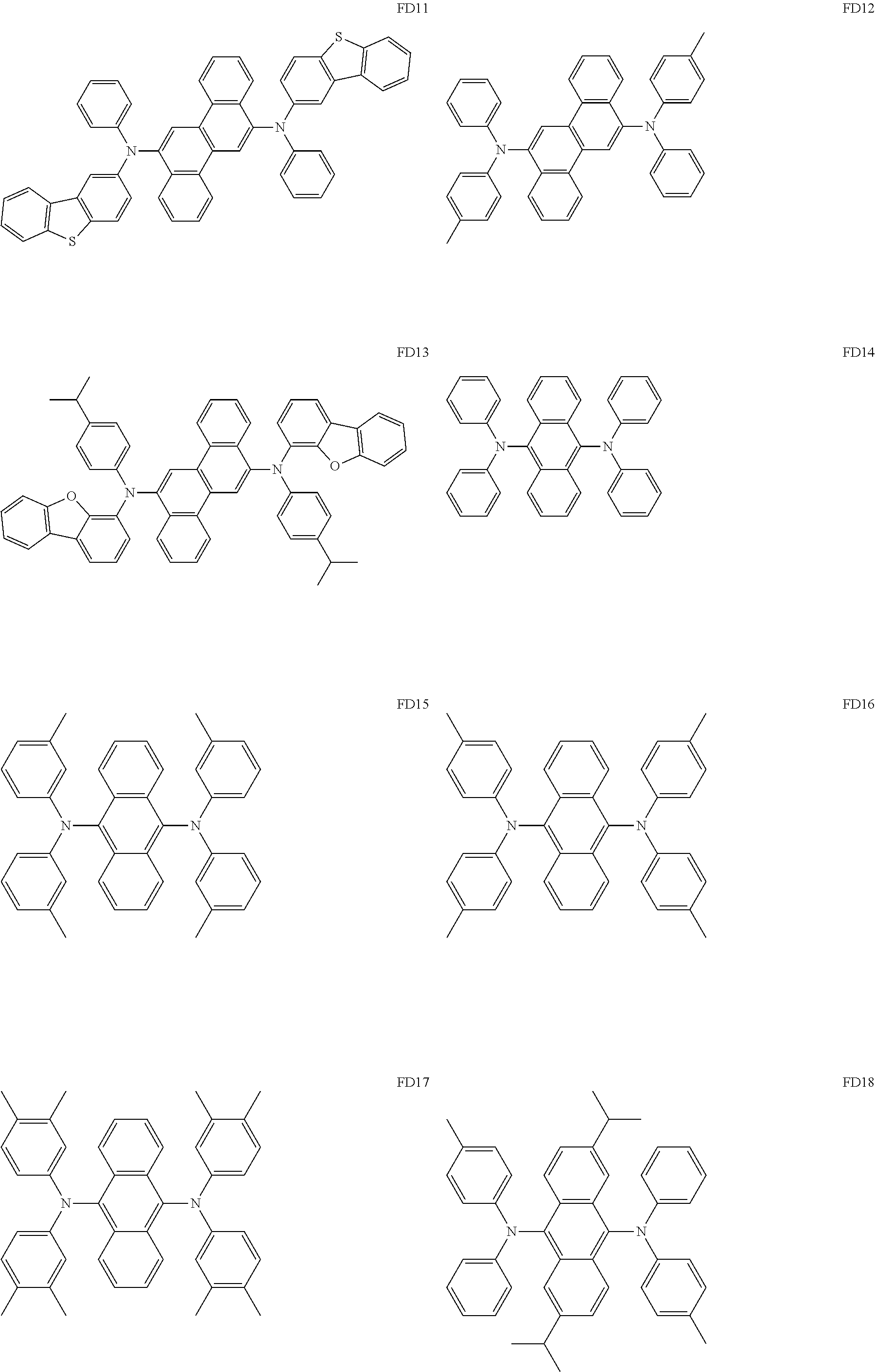

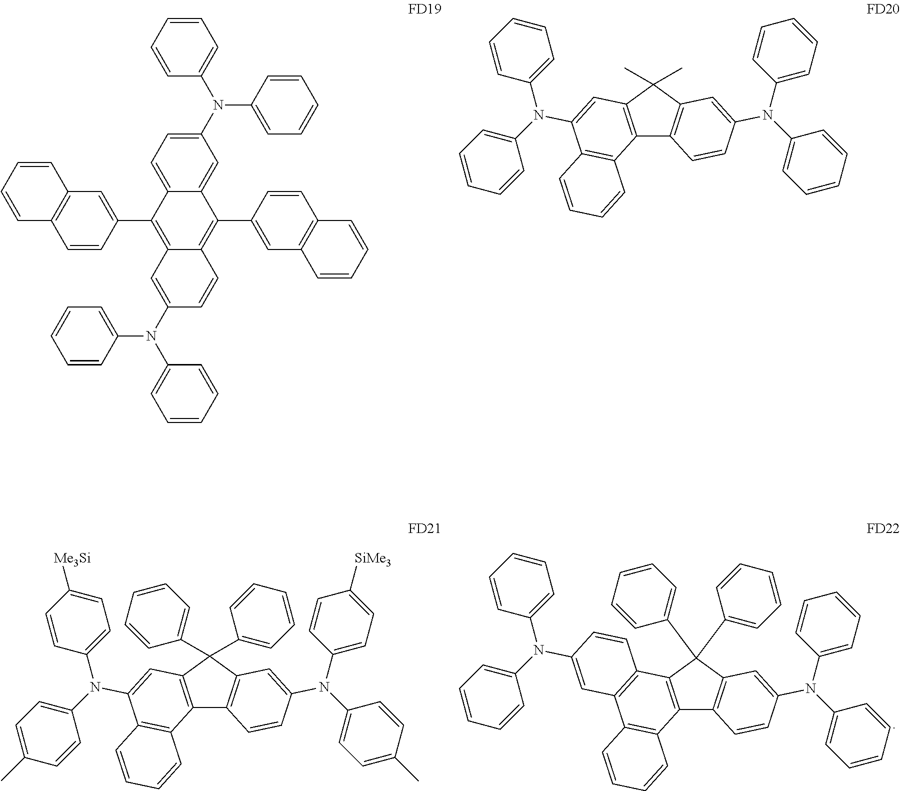

In one or more embodiments, the fluorescent dopant may be selected from the following compounds, but embodiments of the present disclosure are not limited thereto:

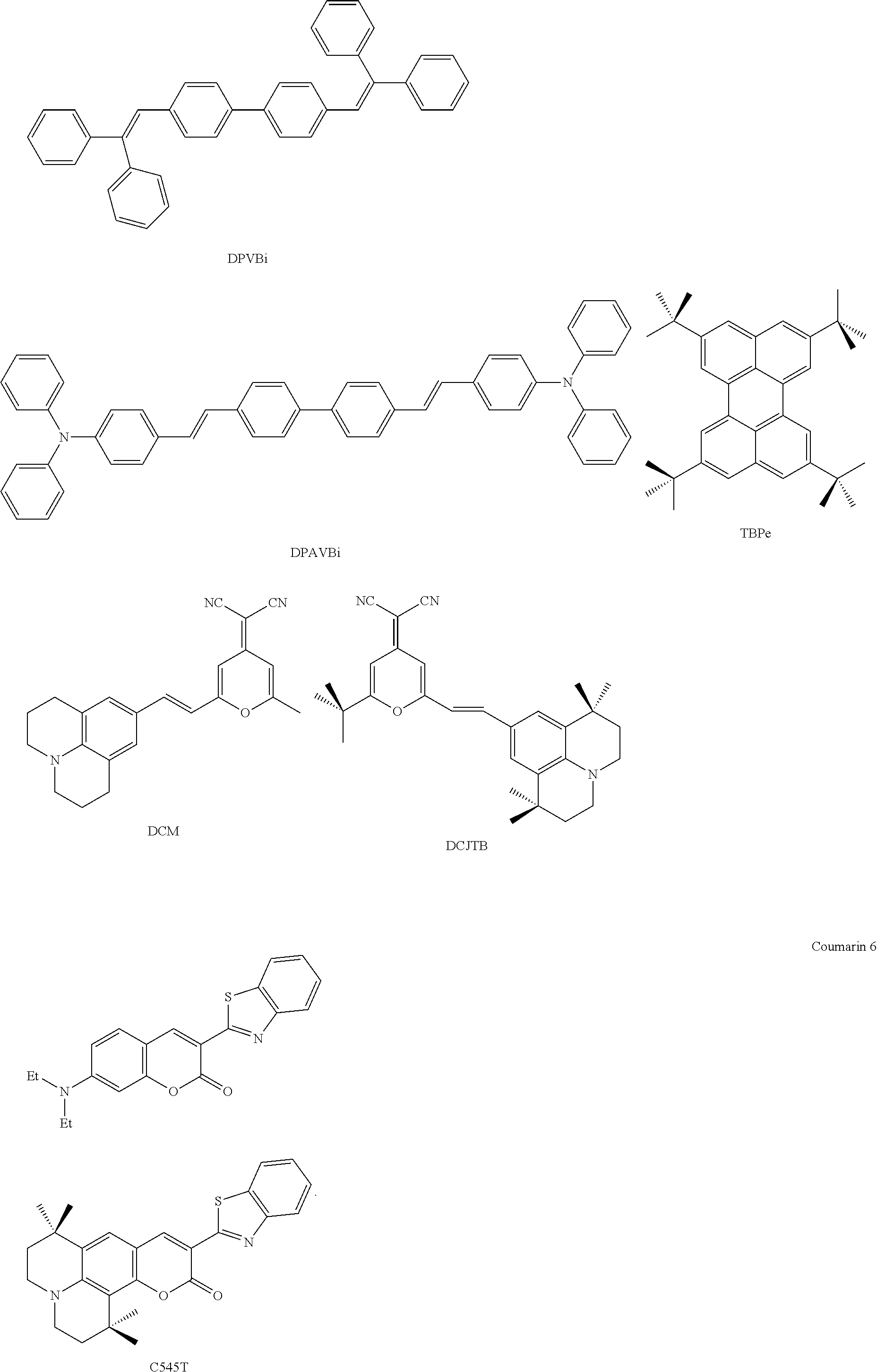

### Electron Transport Region in Organic Layer 150

The electron transport region may have: i) a single-layered structure including a single layer including a single material, ii) a single-layered structure including a single layer including a plurality of different materials, or iii) a multi-layered structure having a plurality of layers including a plurality of different materials.

The electron transport region may include at least one selected from a buffer layer, a hole blocking layer, an electron control layer, an electron transport layer (ETL), and an electron injection layer, but embodiments of the present disclosure are not limited thereto.

For example, the electron transport region may have a structure of electron transport layer/electron injection layer, a structure of hole blocking layer/electron transport layer/electron injection layer, a structure of electron control layer/electron transport layer/electron injection layer, or a structure of buffer layer/electron transport layer/electron injection layer, wherein layers of each structure are sequentially stacked on the emission layer in each stated order. However, embodiments of the structure of the electron transport layer are not limited thereto.

The electron transport region may include the second compound represented by Formula 2A or 2B as described above.

In one embodiment, the electron transport region may include an buffer layer, the buffer layer may directly contact the emission layer, and the buffer layer may include the second compound represented by Formula 2A or 2B as described above.

In one or more embodiments, the electron transport region may include a buffer layer, an electron layer, and an electron injection layer stacked in this stated order on the emission layer, and the buffer layer may include the second compound represented by Formula 2A or 2B as described above.

The electron transport region (for example, a hole blocking layer, an electron control layer, and/or an electron transport layer in the electron transport region) may include a metal-free compound containing at least one π electron-depleted nitrogen-containing ring.

As used herein, the term “π electron-depleted nitrogen-containing ring” indicates a C₁-C₆₀ heterocyclic group having at least one *—N═*′ moiety as a ring-forming moiety.

For example, the “π electron-depleted nitrogen-containing ring” may be i) a 5-membered to 7-membered heteromonocyclic group having at least one *—N═*′ moiety, ii) a heteropolycyclic group in which two or more 5-membered to 7-membered heteromonocyclic groups each having at least one *—N═*′ moiety are condensed with each other, or iii) a heteropolycyclic group in which at least one 5-membered to 7-membered heteromonocyclic group having at least one *—N═*′ moiety is condensed with at least one C₅-C₆₀ carbocyclic group.

Non-limiting examples of the π electron-depleted nitrogen-containing ring may include an imidazole, a pyrazole, a thiazole, an isothiazole, an oxazole, an isoxazole, a pyridine, a pyrazine, a pyrimidine, a pyridazine, an indazole, a purine, a quinoline, an isoquinoline, a benzoquinoline, a phthalazine, a naphthyridine, a quinoxaline, a quinazoline, a cinnoline, a phenanthridine, an acridine, a phenanthroline, a phenazine, a benzimidazole, an isobenzothiazole, a benzoxazole, an isobenzoxazole, a triazole, a tetrazole, an oxadiazole, a triazine, a thiadiazole, an imidazopyridine, an imidazopyrimidine, and an azacarbazole, but embodiments of the present disclosure are not limited thereto.

For example, the electron transport region may include a compound represented by Formula 601:

[Ar₆₀₁]ₓₑ₁₁-[(L₆₀₁)ₓₑ₁-R₆₀₁]ₓₑ₂₁. Formula 601

In Formula 601,

Ar₆₀₁ may be a substituted or unsubstituted C₅-C₆₀ carbocyclic group or a substituted or unsubstituted C₁-C₆₀ heterocyclic group,

xe11 may be 1, 2, or 3,

L₆₀₁ may be selected from a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed heteropolycyclic group,

xe1 may be an integer selected from 0 to 5,

R₆₀₁ may be selected from a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₆₀₁)(Q₆₀₂)(Q₆₀₃), —C(═O)(Q₆₀₁), —S(═O)₂(Q₆₀₁), and —P(═O)(Q₆₀₁)(Q₆₀₂),

Q₆₀₁ to Q₆₀₃ may each independently be a C₁-C₁₀ alkyl group, a C₁-C₁₀ alkoxy group, a phenyl group, a biphenyl group, a terphenyl group, or a naphthyl group, and

xe21 may be an integer selected from 1 to 5.

In one embodiment, at least one of the xe11 Ar₆₀₁(s) and/or at least one of the xe21 R₆₀₁(s) may include the π electron-depleted nitrogen-containing ring.

In one embodiment, ring Ar₆₀₁ in Formula 601 may be selected from the group consisting of:

a benzene group, a naphthalene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, naphthacene group, a picene group, a perylene group, a pentaphene group, an indenoanthracene group, a dibenzofuran group, a dibenzothiophene group, a carbazole group, an imidazole group, a pyrazole group, a thiazole group, an isothiazole group, an oxazole group, an isoxazole group, a pyridine group, a pyrazine group, a pyrimidine group, a pyridazine group, an indazole group, a purine group, a quinoline group, an isoquinoline group, a benzoquinoline group, a phthalazine group, naphthyridine group, a quinoxaline group, a quinazoline group, a cinnoline group, a phenanthridine group, an acridine group, a phenanthroline group, a phenazine group, a benzimidazole group, an iso-benzothiazole group, a benzoxazole group, an isobenzoxazole group, a triazole group, a tetrazole group, an oxadiazole group, a triazine group, thiadiazole group, an imidazopyridine group, an imidazopyrimidine group, and an azacarbazole group; and

a benzene group, a naphthalene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, naphthacene group, a picene group, a perylene group, a pentaphene group, an indenoanthracene group, a dibenzofuran group, a dibenzothiophene group, a carbazole group, an imidazole group, a pyrazole group, a thiazole group, an isothiazole group, an oxazole group, an isoxazole group, a pyridine group, a pyrazine group, a pyrimidine group, a pyridazine group, an indazole group, a purine group, a quinoline group, an isoquinoline group, a benzoquinoline group, a phthalazine group, naphthyridine group, a quinoxaline group, a quinazoline group, a cinnoline group, a phenanthridine group, an acridine group, a phenanthroline group, a phenazine group, a benzimidazole group, an iso-benzothiazole group, a benzoxazole group, an isobenzoxazole group, a triazole group, a tetrazole group, an oxadiazole group, a triazine group, thiadiazole group, an imidazopyridine group, an imidazopyrimidine group, and an azacarbazole group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, a naphthyl group, —Si(Q₃₁)(Q₃₂)(Q₃₃), —S(═O)₂(Q₃₁), and —P(═O)(Q₃₁)(Q₃₂),

wherein Q₃₁ to Q₃₃ may each independently be selected from a C₁-C₁₀ alkyl group, a C₁-C₁₀ alkoxy group, a phenyl group, a biphenyl group, a terphenyl group, and a naphthyl group.

When xe11 in Formula 601 is two or more, two or more Ar₆₀₁(s) may be linked (e.g., coupled) via one or more single bonds.

In one or more embodiments, Ar₆₀₁ in Formula 601 may be an anthracene group.

In one or more embodiments, a compound represented by Formula 601 may be represented by Formula 601-1:

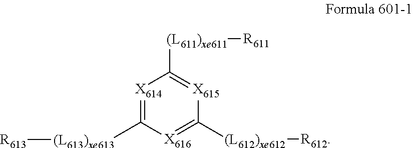

In Formula 601-1,

X₆₁₄ may be N or C(R₆₁₄), X₆₁₅ may be N or C(R₆₁₅), X₆₁₆ may be N or C(R₆₁₆), and at least one selected from X₆₁₄ to X₆₁₆ may be N,

L₆₁₁ to L₆₁₃ may each independently be the same as described herein in connection with L₆₀₁,

xe611 to xe613 may each independently be the same as described herein in connection with xe1,

R₆₁₁ to R₆₁₃ may each independently be the same as described herein in connection with R₆₀₁,

R₆₁₄ to R₆₁₆ may each independently be selected from hydrogen, deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, and a naphthyl group.

In one embodiment, L₆₀₁ and L₆₁₁ to L₆₁₃ in Formulae 601 and 601-1 may each independently be selected from the group consisting of:

a phenylene group, a naphthylene group, a fluorenylene group, a spiro-bifluorenylene group, a benzofluorenylene group, a dibenzofluorenylene group, a phenanthrenylene group, an anthracenylene group, a fluoranthenylene group, a triphenylenylene group, a pyrenylene group, a chrysenylene group, a perylenylene group, a pentaphenylene group, a hexacenylene group, a pentacenylene group, a thiophenylene group, a furanylene group, a carbazolylene group, an indolylene group, an isoindolylene group, a benzofuranylene group, a benzothiophenylene group, a dibenzofuranylene group, a dibenzothiophenylene group, a benzocarbazolylene group, a dibenzocarbazolylene group, a dibenzosilolylene group, a pyridinylene group, an imidazolylene group, a pyrazolylene group, a thiazolylene group, an isothiazolylene group, an oxazolylene group, an isoxazolylene group, a thiadiazolylene group, an oxadiazolylene group, a pyrazinylene group, a pyrimidinylene group, a pyridazinylene group, a triazinylene group, a quinolinylene group, an isoquinolinylene group, a benzoquinolinylene group, a phthalazinylene group, a naphthyridinylene group, a quinoxalinylene group, a quinazolinylene group, a cinnolinylene group, a phenanthridinylene group, an acridinylene group, a phenanthrolinylene group, a phenazinylene group, a benzimidazolylene group, an isobenzothiazolylene group, a benzoxazolylene group, an isobenzoxazolylene group, a triazolylene group, a tetrazolylene group, an imidazopyridinylene group, an imidazopyrimidinylene group, and an azacarbazolylene group; and

a phenylene group, a naphthylene group, a fluorenylene group, a spiro-bifluorenylene group, a benzofluorenylene group, a dibenzofluorenylene group, a phenanthrenylene group, an anthracenylene group, a fluoranthenylene group, a triphenylenylene group, a pyrenylene group, a chrysenylene group, a perylenylene group, a pentaphenylene group, a hexacenylene group, a pentacenylene group, a thiophenylene group, a furanylene group, a carbazolylene group, an indolylene group, an isoindolylene group, a benzofuranylene group, a benzothiophenylene group, a dibenzofuranylene group, a dibenzothiophenylene group, a benzocarbazolylene group, a dibenzocarbazolylene group, a dibenzosilolylene group, a pyridinylene group, an imidazolylene group, a pyrazolylene group, a thiazolylene group, an isothiazolylene group, an oxazolylene group, an isoxazolylene group, a thiadiazolylene group, an oxadiazolylene group, a pyrazinylene group, a pyrimidinylene group, a pyridazinylene group, a triazinylene group, a quinolinylene group, an isoquinolinylene group, a benzoquinolinylene group, a phthalazinylene group, a naphthyridinylene group, a quinoxalinylene group, a quinazolinylene group, a cinnolinylene group, a phenanthridinylene group, an acridinylene group, a phenanthrolinylene group, a phenazinylene group, a benzimidazolylene group, an isobenzothiazolylene group, a benzoxazolylene group, an isobenzoxazolylene group, a triazolylene group, a tetrazolylene group, an imidazopyridinylene group, an imidazopyrimidinylene group, and an azacarbazolylene group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, a naphthyl group, a fluorenyl group, a spiro-bifluorenyl group, a banzofluorenyl group, a dibenzofluorenyl group, a phenanthrenyl group, an anthracenyl group, a fluoranthenyl group, a triphenylenyl group, a pyrenyl group, a chrysenyl group, a peryenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzoccarbazolyl group, a dibenzosilolyl group, a pyridinyl group, an imidazolyl group, a pyrazolyl group, a thiazolyl group, an isothiazolyl group, an oxazolyl group, an isoxazolyl group, a thiadiazolyl group, an oxadiazolyl group, a pyrazinyl group, a pyrimidinyl group, a pyridazinyl group, a triazinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzimidazolyl group, an isobenzothiazolyl group, a benzoxazolyl group, an isobenzoxazolyl group, a triazolyl group, a tetrazolyl group, an imidazopyridinyl group, an imidazopyrimidinyl group, and an azacarbazolyl group, but embodiments of the present disclosure are not limited thereto.

In one or more embodiments, xe1 and xe611 to xe613 in Formulae 601 and 601-1 may each independently be 0, 1, or 2.

In one or more embodiments, R₆₀₁ and R₆₁₁ to R₆₁₃ in Formula 601 and 601-1 may each independently be selected from the group consisting of:

a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, an imidazolyl group, a pyrazolyl group, a thiazolyl group, an isothiazolyl group, an oxazolyl group, an isoxazolyl group, a thiadiazolyl group, an oxadiazolyl group, a pyrazinyl group, a pyrimidinyl group, a pyridazinyl group, a triazinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzimidazolyl group, an isobenzothiazolyl group, a benzoxazolyl group, an isobenzoxazolyl group, a triazolyl group, a tetrazolyl group, an imidazopyridinyl group, an imidazopyrimidinyl group, and an azacarbazolyl group;

a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, an imidazolyl group, a pyrazolyl group, a thiazolyl group, an isothiazolyl group, an oxazolyl group, an isoxazolyl group, a thiadiazolyl group, an oxadiazolyl group, a pyrazinyl group, a pyrimidinyl group, a pyridazinyl group, a triazinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzimidazolyl group, an isobenzothiazolyl group, a benzoxazolyl group, an isobenzoxazolyl group, a triazolyl group, a tetrazolyl group, an imidazopyridinyl group, an imidazopyrimidinyl group, and an azacarbazolyl group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, an imidazolyl group, a pyrazolyl group, a thiazolyl group, an isothiazolyl group, an oxazolyl group, an isoxazolyl group, a thiadiazolyl group, an oxadiazolyl group, a pyrazinyl group, a pyrimidinyl group, a pyridazinyl group, a triazinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzimidazolyl group, an isobenzothiazolyl group, a benzoxazolyl group, an isobenzoxazolyl group, a triazolyl group, a tetrazolyl group, an imidazopyridinyl group, an imidazopyrimidinyl group, and an azacarbazolyl group; and

—S(═O)₂(Q₆₀₁) and —P(═O)(Q₆₀₁)(Q₆₀₂),

wherein Q₆₀₁ and Q₆₀₂ may each independently be the same as described above.

The electron transport region may include at least one compound selected from Compounds ET1 to ET36, but embodiments of the present disclosure are not limited thereto:

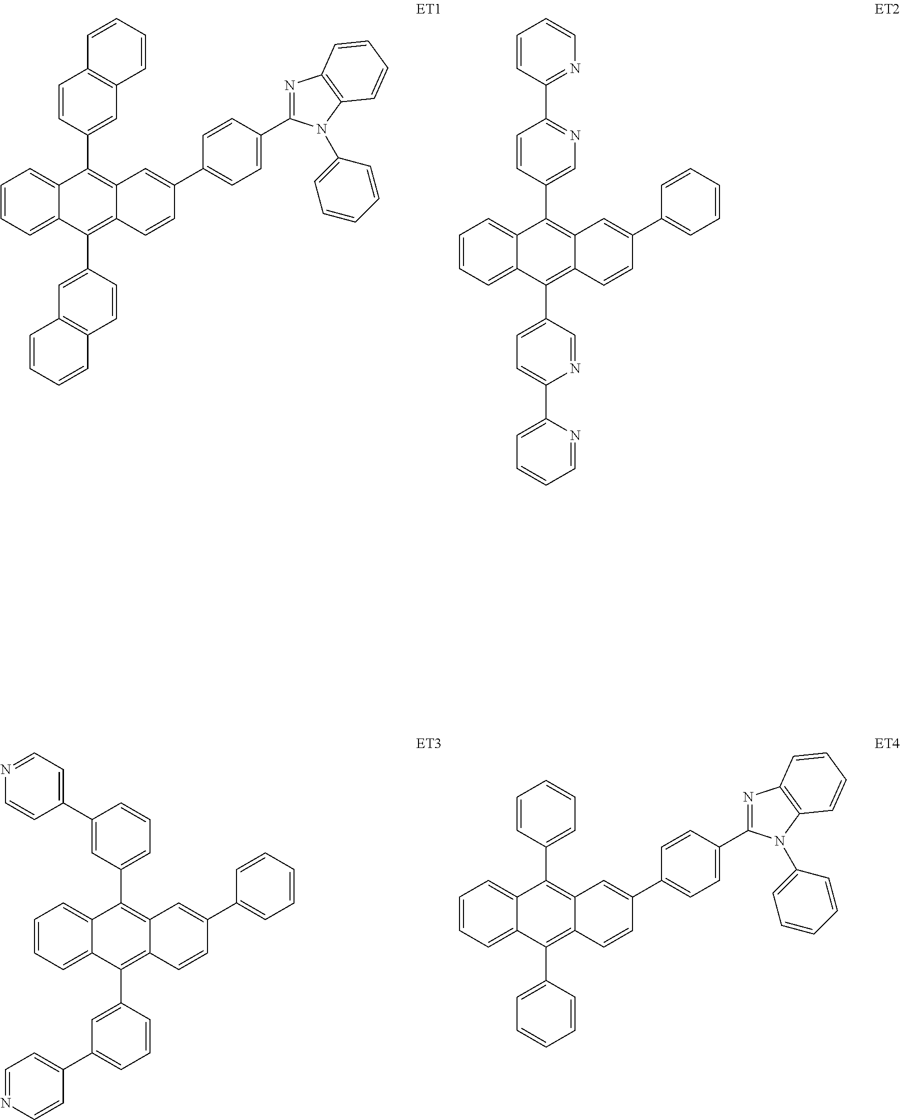 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1 ; c1ccc(-c2c3ccccc3c(-c3ccccc3)c3cc(-c4ccc(-c5nc6ccccc6n5-c5ccccc5)cc4)ccc23)cc1]

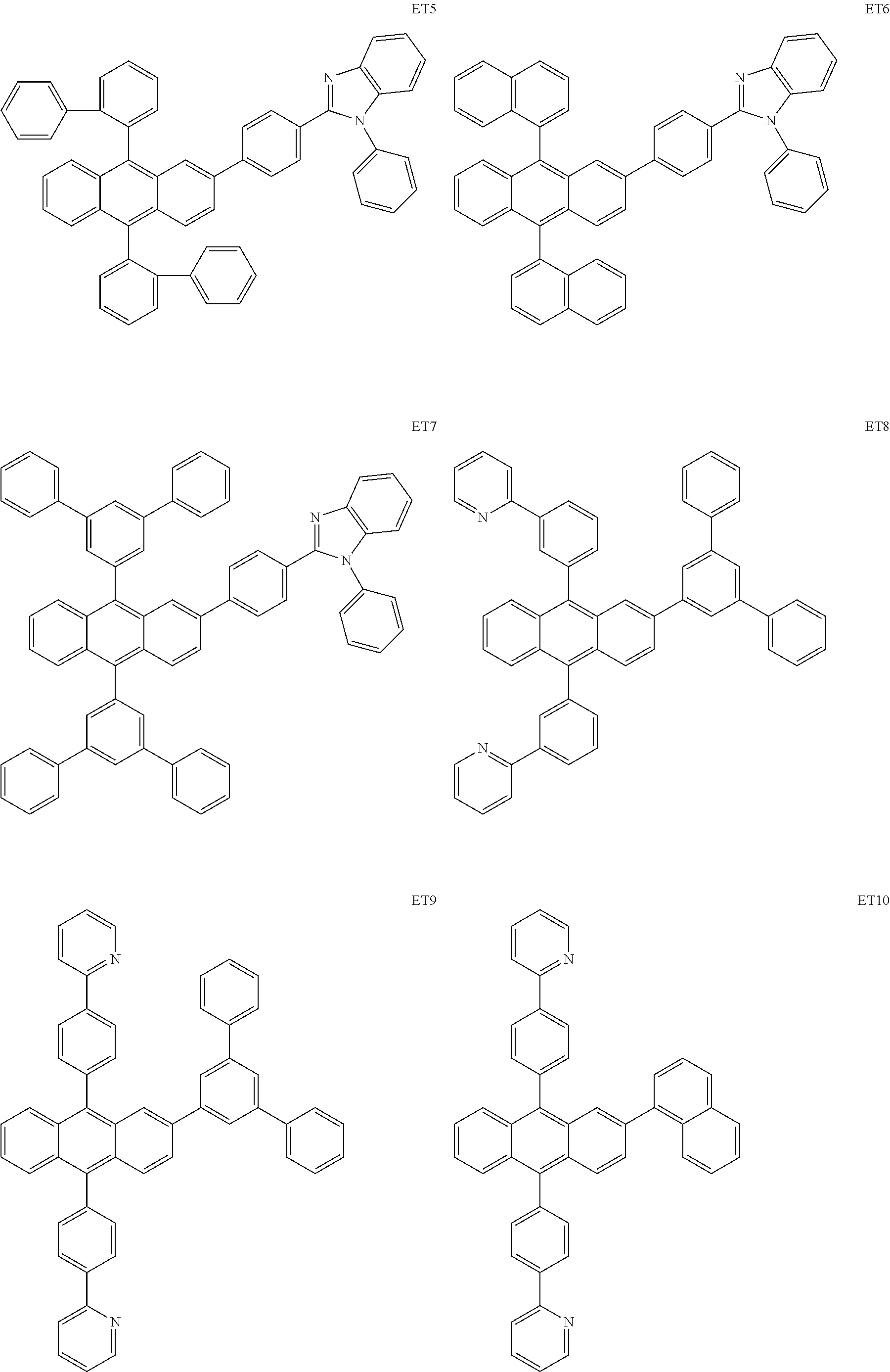

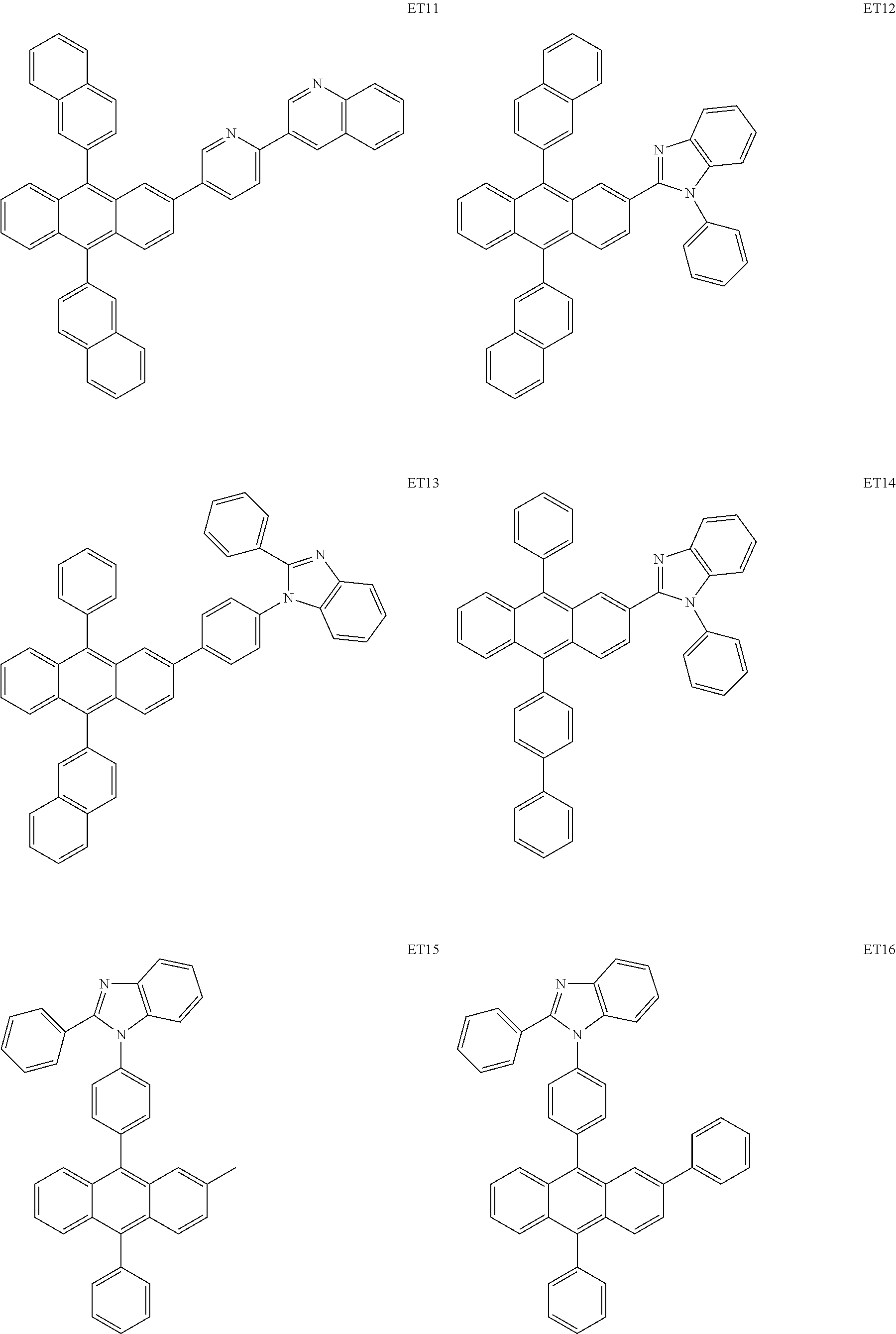 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

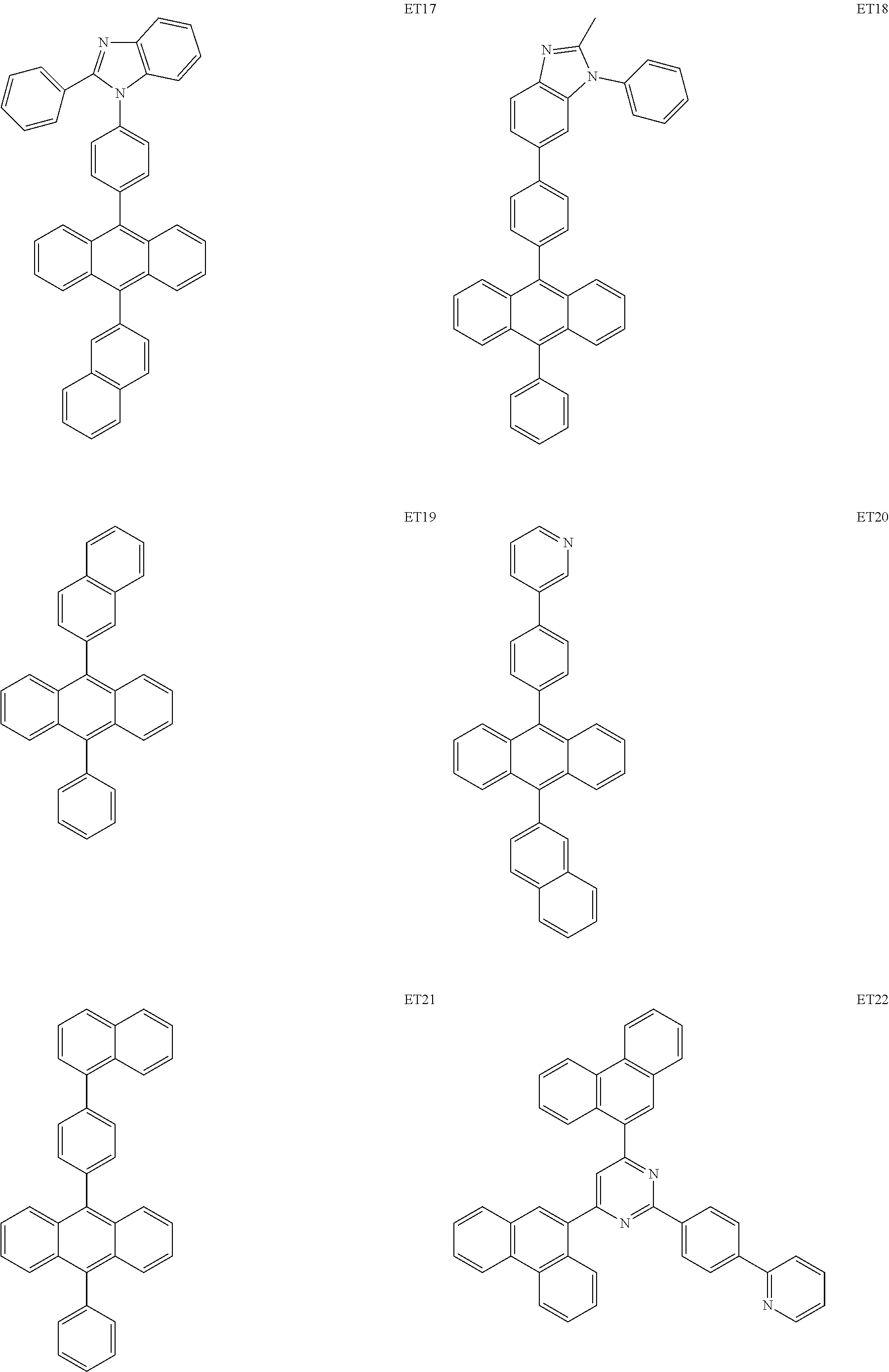

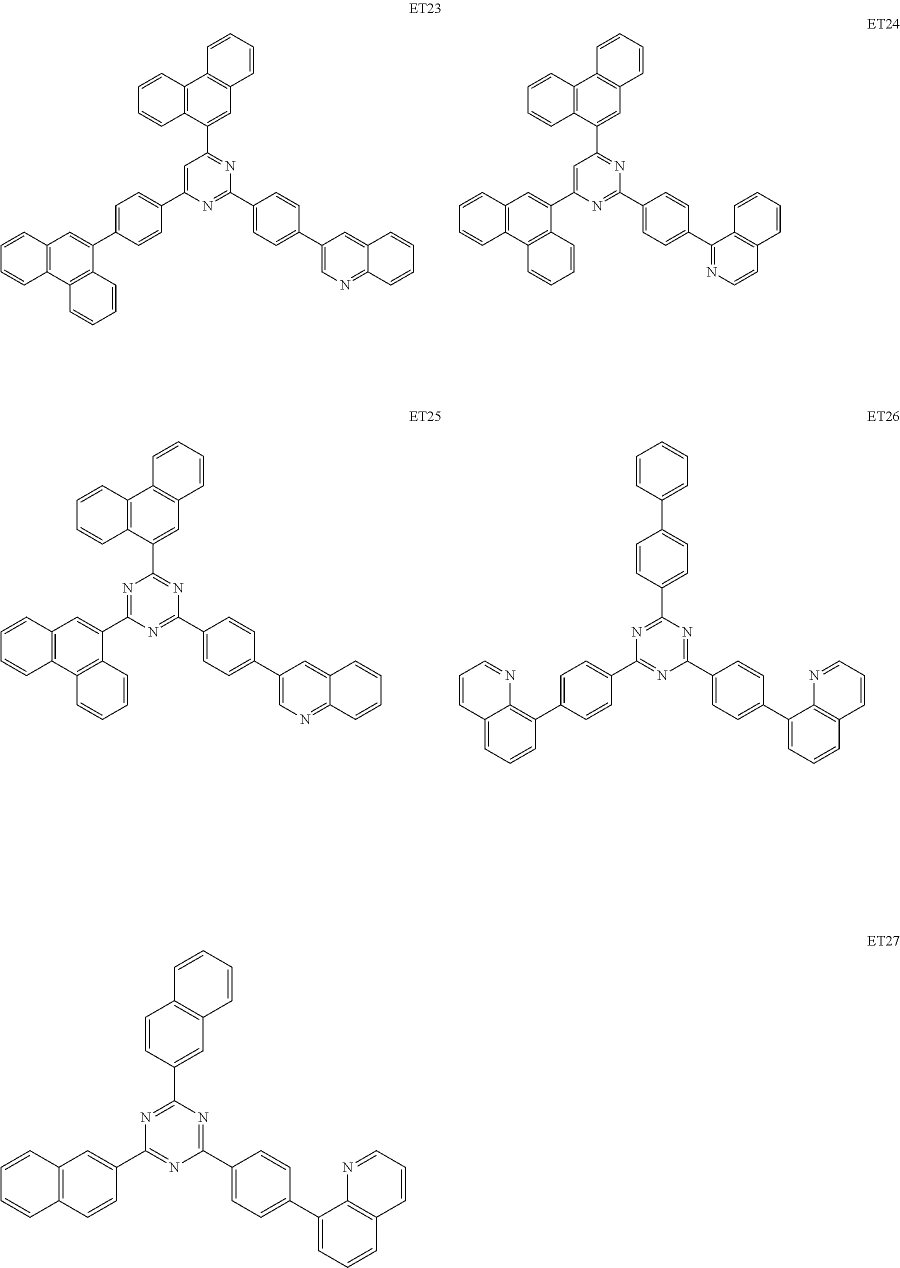 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

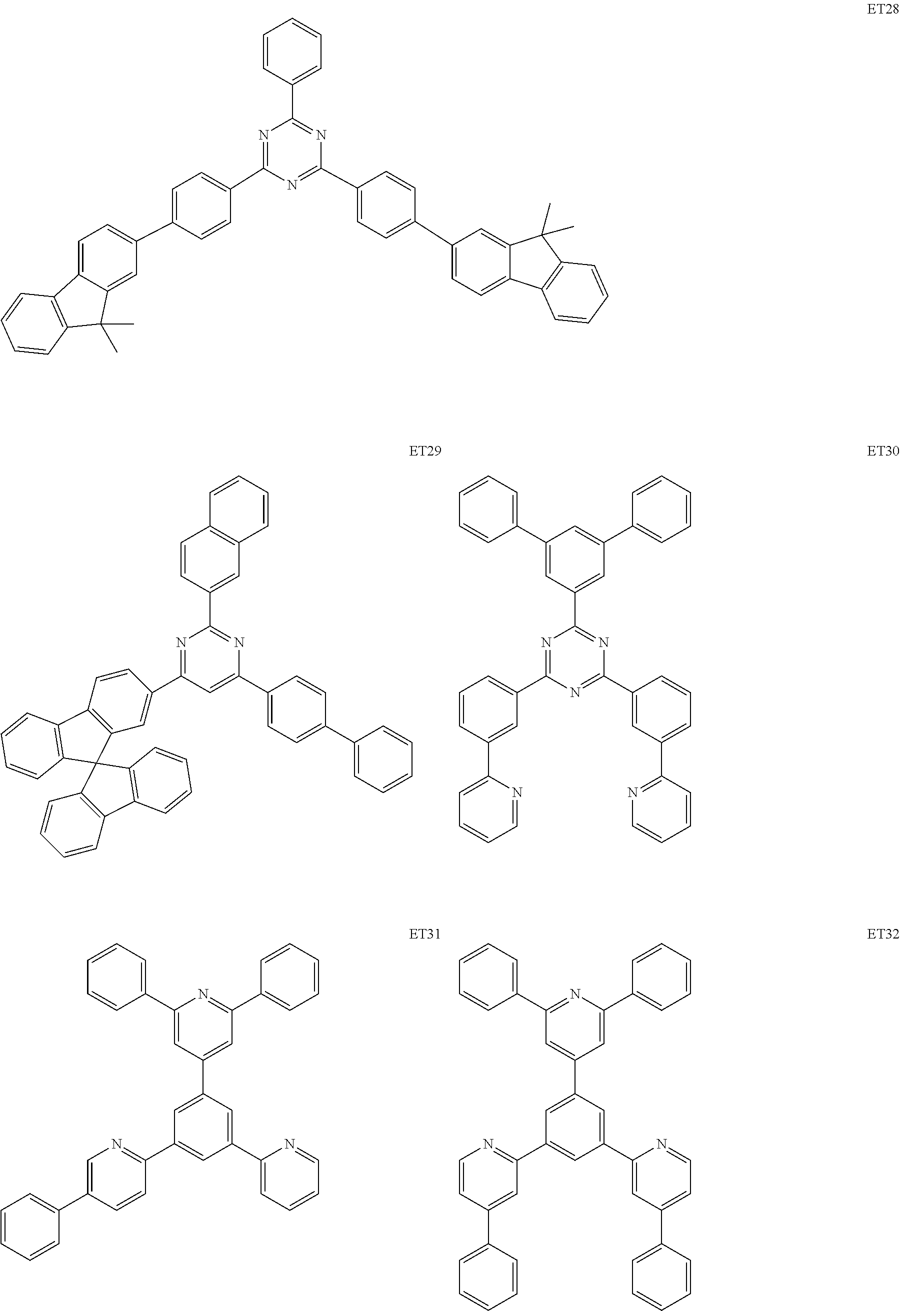 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1]

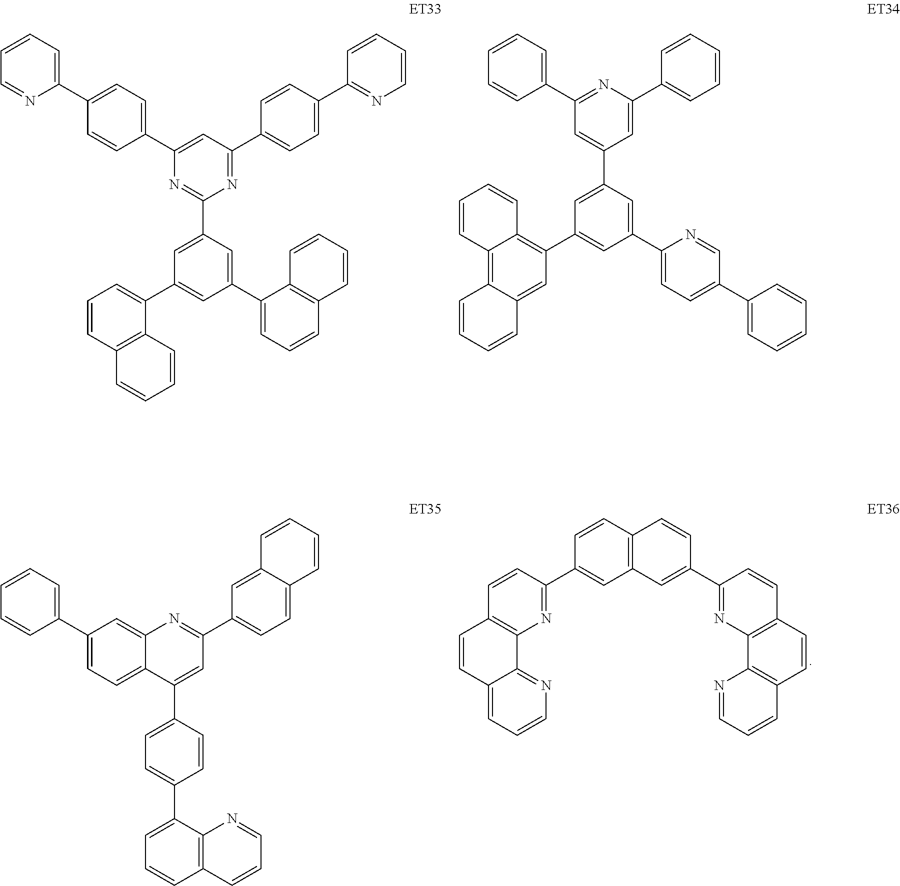 [SMILES: c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In one or more embodiments, the electron transport region may include at least one selected from BCP (2,9-dimethyl-4,7-diphenyl-1,10-phenanthroline), BPhen (4,7-diphenyl-1,10-phenanthroline), Alq₃, BAlq, TAZ(3-(biphenyl-4-yl)-5-(4-tert-butylphenyl)-4-phenyl-4H-1,2,4-triazole), and NTAZ.

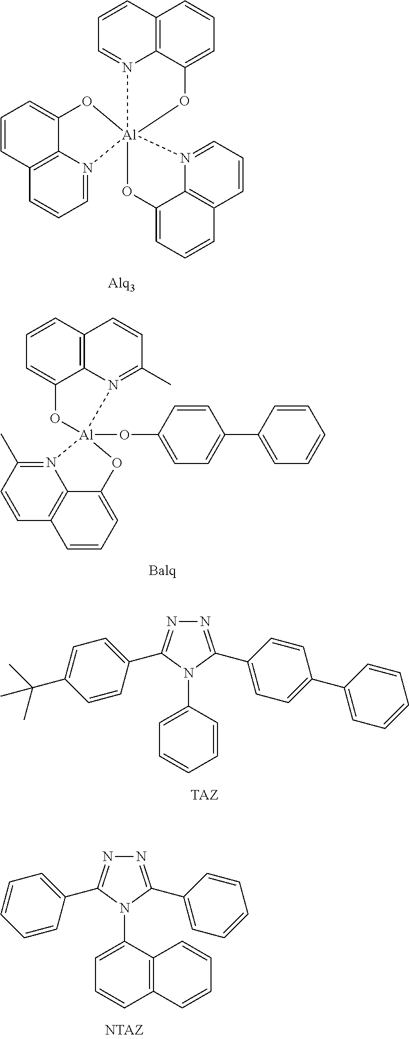

The thicknesses of the buffer layer, the hole blocking layer, and/or the electron controlling layer may each independently be about 20 Å to about 1,000 Å, and in some embodiments, about 30 Å to about 300 Å. When the thicknesses of the buffer layer, the hole blocking layer, and the electron control layer are each within these ranges, the electron blocking layer may have excellent electron blocking characteristics and/or electron control characteristics without a substantial increase in driving voltage.

The thickness of the electron transport layer may be about 100 Å to about 1,000 Å, and in some embodiments, about 150 Å to about 500 Å. When the thickness of the electron transport layer is within these ranges, the electron transport layer may have satisfactory electron transport characteristics without a substantial increase in driving voltage.

The electron transport region (for example, the electron transport layer in the electron transport region) may further include, in addition to the materials described above, a metal-containing material.

The metal-containing material may include at least one selected from an alkali metal complex and an alkaline earth metal complex. The alkali metal complex may include a metal ion selected from a lithium (Li) ion, a sodium (Na) ion, a potassium (K) ion, a rubidium (Rb) ion, and a cesium (Cs) ion, and the alkaline earth metal complex may include a metal ion selected from a beryllium (Be) ion, a magnesium (Mg) ion, a calcium (Ca) ion, a strontium (Sr) ion, and a barium (Ba) ion. Each ligand coordinated with the metal ion of the alkali metal complex or the alkaline earth metal complex may independently be selected from a hydroxyquinoline, a hydroxyisoquinoline, a hydroxybenzoquinoline, a hydroxyacridine, a hydroxyphenanthridine, a hydroxyphenyl oxazole, a hydroxyphenyl thiazole, a hydroxydiphenyl oxadiazole, a hydroxydiphenyl thiadiazole, a hydroxyphenyl pyridine, a hydroxyphenyl benzimidazole, a hydroxyphenyl benzothiazole, a bipyridine, a phenanthroline, and a cyclopentadiene, but embodiments of the present disclosure are not limited thereto.

For example, the metal-containing material may include a Li complex. The Li complex may include, for example, Compound ET-D1 (lithium quinolate, LiQ) and/or ET-D2.

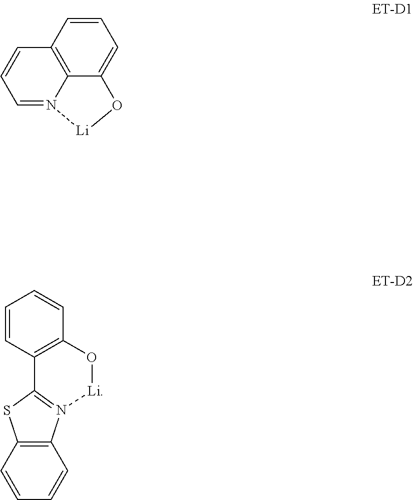

The electron transport region may include an electron injection layer that facilitates injection of electrons from the second electrode 190. The electron injection layer may directly contact the second electrode 190.

The electron injection layer may have i) a single-layered structure including a single layer including a single material, ii) a single-layered structure including a single layer including a plurality of different materials, or iii) a multi-layered structure having a plurality of layers including a plurality of different materials.

The electron injection layer may include an alkali metal, an alkaline earth metal, a rare earth metal, an alkali metal compound, an alkaline earth metal compound, a rare earth metal compound, an alkali metal complex, an alkaline earth metal complex, a rare earth metal complex, or a combination thereof.

In one or more embodiments, the electron injection layer may include Li, Na, K, rubidium (Rb), cesium (Cs), Mg, Ca, erbium (Er), thulium (Tm), ytterbium (Yb), or a combination thereof. However, embodiments of the material included in the electron injection layer are not limited thereto.

The alkali metal may be selected from Li, Na, K, Rb, and Cs. In one embodiment, the alkali metal may be Li, Na, or Cs. In one or more embodiments, the alkali metal may be Li or Cs, but embodiments of the present disclosure are not limited thereto.

The alkaline earth metal may be selected from Mg, Ca, Sr, and Ba.

The rare earth metal may be selected from scandium (Sc), yttrium (Y), cerium (Ce), ytterbium (Yb), gadolinium (Gd), and terbium (Tb).

The alkali metal compound, the alkaline earth metal compound, and the rare earth metal compound may be selected from oxides and halides (for example, fluorides, chlorides, bromides, and/or iodides) of the alkali metal, the alkaline earth metal, and the rare earth metal.

The alkali metal compound may be selected from alkali metal oxides (such as Li₂O, Cs₂O, and/or K₂O) and alkali metal halides (such as LiF, NaF, CsF, KF, LiI, NaI, CsI, RbI, and/or KI). In one embodiment, the alkali metal compound may be selected from LiF, Li₂O, NaF, LiI, NaI, CsI, and KI, but embodiments of the present disclosure are not limited thereto.

The alkaline earth metal compound may be selected from alkaline earth metal compounds (such as BaO, SrO, CaO, BaₓSr₁₋ₓO (0<x<1), and/or BaₓCa₁₋ₓO (0<x<1)). In one embodiment, the alkaline earth metal compound may be selected from BaO, SrO, and CaO, but embodiments of the present disclosure are not limited thereto.

The rare earth metal compound may be selected from YbF₃, ScF₃, ScO₃, Y₂O₃, Ce₂O₃, GdF₃, and TbF₃. In one embodiment, the rare earth metal compound may be selected from YbF₃, ScF₃, TbF₃, YbI₃, ScI₃, and TbI₃, but embodiments of the present disclosure are not limited thereto.

The alkali metal complex, the alkaline earth metal complex, and the rare earth metal complex may include an alkali metal ion, an alkaline earth metal ion, and a rare earth metal ion, respectively, as described above, and each ligand coordinated with a metal ion of the alkali metal complex, the alkaline earth metal complex, and the rare earth metal complex may independently be selected from hydroxyquinoline, hydroxyisoquinoline, hydroxybenzoquinoline, hydroxyacridine, hydroxyphenanthridine, hydroxyphenyl oxazole, hydroxyphenyl thiazole, hydroxydiphenyl oxadiazole, hydroxydiphenyl thiadiazole, hydroxyphenyl pyridine, hydroxyphenyl benzimidazole, hydroxyphenyl benzothiazole, bipyridine, phenanthroline, and cyclopentadiene, but embodiments of the present disclosure are not limited thereto.

The electron injection layer may include (e.g., consist of) an alkali metal, an alkaline earth metal, a rare earth metal, an alkali metal compound, an alkaline earth metal compound, a rare earth metal compound, an alkali metal complex, an alkaline earth metal complex, a rare earth metal complex, or a combination thereof, as described above. In one or more embodiments, the electron injection layer may further include an organic material. When the electron injection layer further includes an organic material, the alkali metal, the alkaline earth metal, the rare earth metal, the alkali metal compound, the alkaline earth metal compound, the rare earth metal compound, the alkali metal complex, the alkaline earth metal complex, the rare earth metal complex, or the combination thereof may be homogeneously or non-homogeneously dispersed in a matrix including the organic material.

The thickness of the electron injection layer may be about 1 Å to about 100 Å, and in some embodiments, about 3 Å to about 90 Å. When the thickness of the electron injection layer is within these ranges, the electron injection layer may have satisfactory electron injection characteristics without a substantial increase in driving voltage.

At least one layer selected from the electron transport layer and the electron injection layer may include the alkali metal, the alkaline earth metal, the rare earth metal, the alkali metal compound, the alkaline earth metal compound, the rare earth metal compound, the alkali metal complex, the alkaline earth metal complex, the rare earth metal complex, or the combination thereof.

### Second Electrode 190

The second electrode 190 may be on the organic layer 150. The second electrode 190 may be a cathode that is an electron injection electrode, and in this regard, the material for forming the second electrode 190 may be a material having a low work function, and such a material may be a metal, an alloy, an electrically conductive compound, or a combination thereof.

The second electrode 190 may include at least one selected from lithium (Li), silver (Ag), magnesium (Mg), aluminum (Al), aluminum-lithium (Al—Li), calcium (Ca), magnesium-indium (Mg—In), magnesium-silver (Mg—Ag), ITO, and IZO, but embodiments of the present disclosure are not limited thereto. The second electrode 190 may be a transmissive electrode, a semi-transmissive electrode, or a reflective electrode.

The second electrode 190 may have a single-layer structure, or a multi-layer structure including two or more layers.

### Description of FIGS. 2 to 5

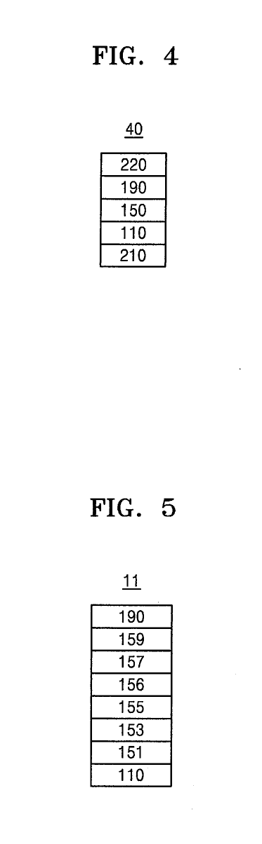

An organic light-emitting device 20 represented by FIG. 2 includes a first capping layer 210, a first electrode 110, an organic layer 150, and a second electrode 190 sequentially stacked in this stated order. An organic light-emitting device 30 represented by FIG. 3 includes a first electrode 110, an organic layer 150, a second electrode 190, and a second capping layer 220 sequentially stacked in this stated order. An organic light-emitting device 40 represented by FIG. 4 includes a first capping layer 210, a first electrode 110, an organic layer 150, a second electrode 190, and a second capping layer 220.

Regarding FIGS. 2 to 4, the first electrode 110, the organic layer 150, and the second electrode 190 may each be the same as described herein in connection with FIG. 1.

In the organic layer 150 of each of the organic light-emitting devices 20 and 40, light generated in an emission layer may pass through the first electrode 110 (which may be a semi-transmissive electrode or a transmissive electrode) and the first capping layer 210 toward the outside. In the organic layer 150 of each of the organic light-emitting devices 30 and 40, light generated in an emission layer may pass through the second electrode 190 (which may be a semi-transmissive electrode or a transmissive electrode) and the second capping layer 220 toward the outside.

The first capping layer 210 and the second capping layer 220 may increase the external luminescent efficiency of the device according to the principle of constructive interference.

The first capping layer 210 and the second capping layer 220 may each independently be a capping layer including an organic material, an inorganic capping layer including an inorganic material, or a composite capping layer including an organic material and an inorganic material.

At least one selected from the first capping layer 210 and the second capping layer 220 may include at least one material selected from carbocyclic compounds, heterocyclic compounds, amine-based compounds, porphyrin derivatives, phthalocyanine derivatives, naphthalocyanine derivatives, alkali metal-based complexes, and alkaline earth metal-based complexes. The carbocyclic compound, the heterocyclic compound, and the amine-based compound may each be optionally substituted with a substituent containing at least one element selected from O, N, S, Se, silicon (Si), fluorine (F), chlorine (Cl), bromine (Br), and iodine (I).

In one embodiment, at least one selected from the first capping layer 210 and the second capping layer 220 may include an amine-based compound.

In one embodiment, at least one selected from the first capping layer 210 and the second capping layer 220 may include the compound represented by Formula 201 and/or the compound represented by Formula 202.

In one or more embodiments, at least one selected from the first capping layer 210 and the second capping layer 220 may include a compound selected from Compounds HT28 to HT33 and Compounds CP1 to CP5, but embodiments of the present disclosure are not limited thereto.

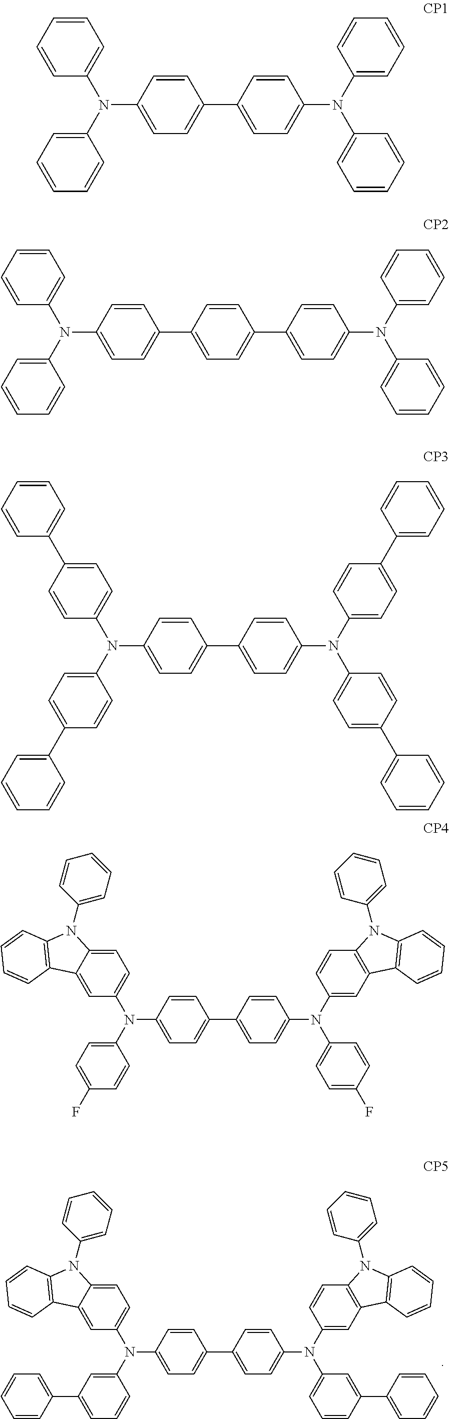 [SMILES: c1ccc(N(c2ccccc2)c2ccc(-c3ccc(N(c4ccccc4)c4ccccc4)cc3)cc2)cc1 ; c1ccc(N(c2ccccc2)c2ccc(-c3ccc(-c4ccc(N(c5ccccc5)c5ccccc5)cc4)cc3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1]

FIG. 5 is a schematic view of an organic light-emitting device 11 according to an embodiment of the present disclosure. The organic light-emitting device 11 may include a first electrode 110, a hole transport layer 151, an emission auxiliary layer 153, an emission layer 155, a buffer layer 156, an electron transport layer 157, an electron injection layer 159, and a second electrode 190 sequentially stacked in this stated order.

The layers included in the organic light-emitting device 11 of FIG. 5 may be the same as described above.

Hereinbefore, an organic light-emitting device according to an embodiment of the present disclosure has been described in connection with FIGS. 1 to 5. However, embodiments of the present disclosure are not limited thereto.

The layers constituting the hole transport region, the emission layer, and the layers constituting the electron transport region may be formed in a specific region using one or more suitable methods selected from vacuum deposition, spin coating, casting, a Langmuir-Blodgett (LB) method, ink-jet printing, laser-printing, and laser-induced thermal imaging (LITI).

When the respective layers of the hole transport region, the emission layer, and the respective layers of the electron transport region are each formed by deposition, the deposition may be performed at a deposition temperature of about 100 to about 500° C., at a vacuum degree of about 10⁻⁸ to about 10⁻³ torr, and at a deposition rate of about 0.01 to about 100 Å/sec, depending on the material to be deposited in each layer, and the structure of each layer to be formed.

When the layers constituting the hole transport region, the emission layer, and the layers constituting the electron transport region are each formed by spin coating, the spin coating may be performed at a coating speed of about 2,000 rpm to about 5,000 rpm and at a heat treatment temperature of about 80° C. to 200° C., depending on the material to be included in each layer, and the structure of each layer to be formed.

### General Definitions of Substituents

The term “C₁-C₆₀ alkyl group”, as used herein, refers to a linear or branched aliphatic saturated hydrocarbon monovalent group having 1 to 60 carbon atoms, and non-limiting examples thereof may include a methyl group, an ethyl group, a propyl group, an isobutyl group, a sec-butyl group, a ted-butyl group, a pentyl group, an iso-amyl group, and a hexyl group. The term “C₁-C₆₀ alkylene group”, as used herein, refers to a divalent group having substantially the same structure as the C₁-C₆₀ alkyl group.

The term “C₂-C₆₀ alkenyl group”, as used herein, refers to a hydrocarbon group formed by substituting at least one carbon-carbon double bond in the body (e.g., middle) or at the terminus of the C₂-C₆₀ alkyl group, and non-limiting examples thereof may include an ethenyl group, a propenyl group, and a butenyl group. The term “C₂-C₆₀ alkylene group”, as used herein, refers to a divalent group having substantially the same structure as the C₂-C₆₀ alkyl group.

The term “C₂-C₆₀ alkynyl group”, as used herein, refers to a hydrocarbon group formed by substituting at least one carbon-carbon triple bond in the body (e.g., middle) or at the terminus of the C₂-C₆₀ alkyl group, and non-limiting examples thereof may include an ethynyl group and a propynyl group. The term “C₂-C₆₀ alkylene group”, as used herein, refers to a divalent group having substantially the same structure as the C₂-C₆₀ alkyl group.

The term “C₁-C₆₀ alkoxy group”, as used herein, refers to a monovalent group represented by —O-A₁₀₁ (wherein A₁₀₁ is a C₁-C₆₀ alkyl group), and non-limiting examples thereof may include a methoxy group, an ethoxy group, and an isopropyloxy group.

The term “C₃-C₁₀ cycloalkyl group”, as used herein, refers to a monovalent saturated hydrocarbon monocyclic group having 3 to 10 carbon atoms, and non-limiting examples thereof may include a cyclopropyl group, a cyclobutyl group, a cyclopentyl group, a cyclohexyl group, and a cycloheptyl group. The term “C₃-C₁₀ cycloalkylene group”, as used herein, refers to a divalent group having substantially the same structure as the C₃-C₁₀ cycloalkyl group.

The term “C₁₀-C₁₀ heterocycloalkyl group”, as used herein, refers to a monovalent monocyclic group having at least one heteroatom selected from N, O, Si, P, and S as a ring-forming atom and 1 to 10 carbon atoms, and non-limiting examples thereof may include a 1,2,3,4-oxatriazolidinyl group, a tetrahydrofuranyl group, and a tetrahydrothiophenyl group. The term “C₁-C₁₀ heterocycloalkylene group”, as used herein, refers to a divalent group having substantially the same structure as the C₁-C₁₀ heterocycloalkyl group.

The term “C₃-C₁₀ cycloalkenyl group”, as used herein, refers to a monovalent monocyclic group that has 3 to 10 carbon atoms and at least one double bond in the ring thereof and does not have aromaticity, and non-limiting examples thereof include a cyclopentenyl group, a cyclohexenyl group, and a cycloheptenyl group. The term “C₃-C₁₀ cycloalkenylene group”, as used herein, refers to a divalent group having substantially the same structure as the C₃-C₁₀ cycloalkenyl group.

The term “C₁-C₁₀ heterocycloalkenyl group”, as used herein, refers to a monovalent monocyclic group that has at least one heteroatom selected from N, O, Si, P, and S as a ring-forming atom, 1 to 10 carbon atoms, and at least one double bond in its ring. Non-limiting examples of the C₁-C₁₀ heterocycloalkenyl group may include a 4,5-dihydro-1,2,3,4-oxatriazolyl group, a 2,3-dihydrofuranyl group, and a 2,3-dihydrothiophenyl group. The term “C₁-C₁₀ heterocycloalkenylene group”, as used herein, refers to a divalent group having substantially the same structure as the C₁-C₁₀ heterocycloalkenyl group.

The term “C₆-C₆₀ aryl group”, as used herein, refers to a monovalent group having a carbocyclic aromatic system having 6 to 60 carbon atoms, and the term “C₆-C₆₀ arylene group”, as used herein, refers to a divalent group having a carbocyclic aromatic system having 6 to 60 carbon atoms. Non-limiting examples of the C₆-C₆₀ aryl group may include a phenyl group, a naphthyl group, an anthracenyl group, a phenanthrenyl group, a pyrenyl group, and a chrysenyl group. When the C₆-C₆₀ aryl group and the C₆-C₆₀ arylene group each include two or more rings, the rings may be fused (e.g., condensed).

The term “C₁-C₆₀ heteroaryl group”, as used herein, refers to a monovalent group having a heterocyclic aromatic system that has at least one heteroatom selected from N, O, Si, P, and S as a ring-forming atom, and 1 to 60 carbon atoms. The term “C₁-C₆₀ heteroarylene group”, as used herein, refers to a divalent group having a heterocyclic aromatic system that has at least one heteroatom selected from N, O, Si, P, and S as a ring-forming atom, and 1 to 60 carbon atoms. Non-limiting examples of the C₁-C₆₀ heteroaryl group may include a pyridinyl group, a pyrimidinyl group, a pyrazinyl group, a pyridazinyl group, a triazinyl group, a quinolinyl group, and an isoquinolinyl group. When the C₁-C₆₀ heteroaryl group and the C₁-C₆₀ heteroarylene group each include two or more rings, the rings may be fused (e.g., condensed).

The term “C₆-C₆₀ aryloxy group”, as used herein, refers to —O-A₁₀₂ (wherein A₁₀₂ is a C₆-C₆₀ aryl group), and the term “C₆-C₆₀ arylthio group” as used herein indicates —S-A₁₀₃ (wherein A₁₀₃ is a C₆-C₆₀ aryl group).

The term “monovalent non-aromatic condensed polycyclic group”, as used herein, refers to a monovalent group that has two or more rings condensed (e.g., fused), only carbon atoms (for example, 8 to 60 carbon atoms) as a ring forming atom, and non-aromaticity in the entire molecular structure. A non-limiting example of a monovalent non-aromatic condensed polycyclic group may be a fluorenyl group. The term “divalent non-aromatic condensed polycyclic group”, as used herein, refers to a divalent group having substantially the same structure as the monovalent non-aromatic condensed polycyclic group.

The term “monovalent non-aromatic condensed heteropolycyclic group”, as used herein, refers to a monovalent group that has two or more rings condensed (e.g., fused), has at least one heteroatom selected from N, O, Si, P, and S, other than carbon atoms (for example, 1 to 60 carbon atoms), as a ring forming atom, and has non-aromaticity in the entire molecular structure. A non-limiting example of a monovalent non-aromatic condensed heteropolycyclic group may be a carbazolyl group. The term “divalent non-aromatic condensed heteropolycyclic group”, as used herein, refers to a divalent group having substantially the same structure as the monovalent non-aromatic condensed heteropolycyclic group.

The term “C₅-C₆₀ carbocyclic group”, as used herein, refers to a monocyclic or polycyclic group having 5 to 60 carbon atoms as the only ring-forming atoms. The term “C₅-C₆₀ carbocyclic group”, as used herein refers to an aromatic carbocyclic group or a non-aromatic carbocyclic group. The term “C₅-C₆₀ carbocyclic group”, as used herein, refers to a ring (such as a benzene), a monovalent group (such as a phenyl group), or a divalent group (such as a phenylene group). In one or more embodiments, depending on the number of substituents connected to the C₅-C₆₀ carbocyclic group, the C₅-C₆₀ carbocyclic group may be a trivalent group or a quadrivalent group.

The term “C₁-C₆₀ heterocyclic group”, as used herein, refers to a group having substantially the same structure as the C₁-C₆₀ carbocyclic group, except that as a ring-forming atom, at least one heteroatom selected from N, O, Si, P, and S is used in addition to carbon (the number of carbon atoms may be 1 to 60).

As used herein, at least one substituent of the substituted C₅-C₆₀carbocyclic group, substituted C₁-C₆₀ heterocyclic group, substituted C₃-C₁₀ cycloalkylene group, substituted C₁-C₁₀ heterocycloalkylene group, substituted C₃-C₁₀ cycloalkenylene group, substituted C₁-C₁₀ heterocycloalkenylene group, substituted C₆-C₆₀ arylene group, substituted C₁-C₆₀ heteroarylene group, a substituted divalent non-aromatic condensed polycyclic group, a substituted divalent non-aromatic condensed heteropolycyclic group, substituted C₁-C₆₀ alkyl group, substituted C₂-C₆₀ alkenyl group, substituted C₂-C₆₀ alkynyl group, substituted C₁-C₆₀ alkoxy group, substituted C₃-C₁₀ cycloalkyl group, substituted C₁-C₁₀ heterocycloalkyl group, substituted C₃-C₁₀ cycloalkenyl group, substituted C₁-C₁₀ heterocycloalkenyl group, substituted C₆-C₆₀ aryl group, substituted C₆-C₆₀ aryloxy group, substituted C₆-C₆₀ arylthio group, substituted C₁-C₆₀ heteroaryl group, substituted monovalent non-aromatic condensed polycyclic group, and substituted monovalent non-aromatic condensed heteropolycyclic group may be selected from the group consisting of:

deuterium (-D), —F, —Cl, —Br, —I, a hydroxyl group, a cyano group, a nitro group, an amidino group, a hydrazino group, a hydrazono group, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₂-C₆₀ alkenyl group, a C₂-C₆₀ alkynyl group, and a C₁-C₆₀ alkoxy group, each substituted with at least one selected from deuterium, —F, —Cl, —Br, —I, a hydroxyl group, a cyano group, a nitro group, an amidino group, a hydrazino group, a hydrazono group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), and —P(═O)(Q₁₁)(Q₁₂),

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group, each substituted with at least one selected from deuterium, —F, —Cl, —Br, —I, a hydroxyl group, a cyano group, a nitro group, an amidino group, a hydrazino group, a hydrazono group, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), and —P(═O)(Q₂₁)(Q₂₂), and

—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), and —P(═O)(Q₃₁)(Q₃₂),

wherein Q₁ to Q₃, Q₁₁ to Q₁₃, Q₂₁ to Q₂₃, and Q₃₁ to Q₃₃ may each independently be selected from hydrogen, deuterium, —F, —Cl, —Br, —I, a hydroxyl group, a cyano group, a nitro group, an amidino group, a hydrazino group, a hydrazono group, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryl group substituted with a C₁-C₆₀ alkyl group, a C₆-C₆₀ aryl group substituted with a C₆-C₆₀ aryl group, a terphenyl group, a C₁-C₆₀ heteroaryl group, a C₁-C₆₀ heteroaryl group substituted with C₁-C₆₀ alkyl group, a C₁-C₆₀ heteroaryl group substituted with a C₆-C₆₀ aryl group, a monovalent non-aromatic condensed polycyclic group, and a monovalent non-aromatic condensed heteropolycyclic group.

The term “Ph”, as used herein, may refer to a phenyl group; the term “Me”, as used herein, may refer to a methyl group; the term “Et”, as used herein, may refer to an ethyl group; the terms “ter-Bu” or “Bu^{t}”, as used herein, may refer to a ted-butyl group; and the term “OMe,” as used herein, may refer to a methoxy group.

The term “biphenyl group”, as used herein, may refer to “a phenyl group substituted with a phenyl group”. In other words, a biphenyl group is a substituted phenyl group having a C₆-C₆₀ aryl group as a substituent.

The term “terphenyl group”, as used herein, may refer to “a phenyl group substituted with a biphenyl group”. In other words, a terphenyl group is a substituted phenyl group having a C₆-C₆₀ aryl group substituted with a C₆-C₆₀ aryl group.

The symbols * and *′ used herein, unless defined otherwise, may refer to a binding site to a neighboring atom in a corresponding formula.

Hereinafter, compounds according to embodiments of the present disclosure and an organic light-emitting device according to embodiments of the present disclosure will be described in more detail with reference to Synthesis Examples and Examples. The wording “B was used instead of A” used in describing Synthesis Examples refers to that a molar equivalent of B was used in place of A.

### EXAMPLE

### Example 1-1

### Manufacture of Red Organic Light-Emitting Device

An ITO glass substrate (a product of Corning Co., Ltd) with an ITO layer having a thickness of 15 Ω/cm² (1,200 Å) thereon was cut to a size of 50 mm×50 mm×0.5mm, sonicated using isopropyl alcohol and pure water for 15 minutes, and cleaned by exposure to ultraviolet rays and ozone for 30 minutes, and the ITO glass substrate (anode) was mounted on a vacuum deposition apparatus.

m-MTDATA was vacuum-deposited on the ITO glass substrate to form a hole transport layer having a thickness of 700 Å. TCTA was vacuum-deposited on the hole transport layer to form an emission auxiliary layer having a thickness of 100 Å.

Compound 1-3 (host) and PD11 (dopant) were co-deposited on the emission auxiliary layer at a weight ratio of 98:2 to form an emission layer having a thickness of 300 Å.

Compound 2-9 was deposited on the emission layer to form a buffer layer having a thickness of 100 Å, and Alq₃ was vacuum-deposited on the buffer layer to form an electron transport layer having a thickness of 200 Å. LiF was deposited on the electron transport layer to form an electron injection layer having a thickness of 10 Å.

Then, Al was deposited on the electron injection layer to form a cathode having a thickness of 2,000 Å, thereby completing the manufacture of an organic light-emitting device.

### Examples 1-2 to 1-10 and Comparative Examples 1-1 to 1-3

Additional organic light-emitting devices were manufactured in substantially the same manner as in Example 1-1, except that each emission layer and each buffer layer were formed using the compounds shown in Table 5.

### Example 2-1

### Manufacture of Green Organic Light-Emitting Device

An ITO glass substrate (a product of Corning Co., Ltd) with an ITO layer having a thickness of 15 Ω/cm² (1,200 Å) thereon was cut to a size of 50 mm×50 mm×0.5mm, sonicated using isopropyl alcohol and pure water for 15 minutes each, and cleaned by exposure to ultraviolet rays and ozone for 30 minutes, and the ITO glass substrate (anode) was mounted on a vacuum deposition apparatus.

m-MTDATA was vacuum-deposited on the ITO glass substrate to form a hole transport layer having a thickness of 700 Å. TCTA was vacuum-deposited on the hole transport layer to form an emission auxiliary layer having a thickness of 100 Å.

Compound 1-3 (host) and PD13 (dopant) were co-deposited at a weight ratio of 90:10 on the emission auxiliary layer to form an emission layer having a thickness of 300 Å.

Compound 2-9 was deposited on the emission layer to form a buffer layer having a thickness of 100 Å, and Alq₃ was vacuum-deposited on the buffer layer to form an electron transport layer having a thickness of 200 Å. LiF was deposited on the electron transport layer to form an electron injection layer having a thickness of 10 Å.

Al was deposited on the electron injection layer to form a cathode having a thickness of 2,000 Å, thereby completing the manufacture of an organic light-emitting device.

### Examples 2-2 to 2-5 and Comparative Examples 2-1 to 2-3

Additional organic light-emitting devices were manufactured in substantially the same manner as in Example 2-1, except that each emission layer and each buffer layer were formed using the compounds shown in Table 5.

### Example 2-6

An organic light-emitting device was manufactured in substantially the same manner as in Example 2-1, except that in forming the emission layer, Compound 1-3 (first host), CBP (second host), and PD13 (dopant) were co-deposited at a weight ratio of 50:50:10.

### Examples 2-7 to 2-10

Additional organic light-emitting devices were manufactured in substantially the same manner as in Example 2-6, except that each emission layer and each buffer layer were formed using the compounds shown in Table 6.

### Examples 2-11 to 2-20

Additional organic light-emitting devices were manufactured in substantially the same manner as in Example 2-1, except that 1 wt % F4-TCNQ was doped in forming the hole transport layer, and the compounds shown in Table 5 were used in forming the emission layer and the buffer layer.

### Evaluation Example 1

The driving voltage and efficiency of each of the organic light-emitting devices of Examples 1-1 to 1-5 and 2-1 to 2-20 and Comparative Examples 1-1 to 1-3 and 2-1 to 2-3 were measured using a Keithley SMU 236 at 5 mA/cm². The results thereof are shown in Tables 5 and 6:

TABLE 5

| | Emission layer | | Weight ratio | Driving | |
|---|---|---|---|---|---|
| | (host) | Buffer layer | (host:dopant) | voltage (V) | Efficiency (cd/A) |
| Example 1-1 | Compound | Compound | 98:2 | 5.7 | 24.3 |
| | 1-3 | 2-9 | | | |
| Example 1-2 | Compound | Compound | 98:2 | 5.7 | 24.0 |
| | 1-7 | 2-19a | | | |
| Example 1-3 | Compound | Compound | 98:2 | 5.5 | 23.7 |
| | 1-7 | 2-149a | | | |
| Example 1-4 | Compound | Compound | 98:2 | 5.5 | 23.5 |
| | 1-24 | 2-38 | | | |
| Example 1-5 | Compound | Compound | 98:2 | 5.6 | 23.9 |
| | 1-24 | 2-58 | | | |
| Example 1-6 | Compound | Compound | 98:2 | 5.5 | 24.1 |
| | 1-43 | 2-162 | | | |
| Example 1-7 | Compound | Compound | 98:2 | 5.4 | 23.8 |
| | 1-71 | 2-176 | | | |
| Example 1-8 | Compound | Compound | 98:2 | 5.2 | 24.5 |
| | 1-71 | 2-13 | | | |
| Example 1-9 | Compound | Compound | 98:2 | 5.3 | 24.0 |
| | 1-72 | 2-217 | | | |
| Example 1-10 | Compound | Compound | 98:2 | 5.5 | 24.2 |
| | 1-57 | 2-59a | | | |
| Comparative | CBP | Compound | 98:2 | 5.9 | 22.1 |
| Example 1-1 | | 2-2 | | | |
| Comparative | Compound | BAlq | 98:2 | 6.1 | 21.8 |
| Example 1-2 | 1-3 | | | | |
| Comparative | CBP | BAlq | 98:2 | 6.2 | 21.6 |
| Example 1-3 | | | | | |
| Example 2-1 | Compound | Compound | 90:10 | 5.8 | 39.8 |
| | 1-3 | 2-9 | | | |
| Example 2-2 | Compound | Compound | 90:10 | 5.7 | 40.3 |
| | 1-30 | 2-48 | | | |
| Example 2-3 | Compound | Compound | 90:10 | 5.8 | 40.7 |
| | 1-72 | 2-136a | | | |
| Example 2-4 | Compound | Compound | 90:10 | 5.6 | 41.9 |
| | 1-53 | 2-1103 | | | |
| Example 2-5 | Compound | Compound | 90:10 | 5.7 | 41.3 |
| | 1-56 | 2-162 | | | |
| Example 2-11 | Compound | Compound | 90:10 | 5.3 | 41.7 |
| | 1-9 | 2-2a | | | |
| Example 2-12 | Compound | Compound | 90:10 | 5.4 | 42.0 |
| | 1-9 | 2-166 | | | |
| Example 2-13 | Compound | Compound | 90:10 | 5.2 | 41.5 |
| | 1-25 | 2-14a | | | |
| Example 2-14 | Compound | Compound | 90:10 | 5.3 | 41.9 |
| | 1-34 | 2-42a | | | |
| Example 2-15 | Compound | Compound | 90:10 | 5.3 | 42.7 |
| | 1-44 | 2-152a | | | |
| Example 2-16 | Compound | Compound | 90:10 | 5.4 | 42.3 |
| | 1-44 | 2-114 | | | |
| Example 2-17 | Compound | Compound | 90:10 | 5.5 | 41.6 |
| | 1-56 | 2-124 | | | |
| Example 2-18 | Compound | Compound | 90:10 | 5.2 | 41.8 |
| | 1-66 | 2-200 | | | |
| Example 2-19 | Compound | Compound | 90:10 | 5.4 | 42.3 |
| | 1-70 | 2-251 | | | |
| Example 2-20 | Compound | Compound | 90:10 | 5.3 | 42.6 |
| | 1-84 | 2-245 | | | |
| Comparative | CBP | Compound | 90:10 | 5.9 | 38.7 |
| Example 2-1 | | 2-9 | | | |
| Comparative | Compound | BAlq | 90:10 | 6.0 | 36.8 |
| Example 2-2 | 1-3 | | | | |
| Comparative | CBP | BAlq | 90:10 | 6.1 | 36.1 |
| Example 2-3 | | | | | |

TABLE 6

| | Emission layer | | Weight ratio | | |
|---|---|---|---|---|---|
| | (first host:second | | (first host:second | Driving | Efficiency |
| | host) | Buffer layer | host:dopant) | voltage (V) | (cd/A) |
| Example 2-6 | Compound1-1:CPB | Compound | 50:50:10 | 5.8 | 40.8 |
| | | 2-9 | | | |
| Example 2-7 | Compound 1-3:Compound | Compound | 50:50:10 | 5.5 | 41.7 |
| | 1-72 | 2-48 | | | |
| Example 2-8 | Compound 1-76:Compound | Compound | 50:50:10 | 5.7 | 41.6 |
| | CBP | 2-136a | | | |
| Example 2-9 | Compound 1-24:Compound | Compound | 50:50:10 | 5.4 | 42.0 |
| | 1-69 | 2-103 | | | |
| Example 2- | Compound 1-14:Compound | Compound | 50:50:10 | 5.5 | 42.3 |
| 10 | 1-53 | 2-162 | | | |

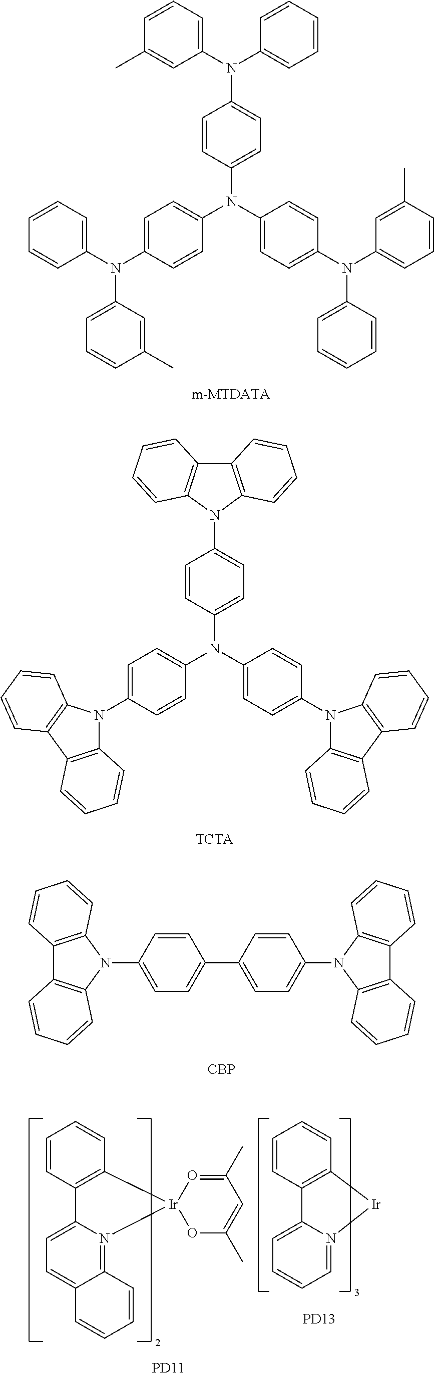

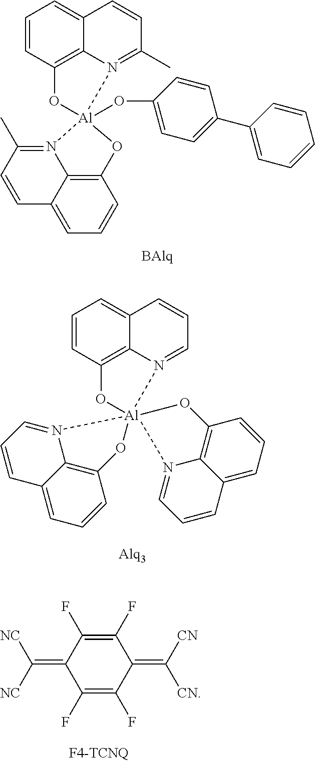

From Tables 5 and 6, it is seen that each of the organic light-emitting devices of Examples 1-1 to 1-10 have lower driving voltage and higher efficiency than each of the organic light-emitting devices of Comparative Examples 1-1 to 1-3, and each of the organic light-emitting devices of Examples 2-1 to 2-20 have lower driving voltage and higher efficiency than each of the organic light-emitting devices of Comparative Examples 2-1 to 2-3.

An organic light-emitting device according to an embodiment of the present disclosure may have low driving voltage and high efficiency.

It should be understood that the embodiments described herein should be considered in a descriptive sense only and not for purposes of limitation. Descriptions of features or aspects within each embodiment should typically be considered as being available for other similar features or aspects in other embodiments.

As used herein, the terms “use”, “using”, and “used” may be considered synonymous with the terms “utilize”, “utilizing”, and “utilized”, respectively. Further, the use of “may” when describing embodiments of the present disclosure refers to “one or more embodiments of the present disclosure”.

As used herein, the terms “substantially”, “about”, and similar terms are used as terms of approximation and not as terms of degree, and are intended to account for the inherent deviations in measured or calculated values that would be recognized by those of ordinary skill in the art.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

While one or more embodiments have been described with reference to the drawings, it will be understood by those of ordinary skill in the art that various changes in form and details may be made therein without departing from the spirit and scope of the present disclosure as defined by the following claims and equivalents thereof.

What is claimed is:

1. An organic light-emitting device comprising:
a first electrode;
a second electrode facing the first electrode;
an emission layer between the first electrode and the second electrode;
a hole transport region between the first electrode and the emission layer; and
an electron transport region between the emission layer and the second electrode,
wherein the emission layer comprises a first compound,
at least one selected from the hole transport region and the electron transport region comprises a second compound,
the first compound is represented by one selected from Formulae 1A to 1E, and
the second compound is represented by Formula 2A or 2B: 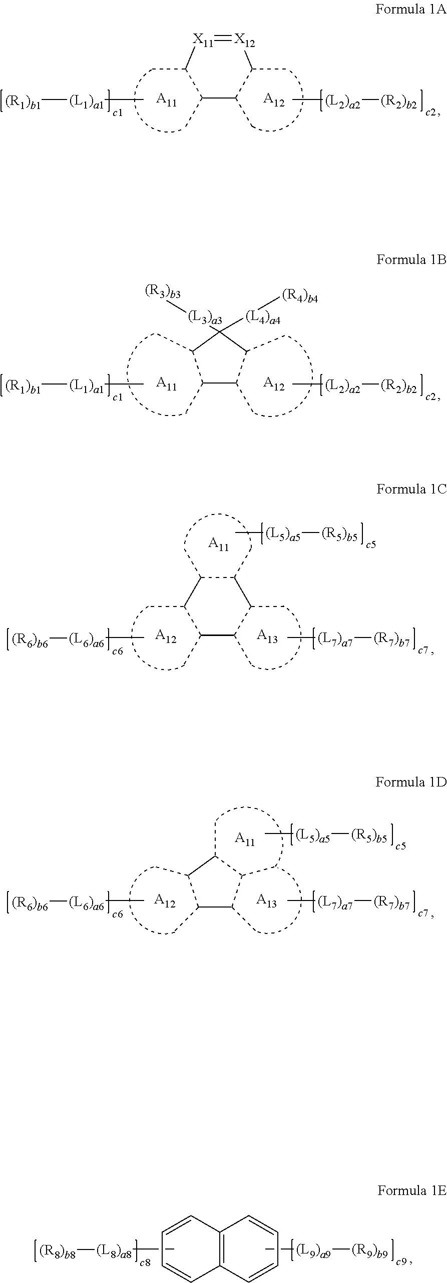 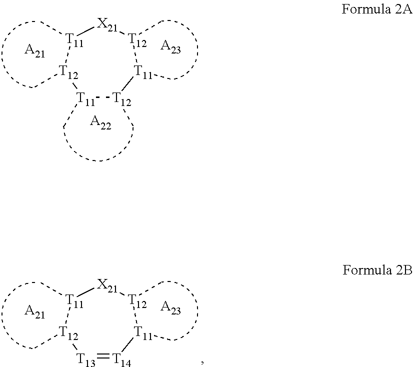
wherein, in Formulae 1A to 1E, 2A, and 2B,
rings A₁₁ to A₁₃ are each independently selected from a C₆-C₆₀ aromatic group, a C₁-C₆₀ heteroaromatic group, and a C₆-C₆₀ non-aromatic condensed polycyclic group,
rings A₂₁, A₂₂, and A₂₃ are each independently selected from a C₅-C₆₀ carbocyclic group and a C₁-C₈₀ heterocyclic group, each substituted with at least one *-[(L₂₂)ₐ₂₂-(R₂₂)_{b22}],
each T₁₁ and each T₁₂ are independently selected from carbon and nitrogen, two or more of the three T₁₁(s) in Formula 2A are identical to or different from each other, T₁₃ is N or C(R₂₇), T₁₄ is N or C(R₂₈), two or more of the three T₁₂(s) in Formula 2A are identical to or different from each other, the two T₁₁(s) in Formula 2B are identical to or different from each other, the two T₁₂(s) in Formula 2B are identical to or different from each other, and each bond between T₁₁ and T₁₂ is a single bond or a double bond; wherein the three T₁₁(s) and the three T₁₂(s) in Formula 2A are not all nitrogen, and the two T₁₁(s), the two T₁₂(s), and T₁₃ and T₁₄ in Formula 2B are not all nitrogen,
rings A₂₁, A₂₂, and A₂₃ are each fused with a central 7-membered ring in Formulae 2A and 2B, such that they each share a T₁₁ and a T₁₂ with the central 7-membered ring,
X₁₁ is N or C[(L₃)ₐ₃-(R₃)_{b3}], and X₁₂ is N or C[(L₄)ₐ₄-(R₄)_{b4}],
X₂₁ is selected from O, S, Se, C(R₂₃)(R₂₄), Si(R₂₃)(R₂₄), and N[(L₂₁)ₐ₂₁-(R₂₁)_{b21}],
L₁ to L₉ are each independently selected from a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, and a substituted or unsubstituted divalent non-aromatic condensed polycyclic group,
L₂₁ and L₂₂ are each independently selected from a substituted or unsubstituted C₃-C₁₈ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed heteropolycyclic group,
a1 to a9, a21, and a22 are each independently an integer selected from 0 to 5,
R₁ to R₉ are each independently selected from hydrogen, deuterium, —F, —Cl, —Br, —I, a hydroxyl group, a cyano group, a nitro group, an amidino group, a hydrazino group, a hydrazono group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, —Si(Q₁)(Q₂)(Q₃), —N(Q₁)(Q₂), —B(Q₁)(Q₂), —C(═O)(Q₁), —S(═O)₂(Q₁), and —P(═O)(Q₁)(Q₂),
R₂₁ to R₂₄, R₂₇, and R₂₈ are each independently selected from hydrogen, deuterium, —F, —Cl, —Br, —I, a hydroxyl group, a cyano group, a nitro group, an amidino group, a hydrazino group, a hydrazono group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₄)(Q₅)(Q₆), —N(Q₄)(Q₅), —B(Q₄)(Q₅), —C(═O)(Q₄), —S(═O)₂(Q₄), and —P(═O)(Q₄)(Q₅),
b1 to b9, b21, and b22 are each independently an integer selected from 1 to 3,
c1, c2, and c5 to c7 are each independently an integer selected from 0 to 10, provided that the sum of c5, c6, and c7 is 1 or more,
c8 and c9 are each independently an integer selected from 0 to 4, provided that the sum of c8 and c9 is 1 or more, and
at least one substituent of the substituted C₃-C₁₀ cycloalkylene group, substituted C₁-C₁₀ heterocycloalkylene group, substituted C₃-C₁₀ cycloalkenylene group, substituted C₁-C₁₀ heterocycloalkenylene group, substituted C₆-C₆₀ arylene group, substituted C₁-C₆₀ heteroarylene group, a substituted divalent non-aromatic condensed polycyclic group, substituted divalent non-aromatic condensed heteropolycyclic group, substituted C₁-C₆₀ alkyl group, substituted C₂-C₆₀ alkenyl group, substituted C₂-C₆₀ alkynyl group, substituted C₁-C₆₀ alkoxy group, substituted C₃-C₁₀ cycloalkyl group, substituted C₁-C₁₀ heterocycloalkyl group, substituted C₃-C₁₀ cycloalkenyl group, substituted C₁-C₁₀ heterocycloalkenyl group, substituted C₆-C₆₀ aryl group, substituted C₆-C₆₀ aryloxy group, substituted C₆-C₆₀ arylthio group, substituted C₁-C₆₀ heteroaryl group, substituted monovalent non-aromatic condensed polycyclic group, and substituted monovalent non-aromatic condensed heteropolycyclic group is selected from the group consisting of:
deuterium, —F, —Cl, —Br, —I, a hydroxyl group, a cyano group, a nitro group, an amidino group, a hydrazino group, a hydrazono group, a C₁-C₆₀ alkyl group, a C₂-C₆₀ alkenyl group, a C₂-C₆₀ alkynyl group, and a C₁-C₆₀ alkoxy group;
a C₁-C₆₀ alkyl group, a C₂-C₆₀ alkenyl group, a C₂-C₆₀ alkynyl group, and a C₁-C₆₀ alkoxy group, each substituted with at least one selected from deuterium, —F, —Cl, —Br, —I, a hydroxyl group, a cyano group, a nitro group, an amidino group, a hydrazino group, a hydrazono group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), and —P(═O)(Q₁₁)(Q₁₂),
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, a biphenyl group, and a terphenyl group;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group, each substituted with at least one selected from deuterium, —F, —Cl, —Br, —I, a hydroxyl group, a cyano group, a nitro group, an amidino group, a hydrazino group, a hydrazono group, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), and —P(═O)(Q₂₁)(Q₂₂); and
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), and —P(═O)(Q₃₁)(Q₃₂),
wherein Q₁ to Q₆, Q₁₁ to Q₁₃, Q₂₁ to Q₂₃, and Q₃₁ to Q₃₃ are each independently selected from hydrogen, deuterium, —F, —Cl, —Br, —I, a hydroxyl group, a cyano group, a nitro group, an amidino group, a hydrazino group, a hydrazono group, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryl group substituted with a C₁-C₆₀ alkyl group, a C₆-C₆₀ aryl group substituted with a C₆-C₆₀ aryl group, a terphenyl group, a C₁-C₆₀ heteroaryl group, a C₁-C₆₀ heteroaryl group substituted with a C₁-C₆₀ alkyl group, a C₁-C₆₀ heteroaryl group substituted with a C₆-C₆₀ aryl group, a monovalent non-aromatic condensed polycyclic group, and a monovalent non-aromatic condensed heteropolycyclic group.

2. The organic light-emitting device of claim 1, wherein:
rings A₁₁ to A₁₃ in Formulae 1A to 1D are each independently selected from a benzene group, a naphthalene group, an anthracene group, a phenanthrene group, a pyrene group, a triphenylene group, an indene group, a fluorene group, a benzofluorene group, a spiro-bifluorene group, a pyridine group, a pyrazine group, a pyrimidine group, a pyridazine group, a pyrrole group, an imidazole group, a quinoline group, an isoquinoline group, a quinoxaline group, a quinazoline group, a triazine group, an indenopyrazine group, an indenopyridine group, a phenanthroline group, and a phenanthridine group.

3. The organic light-emitting device of claim 1, wherein:
rings A₂₁, A₂₂, and A₂₃ in Formulae 2A and 2B are each independently selected from a benzene group, a naphthalene group, an anthracene group, an indene group, a fluorene group, a pyridine group, a pyrimidine group, a pyrazine group, a pyridazine group, a quinoline group, an isoquinoline group, a pyrrole group, a pyrazole group, an imidazole group, an oxazole group, a thiazole group, a cyclopentadiene group, a silole group, a selenophene group, a furan group, a thiophene group, an indole group, a benzimidazole group, a benzoxazole group, a benzothiazole group, an indene group, a benzosilole group, a benzoselenophene group, a benzofuran group, a benzothiophene group, a carbazole group, a fluorene group, a dibenzosilole group, a dibenzoselenophene group, a dibenzofuran group, a dibenzothiophene group, a pyrrolopyridine group, a cyclopentapyridine group, a silolopyridine group, a selenophenopyridine group, a furopyridine group, a thienopyridine group, a pyrrolopyrimidine group, a cyclopentapyrimidine group, a silolopyrimidine group, a selenophenopyrimidine group, a furopyrimidine group, a thienopyrimidine group, a pyrrolopyrazine group, a cyclopentapyrazine group, a silolopyrazine group, a selenophenopyrazine group, a furopyrazine group, a thienopyrazine group, a naphthopyrrole group, a cyclopentanaphthalene group, a naphthosilole group, a naphthoselenothiophene group, a naphthofuran group, a naphthothiophene group, a pyrroloquinoline group, a cyclopentaquinoline group, a siloloquinoline group, a selenophenoquinoline group, a furoquinoline group, a thienoquinoline group, a pyrroloisoquinoline group, a cyclopentaisoquinoline group, a siloloisoquinoline group, a selenophenoisoquinoline group, a furoisoquinoline group, a thienoisoquinoline group, an azacarbazole group, an azafluorene group, an azadibenzosilole group, an azadibenzoselenophene group, an azadibenzofuran group, an azadibenzothiophene group, an indenoquinoline group, an indenoisoquinoline group, an indenoquinoxaline group, a phenanthroline group, and an naphthoindole group, each substituted with at least one *-[(L₂₂)ₐ₂₂-(R₂₂)_{b22}].

4. The organic light-emitting device of claim 1, wherein:
rings A₂₁ A₂₂, and A₂₃ in Formulae 2A and 2B are each independently selected from groups represented by Formulae 2-1 to 2-36, each substituted with at least one *-[(L₂₂)ₐ₂₂-(R₂₂)_{b22})]: 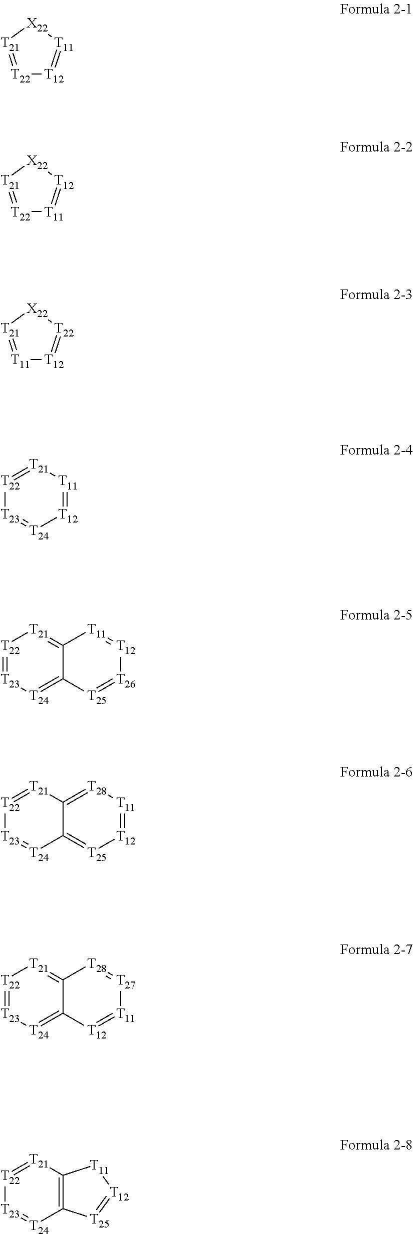 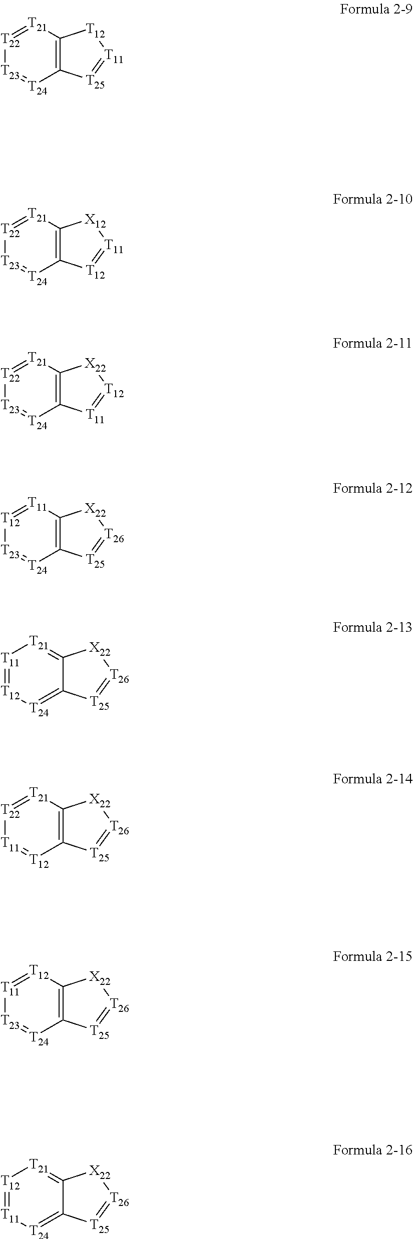 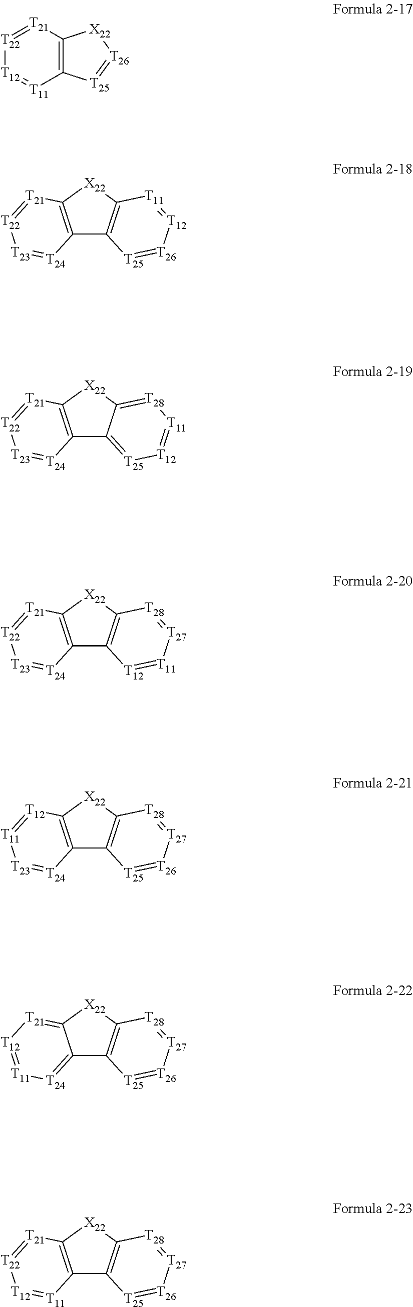 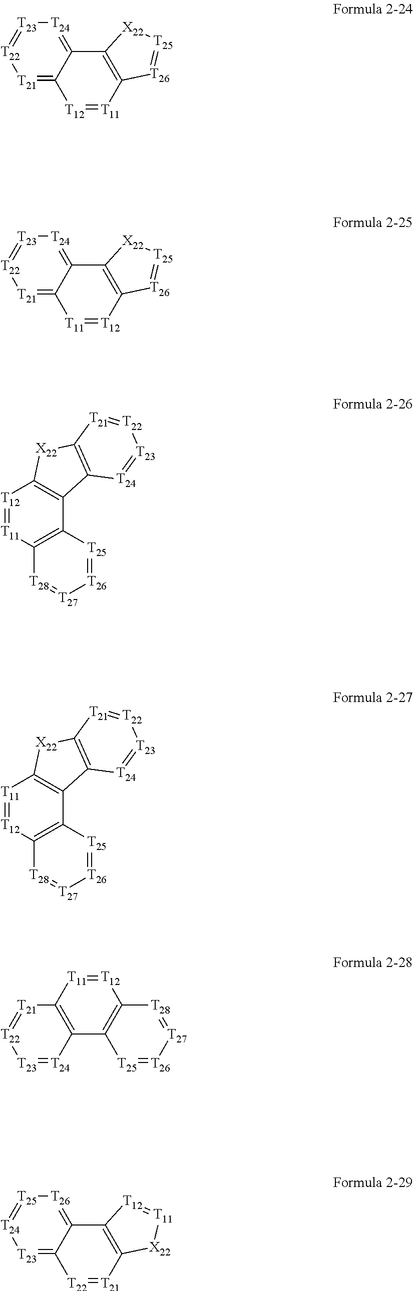 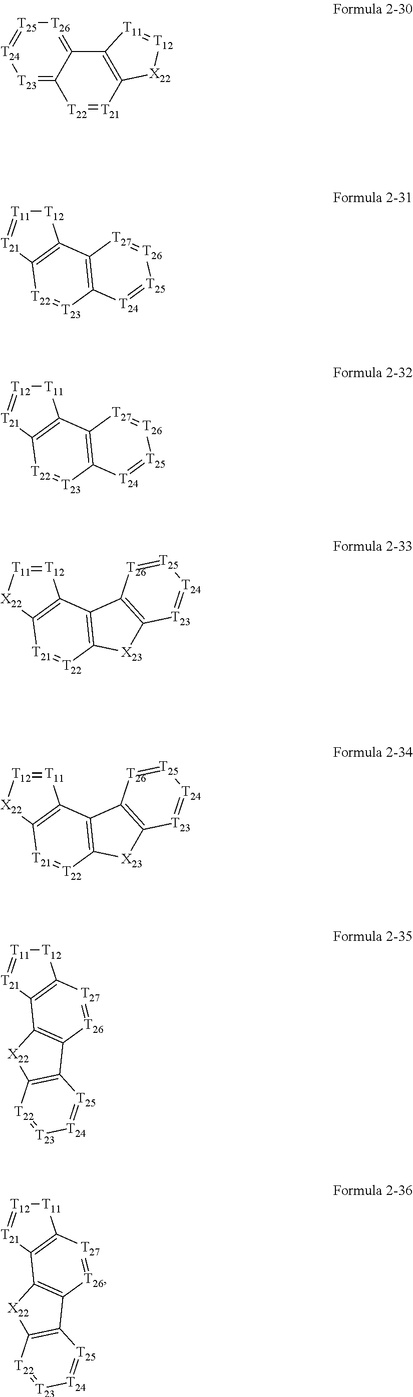
wherein, in Formulae 2-1 to 2-36,
T₁₁ and T₁₂ are each independently the same as described herein in connection with Formulae 2A and 2B,
X₂₂ and X₂₃ are each independently selected from O, S, Se, a moiety comprising C, a moiety comprising N, and a moiety comprising Si, and
T₂₁ to T₂₈ are each independently selected from N and a moiety comprising C.

5. The organic light-emitting device of claim 1, wherein X₂₁ in Formulae 2A and 2B is N[(L₂₁)ₐ₂₁-(R₂₁)_{b21}].

6. The organic light-emitting device of claim 4, wherein:
X₂₁ in Formulae 2A and 2B is O, S, Se, C(R₂₃)(R₂₄), or Si(R₂₃)(R₂₄),
at least one selected from rings A₂₁, A₂₂ and A₂₃ in Formula 2A and at least one selected from rings A₂₁ and A₂₃ in Formula 2B are each independently selected from groups represented by Formulae 2-1 to 2-3, 2-10 to 2-27, and 2-33 to 2-36, and
X₂₂ or X₂₃ in Formulae 2-1 to 2-3, 2-10 to 2-27, and 2-33 to 2-36 is N-[(L₂₂)ₐ₂₂-(R₂₂)_{b22}].

7. The organic light-emitting device of claim 1, wherein:
in Formulae 1A to 1E, 2A, and 2B,
L₁ to L₉ and L₂₁ and L₂₂ are each independently selected from the group consisting of:
a phenylene group, a pentalenylene group, an indenylene group, a naphthylene group, an azulenylene group, an indacenylene group, an acenaphthylene group, a fluorenylene group, a spiro-bifluorenylene group, a spiro-benzofluorene-fluorenylene group, a benzofluorenylene group, a dibenzofluorenylene group, a phenalenylene group, a phenanthrenylene group, an anthracenylene group, a fluoranthenylene group, a triphenylenylene group, a pyrenylene group, a chrysenylene group, a perylenylene group, a pentaphenylene group, a pyrrolylene group, a thiophenylene group, a furanylene group, a silolylene group, an imidazolylene group, a pyrazolylene group, a thiazolylene group, an isothiazolylene group, an oxazolylene group, an isoxazolylene group, a pyridinylene group, a pyrazinylene group, a pyrimidinylene group, a pyridazinylene group, an indolylene group, an isoindolylene group, an indazolylene group, a purinylene group, a quinolinylene group, an isoquinolinylene group, a benzoquinolinylene group, a phthalazinylene group, a naphthyridinylene group, a quinoxalinylene group, a quinazolinylene group, a cinnolinylene group, a phenanthridinylene group, an acridinylene group, a phenanthrolinylene group, a phenazinylene group, a benzimidazolylene group, a benzofuranylene group, a benzothiophenylene group, a benzosilolylene group, an isobenzothiazolylene group, a benzoxazolylene group, an isobenzoxazolylene group, a triazolylene group, a tetrazolylene group, an oxadiazolylene group, a triazinylene group, a dibenzofuranylene group, a dibenzothiophenylene group, a dibenzosilolylene group, a carbazolylene group, a benzocarbazolylene group, a dibenzocarbazolylene group, a thiadiazolylene group, an imidazopyridinylene group, an imidazopyrimidinylene group, an oxazolopyridinylene group, a thiazolopyridinylene group, a benzonaphthyridinylene group, an azafluorenylene group, an azaspiro-bifluorenylene group, an azacarbazolylene group, an azadibenzofuranylene group, an azadibenzothiophenylene group, and an azadibenzosilolylene group; and
a phenylene group, a pentalenylene group, an indenylene group, a naphthylene group, an azulenylene group, an indacenylene group, an acenaphthylene group, a fluorenylene group, a spiro-bifluorenylene group, a spiro-benzofluorene-fluorenylene group, a benzofluorenylene group, a dibenzofluorenylene group, a phenalenylene group, a phenanthrenylene group, an anthracenylene group, a fluoranthenylene group, a triphenylenylene group, a pyrenylene group, a chrysenylene group, a perylenylene group, a pentaphenylene group, a pyrrolylene group, a thiophenylene group, a furanylene group, a silolylene group, an imidazolylene group, a pyrazolylene group, a thiazolylene group, an isothiazolylene group, an oxazolylene group, an isoxazolylene group, a pyridinylene group, a pyrazinylene group, a pyrimidinylene group, a pyridazinylene group, an indolylene group, an isoindolylene group, an indazolylene group, a purinylene group, a quinolinylene group, an isoquinolinylene group, a benzoquinolinylene group, a phthalazinylene group, a naphthyridinylene group, a quinoxalinylene group, a quinazolinylene group, a cinnolinylene group, a phenanthridinylene group, an acridinylene group, a phenanthrolinylene group, a phenazinylene group, a benzimidazolylene group, a benzofuranylene group, a benzothiophenylene group, a benzosilolylene group, an isobenzothiazolylene group, a benzoxazolylene group, an isobenzoxazolylene group, a triazolylene group, a tetrazolylene group, an oxadiazolylene group, a triazinylene group, a dibenzofuranylene group, a dibenzothiophenylene group, a dibenzosilolylene group, a carbazolylene group, a benzocarbazolylene group, a dibenzocarbazolylene group, a thiadiazolylene group, an imidazopyridinylene group, an imidazopyrimidinylene group, an oxazolopyridinylene group, a thiazolopyridinylene group, a benzonaphthyridinylene group, an azafluorenylene group, an azaspiro-bifluorenylene group, an azacarbazolylene group, an azadibenzofuranylene group, an azadibenzothiophenylene group, and an azadibenzosilolylene group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, a monovalent non-aromatic condensed heteropolycyclic group, a biphenyl group, a terphenyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), and —P(═O)(Q₃₁)(Q₃₂); and
L₁ to L₉ are each not a substituted or unsubstituted carbazolylene group, a substituted or unsubstituted dibenzofuranylene group, a substituted or unsubstituted dibenzothiophenylene group, a substituted or unsubstituted dibenzosilolylene group, or a substituted or unsubstituted dibenzocarbazolylene group,
wherein Q₃₁ to Q₃₃ are each independently selected from the group consisting of:
a C₁-C₁₀ alkyl group, a C₁-C₁₀ alkoxy group, a phenyl group, a biphenyl group, a terphenyl group, a naphthyl group, a pyridinyl group, a pyrimidinyl group, a pyrazinyl group, a quinolinyl group, an isoquinolinyl group, a quinoxalinyl group, and a quinazolinyl group; and
a phenyl group, a biphenyl group, a terphenyl group, a naphthyl group, a pyridinyl group, a pyrimidinyl group, a pyrazinyl group, a quinolinyl group, an isoquinolinyl group, a quinoxalinyl group, and a quinazolinyl group, each substituted with at least one selected from a C₁-C₁₀ alkyl group, a C₁-C₁₀ alkoxy group, and a phenyl group.

8. The organic light-emitting device of claim 1, wherein:
in Formulae 1A to 1E, 2A, and 2B,
L₁ to L₉, L₂₁, and L₂₂ are each independently selected from the group consisting of:
a phenylene group, a pentalenylene group, an indenylene group, a naphthylene group, an azulenylene group, an indacenylene group, an acenaphthylene group, a fluorenylene group, a spiro-bifluorenylene group, a benzofluorenylene group, a dibenzofluorenylene group, a phenalenylene group, a phenanthrenylene group, an anthracenylene group, a fluoranthenylene group, a triphenylenylene group, a pyrenylene group, a chrysenylene group, a perylenylene group, a pentaphenylene group, a hexacenylene group, a pyrrolylene group, a thiophenylene group, a furanylene group, a silolylene group, an indolylene group, an isoindolylene group, a benzofuranylene group, a benzothiophenylene group, a benzosilolylene group, a dibenzofuranylene group, a dibenzothiophenylene group, a dibenzosilolylene group, a carbazolylene group, a benzocarbazolylene group, a dibenzocarbazolylene group, and a pyridinylene group; and
a phenylene group, a pentalenylene group, an indenylene group, a naphthylene group, an azulenylene group, an indacenylene group, an acenaphthylene group, a fluorenylene group, a spiro-bifluorenylene group, a benzofluorenylene group, a dibenzofluorenylene group, a phenalenylene group, a phenanthrenylene group, an anthracenylene group, a fluoranthenylene group, a triphenylenylene group, a pyrenylene group, a chrysenylene group, a perylenylene group, a pentaphenylene group, a hexacenylene group, a pyrrolylene group, a thiophenylene group, a furanylene group, a silolylene group, an indolylene group, an isoindolylene group, a benzofuranylene group, a benzothiophenylene group, a benzosilolylene group, a dibenzofuranylene group, a dibenzothiophenylene group, a dibenzosilolylene group, a carbazolylene group, a benzocarbazolylene group, a dibenzocarbazolylene group, and a pyridinylene group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, a pentalenyl group, an indenyl group, a naphthyl group, an azulenyl group, an indacenyl group, an acenaphthyl group, a fluorenyl group, a spiro-bifluorenylene group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pyrrolyl group, a thiophenyl group, a furanyl group, a silolyl group, a an indolyl group, an isoindolyl group, a benzofuranyl group, a benzothiophenyl group, a benzosilolyl group, a dibenzofuranyl group, a dibenzothiophenyl group, a dibenzosilolyl group, a carbazolyl group, a benzocarbazolyl group, a dibenzocarbazolyl group, a pyridinyl group, —Si(Q₃₁)(Q₃₂)(Q₃₃) —N(Q₃₁)(Q₃₂), —B(Q₃₁)(Q₃₂), —C(═O)(Q₃₁), —S(═O)₂(Q₃₁), and —P(═O)(Q₃₁)(Q₃₂),
L₁ to L₉ are each not a substituted or unsubstituted carbazolylene group, a substituted or unsubstituted dibenzofuranylene group, a substituted or unsubstituted dibenzothiophenylene group, a substituted or unsubstituted dibenzosilolylene group, or a substituted or unsubstituted dibenzocarbazolylene group,
Q31 to Q₃₃ are each independently selected from the group consisting of:
a C₁-C₁₀ alkyl group, a C₁-C₁₀ alkoxy group, a phenyl group, a biphenyl group, a terphenyl group, a naphthyl group, a pyridinyl group, a pyrimidinyl group, a pyrazinyl group, a quinolinyl group, an isoquinolinyl group, a quinoxalinyl group, and a quinazolinyl group; and
a phenyl group, a biphenyl group, a terphenyl group, a naphthyl group, a pyridinyl group, a pyrimidinyl group, a pyrazinyl group, a quinolinyl group, an isoquinolinyl group, a quinoxalinyl group, and a quinazolinyl group, each substituted with at least one selected from a C₁-C₁₀ alkyl group, a C₁-C₁₀ alkoxy group, and a phenyl group.

9. The organic light-emitting device of claim 1, wherein:
in Formulae 1A to 1E, 2A, and 2B,
R₁ to R₉ are each independently selected from the group consisting of:
hydrogen, deuterium, —F, —Cl, —Br, —I, a hydroxyl group, a cyano group, a nitro group, an amidino group, a hydrazino group, a hydrazono group, a C₁-C₂₀ alkyl group, and a C₁-C₂₀ alkoxy group;
a cyclopentyl group, a cyclohexyl group, a cycloheptyl group, a cyclopentenyl group, a cyclohexenyl group, a phenyl group, a biphenyl group, a terphenyl group, a pentalenyl group, an indenyl group, a naphthyl group, an azulenyl group, an indacenyl group, an acenaphthyl group, a fluorenyl group, a spiro-bifluorenyl group, a spiro-benzofluorene-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a pyrrolyl group, a thiophenyl group, a furanyl group, a silolyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an indolyl group, an isoindolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzimidazolyl group, a benzofuranyl group, a benzothiophenyl group, a benzosilyl group, an isobenzothiazolyl group, a benzoxazolyl group, an isobenzoxazolyl group, a triazolyl group, a tetrazolyl group, an oxadiazolyl group, a triazinyl group, a benzocarbazolyl group, a thiadiazolyl group, an imidazopyridinyl group, an imidazopyrimidinyl group, an oxazolopyridinyl group, a thiazolopyridinyl group, a benzonaphthyridinyl group, an azafluorenyl group, an azaspiro-bifluorenyl group, an azacarbazolyl group, an azadibenzofuranyl group, an azadibenzothiophenyl group, an azadibenzosilolyl group, —Si(Q₁)(Q₂)(Q₃), —N(Q₁)(Q₂), —B(Q₁(Q₂), —C(═O)(Q₁), —S(═O)₂(Q₁), and —P(═O)(Q₁)(Q₂); and
a cyclopentyl group, a cyclohexyl group, a cycloheptyl group, a cyclopentenyl group, a cyclohexenyl group, a phenyl group, a biphenyl group, a terphenyl group, a pentalenyl group, an indenyl group, a naphthyl group, an azulenyl group, an indacenyl group, an acenaphthyl group, a fluorenyl group, a spiro-bifluorenyl group, a spiro-benzofluorene-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a pyrrolyl group, a thiophenyl group, a furanyl group, a silolyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an indolyl group, an isoindolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzimidazolyl group, a benzofuranyl group, a benzothiophenyl group, a benzosilolyl group, an isobenzothiazolyl group, a benzoxazolyl group, an isobenzoxazolyl group, a triazolyl group, a tetrazolyl group, an oxadiazolyl group, a triazinyl group, a benzocarbazolyl group, a dibenzocarbazolyl group, a thiadiazolyl group, an imidazopyridinyl group, an imidazopyrimidinyl group, an oxazolopyridinyl group, a thiazolopyridinyl group, a benzonaphthyridinyl group, an azafluorenyl group, an azaspiro-bifluorenyl group, an azacarbazolyl group, an azadibenzofuranyl group, an azadibenzothiophenyl group, and an azadibenzosilolyl group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, a monovalent non-aromatic condensed heteropolycyclic group, a biphenyl group, a terphenyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), and —P(═O)(Q₃₁)(Q₃₂),
R₂₁ to R₂₄, R₂₇, and R₂₈ are each independently selected from the group consisting of:
hydrogen, deuterium, —F, —Cl, —Br, —I, a hydroxyl group, a cyano group, a nitro group, an amidino group, a hydrazino group, a hydrazono group, a C₁-C₂₀ alkyl group, and a C₁-C₂₀ alkoxy group;
a cyclopentyl group, a cyclohexyl group, a cycloheptyl group, a cyclopentenyl group, a cyclohexenyl group, a phenyl group, a biphenyl group, a terphenyl group, a pentalenyl group, an indenyl group, a naphthyl group, an azulenyl group, an indacenyl group, an acenaphthyl group, a fluorenyl group, a spiro-bifluorenyl group, a spiro-benzofluorene-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a pyrrolyl group, a thiophenyl group, a furanyl group, a silolyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an indolyl group, an isoindolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzimidazolyl group, a benzofuranyl group, a benzothiophenyl group, a benzosilolyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a dibenzosilolyl group, a carbazolyl group, a benzocarbazolyl group, a dibenzocarbazolyl group, a thiadiazolyl group, an imidazopyridinyl group, an imidazopyrimidinyl group, an oxazolopyridinyl group, a thiazolopyridinyl group, a benzonaphthyridinyl group, an azafluorenyl group, an azaspiro-bifluorenyl group, an azacarbazolyl group, an azadibenzofuranyl group, an azadibenzothiophenyl group, an azadibenzosilolyl group, —Si(Q₄)(Q₅)(Q₆), —N(Q₄)(Q₅), —B(Q₄)(Q₅), —C(═O)(Q₄), —S(═O)₂(Q₄), and —P(═O)(Q₄)(Q₅); and
a cyclopentyl group, a cyclohexyl group, a cycloheptyl group, a cyclopentenyl group, a cyclohexenyl group, a phenyl group, a biphenyl group, a terphenyl group, a pentalenyl group, an indenyl group, a naphthyl group, an azulenyl group, an indacenyl group, an acenaphthyl group, a fluorenyl group, a spiro-bifluorenyl group, a spiro-benzofluorene-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a pyrrolyl group, a thiophenyl group, a furanyl group, a silolyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an indolyl group, an isoindolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzimidazolyl group, a benzofuranyl group, a benzothiophenyl group, a benzosilolyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a dibenzosilolyl group, a carbazolyl group, a benzocarbazolyl group, a dibenzocarbazolyl group, a thiadiazolyl group, an imidazopyridinyl group, an imidazopyrimidinyl group, an oxazolopyridinyl group, a thiazolopyridinyl group, a benzonaphthyridinyl group, an azafluorenyl group, an azaspiro-bifluorenyl group, an azacarbazolyl group, an azadibenzofuranyl group, an azadibenzothiophenyl group, and an azadibenzosilolyl group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, a monovalent non-aromatic condensed heteropolycyclic group, a biphenyl group, a terphenyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), and —P(═O)(Q₃₁)(Q₃₂),
wherein Q₁ to Q₆ and Q₃₁ to Q₃₃ are each independently selected from the group consisting of:
a C₁-C₁₀ alkyl group, a C₁-C₁₀ alkoxy group, a phenyl group, a biphenyl group, a terphenyl group, a naphthyl group, a pyridinyl group, a pyrimidinyl group, a pyrazinyl group, a quinolinyl group, an isoquinolinyl group, a quinoxalinyl group, and a quinazolinyl group; and
a phenyl group, a biphenyl group, a terphenyl group, a naphthyl group, a pyridinyl group, a pyrimidinyl group, a pyrazinyl group, a quinolinyl group, an isoquinolinyl group, a quinoxalinyl group, and a quinazolinyl group, each substituted with at least one selected from a C₁-C₁₀ alkyl group, a C₁-C₁₀ alkoxy group, and a phenyl group.

10. The organic light-emitting device of claim 1, wherein:
in Formulae 1A to 1E, 2A, and 2B,
R₁ to R₉ are each independently selected from the group consisting of:
hydrogen, deuterium, —F, —Cl, —Br, —I, a hydroxyl group, a cyano group, a nitro group, an amidino group, a hydrazino group, a hydrazono group, a C₁-C₂₀ alkyl group, and a C₁-C₂₀ alkoxy group;
a phenyl group, a biphenyl group, a terphenyl group, a pentalenyl group, an indenyl group, a naphthyl group, an azulenyl group, an indacenyl group, an acenaphthyl group, a fluorenyl group, a spiro-bifluorenyl group, a benzofluorenyl group, a dibenzofluorenyl group, a spiro-benzofluorene-fluorenyl group, an indenofluorenyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzimidazolyl group, an isobenzothiazolyl group, a benzoxazolyl group, an isobenzoxazolyl group, a triazolyl group, a tetrazolyl group, an oxadiazolyl group, a triazinyl group, a thiadiazolyl group, an imidazopyridinyl group, an imidazopyrimidinyl group, —Si(Q₁)(Q₂)(Q₃), —N(Q₁)(Q₂), —B(Q₁)(Q₂), —C(═O)(Q₁), —S(═O)₂(Q₁), and —P(═O)(Q₁)(Q₂); and
a phenyl group, a biphenyl group, a terphenyl group, a pentalenyl group, an indenyl group, a napthyl group, an azulenyl group, an indacenyl group, an acenaphthyl group, a fluorenyl group, a spiro-bifluorenyl group, a benzofluorenyl group, a dibenzofluorenyl group, a spiro-benzofluorene-fluorenyl group, an indenofluorenyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzimidazolyl group, an isobenzothiazolyl group, a benzoxazolyl group, an isobenzoxazolyl group, a triazolyl group, a tetrazolyl group, an oxadiazolyl group, a triazinyl group, a thiadiazolyl group, an imidazopyridinyl group, and an imidazopyrimidinyl group, each substituted with at least one selected from deuterium, —F, —Cl, —Br, —I, a hydroxyl group, a cyano group, a nitro group, an amidino group, a hydrazino group, a hydrazono group, a C₁-C₁₀ alkyl group, a C₁-C₁₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, a monovalent non-aromatic condensed heteropolycyclic group, a biphenyl group, a terphenyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), and —P(═O)(Q₃₁)(Q₃₂),
R₂₁ to R₂₄, R₂₇, and R₂₈ are each independently selected from the group consisting of:
a phenyl group, a biphenyl group, a terphenyl group, a pentalenyl group, an indenyl group, a naphthyl group, an azulenyl group, an indacenyl group, an acenaphthyl group, a fluorenyl group, a spiro-bifluorenyl group, a benzofluorenyl group, a dibenzofluorenyl group, a spiro-benzofluorene-fluorenyl group, an indenofluorenyl group, a phenalenyl group, a phenanthrenyl group, an anthracenyl group, a fluoranthenyl group, a triphenylenyl group, a pyrenyl group, a chrysenyl group, a picenyl group, a perylenyl group, a pentaphenyl group, a hexacenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a dibenzosilolyl group, a thiadiazolyl group, an imidazopyridinyl group, an imidazopyrimidinyl group, —Si(Q₄)(Q₅)(Q₆), —N(Q₄)(Q₅), —B(Q₄)(Q₅), —C(═O)(Q₄), —S(═O)₂(Q₄), and —P(═O)(Q₄)(Q₅); and
a phenyl group, a biphenyl group, a terphenyl group, a pentalenyl group, an indenyl group, a naphthyl group, an azulenyl group, an indacenyl group, an acenaphthyl group, a fluorenyl group, a spiro-bifluorenyl group, a benzofluorenyl group, a dibenzofluorenyl group, a spiro-benzofluorene-fluorenyl group, an indenofluorenyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a pentacenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a dibenzosilolyl group, a thiadiazolyl group, an imidazopyridinyl group, and an imidazopyrimidinyl group, each substituted with at least one selected from deuterium, —F, —Cl, —Br, —I, a hydroxyl group, a cyano group, a nitro group, an amidino group, a hydrazino group, a hydrazono group, a C₁-C₁₀ alkyl group, a C₁-C₁₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, a monovalent non-aromatic condensed heteropolycyclic group, a biphenyl group, a terphenyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), and —P(═O)(Q₃₁)(Q₃₂), and
R₂₂ to R₂₄, R₂₇, and R₂₈ are each independently selected from hydrogen, deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, —Si(Q₄)(Q₅)(Q₆), —S(═O)₂(Q₄), and —P(═O)(Q₄)(Q₅),
wherein Q₁ to Q₆ and Q₃₁ to Q₃₃ are each independently selected from the group consisting of:
a C₁-C₁₀ alkyl group, a C₁-C₁₀ alkoxy group, a phenyl group, a biphenyl group, a terphenyl group, a naphthyl group, a pyridinyl group, a pyrimidinyl group, a pyrazinyl group, a quinolinyl group, an isoquinolinyl group, a quinoxalinyl group and a quinazolinyl group; and
a phenyl group, a biphenyl group, a terphenyl group, a naphthyl group, a pyridinyl group, a pyrimidinyl group, a pyrazinyl group, a quinolinyl group, an isoquinolinyl group, a quinoxalinyl group, and a quinazolinyl group, each substituted with at least one selected from a C₁-C₁₀ alkyl group, a C₁-C₁₀ alkoxy group, and a phenyl group.

11. The organic light-emitting device of claim 1, wherein:
the first compound is represented by one selected from Formula 1E and Formulae 1-1 to 1-6: 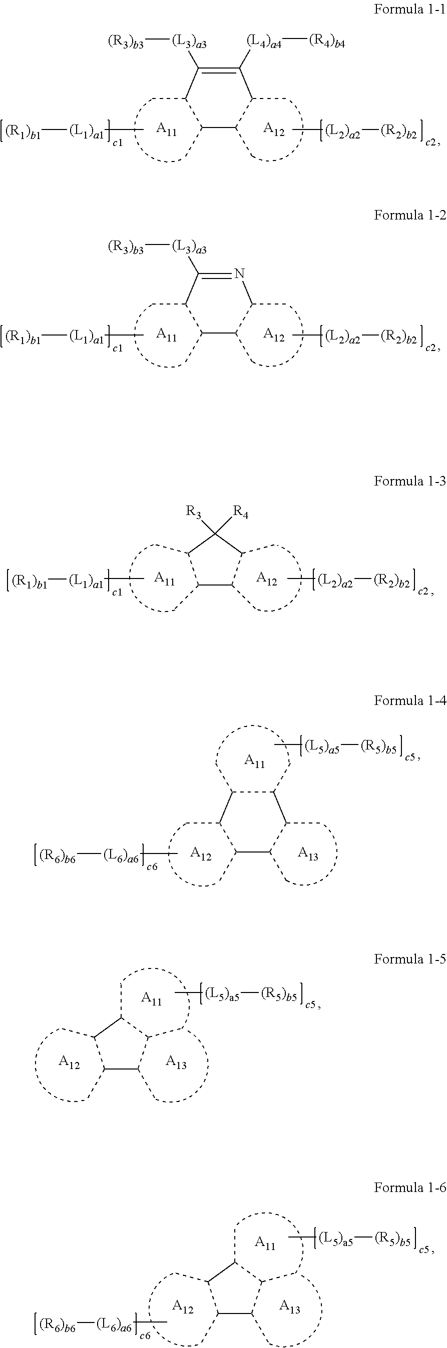
wherein Formula 1E is the same as described above,
rings A₁₁ to A₁₃, L₁ to L₆, a1 to a6, R₁ to R₆, and b1 to b6 in Formulae 1-1 to 1-6 are each independently the same as described herein in connection with Formulae 1A to 1D,
c1, c2, and c6 are each independently an integer selected from 0 to 10, and
c5 is an integer selected from 1 to 10.

12. The organic light-emitting device of claim 1, wherein the second compound has a triplet energy of 2.2 eV or more.

13. The organic light-emitting device of claim 1, wherein:
the emission layer comprises a first host and a second host, and
the first host comprises the first compound.

14. The organic light-emitting device of claim 1, wherein:
the electron transport region comprises a buffer layer,
the buffer layer directly contacts the emission layer, and
the buffer layer comprises the second compound.

15. The organic light-emitting device of claim 1, wherein the emission layer comprises a dopant, wherein the dopant is an organometallic complex.

16. The organic light-emitting device of claim 15, wherein the organometallic complex is represented by Formula 401: 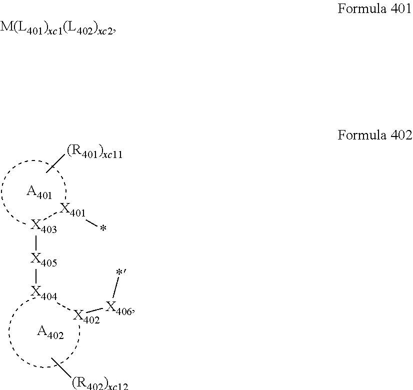
wherein, in Formulae 401 and 402,
M is selected from iridium (Ir), platinum (Pt), palladium (Pd), osmium (Os), titanium (Ti), zirconium (Zr), hafnium (Hf), europium (Eu), terbium (Tb), rhodium (Rh), and thulium (Tm),
L₄₀₁ is a ligand represented by Formula 402, xc1 is 1, 2, or 3, and when xc1 is two or more, two or more L₄₀₁(s) are identical to or different from each other,
L₄₀₂ is an organic ligand, xc2 is an integer selected from 0 to 4, and when xc2 is two or more, two or more L₄₀₂(s) are identical to or different from each other,
X₄₀₁ to X₄₀₄ are each independently nitrogen or carbon,
X₄₀₁ is linked to X₄₀₃ via a single bond or a double bond, and X₄₀₂ is linked to X₄₀₄ via a single bond or a double bond,
A₄₀₁ and A₄₀₂ are each independently a C₅-C₆₀ carbocyclic group or a C₁-C₆₀ heterocyclic group,
X₄₀₅ is a single bond, *—O—*′, *—S—*′, *—C(═O)—*′, *—N(Q₄₁₁)—*′, *—C(Q₄₁₁)(Q₄₁₂)—*′, *—C(Q₄₁₁)=C(Q₄₁₂)-*′, *—C(Q₄₁₁)=*′, or *═C(Q₄₁₁)=*′, and Q₄₁₁ and Q₄₁₂ are each independently hydrogen, deuterium, a C₁-C₂₀ alkyl group, a C₁-C₂₀ alkoxy group, a phenyl group, a biphenyl group, a terphenyl group, or a naphthyl group,
X₄₀₆ is a single bond, O, or S, and
R₄₀₁ and R₄₀₂ are each independently selected from hydrogen, deuterium, —F, —Cl, —Br, —I, —CD₃, —CF₃, a hydroxyl group, a cyano group, a nitro group, an amidino group, a hydrazino group, a hydrazono group, a substituted or unsubstituted C₁-C₂₀ alkyl group, a substituted or unsubstituted C₁-C₂₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group and a substituted or unsubstituted monovalent non-aromatic condensed heteropolycyclic group —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), and —P(═O)(Q₄₀₁)(Q₄₀₂), wherein Q₄₀₁ to Q₄₀₃ are each independently selected from a C₁-C₁₀ alkyl group, a C₁-C₁₀ alkoxy group, a C₆-C₂₀ aryl group, and a C₁-C₂₀ heteroaryl group,
xc11 and xc12 are each independently an integer selected from 0 to 10, and
* and *′ in Formula 402 each independently indicate a binding site to M in Formula 401.

17. The organic light-emitting device of claim 1, wherein:
the electron transport region comprises a buffer layer, an electron transport layer, and an electron injection layer, and
at least one selected from the electron transport layer and the electron injection layer comprises an alkali metal, an alkaline earth metal, a rare earth metal, an alkali metal compound, an alkaline earth metal compound, a rare earth metal compound, an alkali metal complex, an alkaline earth metal complex, a rare earth metal complex, or a combination thereof.

18. The organic light-emitting device of claim 1, wherein:
the hole transport region comprises a p-dopant, and
the p-dopant has a lowest unoccupied molecular orbital (LUMO) of −3.5 eV or less.

19. The organic light-emitting device of claim 18, wherein the p-dopant comprises a cyano group-containing compound.

20. The organic light-emitting device of claim 1, wherein:
the emission layer comprises a first-color-light emitting-emission layer,
the organic light-emitting device further comprises i) at least one second-color-light emitting-emission layer or ii) at least one second-color-light emitting-emission layer and at least one third-color-light emitting-emission layer, each between the first electrode and the second electrode,
a maximum emission wavelength of the first-color-light emitting-emission layer, a maximum emission wavelength of the second-color-light emitting-emission layer, and a maximum emission wavelength of the third-color-light emitting-emission layer are identical to or different from each other, and
the organic light-emitting device emits a mixed light including a first-color-light and a second-color-light, or a mixed light including the first-color-light, the second-color-light, and a third-color-light.
